(19) United States
(12) Patent Application Publication
(10) Pub. No.: US 2025/0351720 A1
(43) Pub. Date: Nov. 13, 2025

(54) ORGANIC COMPOUND, ORGANIC ELECTROLUMINESCENT DEVICE, AND ELECTRONIC APPARATUS

(71) Applicant: SHAANXI LIGHTE OPTOELECTRONICS MATERIAL CO., LTD., Xi'an, Shaanxi (CN)

(72) Inventors: Xianbin XU, Xi'an, Shaanxi (CN); Youngkook KIM, Xi'an, Shaanxi (CN); Lei YANG, Xi'an, Shaanxi (CN)

(21) Appl. No.: 18/871,620

(22) PCT Filed: Sep. 22, 2023
(86) PCT No.: PCT/CN2023/120868

§ 371 Date: Dec. 4, 2024

(30) Foreign Application Priority Data
Jan. 16, 2023 (CN) 202310065095.4

(51) Int. Cl. H10K 85/40; C07B 59/00; C07F 7/08; C09K 11/02; H10K 50/11; H10K 85/60

(52) U.S. Cl. CPC H10K 85/40; C07B 59/004; C07F 7/0816; C09K 11/02; H10K 85/6572; H10K 85/6574; H10K 85/6576; C07B 2200/05; H10K 50/11

(57) ABSTRACT

The present application relates to the technical field of organic electroluminescent materials, and provides an organic compound, an organic electroluminescent device comprising same, and an electronic apparatus. According to the compound of the present application, silafluorenyl and carbazole are used as a core structure of the compound, and when the compound of the present application is used as the host material of an organic light-emitting layer, the charge carrier balance in the organic light-emitting layer can be improved, a charge carrier recombination area is widened, the exciton generation and utilization efficiency is improved, the light emitting efficiency of a device is improved, and the service life of the device is prolonged.

### CROSS-REFERENCE TO RELATED APPLICATIONS

This present disclosure claims the priority of Chinese patent application No. 2023100650954 filed on Jan. 16, 2023, which is incorporated herein by reference in its entirety as a part of this disclosure.

### FIELD OF THE INVENTION

The present disclosure relates to the technical field of organic electroluminescent materials, in particular to an organic compound, and an organic electroluminescent device comprising same and an electronic apparatus.

### BACKGROUND OF THE INVENTION

With the development of electronic technology and the progress of material science, the application range of electronic components and devices used to realize electroluminescence or photoelectric conversion is increasingly extensive. An organic electroluminescent device (OLED) usually comprises a cathode and an anode disposed opposite to each other, and a functional layer disposed between the cathode and the anode. The functional layer is composed of multiple organic or inorganic film layers, and generally includes an organic light-emitting layer, a hole transport layer, an electron transport layer, etc. When a voltage is applied to the cathode and the anode, an electric field is generated between the two electrodes. Under the influence of the electric field, electrons on the cathode side move towards the electroluminescent layer, and holes on the anode side also move towards the light-emitting layer. Electrons and holes combine in the electroluminescent layer to form excitons, which are in an excited state and release energy outward, thereby causing the electroluminescent layer to emit light externally.

In existing organic electroluminescent devices, the most important problems are service life and efficiency. With the large-area display trend, the driving voltage has been correspondingly increased, and enhancements in luminous efficiency and current efficiency are also requisite. Therefore, there is a necessity for the continued development of novel materials to further improve the performance of organic electroluminescent devices.

### SUMMARY OF THE INVENTION

Against the above problem in the existing technology, the objective of the present disclosure is to provide an organic compound, an organic electroluminescent device comprising same, and an electronic apparatus. The organic compound, when utilized in the organic electroluminescent device, can improve the performance of the device.

According to a first aspect of the present disclosure, there is provided an organic compound having a structure represented by Formula 1 as follows:

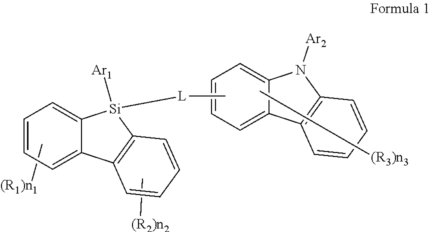

wherein Ar₁ and Ar₂ are the same or different, and are each independently selected from a substituted or unsubstituted aryl having 6 to 40 carbon atoms, and a substituted or unsubstituted heteroaryl having 3 to 40 carbon atoms;
L is a substituted or unsubstituted heteroarylene having 3 to 30 carbon atoms;
each R₁, R₂, and R₃ are the same or different, and are each independently selected from a deuterium, a cyano, a halogen group, an alkyl having 1 to 10 carbon atoms, a haloalkyl having 1 to 10 carbon atoms, a deuterated alkyl having 1 to 10 carbon atoms, a trialkylsilyl having 3 to 12 carbon atoms, a triphenylsilyl, an aryl having 6 to 20 carbon atoms, a deuterated aryl having 6 to 20 carbon atoms, a haloaryl having 6 to 20 carbon atoms, a heteroaryl having 3 to 20 carbon atoms, and a cycloalkyl having 3 to 10 carbon atoms;
n₁ is selected from 0, 1, 2, 3, and 4;
n₂ is selected from 0, 1, 2, 3, and 4;
n₃ is selected from 0, 1, 2, 3, 4, 5, 6, and 7;
substituent(s) in L, Ar₁, and Ar₂ are the same or different, and are each independently selected from a deuterium, a cyano, a halogen group, an alkyl having 1 to 10 carbon atoms, a haloalkyl having 1 to 10 carbon atoms, a deuterated alkyl having 1 to 10 carbon atoms, a trialkylsilyl having 3 to 12 carbon atoms, a triphenylsilyl, an aryl having 6 to 20 carbon atoms, a deuterated aryl having 6 to 20 carbon atoms, a haloaryl having 6 to 20 carbon atoms, a heteroaryl having 3 to 20 carbon atoms, and a cycloalkyl having 3 to 10 carbon atoms; optionally, any two adjacent substituents in Ar₂ form a ring.

According to a second aspect of the present disclosure, there is provided an organic electroluminescent device, comprising an anode and a cathode disposed opposite to each other, and a functional layer disposed between the anode and the cathode; the functional layer comprises the organic compound as described above.

According to a third aspect of the present disclosure, there is provided an electronic apparatus, comprising the organic electroluminescent device described in the second aspect.

In the structure of the compound of the present disclosure, the parent nucleus containing a silafluorenyl is connected to carbazole via a dibenzo-penta-membered ring, wherein the parent nucleus of the silafluorenyl and the two substituents at the position 9 are situated on three distinct planes, resulting in a significant molecular distortion. This endows the compound with a higher glass transition temperature, enabling the formation of a superior amorphous thin film. Particularly, when silafluorenyl and carbazole are connected by a dibenzo-penta-membered heterocyclic ring, the entire molecule is endowed with a higher first excited triplet energy level. When the compound of the present disclosure is used as a hole-transporting type material in a hybrid blue light host material, on one hand, the compound's higher first excited triplet energy level can improve the efficiency of energy transfer from the host material to the blue light doping material, thereby enhancing the luminous efficiency of the device; on the other hand, the compound's higher glass transition temperature can ensure that the light-emitting layer forms a good amorphous thin film, and the film morphology does not change during the long-term operation of the device, thus improving the service life of the device.

### BRIEF DESCRIPTION OF THE DRAWINGS

The drawings are used for a further understanding of the present disclosure and constitute a part of the specification and are used to explain the present disclosure together with the following detailed description, but do not constitute a limitation of the present disclosure.

FIG. 1 is a schematic structural diagram of an organic electroluminescent device according to one embodiment of the present disclosure.

FIG. 2 is a schematic structural diagram of an electronic apparatus according to one embodiment of the present disclosure.

### REFERENCE SIGNS

100: Anode 200: Cathode 300: Functional layer 310: Hole injection layer 321: Hole transport layer 322: Electron blocking layer 330: Organic light-emitting layer 340: Electron transport layer 350: Electron injection layer 400: Electronic apparatus

### DETAILED DESCRIPTION OF THE EMBODIMENTS

Exemplary embodiments will now be described more comprehensively with reference to the accompanying drawings. The exemplary embodiments, however, can be implemented in a variety of forms and should not be interpreted as being limited to the examples set forth herein. On the contrary, these embodiments are provided to make the present disclosure more comprehensive and complete, and to convey the concepts of these exemplary embodiments fully to those skill in the art. Features, structures, or characteristics described herein can be combined in one or more embodiment(s) in any suitable manner. In the following description, many specific details are provided to give a full understanding of the examples of the present disclosure.

In a first aspect, the present disclosure provides an organic compound having a structure represented by Formula 1 as follows:

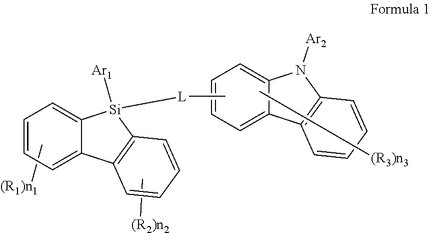

wherein Ar₁ and Ar₂ are the same or different, and are each independently selected from a substituted or unsubstituted aryl having 6 to 40 carbon atoms, and a substituted or unsubstituted heteroaryl having 3 to 40 carbon atoms;
L is selected from a substituted or unsubstituted heteroarylene having 3 to 30 carbon atoms;
each R₁, R₂, and R₃ are the same or different, and are each independently selected from a deuterium, a cyano, a halogen group, an alkyl having 1 to 10 carbon atoms, a haloalkyl having 1 to 10 carbon atoms, a deuterated alkyl having 1 to 10 carbon atoms, a trialkylsilyl having 3 to 12 carbon atoms, a triphenylsilyl, an aryl having 6 to 20 carbon atoms, a deuterated aryl having 6 to 20 carbon atoms, a haloaryl having 6 to 20 carbon atoms, a heteroaryl having 3 to 20 carbon atoms, and a cycloalkyl having 3 to 10 carbon atoms;
n₁ is selected from 0, 1, 2, 3, and 4;
n₂ is selected from 0, 1, 2, 3, and 4;
n₃ is selected from 0, 1, 2, 3, 4, 5, 6, and 7;
substituent(s) in L, Ar₁, and Ar₂ are the same or different, and are each independently selected from a deuterium, a cyano, a halogen group, an alkyl having 1 to 10 carbon atoms, a haloalkyl having 1 to 10 carbon atoms, a deuterated alkyl having 1 to 10 carbon atoms, a trialkylsilyl having 3 to 12 carbon atoms, a triphenylsilyl, an aryl having 6 to 20 carbon atoms, a deuterated aryl having 6 to 20 carbon atoms, a haloaryl having 6 to 20 carbon atoms, a heteroaryl having 3 to 20 carbon atoms, and a cycloalkyl having 3 to 10 carbon atoms; optionally, any two adjacent substituents in Ar₂ form a ring.

In the present disclosure, the terms “optional” and “optionally” mean that the subsequently described event or circumstance may or may not occur. For example, “optionally, any two adjacent substituents form a ring” means that these two substituents may or may not form a ring, including scenarios both where two adjacent substituents form a ring and where two adjacent substituents do not form a ring. For example, “optionally, any two adjacent substituents in Ar₂ form a ring” means that any two adjacent substituents in Ar₂ can be interconnected to form a ring, or any two adjacent substituents in Ar₂ can exist independently of each other. “Any two adjacent” can include having two substituents on the same atom, and can also include having one substituent on each of adjacent atoms; among them, when there are two substituents on the same atom, the two substituents can form a saturated or unsaturated spiro-ring with the atom they are connected to together; when two adjacent atoms each have a substituent, these two substituents can be fused into a ring.

In the present disclosure, the descriptive expressions “each . . . be independently” and “ . . . be independently” and “be . . . each independently” can be interchanged and all these expressions should be interpreted in a broad sense. They can both refer to specific options expressed by the same symbol in different groups are mutually non-influential, and to specific options expressed by the same symbols within the same group are mutually non-influential. For example,

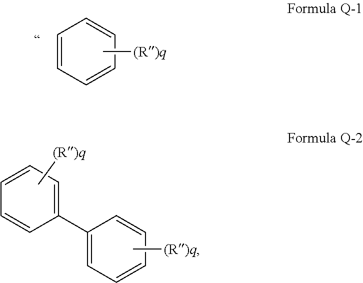

wherein each q is independently 0, 1, 2, or 3, and each R″ is independently selected from a hydrogen, a deuterium, a fluorine, and a chlorine″ means that the benzene ring represented by Formula Q-1 has q substituents R″, and each R″ may be the same or different, with mutual non-influence between the options for each R″; and that each of benzene rings of the biphenyl represented by Formula Q-2 has q substituents R″, and the number q of R″ on each of the two benzene rings may be the same or different and each R″ may be the same or different, with mutual non-influence between the options for each R″.

In the present disclosure, the term “substituted or unsubstituted” means that the functional group defined by the term may or may not have a substituent (hereinafter referred to as Rc for ease of description). For example, “a substituted or unsubstituted aryl” refers to an aryl having a substituent Rc or an unsubstituted aryl. Among them, the above substituent, i.e., Rc, may be, for example, a deuterium, a halogen group, a cyano, a heteroaryl, an aryl, a trialkylsilyl, an alkyl, a haloalkyl, a deuterated alkyl, a deuterated aryl, a haloaryl, or a cycloalkyl, etc. The number of substituents may be one or more.

In the present disclosure, “more” refers to two or more, such as 2, 3, 4, 5, or 6, etc.

In the structure of the compound of the present disclosure, a hydrogen atom includes various isotopic atoms of the hydrogen element, such as hydrogen (H), deuterium (D), or tritium (T).

In the present disclosure, the number of carbon atoms of a substituted or unsubstituted functional group refers to the total number of carbon atoms. For example, if L is a substituted arylene having 12 carbon atoms, the total number of carbon atoms in the arylene and its substituents is 12.

In the present disclosure, an aryl refers to an optional functional group or a substituent derived from an aromatic carbon ring. An aryl may be a monocyclic aryl (e.g., phenyl) or a polycyclic aryl. In other words, an aryl may be a monocyclic aryl, a fused-ring aryl, two or more monocyclic aryls linked by carbon-carbon single bond, a monocyclic aryl and a fused-ring aryl linked by carbon-carbon single bond, or two or more fused-ring aryls linked by carbon-carbon single bond. That is, unless otherwise specified, two or more aromatic groups linked by carbon-carbon single bond may also be regarded as an aryl in the present disclosure. Among them, a fused-ring aryl may include, for example, a bicyclic fused aryl (e.g., naphthyl), a tricyclic fused aryl (e.g., phenanthryl, fluorenyl, and anthryl), etc. The aryl does not contain heteroatoms such as B, N, O, S, P, Se, and Si. Examples of an aryl may include, but not limited to, a phenyl, a naphthyl, a fluorenyl, a phenyl-naphthyl, a spirobifluorenyl, an anthryl, a phenanthryl, a biphenyl, a terphenyl, a triphenylene, a perylenyl, a benzo[9,10]phenanthryl, a pyrenyl, a benzofluoranthryl, or a chrysenyl, etc.

In the present disclosure, “an arylene” involved refers to a divalent or multivalent group formed by further removing one or more hydrogen atom(s) from an aryl.

In the present disclosure, a terphenyl includes

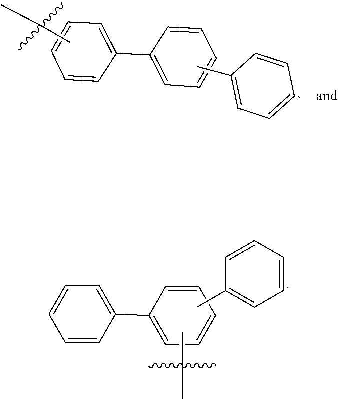

In the present disclosure, the number of carbon atoms in a substituted aryl refers to the total number of carbon atoms of an aryl and the substituents on the aryl. For example, a substituted aryl having 18 carbon atoms, refers to the total number of carbon atoms of the aryl and the substituents thereof is 18.

In the present disclosure, the number of carbon atoms of a substituted or unsubstituted aryl (arylene) may be 6, 8, 10, 12, 13, 14, 15, 16, 17, 18, 19, 20, 21, 22, 23, 24, 25, 26, 28, 30, 31, 33, 34, 35, 36, 38, or 40, etc. In some embodiments, a substituted or unsubstituted aryl is a substituted or unsubstituted aryl having 6 to 40 carbon atoms; in other embodiments, a substituted or unsubstituted aryl is a substituted or unsubstituted aryl having 6 to 30 carbon atoms; in other embodiments, a substituted or unsubstituted aryl is a substituted or unsubstituted aryl having 6 to 25 carbon atoms; and in other embodiments, a substituted or unsubstituted aryl is a substituted or unsubstituted aryl having 6 to 15 carbon atoms.

In the present disclosure, a fluorenyl may be substituted by one or more substituent(s). In the case that the above-mentioned fluorenyl is substituted, the substituted fluorenyl may be:

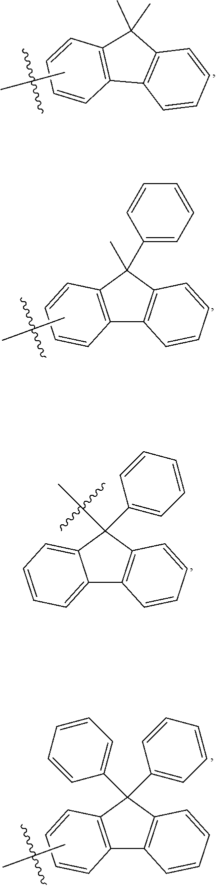

etc, but are not limited thereto.

In the present disclosure, an aryl as a substituent of L, Ar₁ and Ar₂ is, for example, but not limited to, a phenyl, a naphthyl, a phenanthryl, a biphenyl, a fluorenyl, a dimethylfluorenyl, etc.

In the present disclosure, “a heteroaryl” refers to a monovalent aromatic ring containing 1, 2, 3, 4, 5, or 6 heteroatoms or a derivative thereof. The heteroatoms may be one or more selected from B, O, N, P, Si, Se, and S. A heteroaryl may be a monocyclic heteroaryl or a polycyclic heteroaryl. In other words, a heteroaryl may be a single aromatic ring system, or multiple aromatic ring systems linked by carbon-carbon single bond, with any of the aromatic ring systems being an aromatic monocyclic ring or a fused aromatic ring. For example, a heteroaryl may include, thienyl, furyl, pyrrolyl, imidazolyl, thiazolyl, oxazolyl, oxadiazolyl, triazolyl, pyridyl, dipyridyl, pyrimidinyl, triazinyl, acridinyl, pyridazinyl, pyrazinyl, quinolyl, quinazolinyl, quinoxalinyl, phenoxazinyl, phthalazinyl, pyridopyrimidinyl, pyridopyrazinyl, pyrazinopyrazinyl, isoquinolyl, indolyl, carbazolyl, benzoxazolyl, benzimidazolyl, benzothiazolyl, benzocarbazolyl, benzothienyl, dibenzothienyl, thienothienyl, benzofuranyl, phenanthrolinyl, isoxazolyl, thiadiazolyl, phenothiazinyl, silafluorenyl, dibenzofuranyl, etc, but not limited thereto.

In the present disclosure, “a heteroarylene” involved refers to a divalent or multivalent group formed by further removing one or more hydrogen atom(s) from a heteroaryl.

In the present disclosure, the number of carbon atoms of a substituted or unsubstituted heteroaryl (heteroarylene) may be selected from 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, or 40, etc. In some embodiments, a substituted or unsubstituted heteroaryl is a substituted or unsubstituted heteroaryl having 3 to 40 carbon atoms; in other embodiments, a substituted or unsubstituted heteroaryl is a substituted or unsubstituted heteroaryl having 3 to 30 carbon atoms; and in other embodiments, a substituted or unsubstituted heteroaryl is a substituted or unsubstituted heteroaryl having 5 to 12 carbon atoms.

In the present disclosure, a heteroaryl as the substituent of L, Ar₁, and Ar₂ is for example, but not limited to a pyridyl, a carbazolyl, a quinolyl, an isoquinolyl, a phenanthrolinyl, a benzoxazolyl, a benzothiazolyl, a benzimidazolyl, a dibenzothienyl, and a dibenzofuranyl.

In the present disclosure, a substituted heteroaryl may mean that one or more than two hydrogen atom(s) in the heteroaryl are replaced by a group such as a deuterium atom, a halogen group, a cyano, an aryl, a heteroaryl, a trialkylsilyl, an alkyl, a cycloalkyl, and a haloalkyl. It should be understood that the number of carbon atoms in the substituted heteroaryl refers to the total number of carbon atoms in the heteroaryl and the substituents thereon.

In the present disclosure, an alkyl having 1 to 10 carbon atoms may include a straight-chain alkyl having 1 to 10 carbon atoms, and a branched alkyl having 3 to 10 carbon atoms. The number of carbon atoms of an alkyl is for example 1, 2, 3, 4, 5, 6, 7, 8, 9, or 10, and the specific examples of the alkyl include but are not limited to, a methyl, an ethyl, a n-propyl, an isopropyl, a n-butyl, an isobutyl, a tert-butyl, a n-pentyl, an isopentyl, a neopentyl, a n-hexyl, etc.

In the present disclosure, a halogen group is for example, a fluorine, a chlorine, a bromine, or an iodine.

In the present disclosure, the specific examples of a trialkylsilyl include, but are not limited to, a trimethylsilyl, a triethylsilyl, etc.

In the present disclosure, the specific examples of a haloalkyl include, but are not limited to, a trifluoromethyl.

In the present disclosure, the specific examples of a deuterated alkyl include, but are not limited to, a trideuterated methyl.

In the present disclosure, a deuterated aryl refers to an aryl containing a deuterium substitution, and is for example, but not limited to a deuterated phenyl, a deuterated naphthyl, a deuterated biphenyl, etc.

In the present disclosure, a haloaryl refers to an aryl with a halogen substituent, and is, for example, but not limited to a fluorophenyl, a fluoronaphthyl, a fluorobiphenyl, etc.

In the present disclosure, the number of carbon atoms of a cycloalkyl having 3 to 10 carbon atoms is, for example, 3, 4, 5, 6, 7, 8, or 10. The specific examples of a cycloalkyl include, but are not limited to, a cyclopentyl, a cyclohexyl, an adamantyl, etc.

In the present disclosure, a non-positioned bond involves a single bond “ [symbol] ” extending from the ring system, which represents that one end of the connection bond can connect to any position in the ring system through which the bond passes, and the other end connects to the rest of the compound molecule. For example, as shown in Formula (f) below, the naphthyl represented by Formula (f) is connected to other positions of the molecule through two non-positioned bonds passing through the two rings, which indicates any of possible connection forms shown in Formulae (f-1) to (f-10):

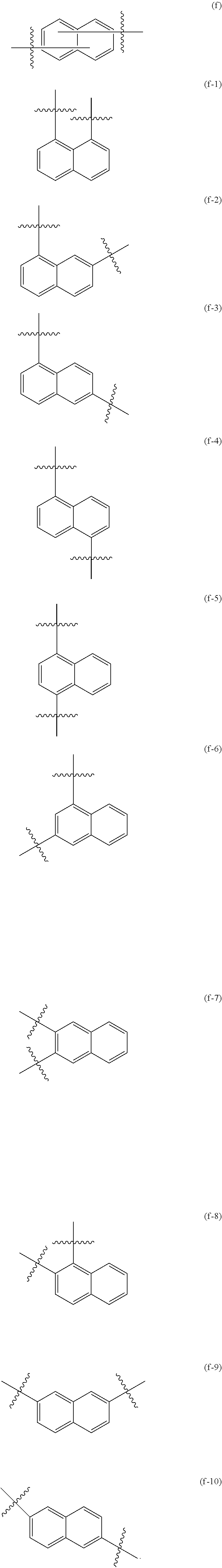

As another example, as shown in Formula (X′) below, the dibenzofuranyl represented by Formula (X′) is connected to other positions of the molecule via a non-positioned connection bond extending from the center of a side benzene ring, which indicates any of possible connection forms shown in Formulae (X′-1) to (X′-4):

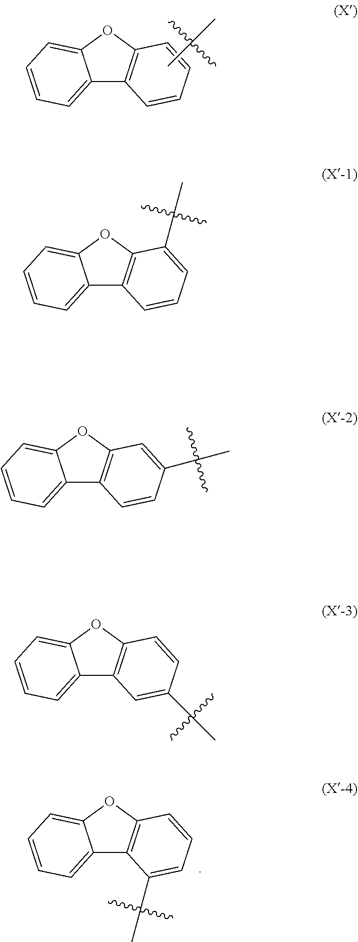

The non-positioned substituent in the present disclosure refers to a substituent connected by a single bond extending from the center of the ring system, indicating that the substituent can be connected to any possible position in the ring system. For example, as represented by Formula (Y) below, the substituent R′ represented by Formula (Y) is linked to a quinoline ring via a non-positioned connection bond, which indicates any of possible connecting mode shown in Formulae (Y-1) to (Y-7):

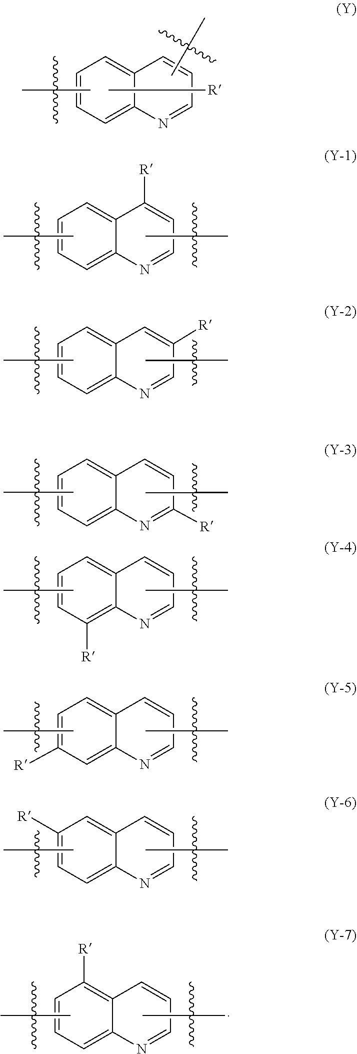

In some embodiments, the organic compound is selected from the structure represented by the following Formula (1-1), (1-2), or (1-3):

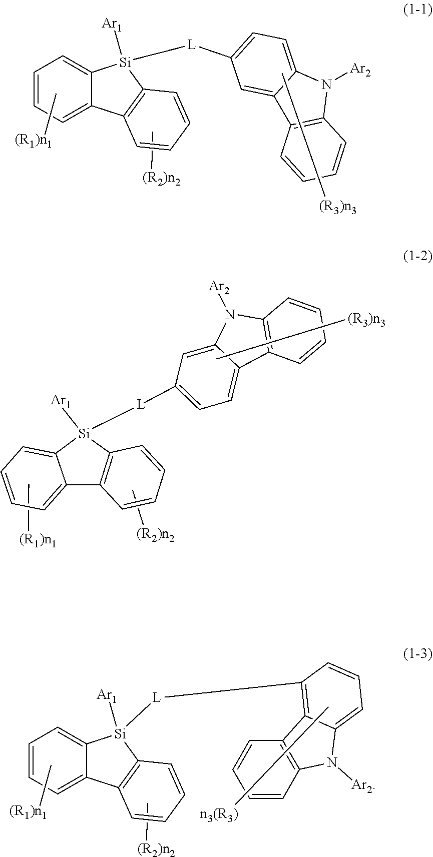

In some embodiments, Ar₂ is selected from a substituted or unsubstituted aryl having 6 to 25 carbon atoms, and a substituted or unsubstituted heteroaryl having 5 to 18 carbon atoms.

In some embodiments, Ar₂ is selected from a substituted or unsubstituted aryl having 6, 7, 8, 9, 10, 11, 12, 13, 14, 15, 16, 17, 18, 19, 20, 21, 22, 23, 24, or 25 carbon atoms, and a substituted or unsubstituted heteroaryl having 5, 6, 7, 8, 9, 10, 11, 12, 13, 14, 15, 16, 17, or 18 carbon atoms.

In some embodiments, substituent(s) in Ar₂ are each independently selected from a deuterium, a halogen group, a cyano, a haloalkyl having 1 to 4 carbon atoms, a deuterated alkyl having 1 to 4 carbon atoms, an alkyl having 1 to 4 carbon atoms, a cycloalkyl having 5 to 10 carbon atoms, an aryl having 6 to 15 carbon atoms, a deuterated aryl having 6 to 12 carbon atoms, a heteroaryl having 5 to 12 carbon atoms, and a trialkylsilyl having 3 to 8 carbon atoms; optionally, any two adjacent substituents in Ar₂ form a 5 to 13 membered ring.

In some embodiments, Ar₂ is selected from a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted phenanthryl, a substituted or unsubstituted anthryl, a substituted or unsubstituted pyrenyl, a substituted or unsubstituted triphenylene, a substituted or unsubstituted spirobifluorenyl, a substituted or unsubstituted dibenzofuranyl, a substituted or unsubstituted dibenzothienyl, and a substituted or unsubstituted carbazolyl.

Optionally, substituent(s) in Ar₂ are each independently selected from a deuterium, a fluorine, a cyano, a trimethylsilyl, a trideuterated methyl, a trifluoromethyl, a cyclopentyl, a cyclohexyl, a methyl, an ethyl, an isopropyl, a tert-butyl, a phenyl, a pentadeuterated phenyl, a naphthyl, a biphenyl, a 9,9-dimethylfluorenyl, a phenanthryl, a dibenzofuranyl, a dibenzothienyl and a carbazolyl; optionally, any two adjacent substituents in Ar₂ form a benzene ring or a fluorene ring.

In some embodiments, Ar₂ is selected from a substituted or unsubstituted group V; wherein the unsubstituted group V is selected from the following groups:

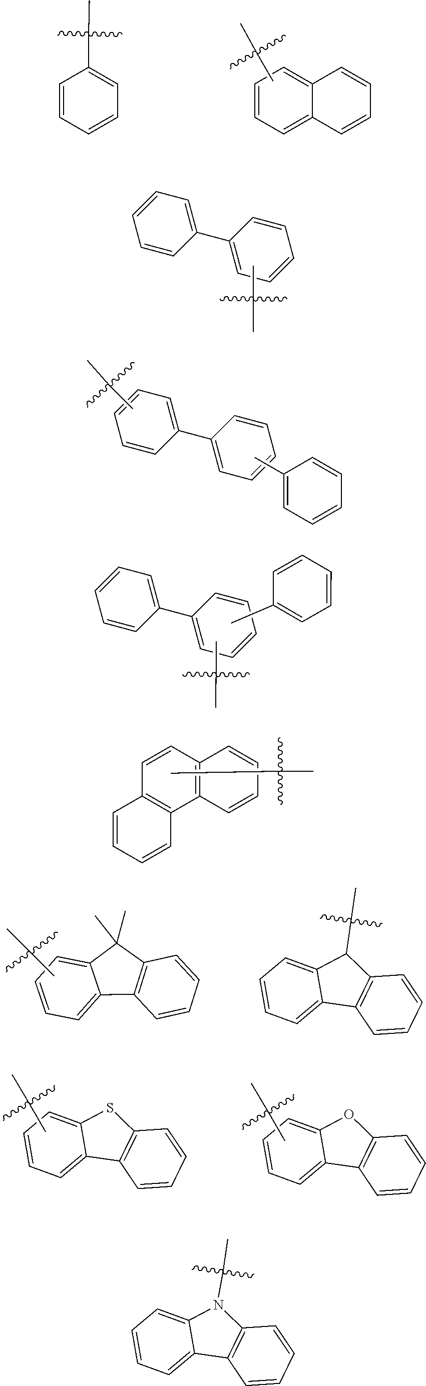

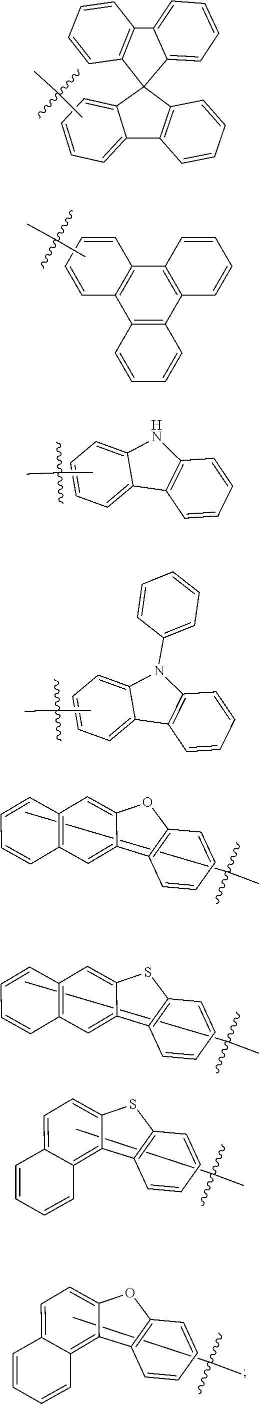

the substituted group V has one or more substituent(s), and the substituent(s) are each independently selected from a deuterium, a fluorine, a cyano, a trimethylsilyl, a trideuterated methyl, a trifluoromethyl, a cyclopentyl, a cyclohexyl, a methyl, an ethyl, an isopropyl, a tert-butyl, a phenyl, a naphthyl, a biphenyl, a fluorenyl, a 9,9-dimethylfluorenyl, a phenanthryl, a dibenzofuranyl, a dibenzothienyl, and a carbazolyl, and when the number of substituents on the group V is greater than 1, the substituents are the same or different.

In some embodiments, Ar₂ is selected from the group consisting of the following groups:

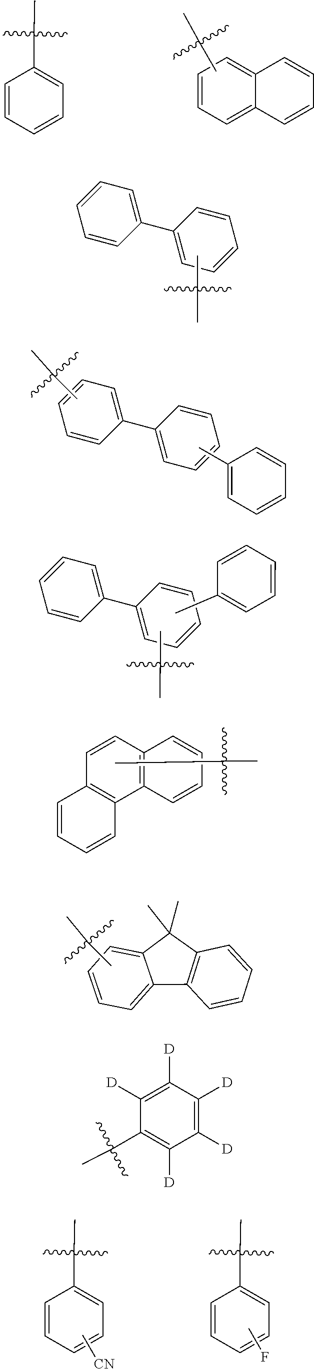

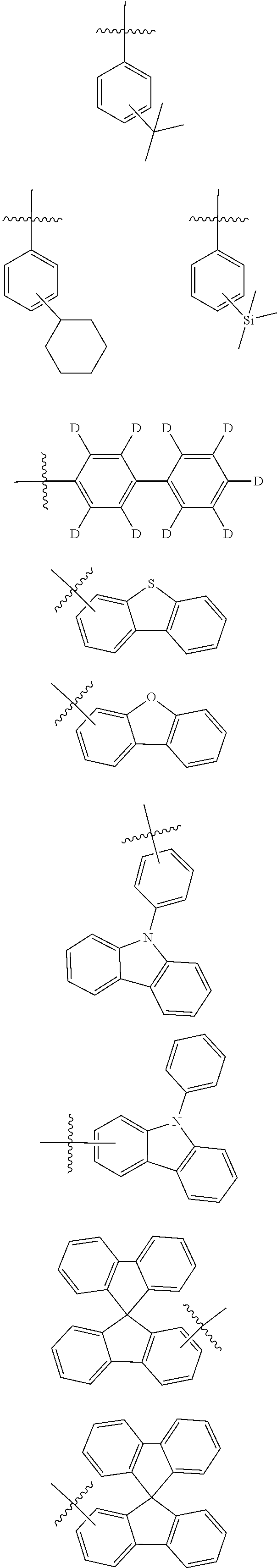

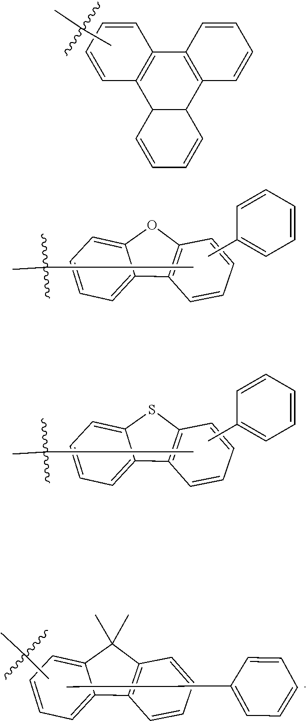

In some embodiments, Ar₂ is selected from the group consisting of the following groups:

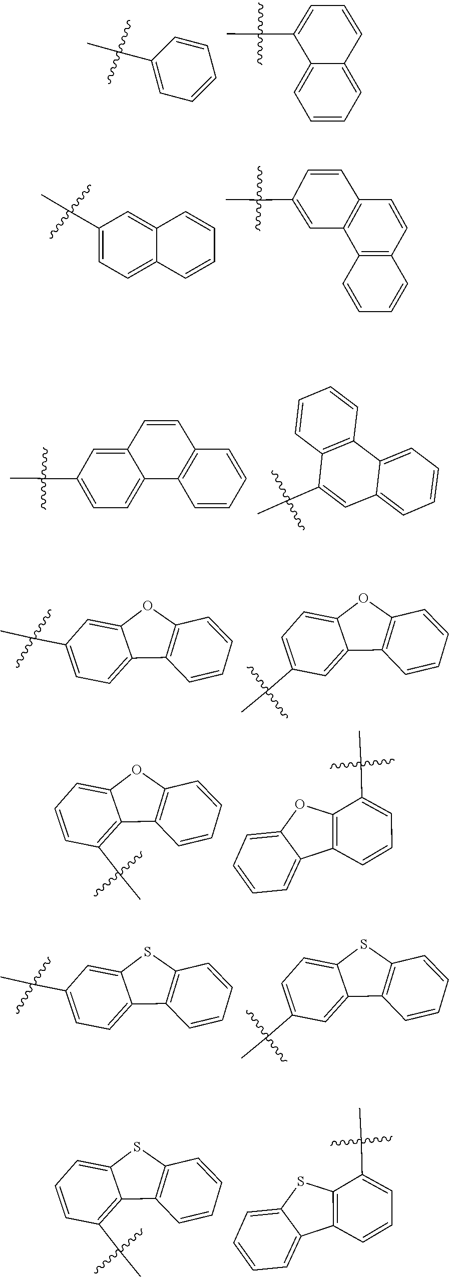

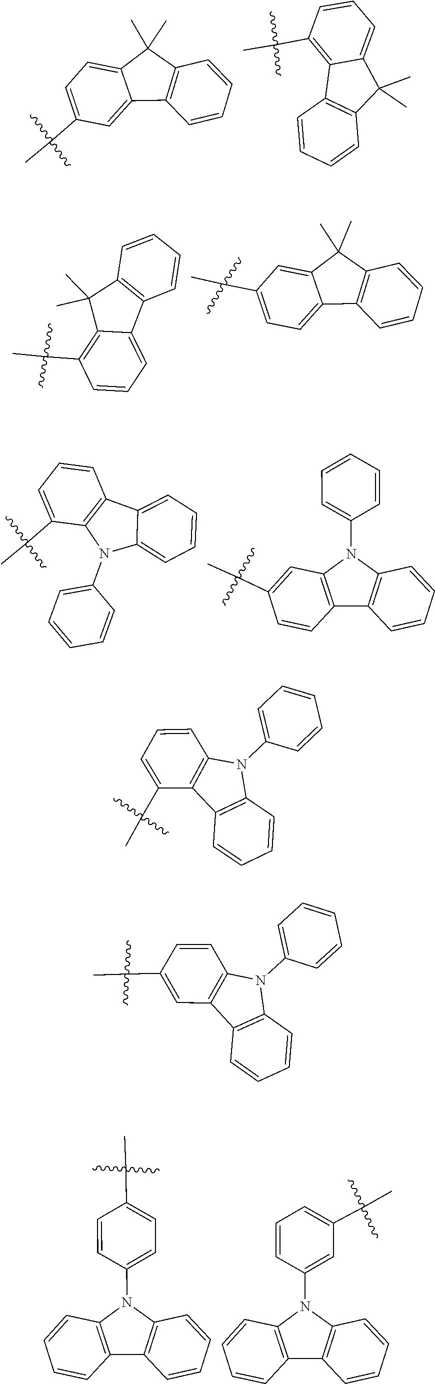

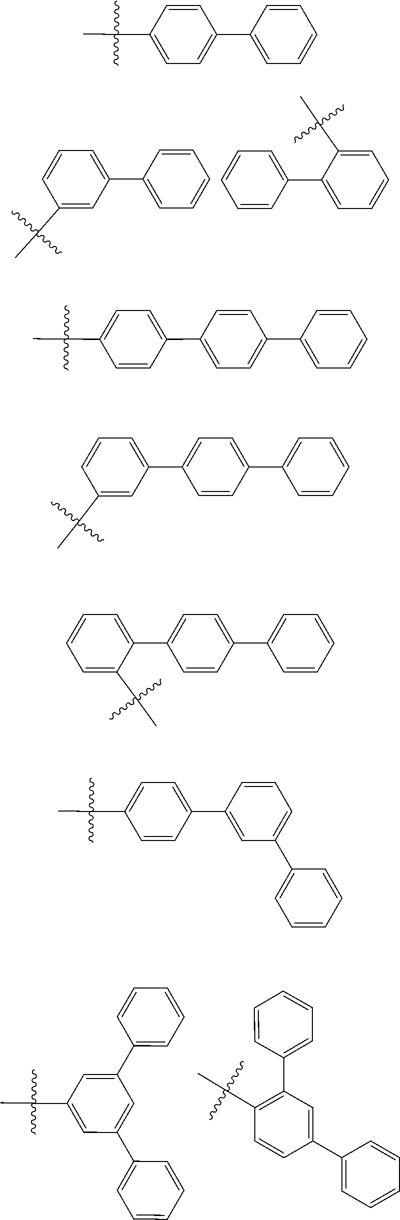

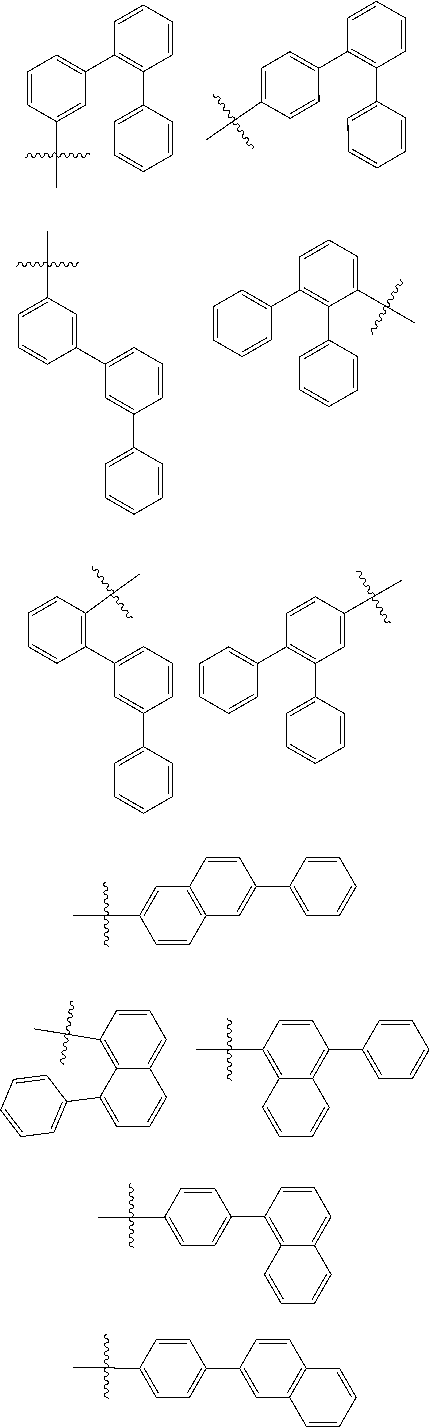

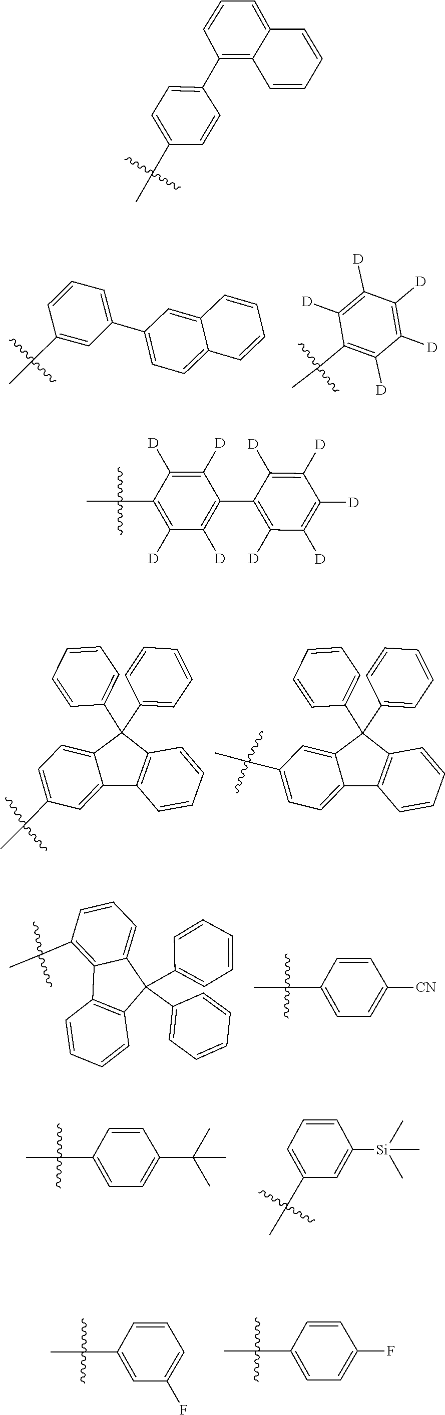

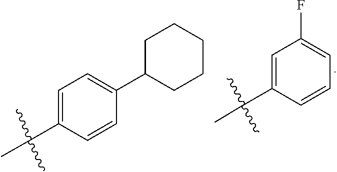 [SMILES: *c1ccc(C2CCCCC2)cc1 ; *c1cccc(F)c1]

In some embodiments, Ar₁ is selected from a substituted or unsubstituted aryl having 6 to 21 carbon atoms, and a substituted or unsubstituted heteroaryl having 12 to 18 carbon atoms.

In some embodiments, Ar₁ is selected from a substituted or unsubstituted aryl having 6, 7, 8, 9, 10, 11, 12, 13, 14, 15, 16, 17, 18, 19, 20, or 21 carbon atoms, and a substituted or unsubstituted heteroaryl having 12, 13, 14, 15, 16, 17, or 18 carbon atoms.

In some embodiments, substituent(s) in Ar₁ are each independently selected from a deuterium, a halogen group, a cyano, a haloalkyl having 1 to 4 carbon atoms, a deuterated alkyl having 1 to 4 carbon atoms, an alkyl having 1 to 4 carbon atoms, a cycloalkyl having 5 to 10 carbon atoms, an aryl having 6 to 12 carbon atoms, a deuterated aryl having 6 to 12 carbon atoms, a heteroaryl having 5 to 12 carbon atoms, and a trialkylsilyl having 3 to 8 carbon atoms.

In some embodiments, Ar₁ is selected from a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted phenanthryl, a substituted or unsubstituted anthryl, a substituted or unsubstituted pyrenyl, a substituted or unsubstituted triphenylene, a substituted or unsubstituted dibenzofuranyl, a substituted or unsubstituted dibenzothienyl, and a substituted or unsubstituted carbazolyl.

Optionally, substituent(s) in Ar₁ are each independently selected from a deuterium, a fluorine, a cyano, a trimethylsilyl, a trideuterated methyl, a trifluoromethyl, a cyclopentyl, a cyclohexyl, a methyl, an ethyl, an isopropyl, a tert-butyl, a carbazolyl, a dibenzothienyl, a dibenzofuranyl, a phenyl, a pentadeuterated phenyl, and a naphthyl.

In some embodiments, Ar₁ is selected from the group consisting of the following groups:

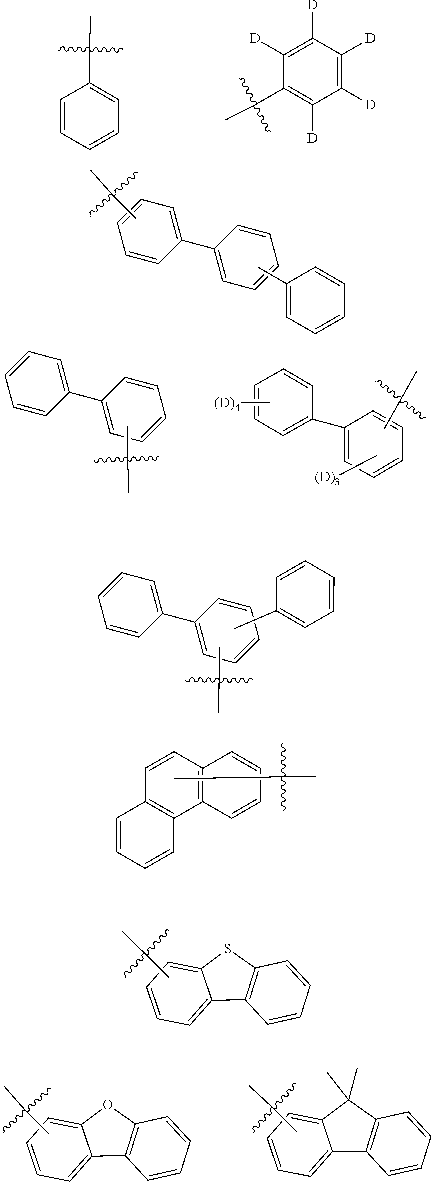

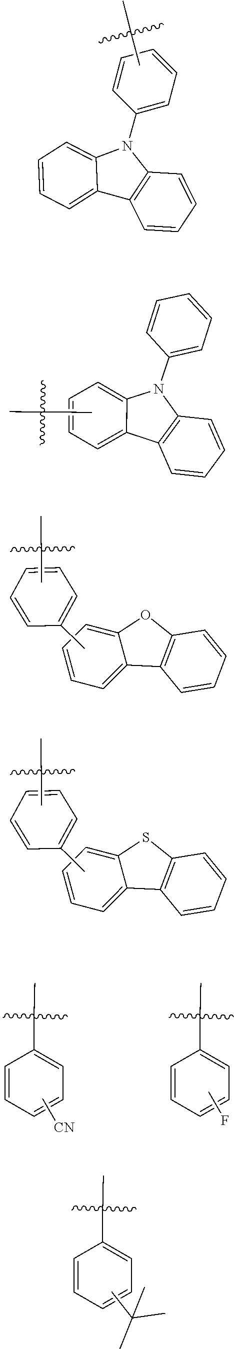

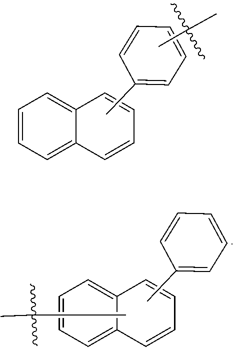

In some embodiments, Ar₁ is selected from the group consisting of the following groups:

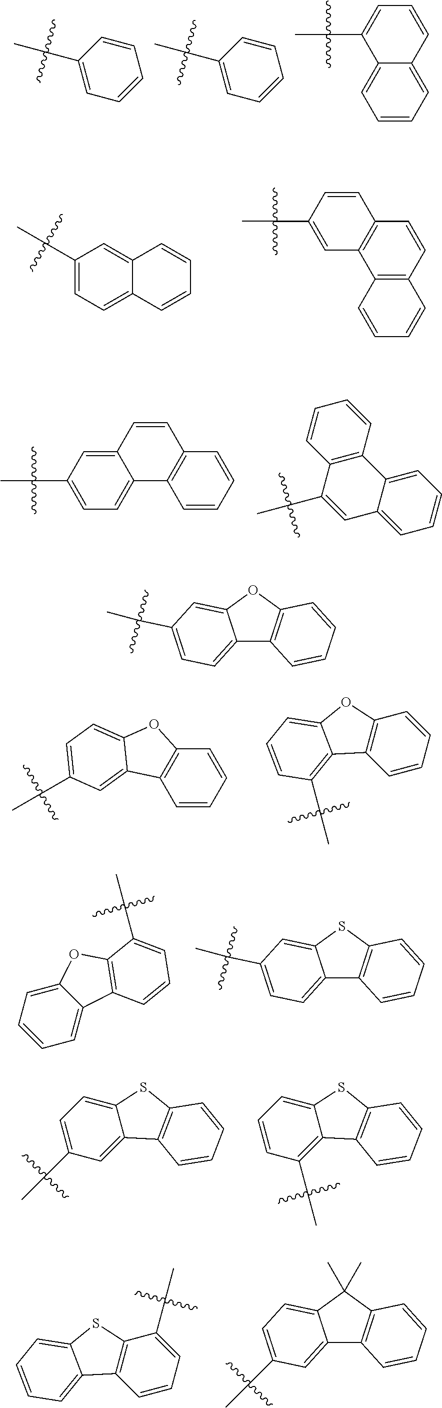

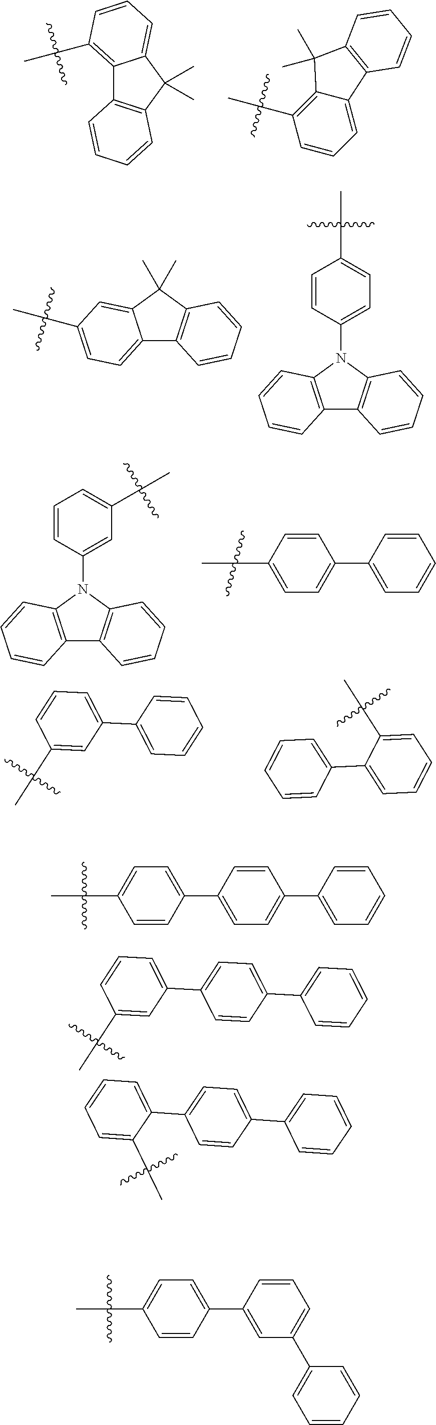

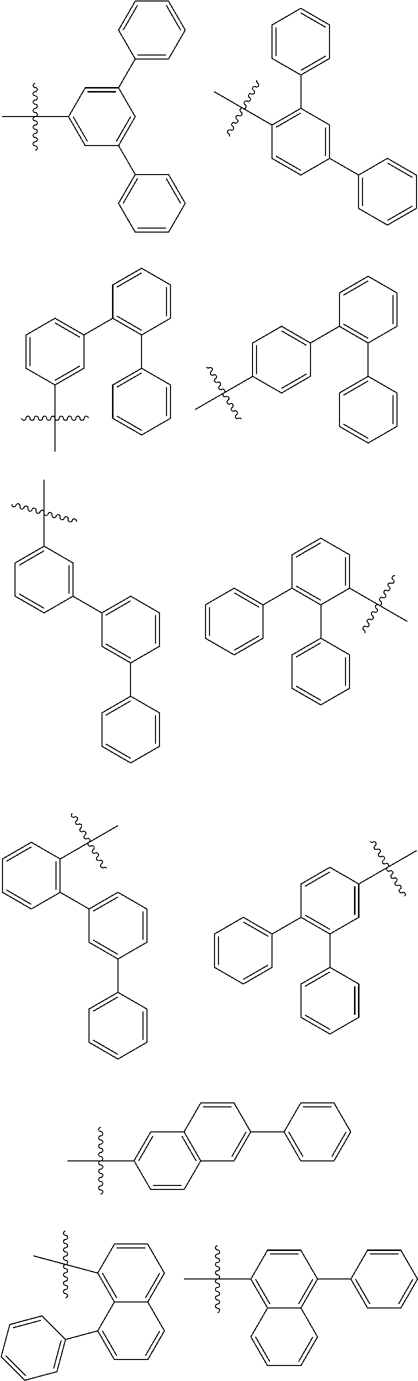

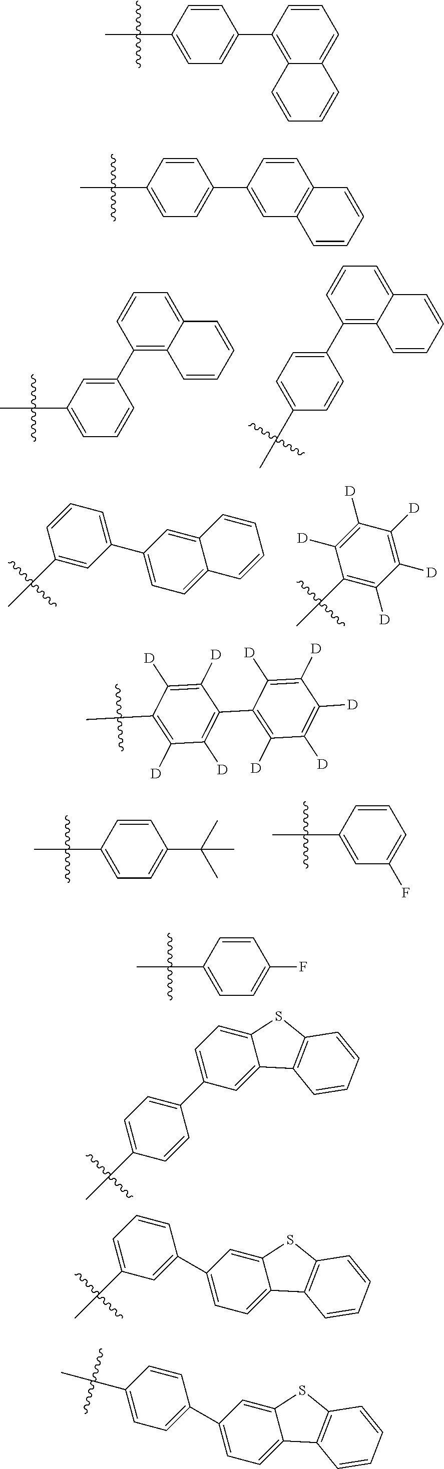

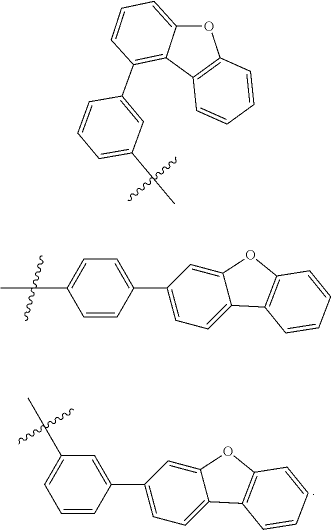 [SMILES: *c1cccc(-c2cccc3oc4ccccc4c23)c1 ; *c1ccc(-c2ccc3c(c2)oc2ccccc23)cc1 ; *c1cccc(-c2ccc3c(c2)oc2ccccc23)c1]

In some embodiments, L is selected from a substituted or unsubstituted heteroarylene having 5 to 18 carbon atoms.

In some embodiments, L is selected from a substituted or unsubstituted heteroarylene having 5, 6, 7, 8, 9, 10, 11, 12, 13, 14, 15, 16, 17, or 18.

Optionally, substituent(s) in L are each independently selected from a deuterium, a fluorine, a cyano, an alkyl having 1 to 5 carbon atoms, a trialkylsilyl having 3 to 8 carbon atoms, a fluoroalkyl having 1 to 4 carbon atoms, a deuterated alkyl having 1 to 4 carbon atoms, a phenyl, a pentadeuterated phenyl, a biphenyl, and a naphthyl.

In some embodiments, L is selected from a dibenzothienylene, a substituted or unsubstituted dibenzofuranylene, and a substituted or unsubstituted carbazolylene.

Optionally, substituent(s) in L are the same or different, and are each independently selected from a deuterium, a fluorine, a cyano, a methyl, an ethyl, an isopropyl, a tert-butyl, a trifluoromethyl, a trideuterated methyl, a trimethylsilyl, a phenyl, a pentadeuterated phenyl, a biphenyl, and a naphthyl.

In some embodiments, L is selected from the group consisting of the following groups:

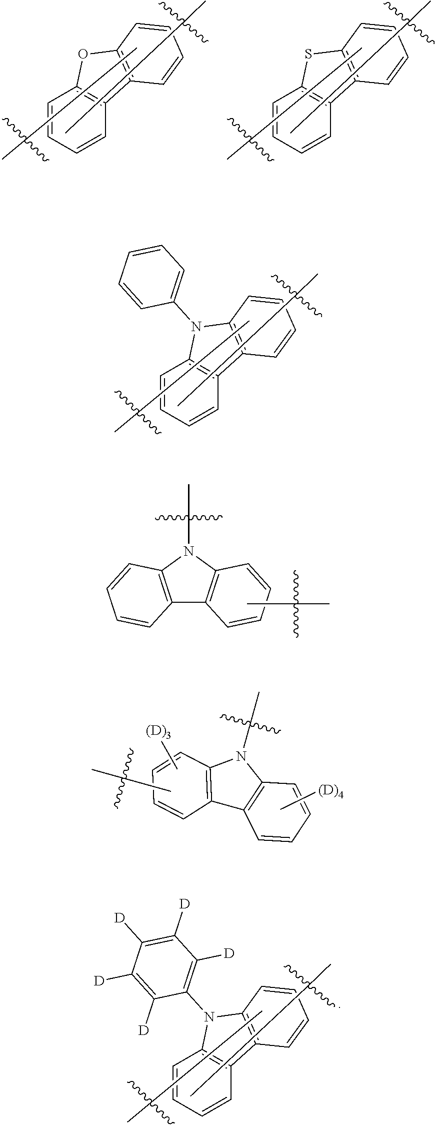

In some embodiments, L is selected from the group consisting of the following groups:

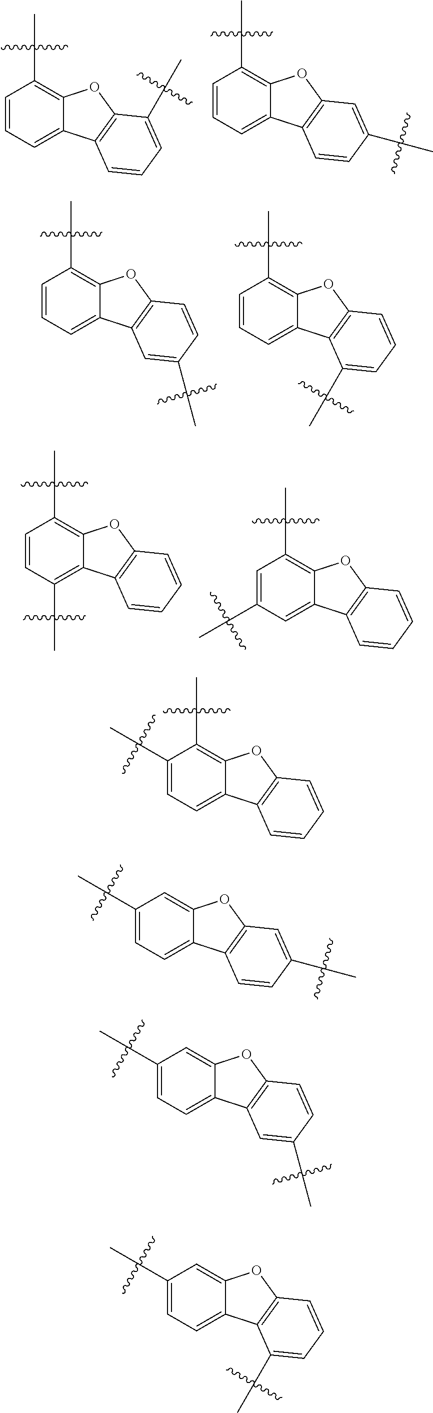

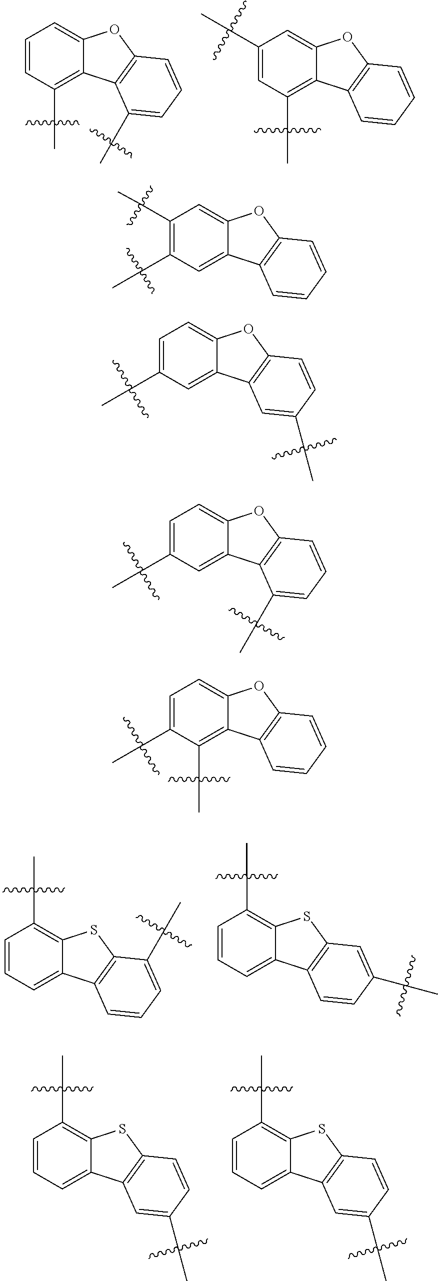

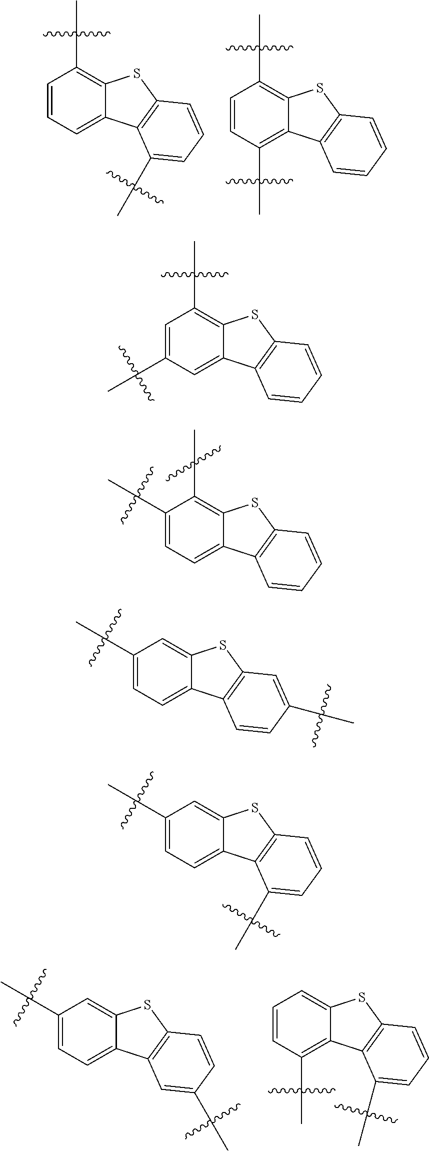

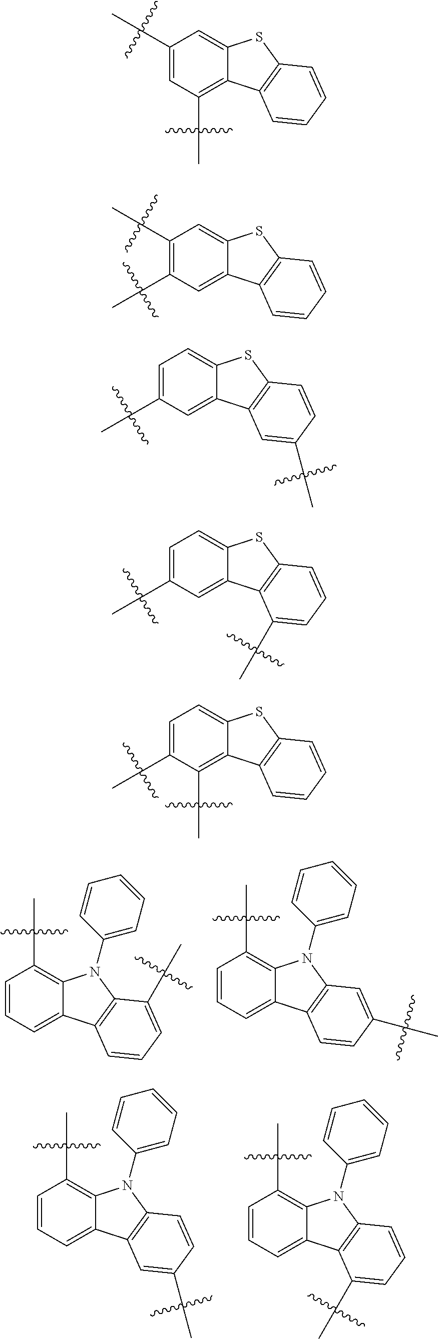

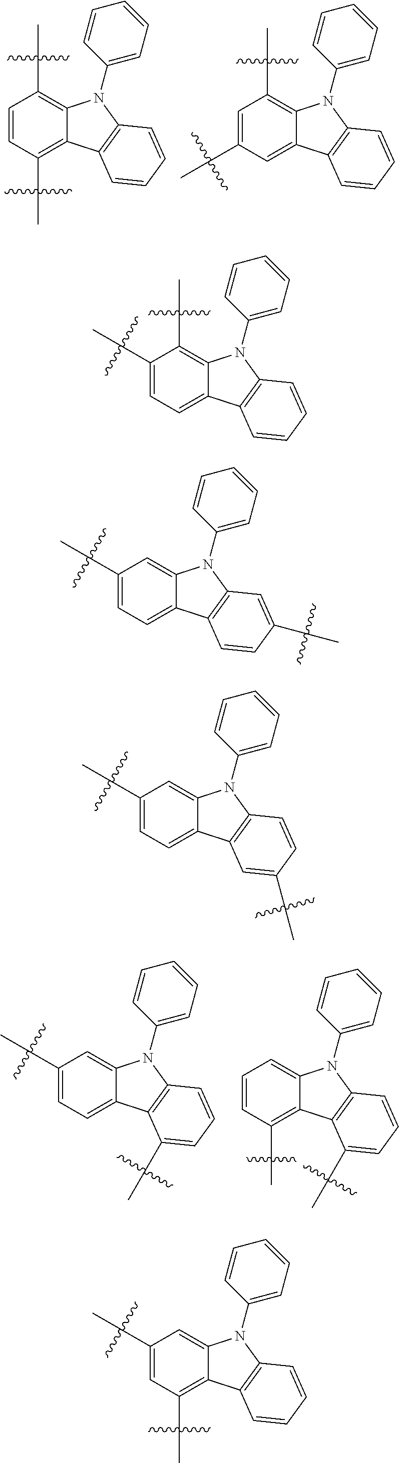

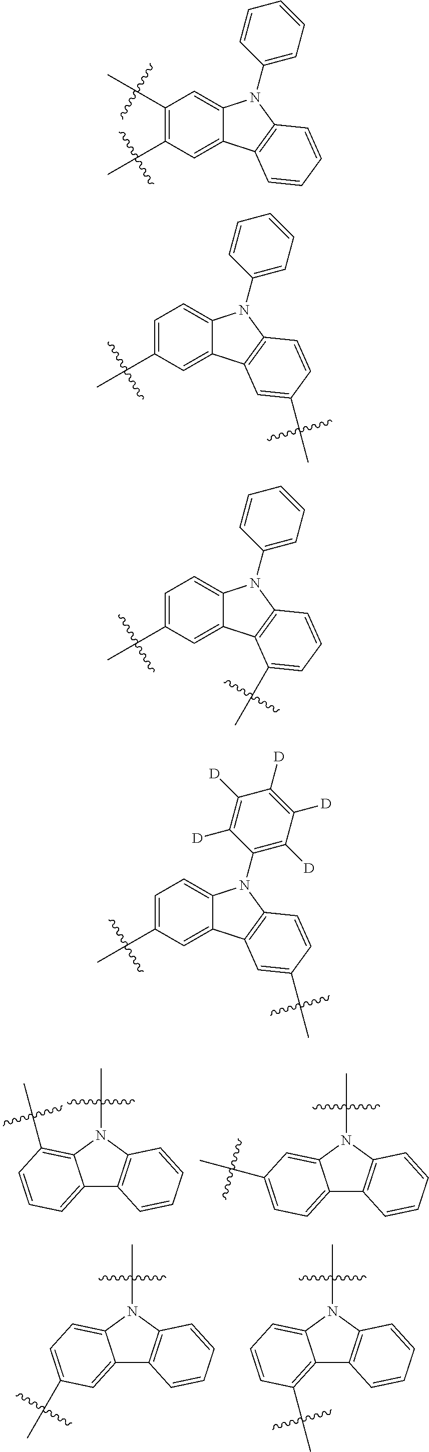

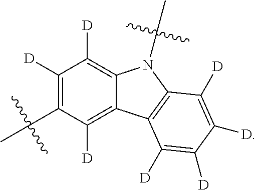

In some embodiments, each R₁, R₂, and R₃ are the same or different, and are each independently selected from a deuterium, a cyano, a fluorine, a methyl, an ethyl, an isopropyl, a tert-butyl, a trifluoromethyl, a trideuterated methyl, a trimethylsilyl, a phenyl, a pentadeuterated phenyl, a biphenyl, and a naphthyl.

In some embodiments, the organic compound is selected from the group consisting of the following compounds:

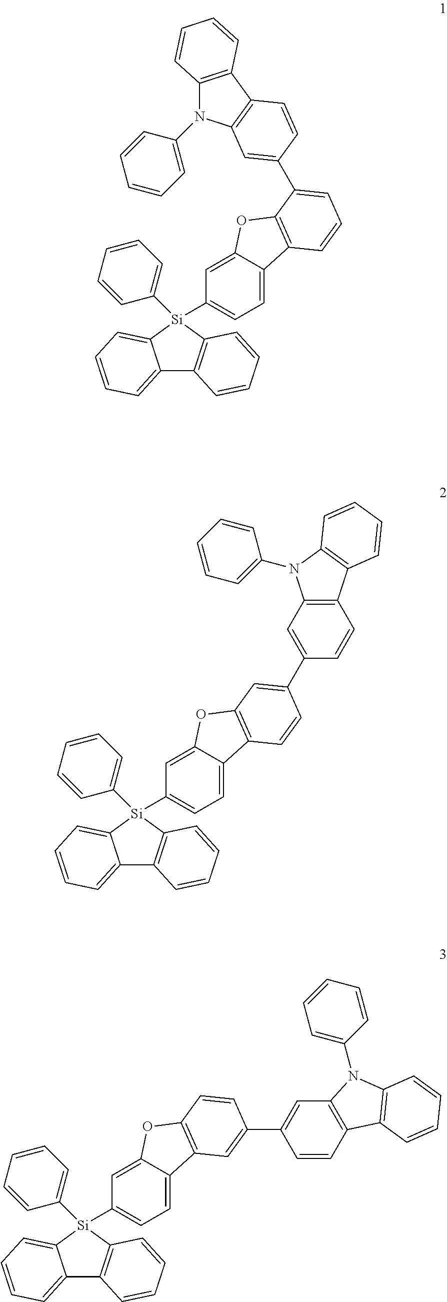 [SMILES: c1ccc(-n2c3ccccc3c3ccc(-c4cccc5c4oc4cc([Si]6(c7ccccc7)c7ccccc7-c7ccccc76)ccc45)cc32)cc1 ; c1ccc(-n2c3ccccc3c3ccc(-c4ccc5c(c4)oc4cc([Si]6(c7ccccc7)c7ccccc7-c7ccccc76)ccc45)cc32)cc1 ; c1ccc(-n2c3ccccc3c3ccc(-c4ccc5oc6cc([Si]7(c8ccccc8)c8ccccc8-c8ccccc87)ccc6c5c4)cc32)cc1]

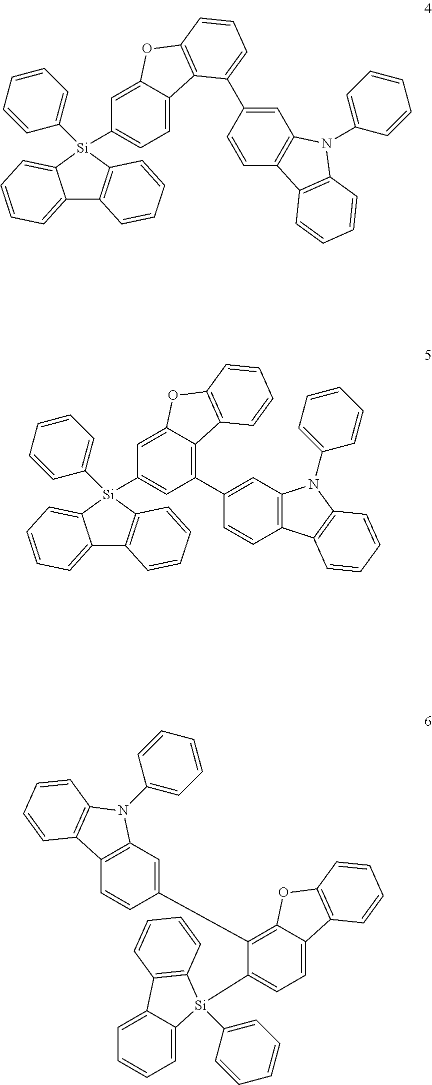 [SMILES: c1ccc(-n2c3ccccc3c3ccc(-c4cccc5oc6cc([Si]7(c8ccccc8)c8ccccc8-c8ccccc87)ccc6c45)cc32)cc1 ; c1ccc(-n2c3ccccc3c3ccc(-c4cc([Si]5(c6ccccc6)c6ccccc6-c6ccccc65)cc5oc6ccccc6c45)cc32)cc1 ; c1ccc(-n2c3ccccc3c3ccc(-c4c([Si]5(c6ccccc6)c6ccccc6-c6ccccc65)ccc5c4oc4ccccc45)cc32)cc1]

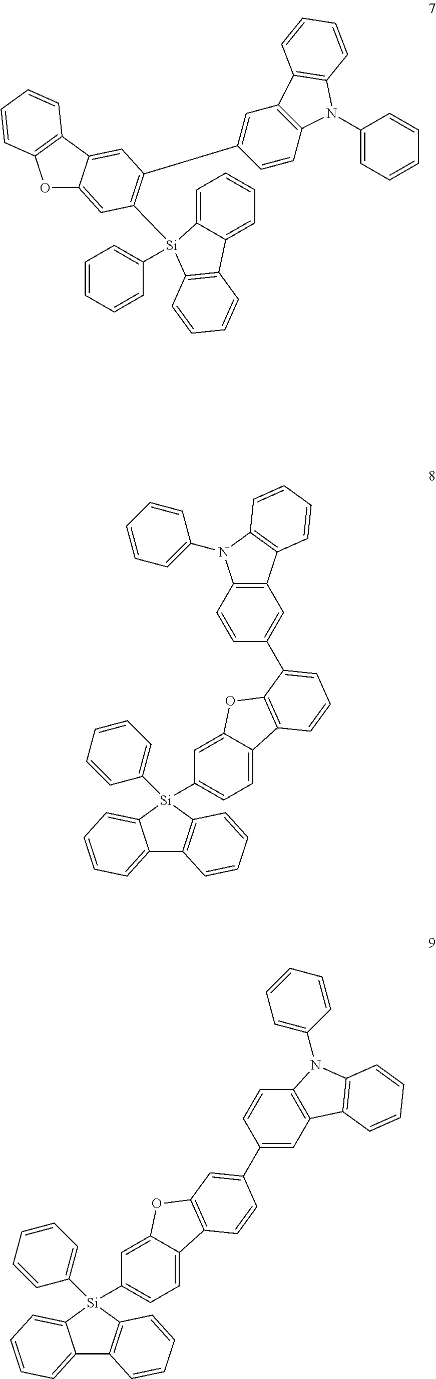 [SMILES: c1ccc(-n2c3ccccc3c3cc(-c4cc5c(cc4[Si]4(c6ccccc6)c6ccccc6-c6ccccc64)oc4ccccc45)ccc32)cc1 ; c1ccc(-n2c3ccccc3c3cc(-c4cccc5c4oc4cc([Si]6(c7ccccc7)c7ccccc7-c7ccccc76)ccc45)ccc32)cc1 ; c1ccc(-n2c3ccccc3c3cc(-c4ccc5c(c4)oc4cc([Si]6(c7ccccc7)c7ccccc7-c7ccccc76)ccc45)ccc32)cc1]

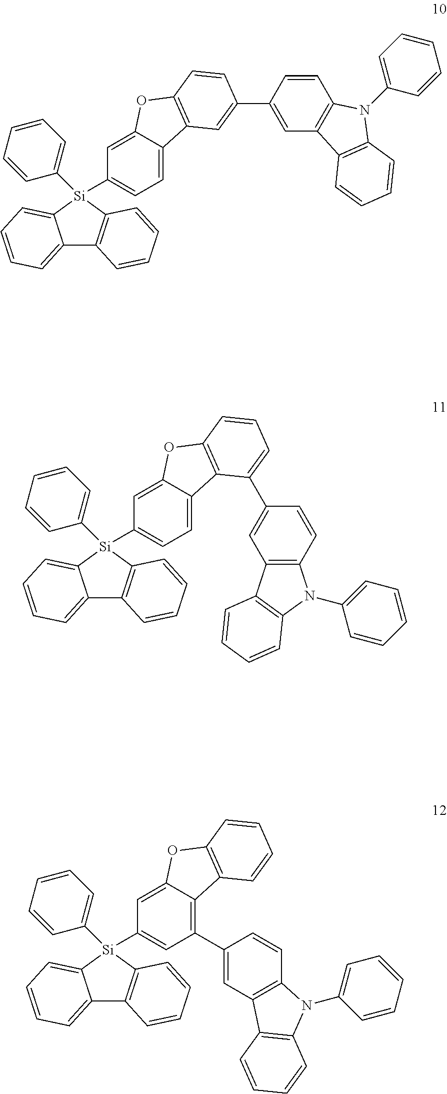 [SMILES: c1ccc(-n2c3ccccc3c3cc(-c4ccc5oc6cc([Si]7(c8ccccc8)c8ccccc8-c8ccccc87)ccc6c5c4)ccc32)cc1 ; c1ccc(-n2c3ccccc3c3cc(-c4cccc5oc6cc([Si]7(c8ccccc8)c8ccccc8-c8ccccc87)ccc6c45)ccc32)cc1 ; c1ccc(-n2c3ccccc3c3cc(-c4cc([Si]5(c6ccccc6)c6ccccc6-c6ccccc65)cc5oc6ccccc6c45)ccc32)cc1]

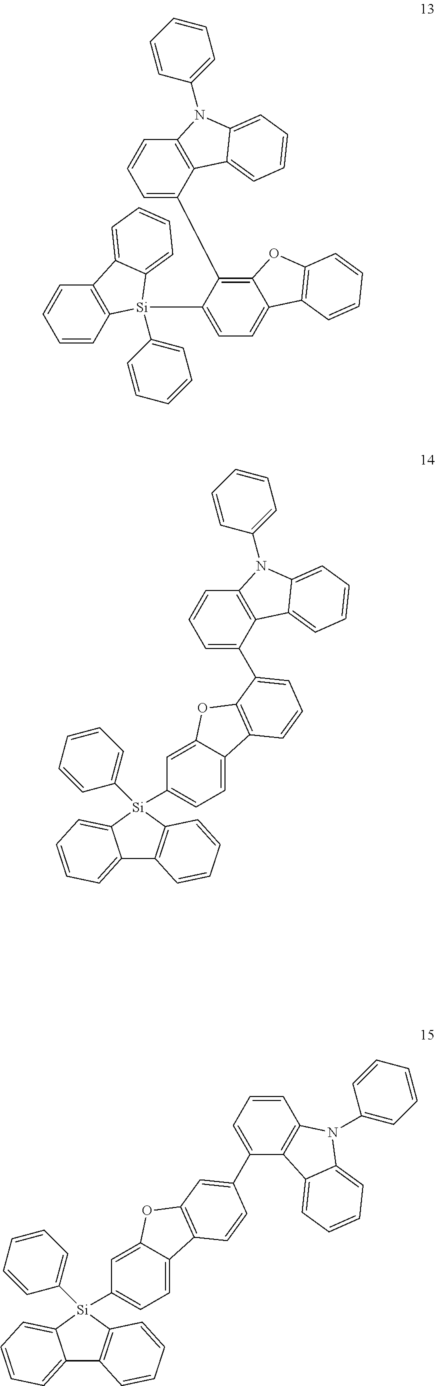 [SMILES: c1ccc(-n2c3ccccc3c3c(-c4c([Si]5(c6ccccc6)c6ccccc6-c6ccccc65)ccc5c4oc4ccccc45)cccc32)cc1 ; c1ccc(-n2c3ccccc3c3c(-c4cccc5c4oc4cc([Si]6(c7ccccc7)c7ccccc7-c7ccccc76)ccc45)cccc32)cc1 ; c1ccc(-n2c3ccccc3c3c(-c4ccc5c(c4)oc4cc([Si]6(c7ccccc7)c7ccccc7-c7ccccc76)ccc45)cccc32)cc1]

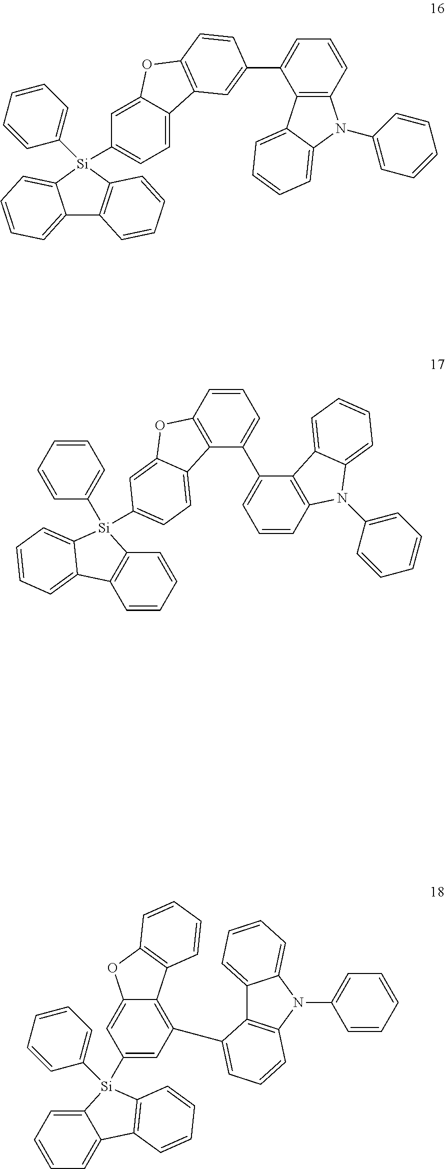 [SMILES: c1ccc(-n2c3ccccc3c3c(-c4ccc5oc6cc([Si]7(c8ccccc8)c8ccccc8-c8ccccc87)ccc6c5c4)cccc32)cc1 ; c1ccc(-n2c3ccccc3c3c(-c4cccc5oc6cc([Si]7(c8ccccc8)c8ccccc8-c8ccccc87)ccc6c45)cccc32)cc1 ; c1ccc(-n2c3ccccc3c3c(-c4cc([Si]5(c6ccccc6)c6ccccc6-c6ccccc65)cc5oc6ccccc6c45)cccc32)cc1]

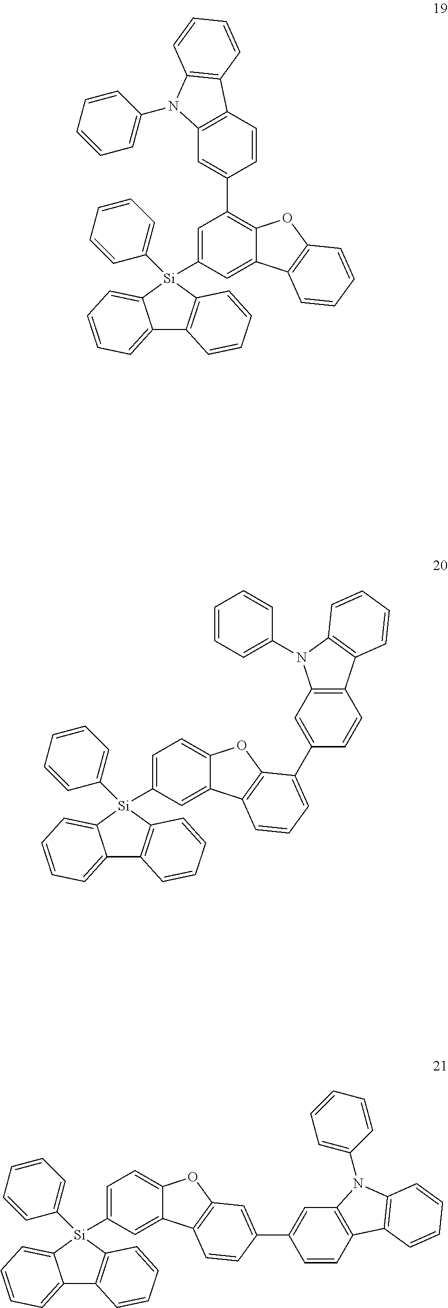 [SMILES: c1ccc(-n2c3ccccc3c3ccc(-c4cc([Si]5(c6ccccc6)c6ccccc6-c6ccccc65)cc5c4oc4ccccc45)cc32)cc1 ; c1ccc(-n2c3ccccc3c3ccc(-c4cccc5c4oc4ccc([Si]6(c7ccccc7)c7ccccc7-c7ccccc76)cc45)cc32)cc1 ; c1ccc(-n2c3ccccc3c3ccc(-c4ccc5c(c4)oc4ccc([Si]6(c7ccccc7)c7ccccc7-c7ccccc76)cc45)cc32)cc1]

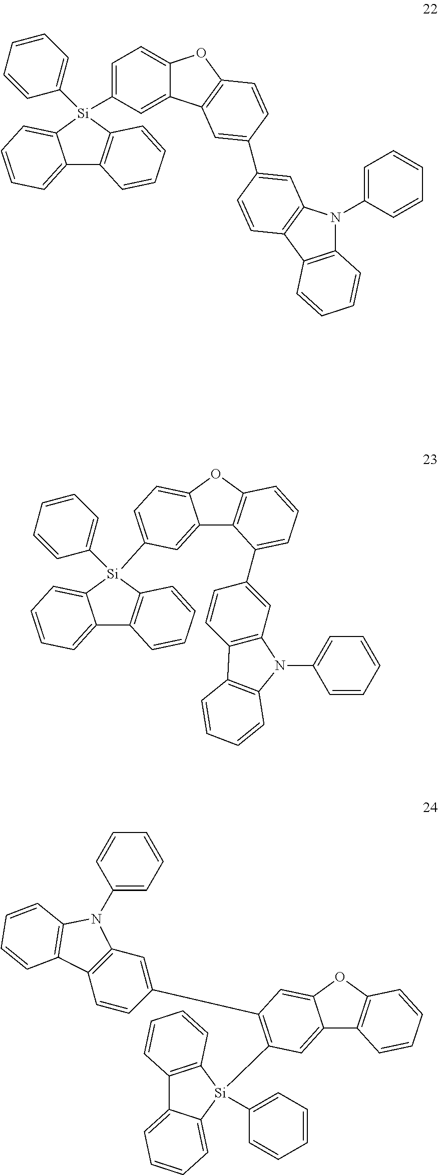 [SMILES: c1ccc(-n2c3ccccc3c3ccc(-c4ccc5oc6ccc([Si]7(c8ccccc8)c8ccccc8-c8ccccc87)cc6c5c4)cc32)cc1 ; c1ccc(-n2c3ccccc3c3ccc(-c4cccc5oc6ccc([Si]7(c8ccccc8)c8ccccc8-c8ccccc87)cc6c45)cc32)cc1 ; c1ccc(-n2c3ccccc3c3ccc(-c4cc5oc6ccccc6c5cc4[Si]4(c5ccccc5)c5ccccc5-c5ccccc54)cc32)cc1]

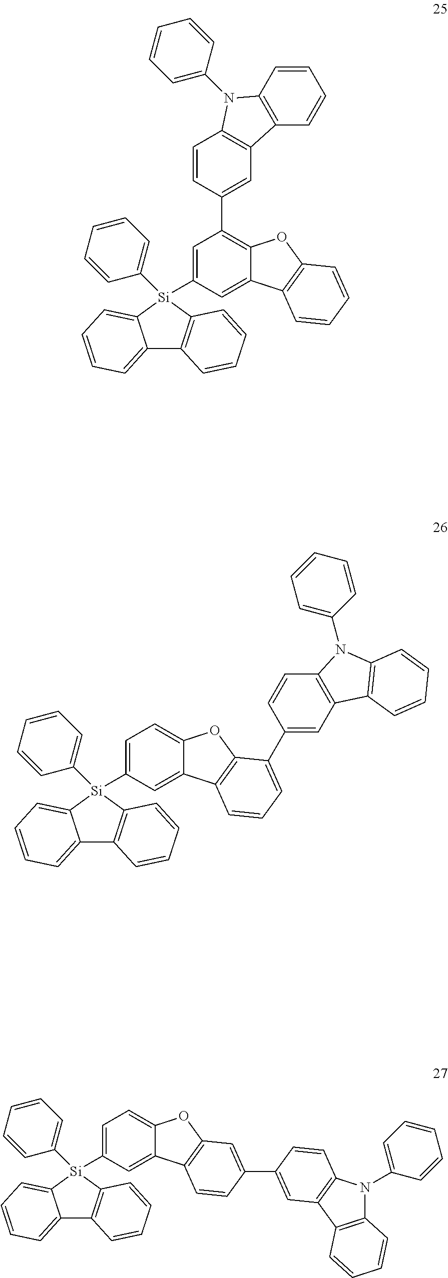 [SMILES: c1ccc(-n2c3ccccc3c3cc(-c4cc([Si]5(c6ccccc6)c6ccccc6-c6ccccc65)cc5c4oc4ccccc45)ccc32)cc1 ; c1ccc(-n2c3ccccc3c3cc(-c4cccc5c4oc4ccc([Si]6(c7ccccc7)c7ccccc7-c7ccccc76)cc45)ccc32)cc1 ; c1ccc(-n2c3ccccc3c3cc(-c4ccc5c(c4)oc4ccc([Si]6(c7ccccc7)c7ccccc7-c7ccccc76)cc45)ccc32)cc1]

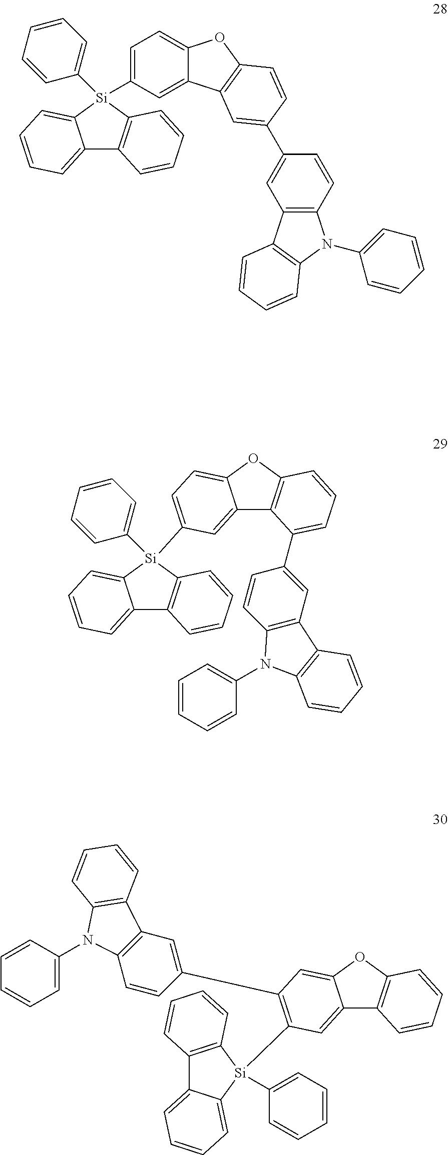 [SMILES: c1ccc(-n2c3ccccc3c3cc(-c4ccc5oc6ccc([Si]7(c8ccccc8)c8ccccc8-c8ccccc87)cc6c5c4)ccc32)cc1 ; c1ccc(-n2c3ccccc3c3cc(-c4cccc5oc6ccc([Si]7(c8ccccc8)c8ccccc8-c8ccccc87)cc6c45)ccc32)cc1 ; c1ccc(-n2c3ccccc3c3cc(-c4cc5oc6ccccc6c5cc4[Si]4(c5ccccc5)c5ccccc5-c5ccccc54)ccc32)cc1]

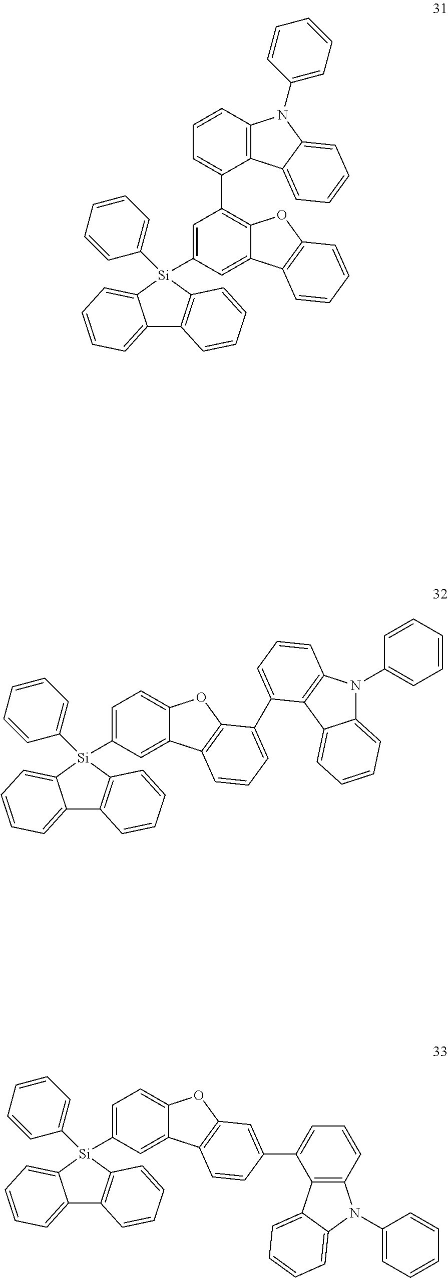 [SMILES: c1ccc(-n2c3ccccc3c3c(-c4cc([Si]5(c6ccccc6)c6ccccc6-c6ccccc65)cc5c4oc4ccccc45)cccc32)cc1 ; c1ccc(-n2c3ccccc3c3c(-c4cccc5c4oc4ccc([Si]6(c7ccccc7)c7ccccc7-c7ccccc76)cc45)cccc32)cc1 ; c1ccc(-n2c3ccccc3c3c(-c4ccc5c(c4)oc4ccc([Si]6(c7ccccc7)c7ccccc7-c7ccccc76)cc45)cccc32)cc1]

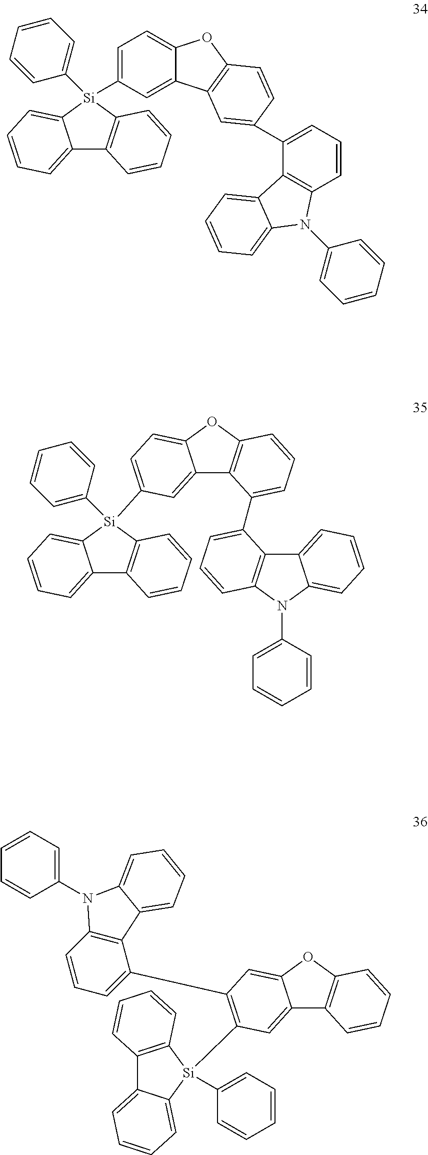 [SMILES: c1ccc(-n2c3ccccc3c3c(-c4ccc5oc6ccc([Si]7(c8ccccc8)c8ccccc8-c8ccccc87)cc6c5c4)cccc32)cc1 ; c1ccc(-n2c3ccccc3c3c(-c4cccc5oc6ccc([Si]7(c8ccccc8)c8ccccc8-c8ccccc87)cc6c45)cccc32)cc1 ; c1ccc(-n2c3ccccc3c3c(-c4cc5oc6ccccc6c5cc4[Si]4(c5ccccc5)c5ccccc5-c5ccccc54)cccc32)cc1]

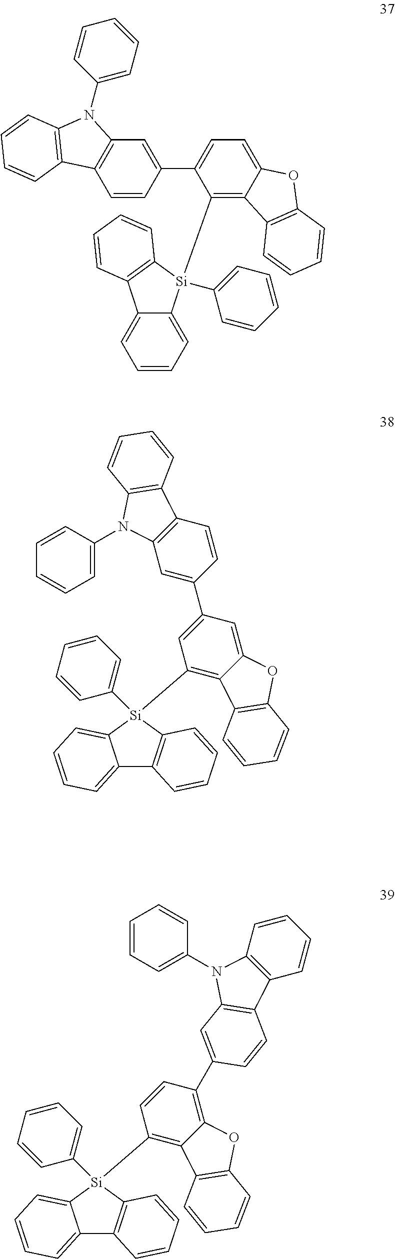 [SMILES: c1ccc(-n2c3ccccc3c3ccc(-c4ccc5oc6ccccc6c5c4[Si]4(c5ccccc5)c5ccccc5-c5ccccc54)cc32)cc1 ; c1ccc(-n2c3ccccc3c3ccc(-c4cc([Si]5(c6ccccc6)c6ccccc6-c6ccccc65)c5c(c4)oc4ccccc45)cc32)cc1 ; c1ccc(-n2c3ccccc3c3ccc(-c4ccc([Si]5(c6ccccc6)c6ccccc6-c6ccccc65)c5c4oc4ccccc45)cc32)cc1]

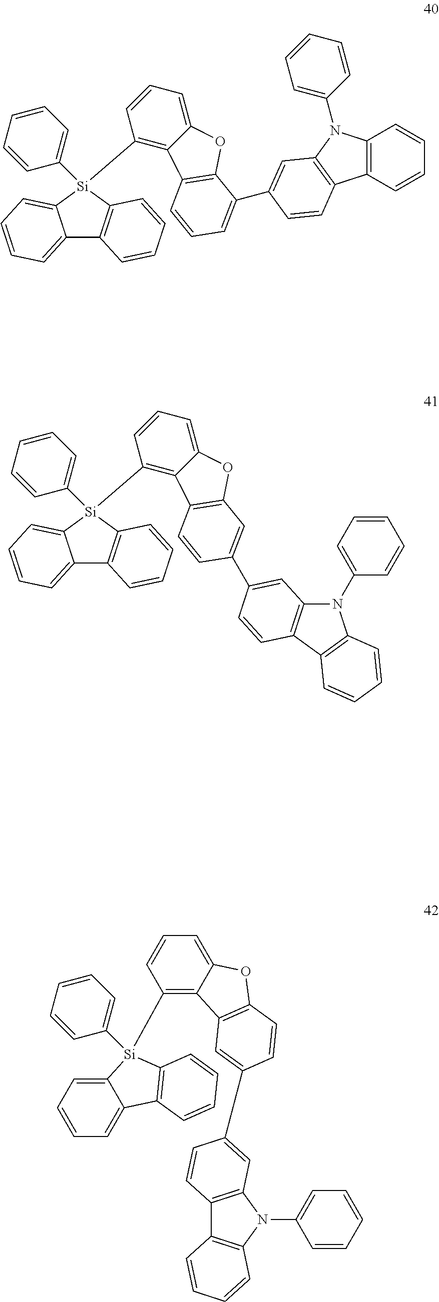 [SMILES: c1ccc(-n2c3ccccc3c3ccc(-c4cccc5c4oc4cccc([Si]6(c7ccccc7)c7ccccc7-c7ccccc76)c45)cc32)cc1 ; c1ccc(-n2c3ccccc3c3ccc(-c4ccc5c(c4)oc4cccc([Si]6(c7ccccc7)c7ccccc7-c7ccccc76)c45)cc32)cc1 ; c1ccc(-n2c3ccccc3c3ccc(-c4ccc5oc6cccc([Si]7(c8ccccc8)c8ccccc8-c8ccccc87)c6c5c4)cc32)cc1]

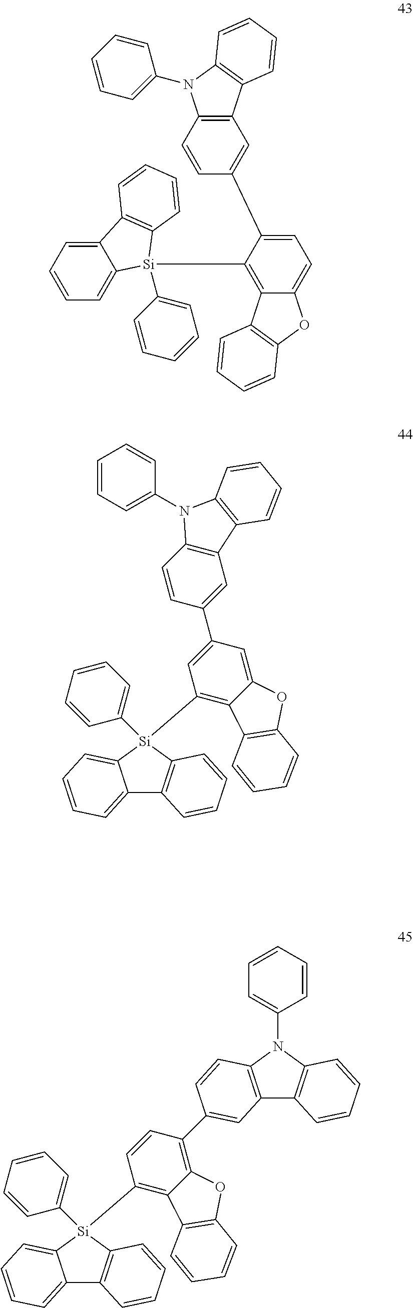 [SMILES: c1ccc(-n2c3ccccc3c3cc(-c4ccc5oc6ccccc6c5c4[Si]4(c5ccccc5)c5ccccc5-c5ccccc54)ccc32)cc1 ; c1ccc(-n2c3ccccc3c3cc(-c4cc([Si]5(c6ccccc6)c6ccccc6-c6ccccc65)c5c(c4)oc4ccccc45)ccc32)cc1 ; c1ccc(-n2c3ccccc3c3cc(-c4ccc([Si]5(c6ccccc6)c6ccccc6-c6ccccc65)c5c4oc4ccccc45)ccc32)cc1]

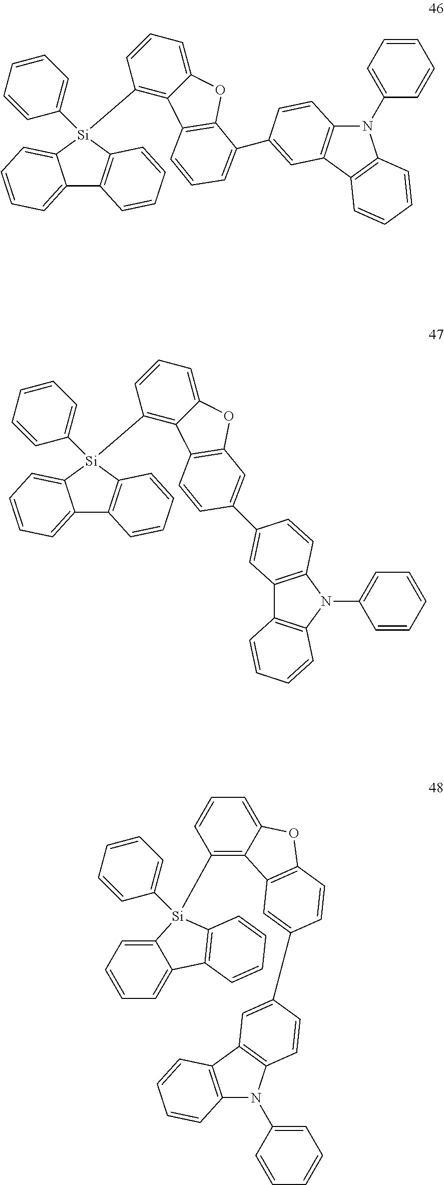 [SMILES: c1ccc(-n2c3ccccc3c3cc(-c4cccc5c4oc4cccc([Si]6(c7ccccc7)c7ccccc7-c7ccccc76)c45)ccc32)cc1 ; c1ccc(-n2c3ccccc3c3cc(-c4ccc5c(c4)oc4cccc([Si]6(c7ccccc7)c7ccccc7-c7ccccc76)c45)ccc32)cc1 ; c1ccc(-n2c3ccccc3c3cc(-c4ccc5oc6cccc([Si]7(c8ccccc8)c8ccccc8-c8ccccc87)c6c5c4)ccc32)cc1]

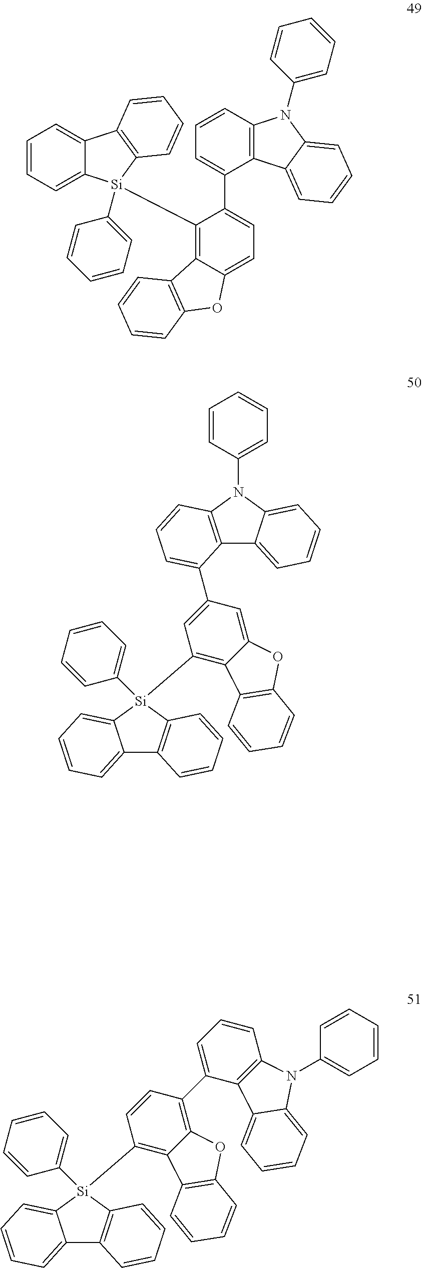 [SMILES: c1ccc(-n2c3ccccc3c3c(-c4ccc5oc6ccccc6c5c4[Si]4(c5ccccc5)c5ccccc5-c5ccccc54)cccc32)cc1 ; c1ccc(-n2c3ccccc3c3c(-c4cc([Si]5(c6ccccc6)c6ccccc6-c6ccccc65)c5c(c4)oc4ccccc45)cccc32)cc1 ; c1ccc(-n2c3ccccc3c3c(-c4ccc([Si]5(c6ccccc6)c6ccccc6-c6ccccc65)c5c4oc4ccccc45)cccc32)cc1]

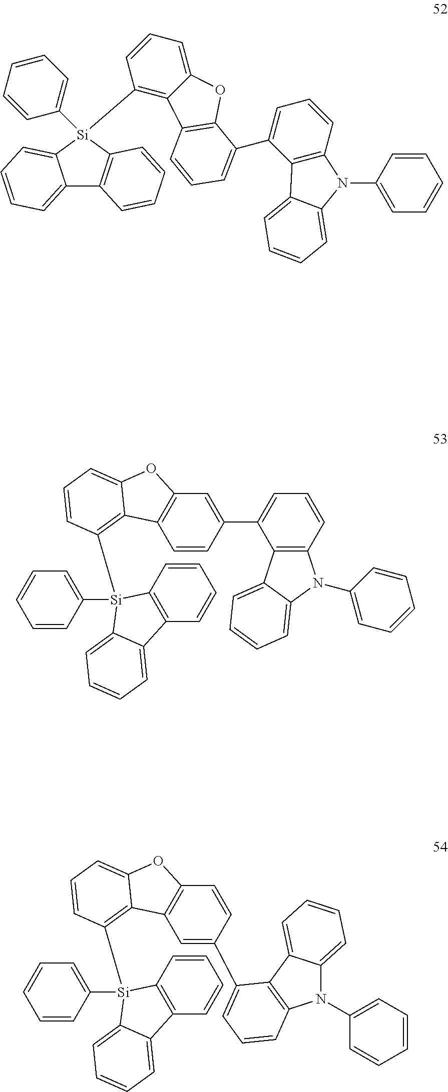 [SMILES: c1ccc(-n2c3ccccc3c3c(-c4cccc5c4oc4cccc([Si]6(c7ccccc7)c7ccccc7-c7ccccc76)c45)cccc32)cc1 ; c1ccc(-n2c3ccccc3c3c(-c4ccc5c(c4)oc4cccc([Si]6(c7ccccc7)c7ccccc7-c7ccccc76)c45)cccc32)cc1 ; c1ccc(-n2c3ccccc3c3c(-c4ccc5oc6cccc([Si]7(c8ccccc8)c8ccccc8-c8ccccc87)c6c5c4)cccc32)cc1]

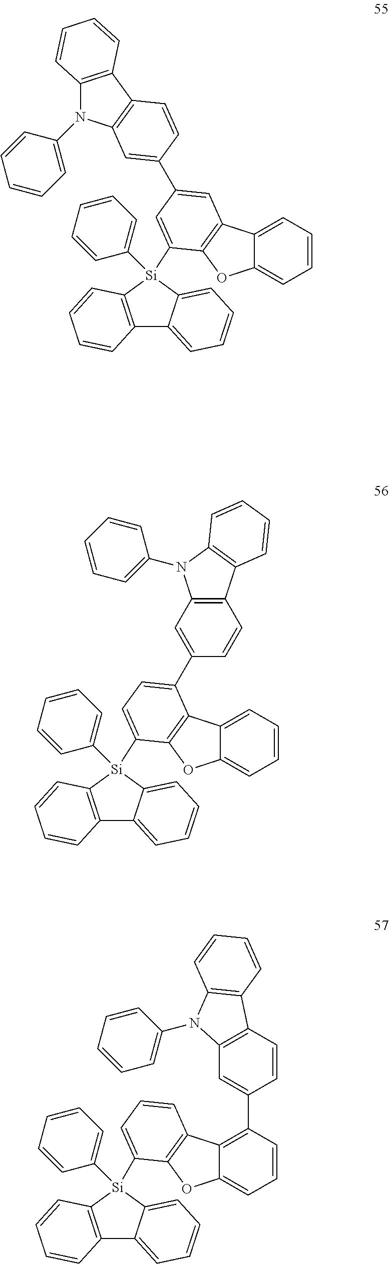 [SMILES: c1ccc(-n2c3ccccc3c3ccc(-c4cc([Si]5(c6ccccc6)c6ccccc6-c6ccccc65)c5oc6ccccc6c5c4)cc32)cc1 ; c1ccc(-n2c3ccccc3c3ccc(-c4ccc([Si]5(c6ccccc6)c6ccccc6-c6ccccc65)c5oc6ccccc6c45)cc32)cc1 ; c1ccc(-n2c3ccccc3c3ccc(-c4cccc5oc6c([Si]7(c8ccccc8)c8ccccc8-c8ccccc87)cccc6c45)cc32)cc1]

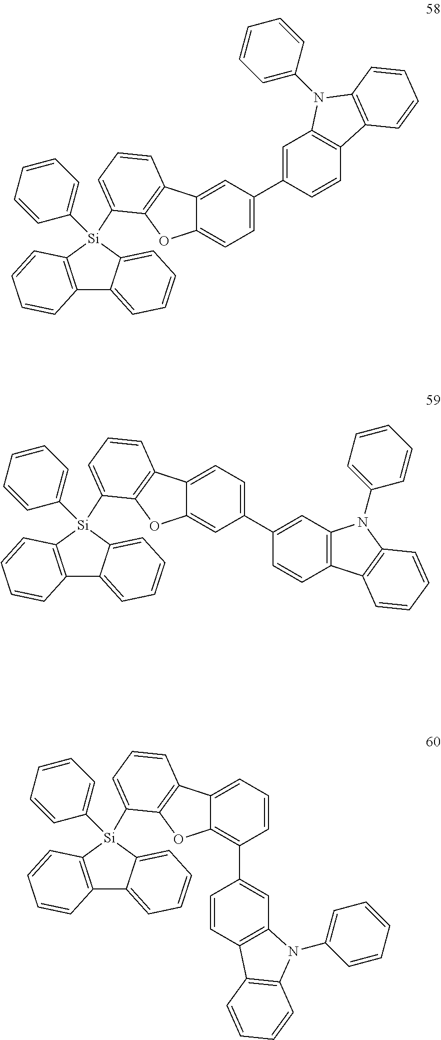 [SMILES: c1ccc(-n2c3ccccc3c3ccc(-c4ccc5oc6c([Si]7(c8ccccc8)c8ccccc8-c8ccccc87)cccc6c5c4)cc32)cc1 ; c1ccc(-n2c3ccccc3c3ccc(-c4ccc5c(c4)oc4c([Si]6(c7ccccc7)c7ccccc7-c7ccccc76)cccc45)cc32)cc1 ; c1ccc(-n2c3ccccc3c3ccc(-c4cccc5c4oc4c([Si]6(c7ccccc7)c7ccccc7-c7ccccc76)cccc45)cc32)cc1]

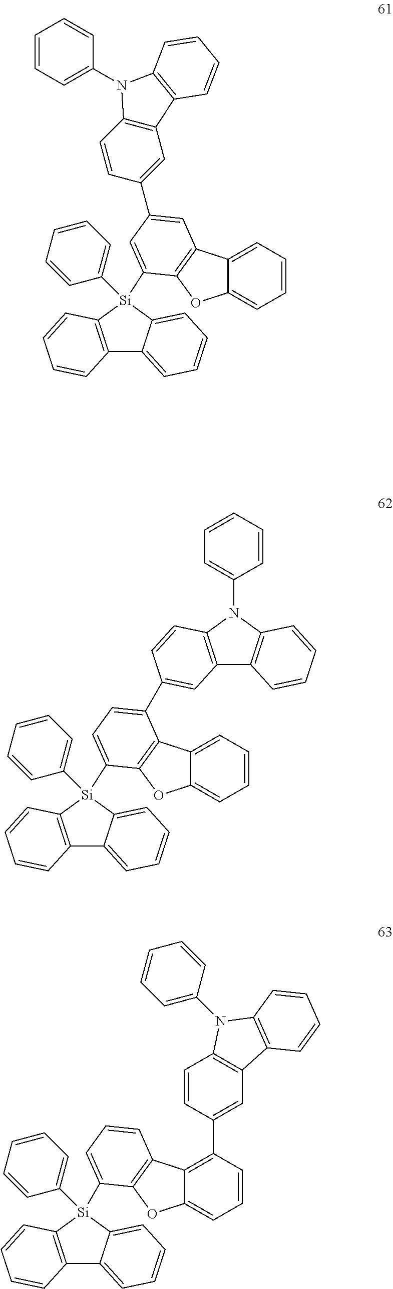 [SMILES: c1ccc(-n2c3ccccc3c3cc(-c4cc([Si]5(c6ccccc6)c6ccccc6-c6ccccc65)c5oc6ccccc6c5c4)ccc32)cc1 ; c1ccc(-n2c3ccccc3c3cc(-c4ccc([Si]5(c6ccccc6)c6ccccc6-c6ccccc65)c5oc6ccccc6c45)ccc32)cc1 ; c1ccc(-n2c3ccccc3c3cc(-c4cccc5oc6c([Si]7(c8ccccc8)c8ccccc8-c8ccccc87)cccc6c45)ccc32)cc1]

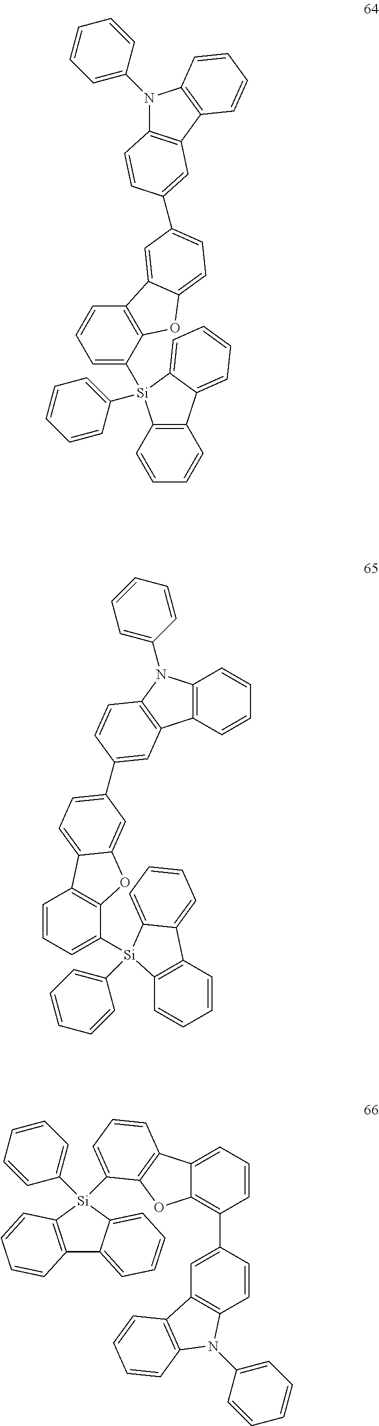 [SMILES: c1ccc(-n2c3ccccc3c3cc(-c4ccc5oc6c([Si]7(c8ccccc8)c8ccccc8-c8ccccc87)cccc6c5c4)ccc32)cc1 ; c1ccc(-n2c3ccccc3c3cc(-c4ccc5c(c4)oc4c([Si]6(c7ccccc7)c7ccccc7-c7ccccc76)cccc45)ccc32)cc1 ; c1ccc(-n2c3ccccc3c3cc(-c4cccc5c4oc4c([Si]6(c7ccccc7)c7ccccc7-c7ccccc76)cccc45)ccc32)cc1]

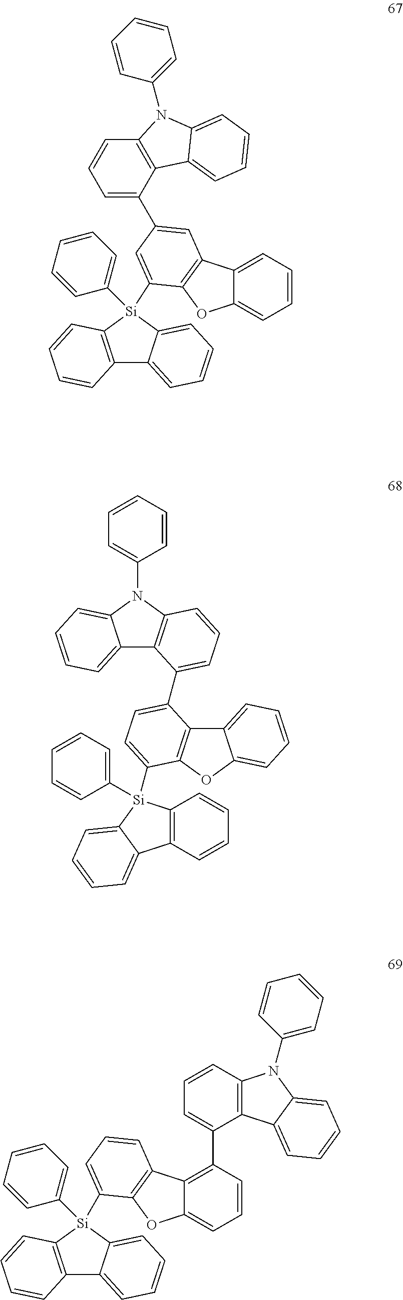 [SMILES: c1ccc(-n2c3ccccc3c3c(-c4cc([Si]5(c6ccccc6)c6ccccc6-c6ccccc65)c5oc6ccccc6c5c4)cccc32)cc1 ; c1ccc(-n2c3ccccc3c3c(-c4ccc([Si]5(c6ccccc6)c6ccccc6-c6ccccc65)c5oc6ccccc6c45)cccc32)cc1 ; c1ccc(-n2c3ccccc3c3c(-c4cccc5oc6c([Si]7(c8ccccc8)c8ccccc8-c8ccccc87)cccc6c45)cccc32)cc1]

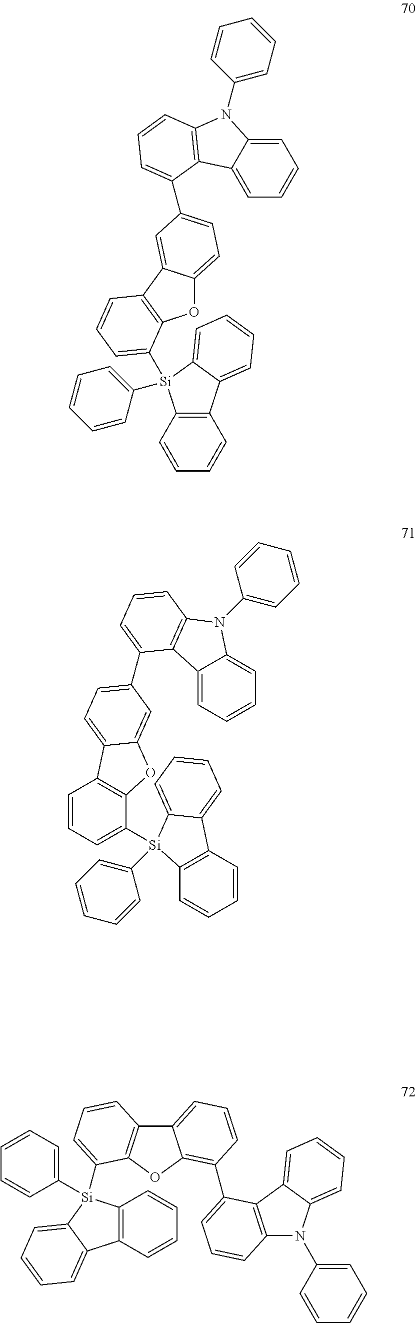 [SMILES: c1ccc(-n2c3ccccc3c3c(-c4ccc5oc6c([Si]7(c8ccccc8)c8ccccc8-c8ccccc87)cccc6c5c4)cccc32)cc1 ; c1ccc(-n2c3ccccc3c3c(-c4ccc5c(c4)oc4c([Si]6(c7ccccc7)c7ccccc7-c7ccccc76)cccc45)cccc32)cc1 ; c1ccc(-n2c3ccccc3c3c(-c4cccc5c4oc4c([Si]6(c7ccccc7)c7ccccc7-c7ccccc76)cccc45)cccc32)cc1]

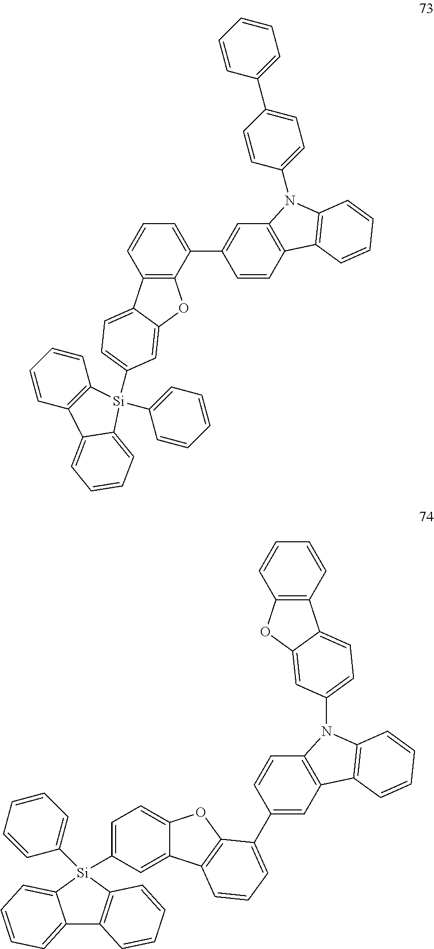 [SMILES: c1ccc(-c2ccc(-n3c4ccccc4c4ccc(-c5cccc6c5oc5cc([Si]7(c8ccccc8)c8ccccc8-c8ccccc87)ccc56)cc43)cc2)cc1 ; c1ccc([Si]2(c3ccc4oc5c(-c6ccc7c(c6)c6ccccc6n7-c6ccc7c(c6)oc6ccccc67)cccc5c4c3)c3ccccc3-c3ccccc32)cc1]

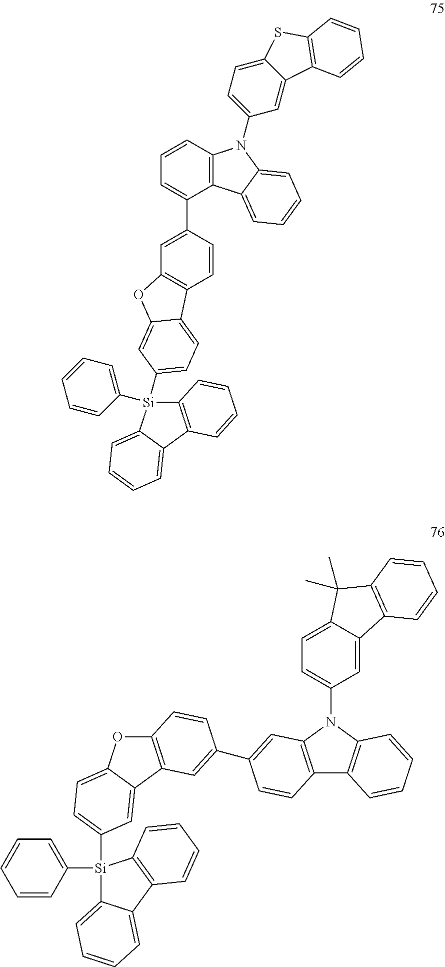 [SMILES: c1ccc([Si]2(c3ccc4c(c3)oc3cc(-c5cccc6c5c5ccccc5n6-c5ccc6sc7ccccc7c6c5)ccc34)c3ccccc3-c3ccccc32)cc1 ; CC1(C)c2ccccc2-c2cc(-n3c4ccccc4c4ccc(-c5ccc6oc7ccc([Si]8(c9ccccc9)c9ccccc9-c9ccccc98)cc7c6c5)cc43)ccc21]

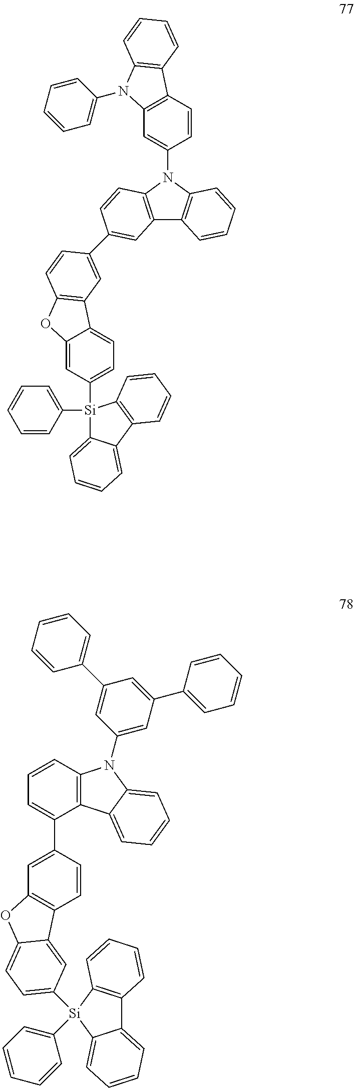 [SMILES: c1ccc(-n2c3ccccc3c3ccc(-n4c5ccccc5c5cc(-c6ccc7oc8cc([Si]9(c%10ccccc%10)c%10ccccc%10-c%10ccccc%109)ccc8c7c6)ccc54)cc32)cc1 ; c1ccc(-c2cc(-c3ccccc3)cc(-n3c4ccccc4c4c(-c5ccc6c(c5)oc5ccc([Si]7(c8ccccc8)c8ccccc8-c8ccccc87)cc56)cccc43)c2)cc1]

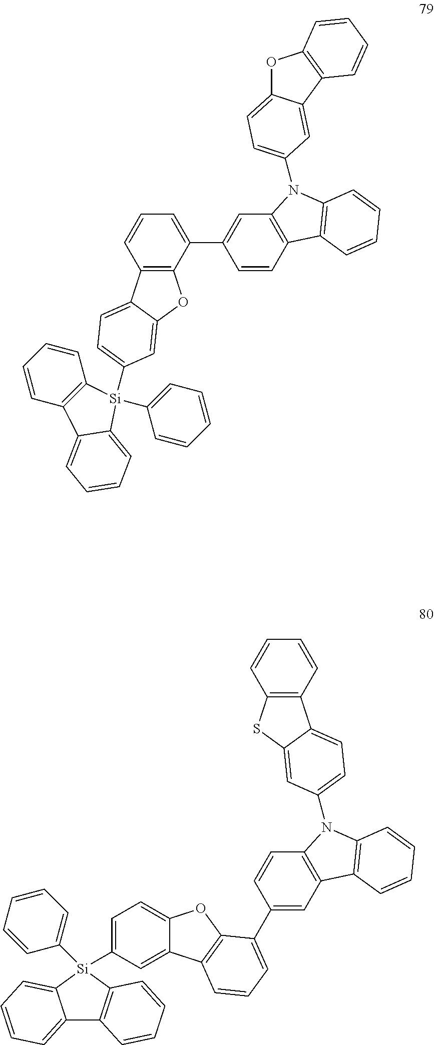 [SMILES: c1ccc([Si]2(c3ccc4c(c3)oc3c(-c5ccc6c7ccccc7n(-c7ccc8oc9ccccc9c8c7)c6c5)cccc34)c3ccccc3-c3ccccc32)cc1 ; c1ccc([Si]2(c3ccc4oc5c(-c6ccc7c(c6)c6ccccc6n7-c6ccc7c(c6)sc6ccccc67)cccc5c4c3)c3ccccc3-c3ccccc32)cc1]

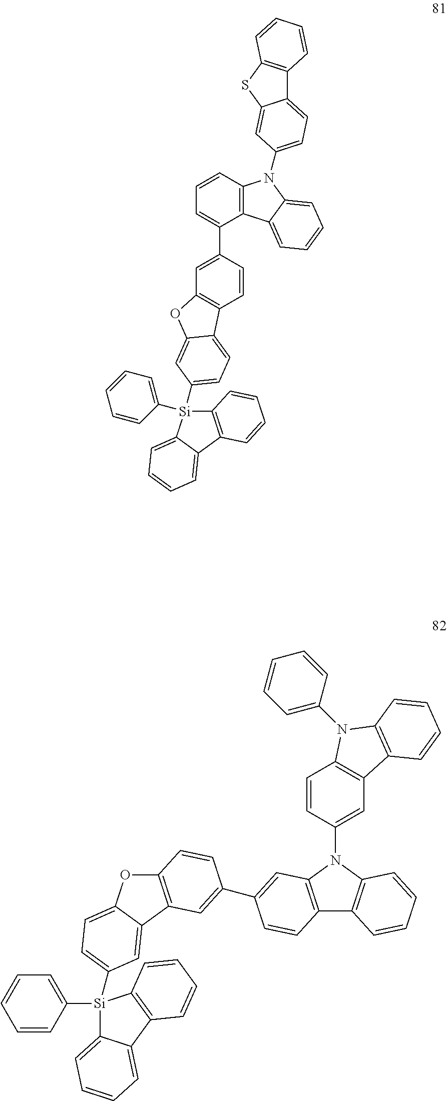 [SMILES: c1ccc([Si]2(c3ccc4c(c3)oc3cc(-c5cccc6c5c5ccccc5n6-c5ccc6c(c5)sc5ccccc56)ccc34)c3ccccc3-c3ccccc32)cc1 ; c1ccc(-n2c3ccccc3c3cc(-n4c5ccccc5c5ccc(-c6ccc7oc8ccc([Si]9(c%10ccccc%10)c%10ccccc%10-c%10ccccc%109)cc8c7c6)cc54)ccc32)cc1]

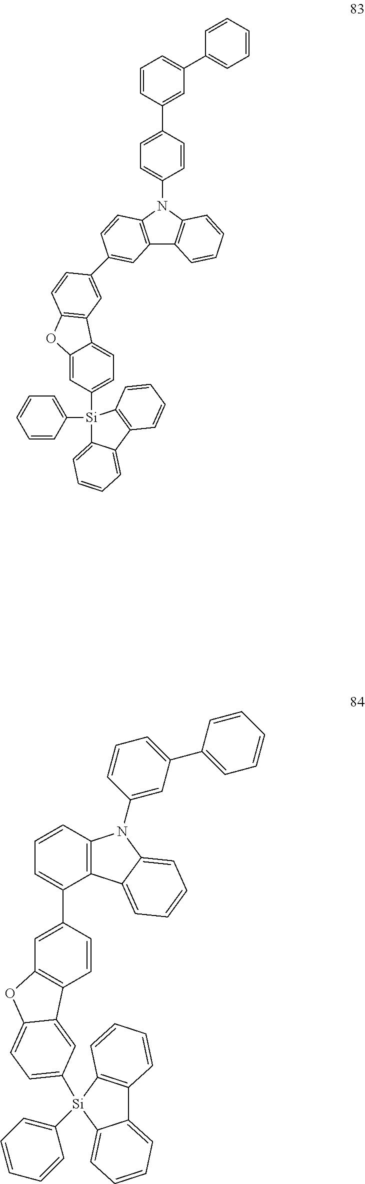 [SMILES: c1ccc(-c2cccc(-c3ccc(-n4c5ccccc5c5cc(-c6ccc7oc8cc([Si]9(c%10ccccc%10)c%10ccccc%10-c%10ccccc%109)ccc8c7c6)ccc54)cc3)c2)cc1 ; c1ccc(-c2cccc(-n3c4ccccc4c4c(-c5ccc6c(c5)oc5ccc([Si]7(c8ccccc8)c8ccccc8-c8ccccc87)cc56)cccc43)c2)cc1]

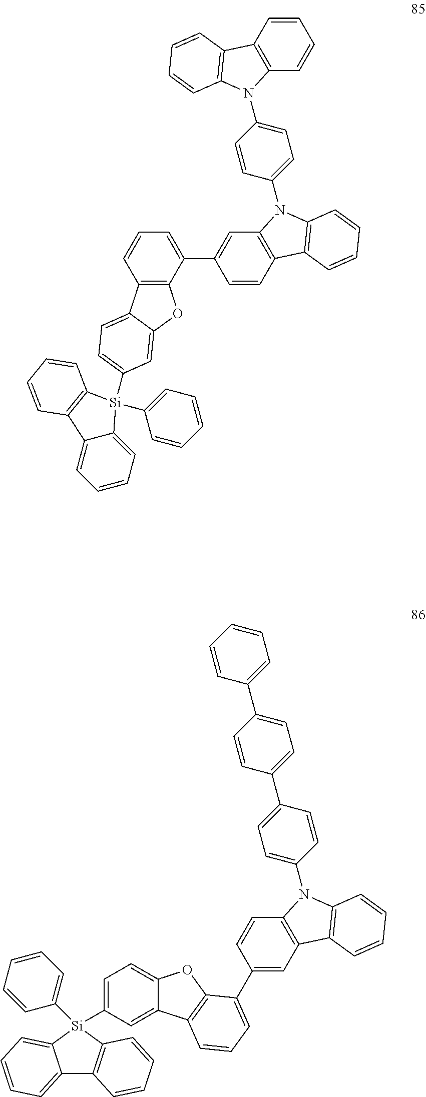 [SMILES: c1ccc([Si]2(c3ccc4c(c3)oc3c(-c5ccc6c7ccccc7n(-c7ccc(-n8c9ccccc9c9ccccc98)cc7)c6c5)cccc34)c3ccccc3-c3ccccc32)cc1 ; c1ccc(-c2ccc(-c3ccc(-n4c5ccccc5c5cc(-c6cccc7c6oc6ccc([Si]8(c9ccccc9)c9ccccc9-c9ccccc98)cc67)ccc54)cc3)cc2)cc1]

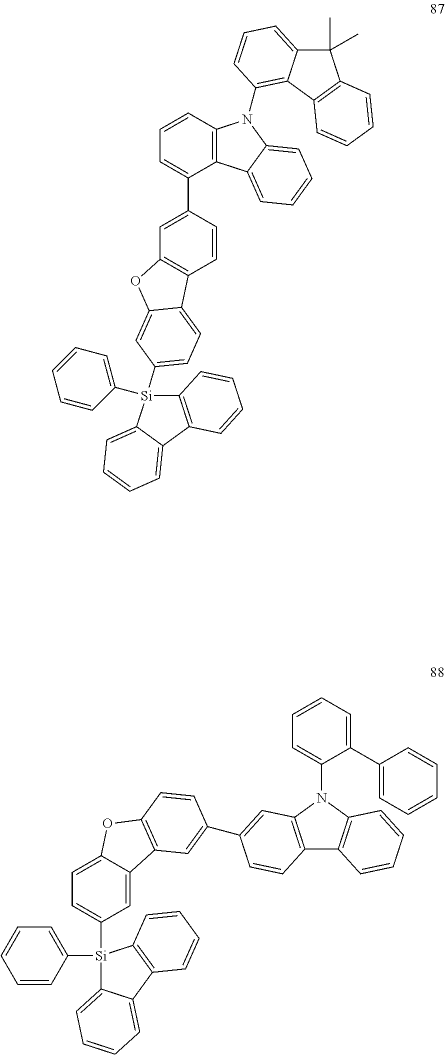 [SMILES: CC1(C)c2ccccc2-c2c(-n3c4ccccc4c4c(-c5ccc6c(c5)oc5cc([Si]7(c8ccccc8)c8ccccc8-c8ccccc87)ccc56)cccc43)cccc21 ; c1ccc(-c2ccccc2-n2c3ccccc3c3ccc(-c4ccc5oc6ccc([Si]7(c8ccccc8)c8ccccc8-c8ccccc87)cc6c5c4)cc32)cc1]

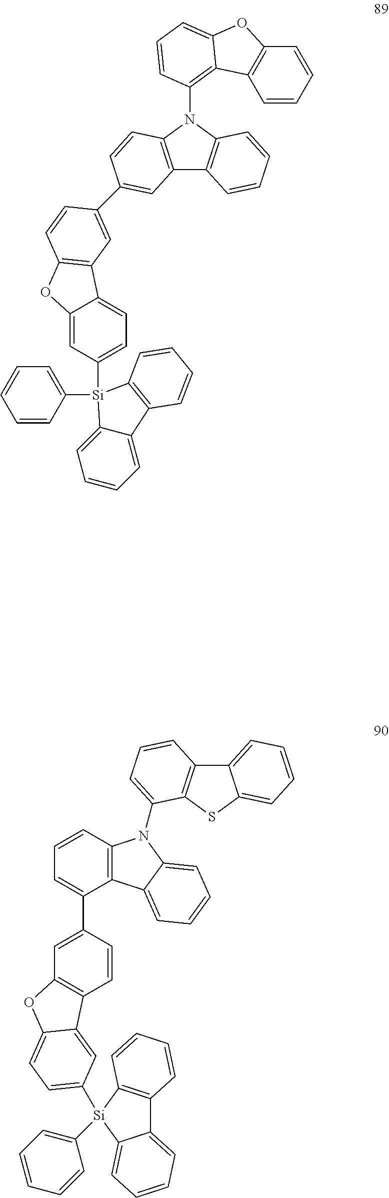 [SMILES: c1ccc([Si]2(c3ccc4c(c3)oc3ccc(-c5ccc6c(c5)c5ccccc5n6-c5cccc6oc7ccccc7c56)cc34)c3ccccc3-c3ccccc32)cc1 ; c1ccc([Si]2(c3ccc4oc5cc(-c6cccc7c6c6ccccc6n7-c6cccc7c6sc6ccccc67)ccc5c4c3)c3ccccc3-c3ccccc32)cc1]

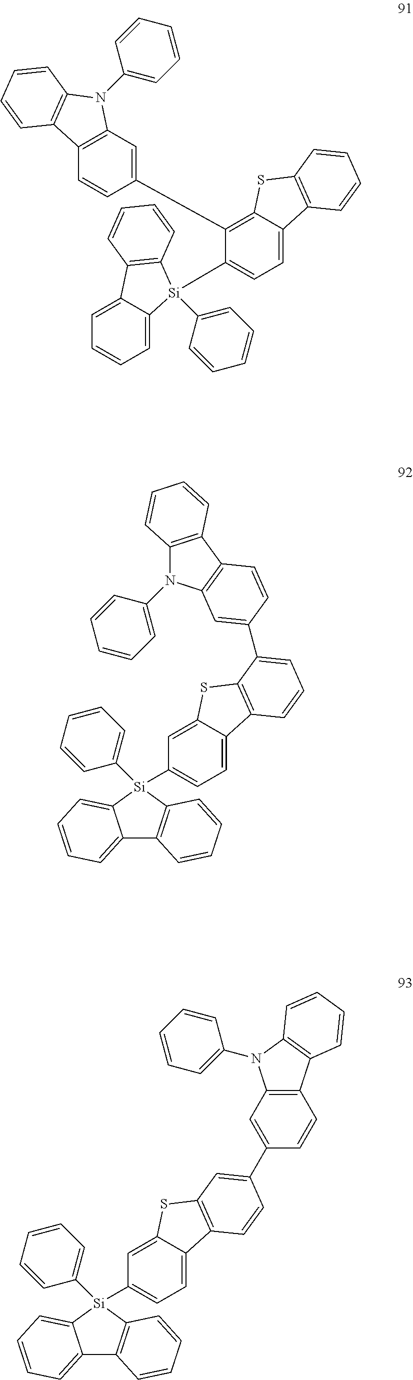 [SMILES: c1ccc(-n2c3ccccc3c3ccc(-c4c([Si]5(c6ccccc6)c6ccccc6-c6ccccc65)ccc5c4sc4ccccc45)cc32)cc1 ; c1ccc(-n2c3ccccc3c3ccc(-c4cccc5c4sc4cc([Si]6(c7ccccc7)c7ccccc7-c7ccccc76)ccc45)cc32)cc1 ; c1ccc(-n2c3ccccc3c3ccc(-c4ccc5c(c4)sc4cc([Si]6(c7ccccc7)c7ccccc7-c7ccccc76)ccc45)cc32)cc1]

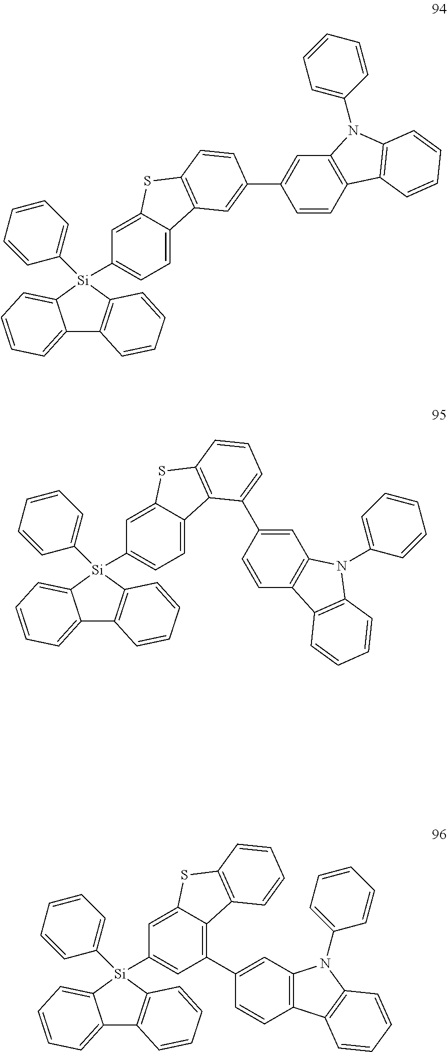 [SMILES: c1ccc(-n2c3ccccc3c3ccc(-c4ccc5sc6cc([Si]7(c8ccccc8)c8ccccc8-c8ccccc87)ccc6c5c4)cc32)cc1 ; c1ccc(-n2c3ccccc3c3ccc(-c4cccc5sc6cc([Si]7(c8ccccc8)c8ccccc8-c8ccccc87)ccc6c45)cc32)cc1 ; c1ccc(-n2c3ccccc3c3ccc(-c4cc([Si]5(c6ccccc6)c6ccccc6-c6ccccc65)cc5sc6ccccc6c45)cc32)cc1]

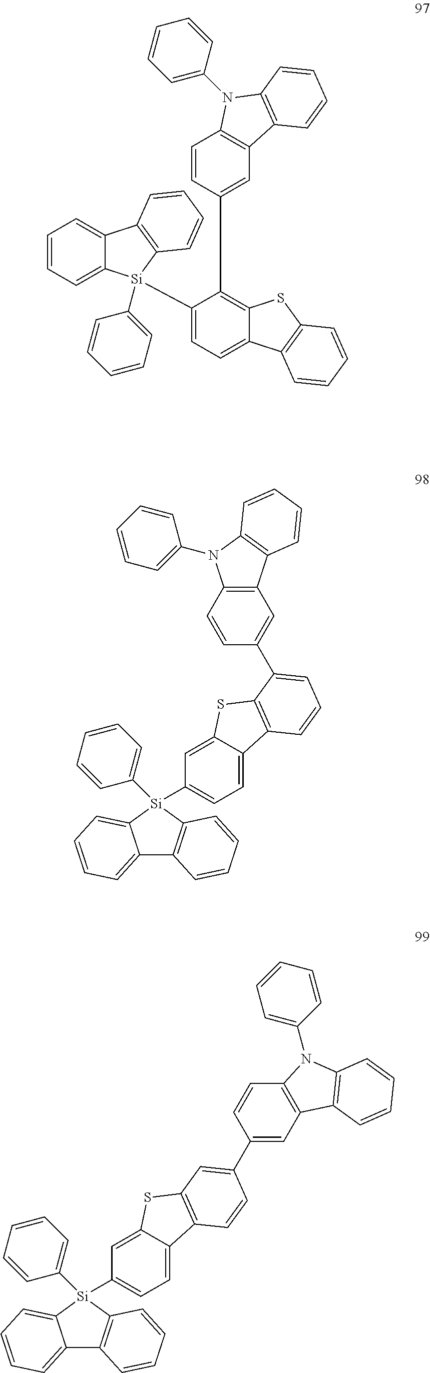 [SMILES: c1ccc(-n2c3ccccc3c3cc(-c4c([Si]5(c6ccccc6)c6ccccc6-c6ccccc65)ccc5c4sc4ccccc45)ccc32)cc1 ; c1ccc(-n2c3ccccc3c3cc(-c4cccc5c4sc4cc([Si]6(c7ccccc7)c7ccccc7-c7ccccc76)ccc45)ccc32)cc1 ; c1ccc(-n2c3ccccc3c3cc(-c4ccc5c(c4)sc4cc([Si]6(c7ccccc7)c7ccccc7-c7ccccc76)ccc45)ccc32)cc1]

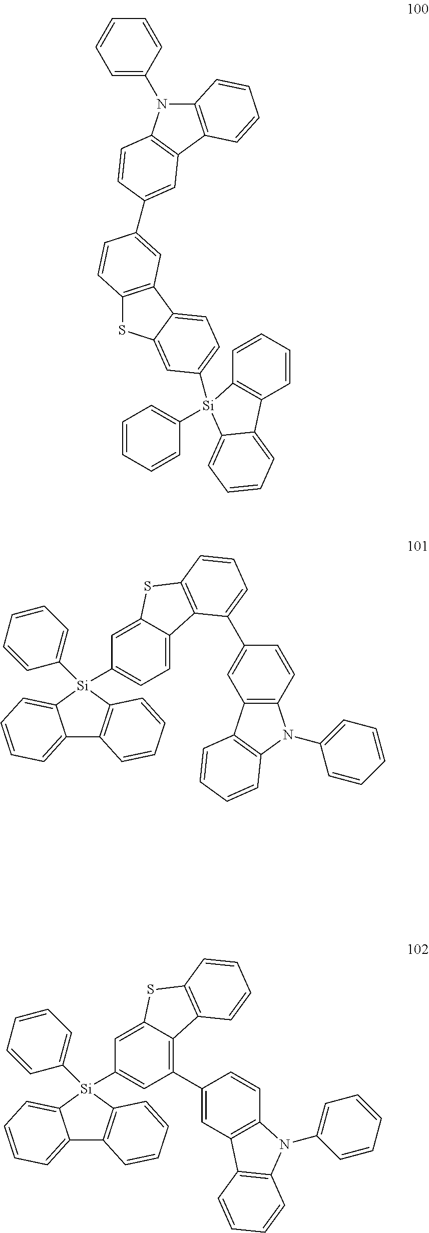 [SMILES: c1ccc(-n2c3ccccc3c3cc(-c4ccc5sc6cc([Si]7(c8ccccc8)c8ccccc8-c8ccccc87)ccc6c5c4)ccc32)cc1 ; c1ccc(-n2c3ccccc3c3cc(-c4cccc5sc6cc([Si]7(c8ccccc8)c8ccccc8-c8ccccc87)ccc6c45)ccc32)cc1 ; c1ccc(-n2c3ccccc3c3cc(-c4cc([Si]5(c6ccccc6)c6ccccc6-c6ccccc65)cc5sc6ccccc6c45)ccc32)cc1]

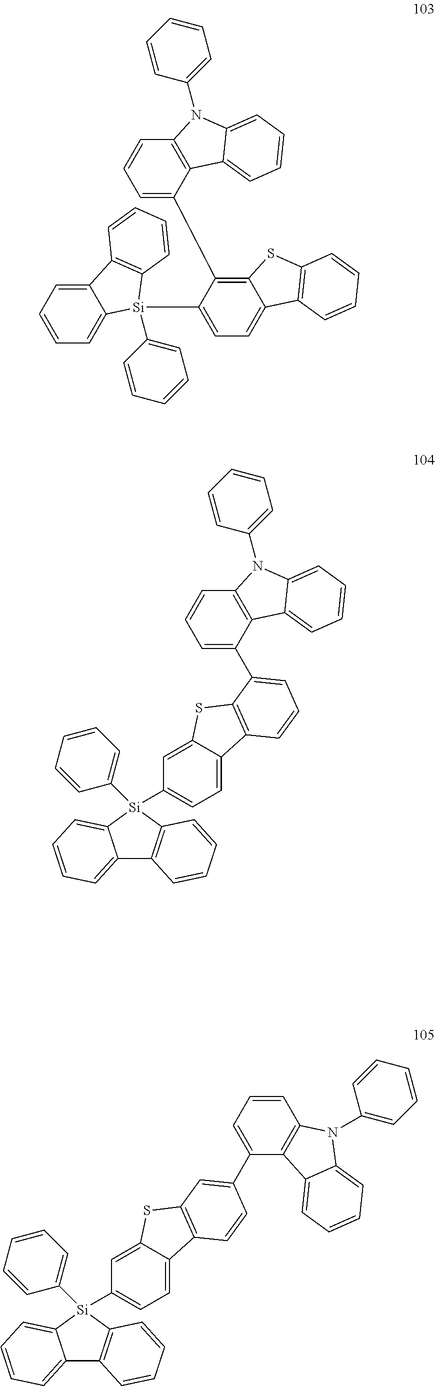 [SMILES: c1ccc(-n2c3ccccc3c3c(-c4c([Si]5(c6ccccc6)c6ccccc6-c6ccccc65)ccc5c4sc4ccccc45)cccc32)cc1 ; c1ccc(-n2c3ccccc3c3c(-c4cccc5c4sc4cc([Si]6(c7ccccc7)c7ccccc7-c7ccccc76)ccc45)cccc32)cc1 ; c1ccc(-n2c3ccccc3c3c(-c4ccc5c(c4)sc4cc([Si]6(c7ccccc7)c7ccccc7-c7ccccc76)ccc45)cccc32)cc1]

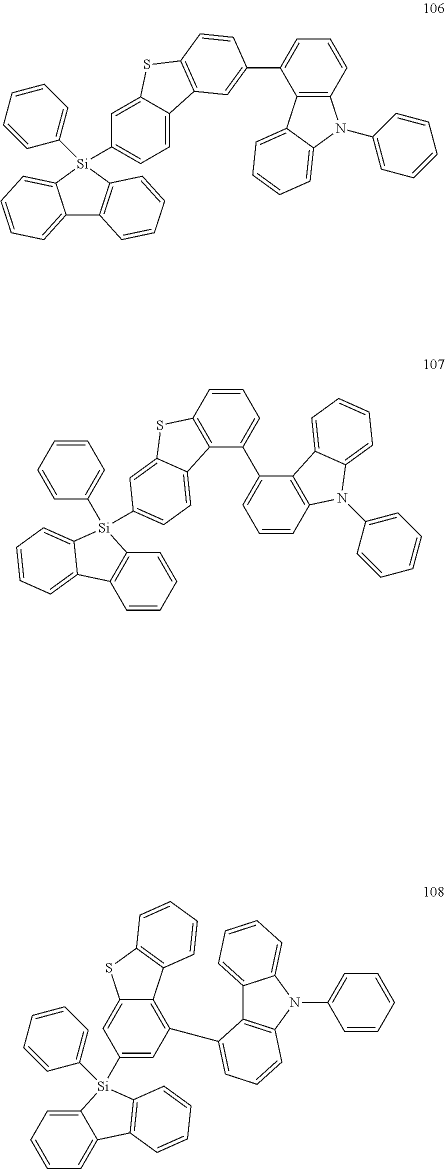 [SMILES: c1ccc(-n2c3ccccc3c3c(-c4ccc5sc6cc([Si]7(c8ccccc8)c8ccccc8-c8ccccc87)ccc6c5c4)cccc32)cc1 ; c1ccc(-n2c3ccccc3c3c(-c4cccc5sc6cc([Si]7(c8ccccc8)c8ccccc8-c8ccccc87)ccc6c45)cccc32)cc1 ; c1ccc(-n2c3ccccc3c3c(-c4cc([Si]5(c6ccccc6)c6ccccc6-c6ccccc65)cc5sc6ccccc6c45)cccc32)cc1]

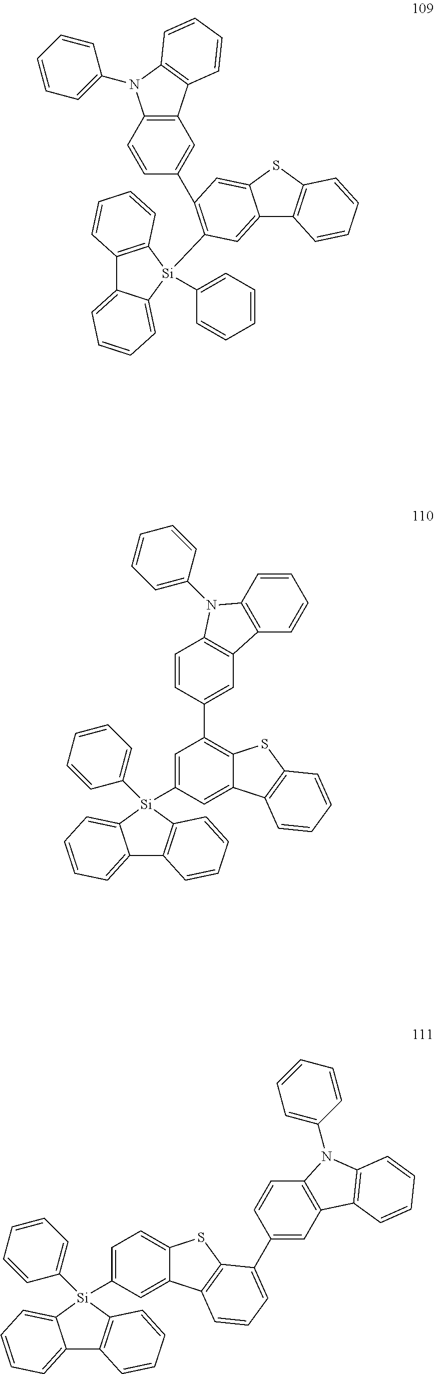 [SMILES: c1ccc(-n2c3ccccc3c3cc(-c4cc5sc6ccccc6c5cc4[Si]4(c5ccccc5)c5ccccc5-c5ccccc54)ccc32)cc1 ; c1ccc(-n2c3ccccc3c3cc(-c4cc([Si]5(c6ccccc6)c6ccccc6-c6ccccc65)cc5c4sc4ccccc45)ccc32)cc1 ; c1ccc(-n2c3ccccc3c3cc(-c4cccc5c4sc4ccc([Si]6(c7ccccc7)c7ccccc7-c7ccccc76)cc45)ccc32)cc1]

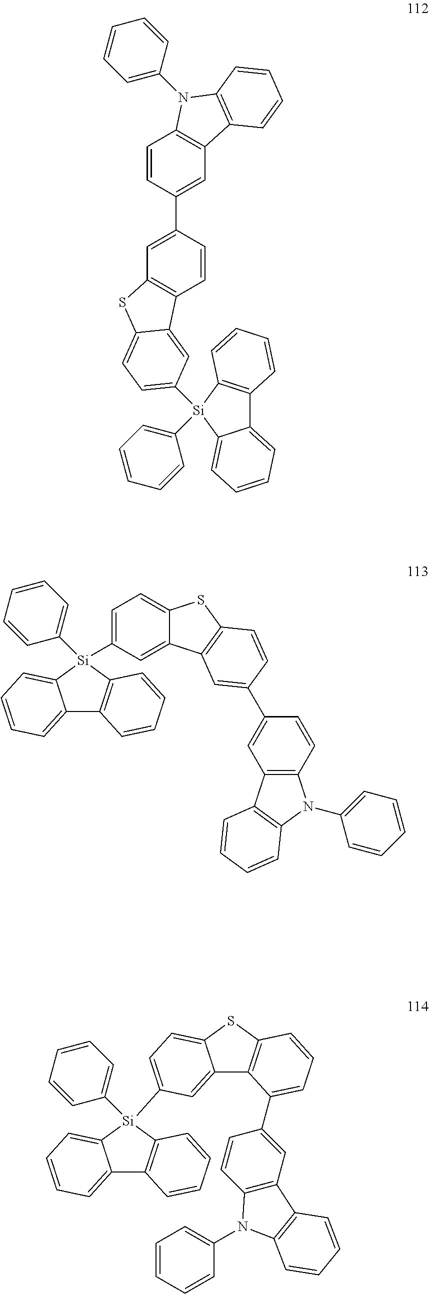 [SMILES: c1ccc(-n2c3ccccc3c3cc(-c4ccc5c(c4)sc4ccc([Si]6(c7ccccc7)c7ccccc7-c7ccccc76)cc45)ccc32)cc1 ; c1ccc(-n2c3ccccc3c3cc(-c4ccc5sc6ccc([Si]7(c8ccccc8)c8ccccc8-c8ccccc87)cc6c5c4)ccc32)cc1 ; c1ccc(-n2c3ccccc3c3cc(-c4cccc5sc6ccc([Si]7(c8ccccc8)c8ccccc8-c8ccccc87)cc6c45)ccc32)cc1]

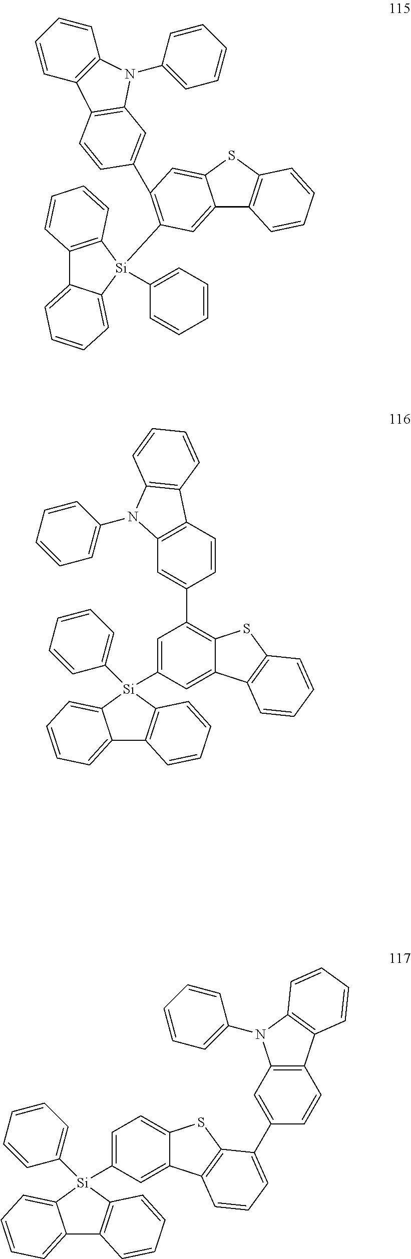 [SMILES: c1ccc(-n2c3ccccc3c3ccc(-c4cc5sc6ccccc6c5cc4[Si]4(c5ccccc5)c5ccccc5-c5ccccc54)cc32)cc1 ; c1ccc(-n2c3ccccc3c3ccc(-c4cc([Si]5(c6ccccc6)c6ccccc6-c6ccccc65)cc5c4sc4ccccc45)cc32)cc1 ; c1ccc(-n2c3ccccc3c3ccc(-c4cccc5c4sc4ccc([Si]6(c7ccccc7)c7ccccc7-c7ccccc76)cc45)cc32)cc1]

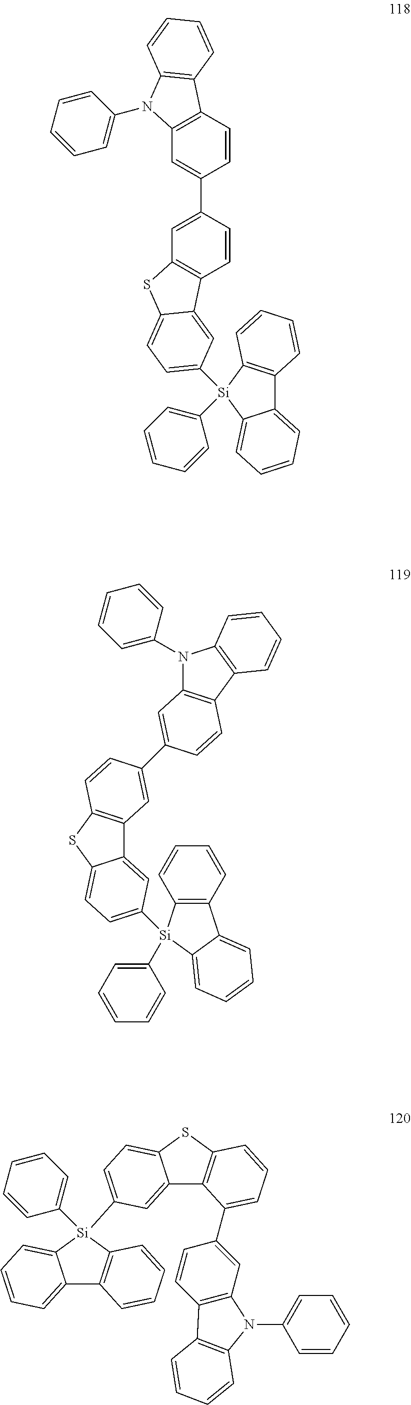 [SMILES: c1ccc(-n2c3ccccc3c3ccc(-c4ccc5c(c4)sc4ccc([Si]6(c7ccccc7)c7ccccc7-c7ccccc76)cc45)cc32)cc1 ; c1ccc(-n2c3ccccc3c3ccc(-c4ccc5sc6ccc([Si]7(c8ccccc8)c8ccccc8-c8ccccc87)cc6c5c4)cc32)cc1 ; c1ccc(-n2c3ccccc3c3ccc(-c4cccc5sc6ccc([Si]7(c8ccccc8)c8ccccc8-c8ccccc87)cc6c45)cc32)cc1]

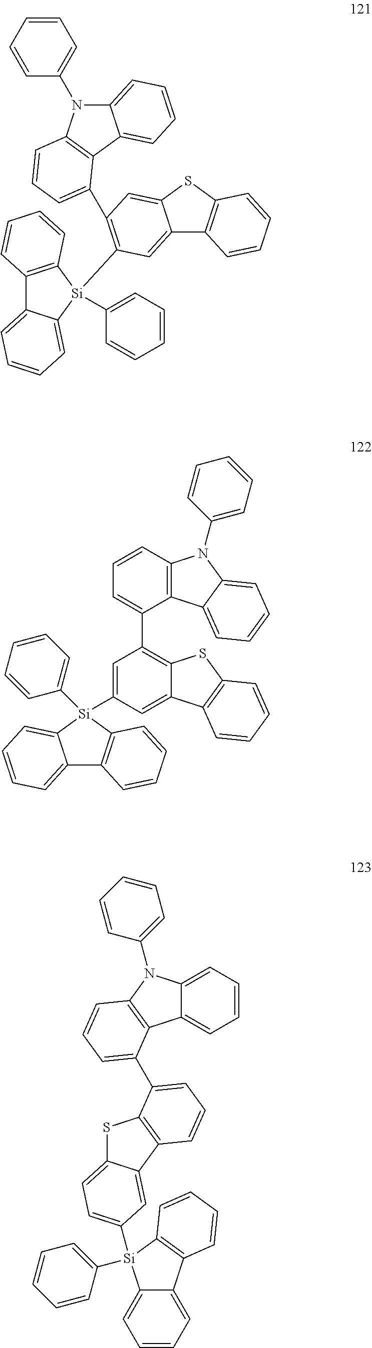 [SMILES: c1ccc(-n2c3ccccc3c3c(-c4cc5sc6ccccc6c5cc4[Si]4(c5ccccc5)c5ccccc5-c5ccccc54)cccc32)cc1 ; c1ccc(-n2c3ccccc3c3c(-c4cc([Si]5(c6ccccc6)c6ccccc6-c6ccccc65)cc5c4sc4ccccc45)cccc32)cc1 ; c1ccc(-n2c3ccccc3c3c(-c4cccc5c4sc4ccc([Si]6(c7ccccc7)c7ccccc7-c7ccccc76)cc45)cccc32)cc1]

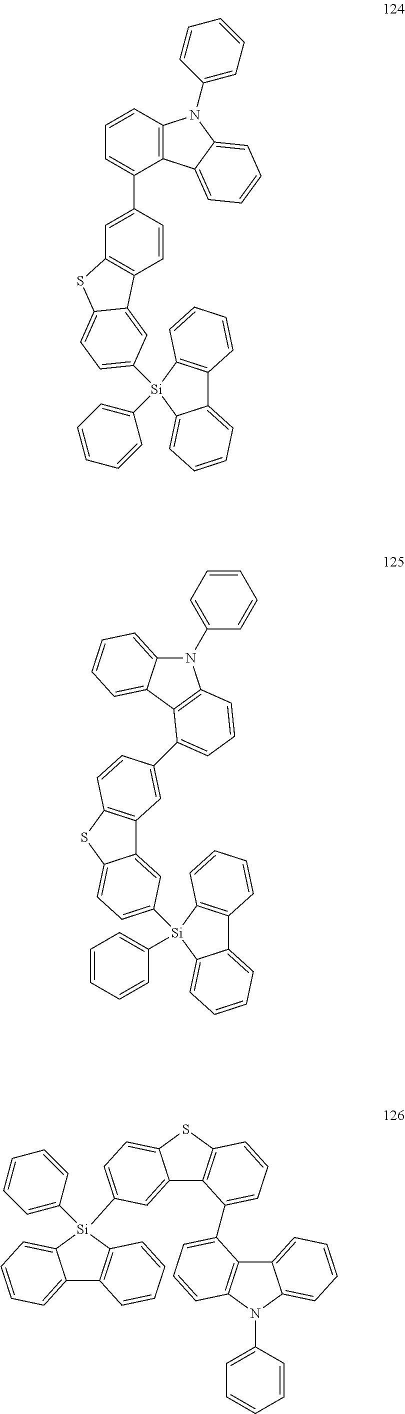 [SMILES: c1ccc(-n2c3ccccc3c3c(-c4ccc5c(c4)sc4ccc([Si]6(c7ccccc7)c7ccccc7-c7ccccc76)cc45)cccc32)cc1 ; c1ccc(-n2c3ccccc3c3c(-c4ccc5sc6ccc([Si]7(c8ccccc8)c8ccccc8-c8ccccc87)cc6c5c4)cccc32)cc1 ; c1ccc(-n2c3ccccc3c3c(-c4cccc5sc6ccc([Si]7(c8ccccc8)c8ccccc8-c8ccccc87)cc6c45)cccc32)cc1]

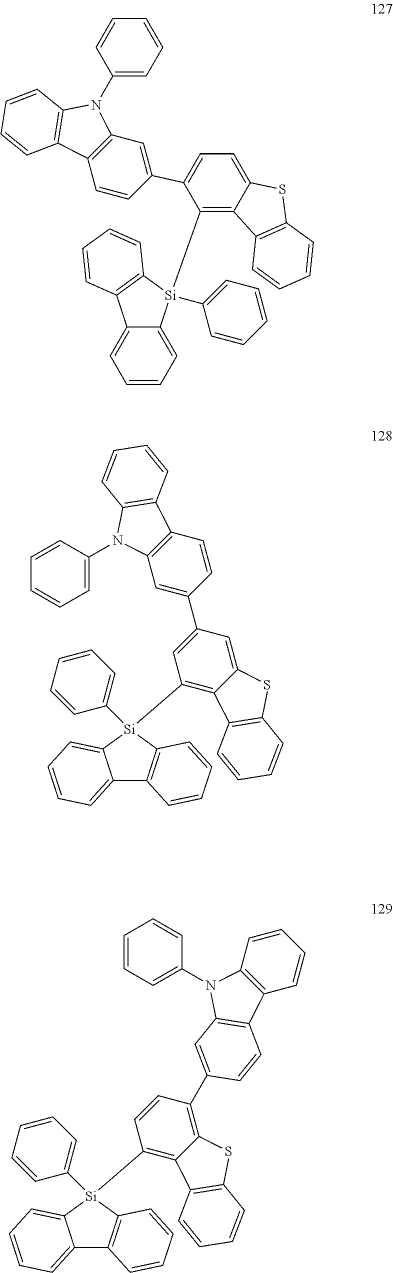 [SMILES: c1ccc(-n2c3ccccc3c3ccc(-c4ccc5sc6ccccc6c5c4[Si]4(c5ccccc5)c5ccccc5-c5ccccc54)cc32)cc1 ; c1ccc(-n2c3ccccc3c3ccc(-c4cc([Si]5(c6ccccc6)c6ccccc6-c6ccccc65)c5c(c4)sc4ccccc45)cc32)cc1 ; c1ccc(-n2c3ccccc3c3ccc(-c4ccc([Si]5(c6ccccc6)c6ccccc6-c6ccccc65)c5c4sc4ccccc45)cc32)cc1]

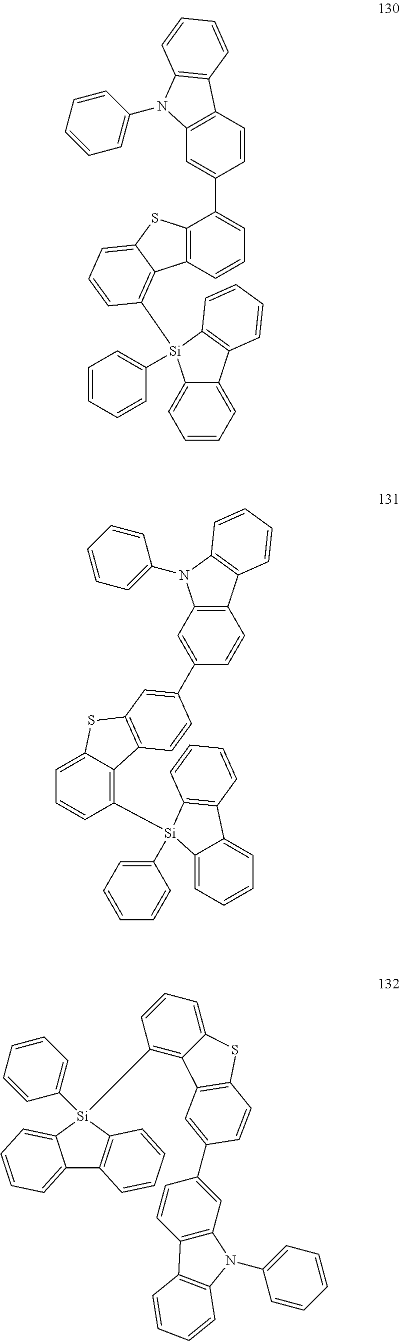 [SMILES: c1ccc(-n2c3ccccc3c3ccc(-c4cccc5c4sc4cccc([Si]6(c7ccccc7)c7ccccc7-c7ccccc76)c45)cc32)cc1 ; c1ccc(-n2c3ccccc3c3ccc(-c4ccc5c(c4)sc4cccc([Si]6(c7ccccc7)c7ccccc7-c7ccccc76)c45)cc32)cc1 ; c1ccc(-n2c3ccccc3c3ccc(-c4ccc5sc6cccc([Si]7(c8ccccc8)c8ccccc8-c8ccccc87)c6c5c4)cc32)cc1]

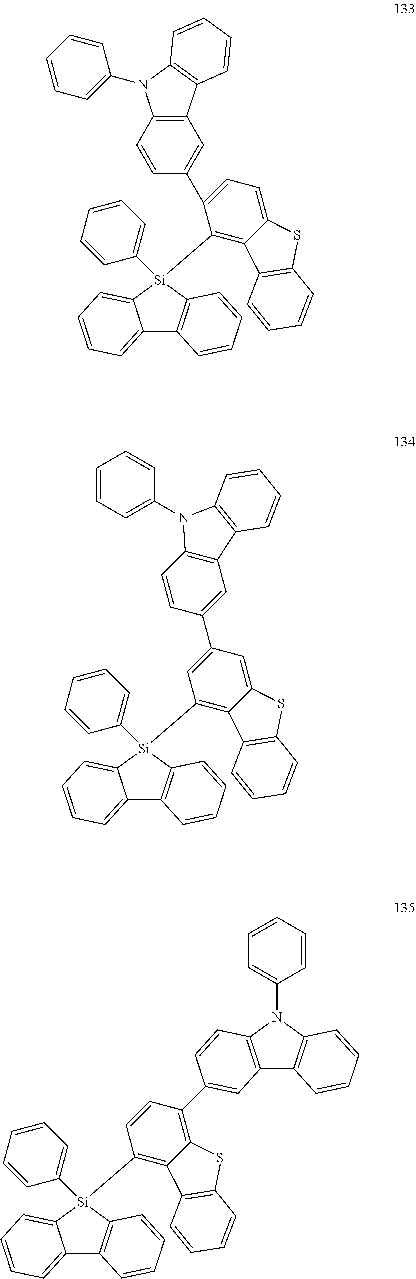 [SMILES: c1ccc(-n2c3ccccc3c3cc(-c4ccc5sc6ccccc6c5c4[Si]4(c5ccccc5)c5ccccc5-c5ccccc54)ccc32)cc1 ; c1ccc(-n2c3ccccc3c3cc(-c4cc([Si]5(c6ccccc6)c6ccccc6-c6ccccc65)c5c(c4)sc4ccccc45)ccc32)cc1 ; c1ccc(-n2c3ccccc3c3cc(-c4ccc([Si]5(c6ccccc6)c6ccccc6-c6ccccc65)c5c4sc4ccccc45)ccc32)cc1]

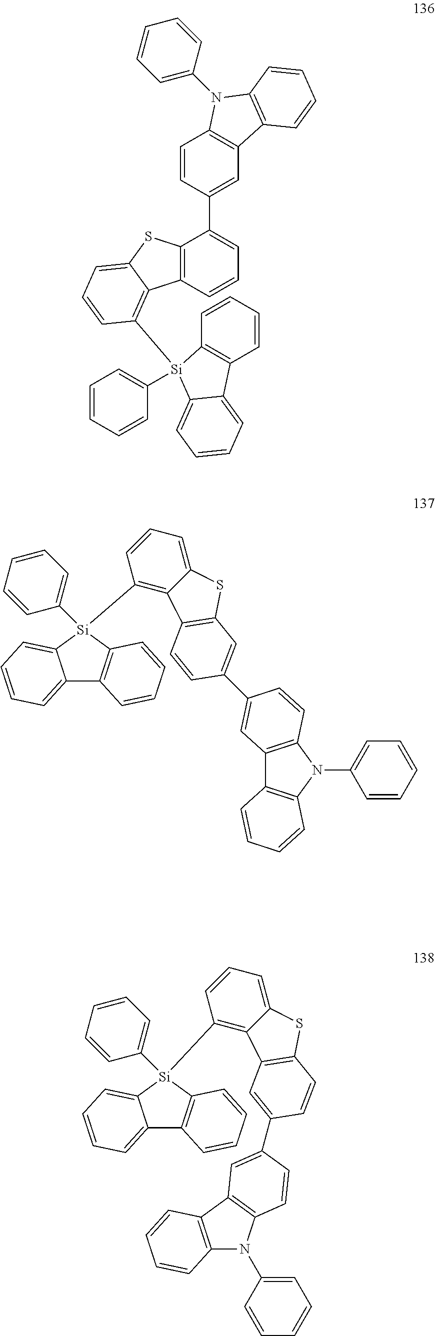 [SMILES: c1ccc(-n2c3ccccc3c3cc(-c4cccc5c4sc4cccc([Si]6(c7ccccc7)c7ccccc7-c7ccccc76)c45)ccc32)cc1 ; c1ccc(-n2c3ccccc3c3cc(-c4ccc5c(c4)sc4cccc([Si]6(c7ccccc7)c7ccccc7-c7ccccc76)c45)ccc32)cc1 ; c1ccc(-n2c3ccccc3c3cc(-c4ccc5sc6cccc([Si]7(c8ccccc8)c8ccccc8-c8ccccc87)c6c5c4)ccc32)cc1]

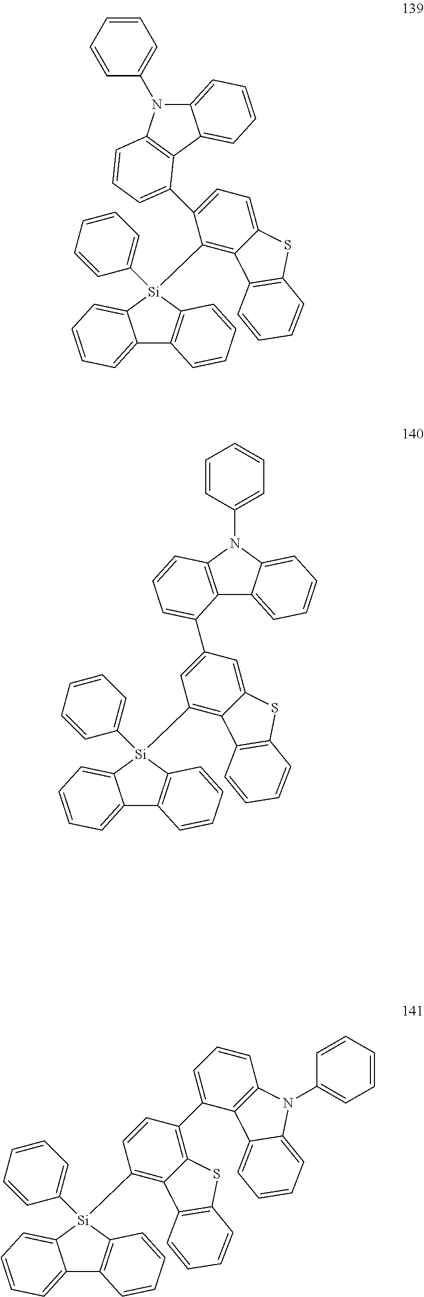 [SMILES: c1ccc(-n2c3ccccc3c3c(-c4ccc5sc6ccccc6c5c4[Si]4(c5ccccc5)c5ccccc5-c5ccccc54)cccc32)cc1 ; c1ccc(-n2c3ccccc3c3c(-c4cc([Si]5(c6ccccc6)c6ccccc6-c6ccccc65)c5c(c4)sc4ccccc45)cccc32)cc1 ; c1ccc(-n2c3ccccc3c3c(-c4ccc([Si]5(c6ccccc6)c6ccccc6-c6ccccc65)c5c4sc4ccccc45)cccc32)cc1]

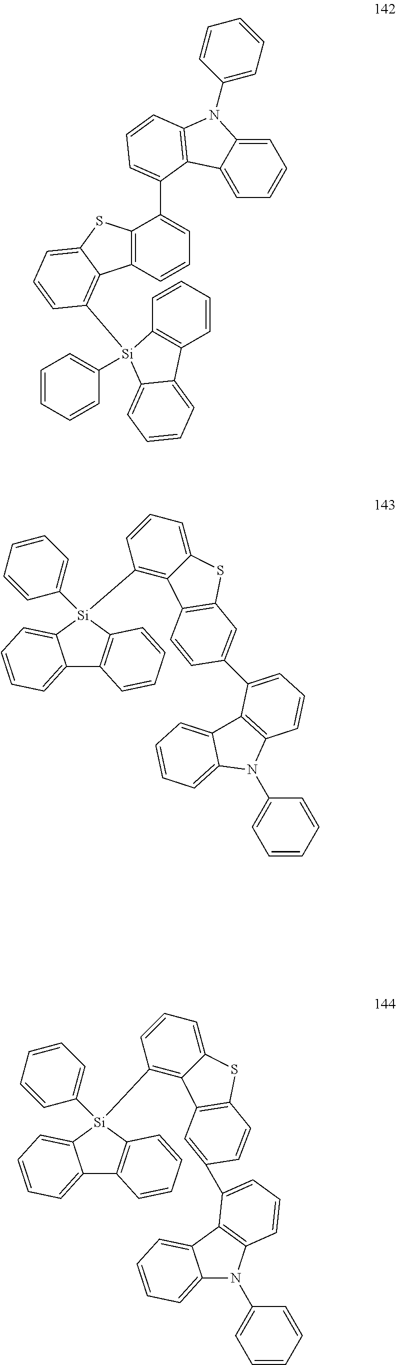 [SMILES: c1ccc(-n2c3ccccc3c3c(-c4cccc5c4sc4cccc([Si]6(c7ccccc7)c7ccccc7-c7ccccc76)c45)cccc32)cc1 ; c1ccc(-n2c3ccccc3c3c(-c4ccc5c(c4)sc4cccc([Si]6(c7ccccc7)c7ccccc7-c7ccccc76)c45)cccc32)cc1 ; c1ccc(-n2c3ccccc3c3c(-c4ccc5sc6cccc([Si]7(c8ccccc8)c8ccccc8-c8ccccc87)c6c5c4)cccc32)cc1]

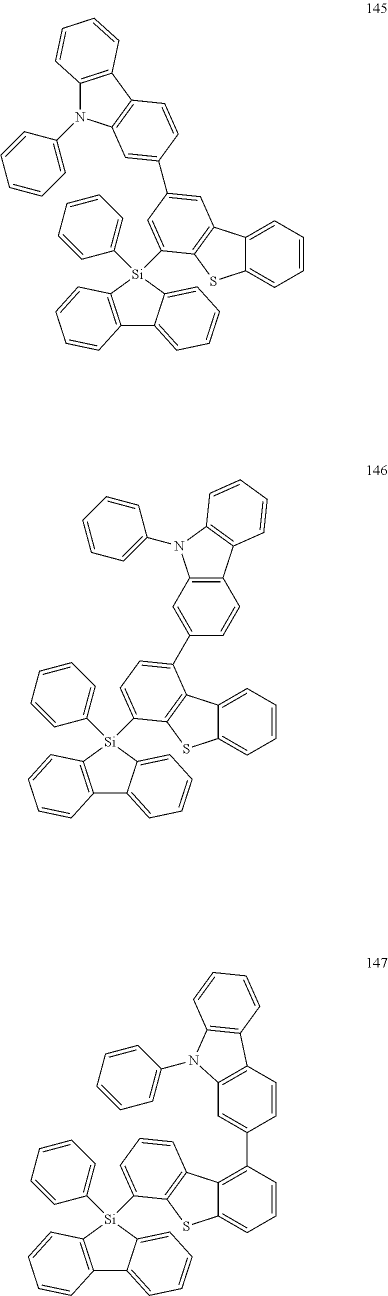 [SMILES: c1ccc(-n2c3ccccc3c3ccc(-c4cc([Si]5(c6ccccc6)c6ccccc6-c6ccccc65)c5sc6ccccc6c5c4)cc32)cc1 ; c1ccc(-n2c3ccccc3c3ccc(-c4ccc([Si]5(c6ccccc6)c6ccccc6-c6ccccc65)c5sc6ccccc6c45)cc32)cc1 ; c1ccc(-n2c3ccccc3c3ccc(-c4cccc5sc6c([Si]7(c8ccccc8)c8ccccc8-c8ccccc87)cccc6c45)cc32)cc1]

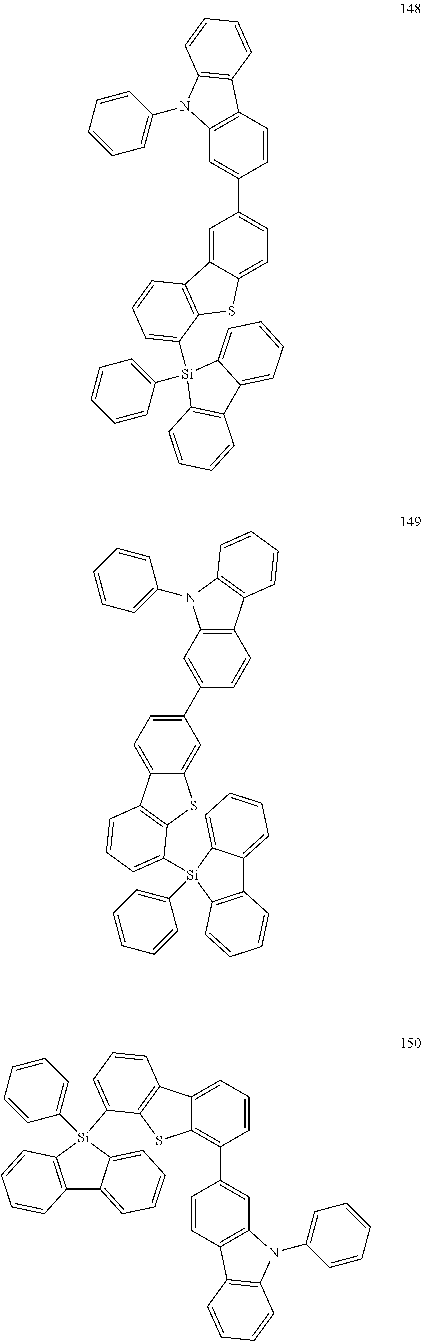 [SMILES: c1ccc(-n2c3ccccc3c3ccc(-c4ccc5sc6c([Si]7(c8ccccc8)c8ccccc8-c8ccccc87)cccc6c5c4)cc32)cc1 ; c1ccc(-n2c3ccccc3c3ccc(-c4ccc5c(c4)sc4c([Si]6(c7ccccc7)c7ccccc7-c7ccccc76)cccc45)cc32)cc1 ; c1ccc(-n2c3ccccc3c3ccc(-c4cccc5c4sc4c([Si]6(c7ccccc7)c7ccccc7-c7ccccc76)cccc45)cc32)cc1]

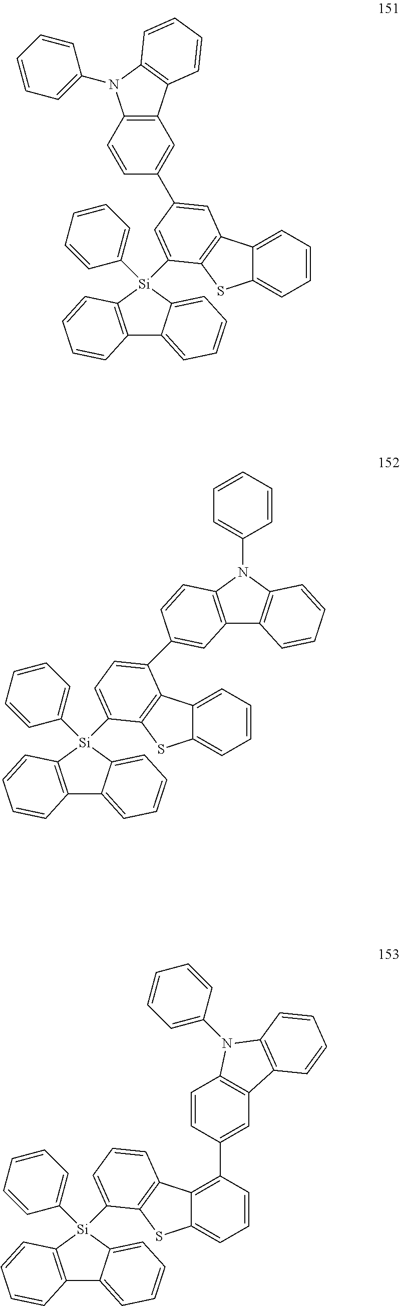 [SMILES: c1ccc(-n2c3ccccc3c3cc(-c4cc([Si]5(c6ccccc6)c6ccccc6-c6ccccc65)c5sc6ccccc6c5c4)ccc32)cc1 ; c1ccc(-n2c3ccccc3c3cc(-c4ccc([Si]5(c6ccccc6)c6ccccc6-c6ccccc65)c5sc6ccccc6c45)ccc32)cc1 ; c1ccc(-n2c3ccccc3c3cc(-c4cccc5sc6c([Si]7(c8ccccc8)c8ccccc8-c8ccccc87)cccc6c45)ccc32)cc1]

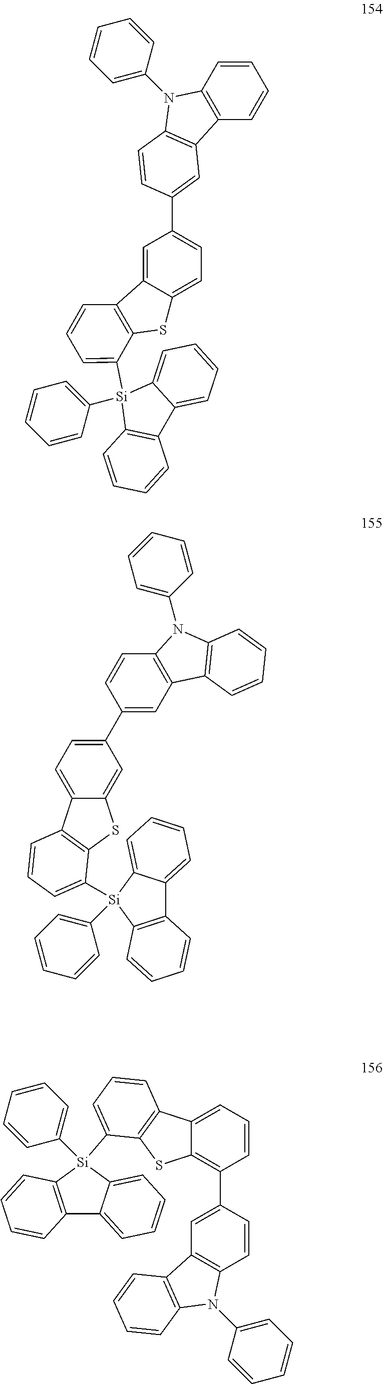

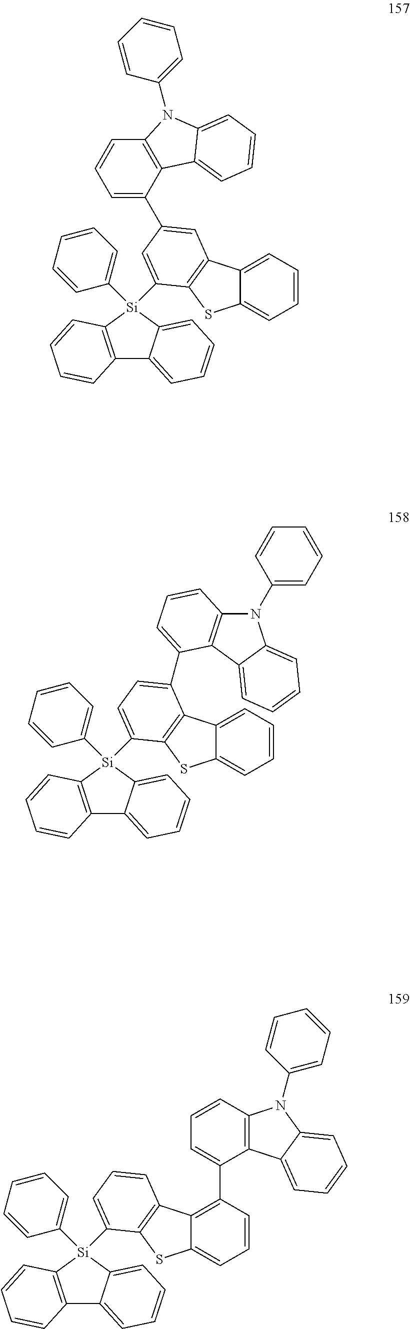 [SMILES: c1ccc(-n2c3ccccc3c3c(-c4cc([Si]5(c6ccccc6)c6ccccc6-c6ccccc65)c5sc6ccccc6c5c4)cccc32)cc1 ; c1ccc(-n2c3ccccc3c3c(-c4ccc([Si]5(c6ccccc6)c6ccccc6-c6ccccc65)c5sc6ccccc6c45)cccc32)cc1 ; c1ccc(-n2c3ccccc3c3c(-c4cccc5sc6c([Si]7(c8ccccc8)c8ccccc8-c8ccccc87)cccc6c45)cccc32)cc1]

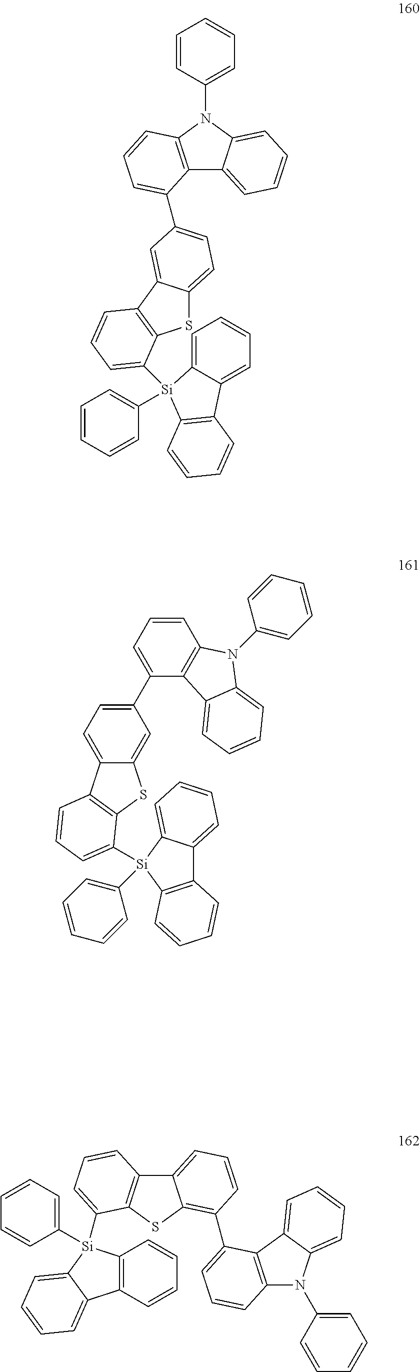 [SMILES: c1ccc(-n2c3ccccc3c3c(-c4ccc5sc6c([Si]7(c8ccccc8)c8ccccc8-c8ccccc87)cccc6c5c4)cccc32)cc1 ; c1ccc(-n2c3ccccc3c3c(-c4ccc5c(c4)sc4c([Si]6(c7ccccc7)c7ccccc7-c7ccccc76)cccc45)cccc32)cc1 ; c1ccc(-n2c3ccccc3c3c(-c4cccc5c4sc4c([Si]6(c7ccccc7)c7ccccc7-c7ccccc76)cccc45)cccc32)cc1]

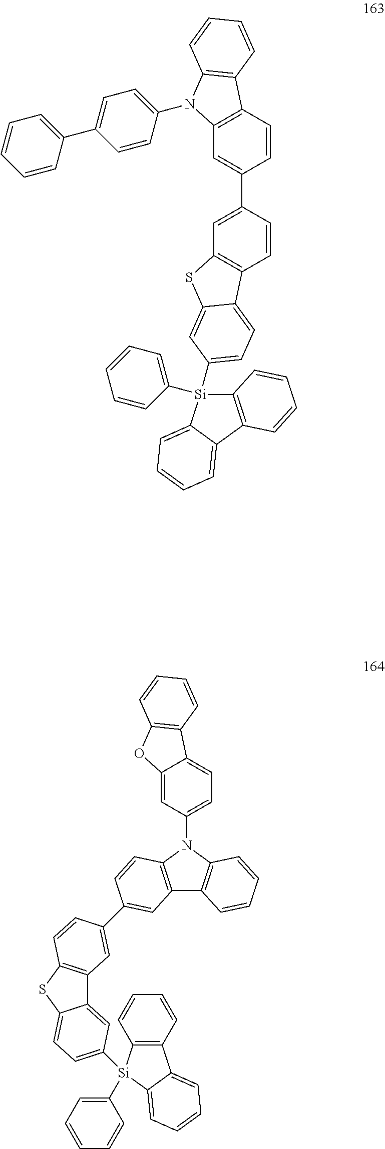 [SMILES: c1ccc(-c2ccc(-n3c4ccccc4c4ccc(-c5ccc6c(c5)sc5cc([Si]7(c8ccccc8)c8ccccc8-c8ccccc87)ccc56)cc43)cc2)cc1 ; c1ccc([Si]2(c3ccc4sc5ccc(-c6ccc7c(c6)c6ccccc6n7-c6ccc7c(c6)oc6ccccc67)cc5c4c3)c3ccccc3-c3ccccc32)cc1]

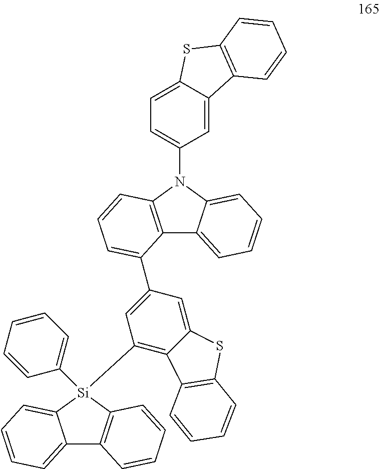 [SMILES: c1ccc([Si]2(c3cc(-c4cccc5c4c4ccccc4n5-c4ccc5sc6ccccc6c5c4)cc4sc5ccccc5c34)c3ccccc3-c3ccccc32)cc1]

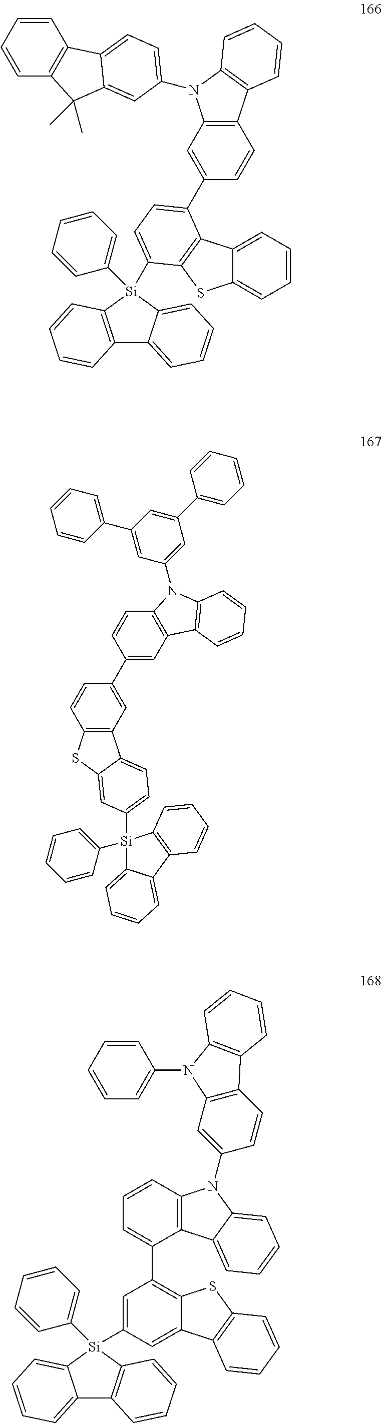 [SMILES: CC1(C)c2ccccc2-c2ccc(-n3c4ccccc4c4ccc(-c5ccc([Si]6(c7ccccc7)c7ccccc7-c7ccccc76)c6sc7ccccc7c56)cc43)cc21 ; c1ccc(-c2cc(-c3ccccc3)cc(-n3c4ccccc4c4cc(-c5ccc6sc7cc([Si]8(c9ccccc9)c9ccccc9-c9ccccc98)ccc7c6c5)ccc43)c2)cc1 ; c1ccc(-n2c3ccccc3c3ccc(-n4c5ccccc5c5c(-c6cc([Si]7(c8ccccc8)c8ccccc8-c8ccccc87)cc7c6sc6ccccc67)cccc54)cc32)cc1]

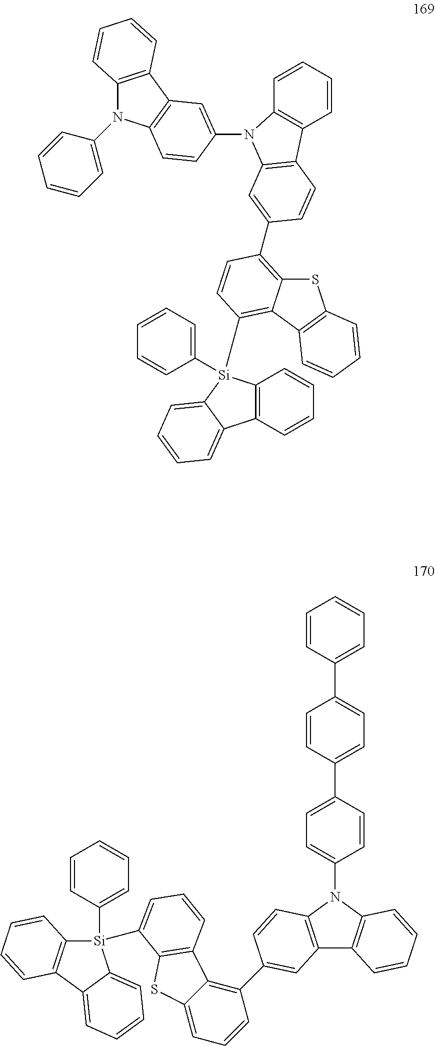 [SMILES: c1ccc(-n2c3ccccc3c3cc(-n4c5ccccc5c5ccc(-c6ccc([Si]7(c8ccccc8)c8ccccc8-c8ccccc87)c7c6sc6ccccc67)cc54)ccc32)cc1 ; c1ccc(-c2ccc(-c3ccc(-n4c5ccccc5c5cc(-c6cccc7sc8c([Si]9(c%10ccccc%10)c%10ccccc%10-c%10ccccc%109)cccc8c67)ccc54)cc3)cc2)cc1]

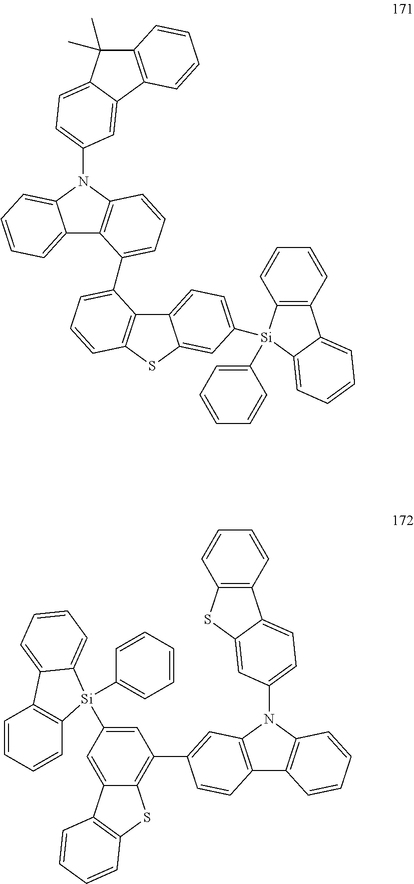 [SMILES: CC1(C)c2ccccc2-c2cc(-n3c4ccccc4c4c(-c5cccc6sc7cc([Si]8(c9ccccc9)c9ccccc9-c9ccccc98)ccc7c56)cccc43)ccc21 ; c1ccc([Si]2(c3cc(-c4ccc5c6ccccc6n(-c6ccc7c(c6)sc6ccccc67)c5c4)c4sc5ccccc5c4c3)c3ccccc3-c3ccccc32)cc1]

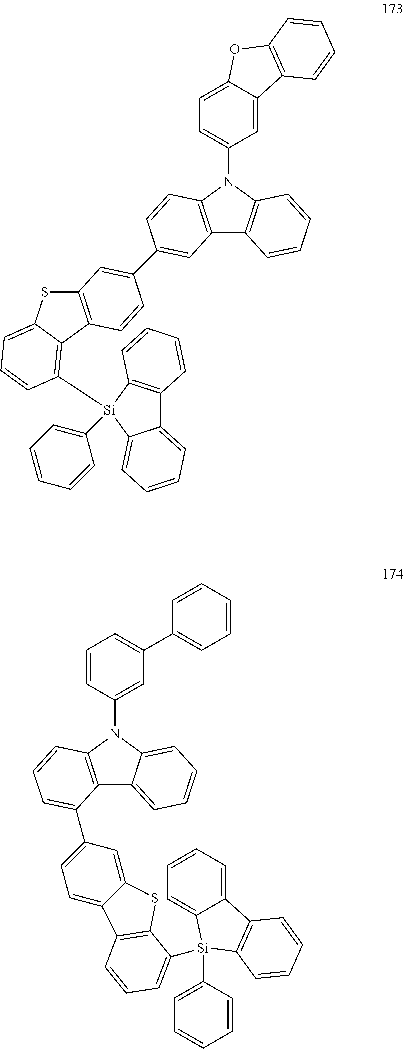 [SMILES: c1ccc([Si]2(c3cccc4sc5cc(-c6ccc7c(c6)c6ccccc6n7-c6ccc7oc8ccccc8c7c6)ccc5c34)c3ccccc3-c3ccccc32)cc1 ; c1ccc(-c2cccc(-n3c4ccccc4c4c(-c5ccc6c(c5)sc5c([Si]7(c8ccccc8)c8ccccc8-c8ccccc87)cccc56)cccc43)c2)cc1]

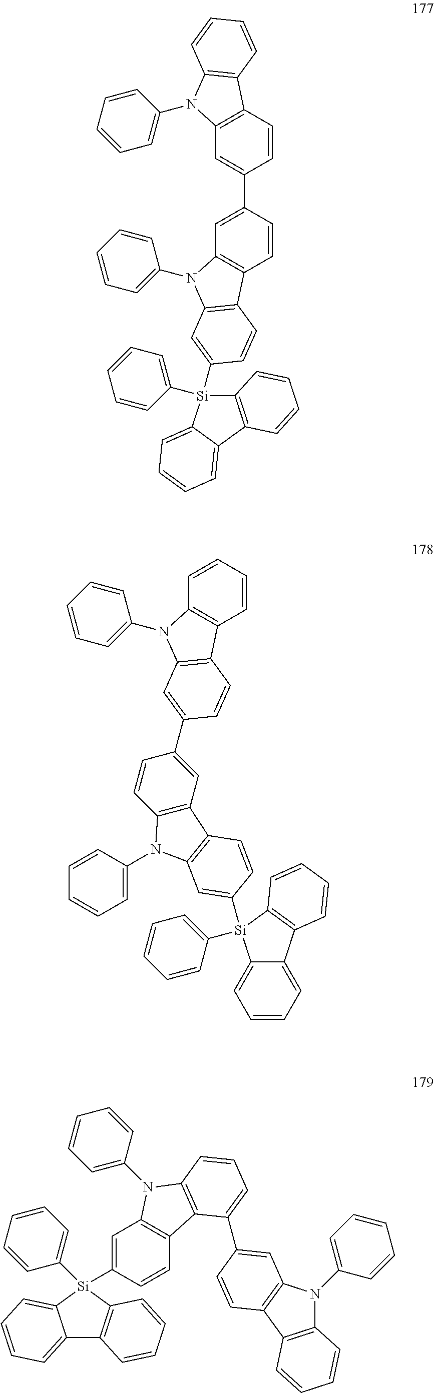 [SMILES: c1ccc(-n2c3ccccc3c3ccc(-c4ccc5c6ccc([Si]7(c8ccccc8)c8ccccc8-c8ccccc87)cc6n(-c6ccccc6)c5c4)cc32)cc1 ; c1ccc(-n2c3ccccc3c3ccc(-c4ccc5c(c4)c4ccc([Si]6(c7ccccc7)c7ccccc7-c7ccccc76)cc4n5-c4ccccc4)cc32)cc1 ; c1ccc(-n2c3ccccc3c3ccc(-c4cccc5c4c4ccc([Si]6(c7ccccc7)c7ccccc7-c7ccccc76)cc4n5-c4ccccc4)cc32)cc1]

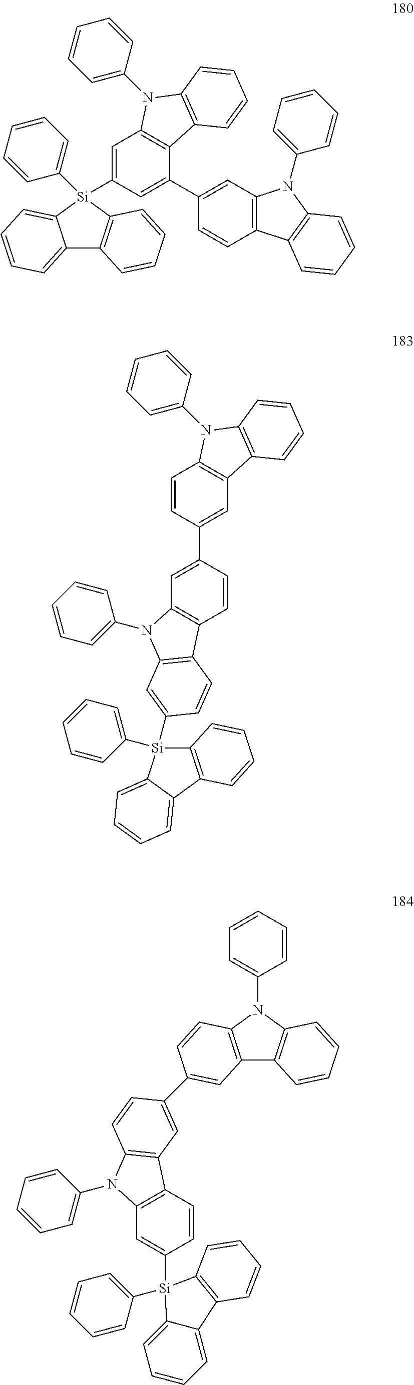 [SMILES: c1ccc(-n2c3ccccc3c3ccc(-c4cc([Si]5(c6ccccc6)c6ccccc6-c6ccccc65)cc5c4c4ccccc4n5-c4ccccc4)cc32)cc1 ; c1ccc(-n2c3ccccc3c3cc(-c4ccc5c6ccc([Si]7(c8ccccc8)c8ccccc8-c8ccccc87)cc6n(-c6ccccc6)c5c4)ccc32)cc1 ; c1ccc(-n2c3ccccc3c3cc(-c4ccc5c(c4)c4ccc([Si]6(c7ccccc7)c7ccccc7-c7ccccc76)cc4n5-c4ccccc4)ccc32)cc1]

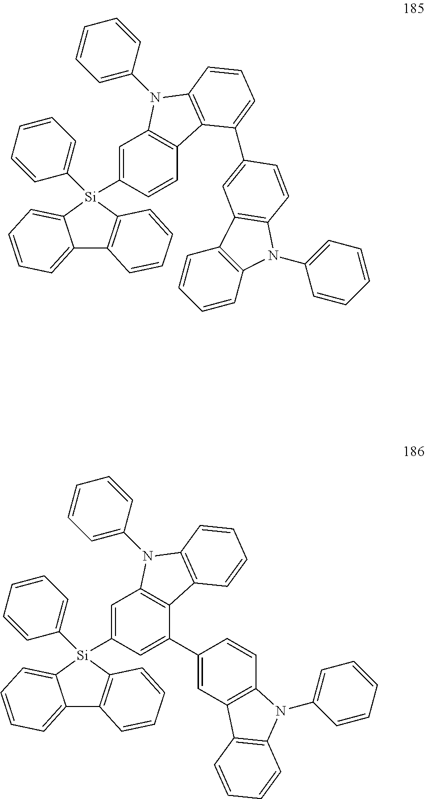 [SMILES: c1ccc(-n2c3ccccc3c3cc(-c4cccc5c4c4ccc([Si]6(c7ccccc7)c7ccccc7-c7ccccc76)cc4n5-c4ccccc4)ccc32)cc1 ; c1ccc(-n2c3ccccc3c3cc(-c4cc([Si]5(c6ccccc6)c6ccccc6-c6ccccc65)cc5c4c4ccccc4n5-c4ccccc4)ccc32)cc1]

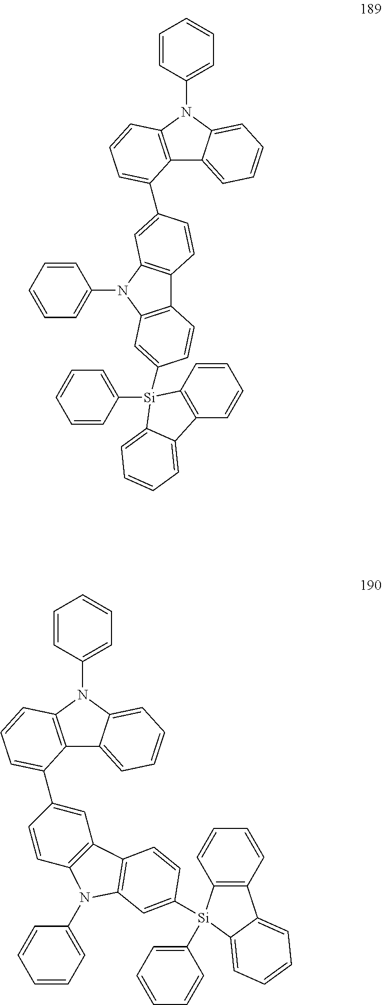 [SMILES: c1ccc(-n2c3cc(-c4cccc5c4c4ccccc4n5-c4ccccc4)ccc3c3ccc([Si]4(c5ccccc5)c5ccccc5-c5ccccc54)cc32)cc1 ; c1ccc(-n2c3ccc(-c4cccc5c4c4ccccc4n5-c4ccccc4)cc3c3ccc([Si]4(c5ccccc5)c5ccccc5-c5ccccc54)cc32)cc1]

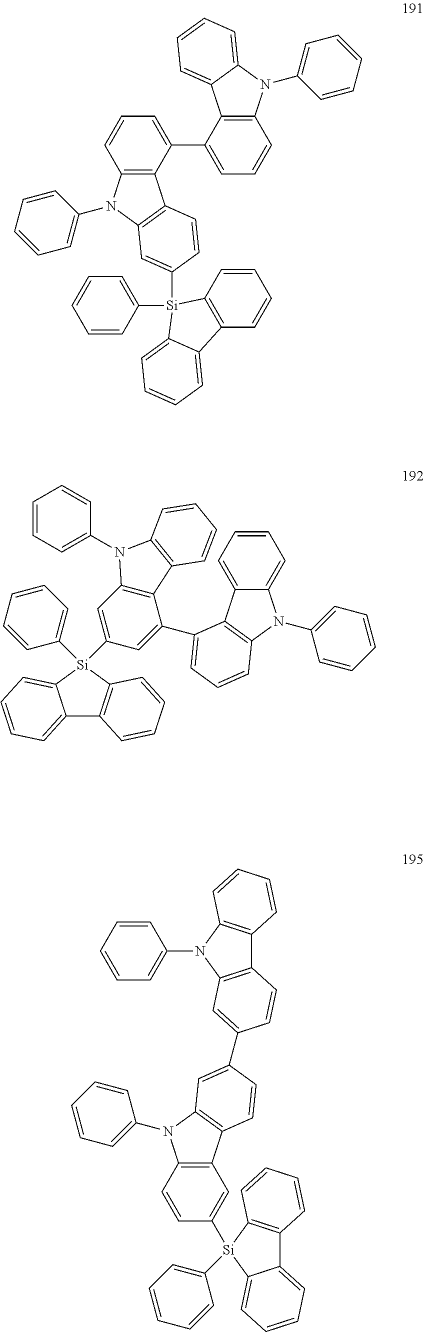 [SMILES: c1ccc(-n2c3ccccc3c3c(-c4cccc5c4c4ccc([Si]6(c7ccccc7)c7ccccc7-c7ccccc76)cc4n5-c4ccccc4)cccc32)cc1 ; c1ccc(-n2c3ccccc3c3c(-c4cc([Si]5(c6ccccc6)c6ccccc6-c6ccccc65)cc5c4c4ccccc4n5-c4ccccc4)cccc32)cc1 ; c1ccc(-n2c3ccccc3c3ccc(-c4ccc5c6cc([Si]7(c8ccccc8)c8ccccc8-c8ccccc87)ccc6n(-c6ccccc6)c5c4)cc32)cc1]

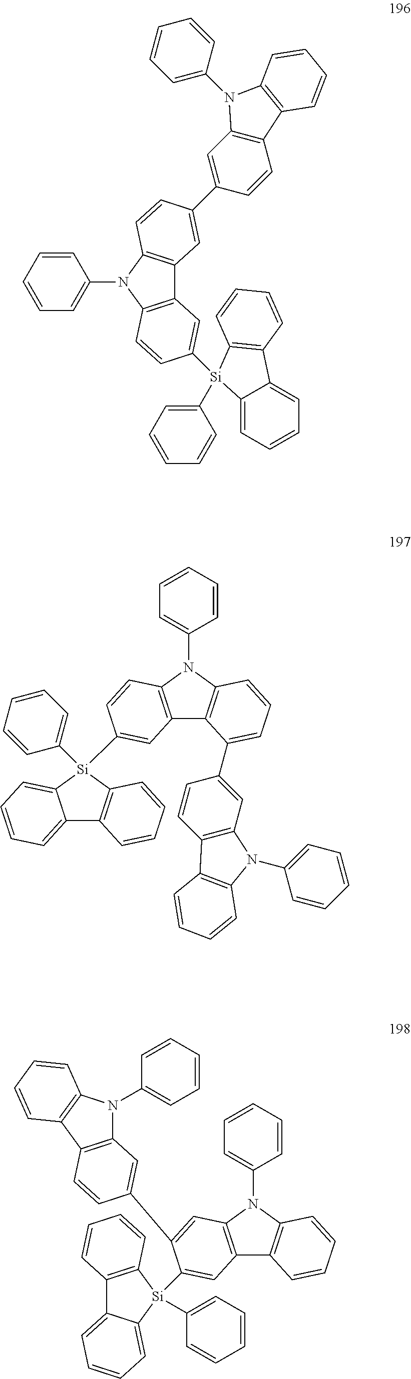 [SMILES: c1ccc(-n2c3ccc(-c4ccc5c6ccccc6n(-c6ccccc6)c5c4)cc3c3cc([Si]4(c5ccccc5)c5ccccc5-c5ccccc54)ccc32)cc1 ; c1ccc(-n2c3ccccc3c3ccc(-c4cccc5c4c4cc([Si]6(c7ccccc7)c7ccccc7-c7ccccc76)ccc4n5-c4ccccc4)cc32)cc1 ; c1ccc(-n2c3ccccc3c3ccc(-c4cc5c(cc4[Si]4(c6ccccc6)c6ccccc6-c6ccccc64)c4ccccc4n5-c4ccccc4)cc32)cc1]

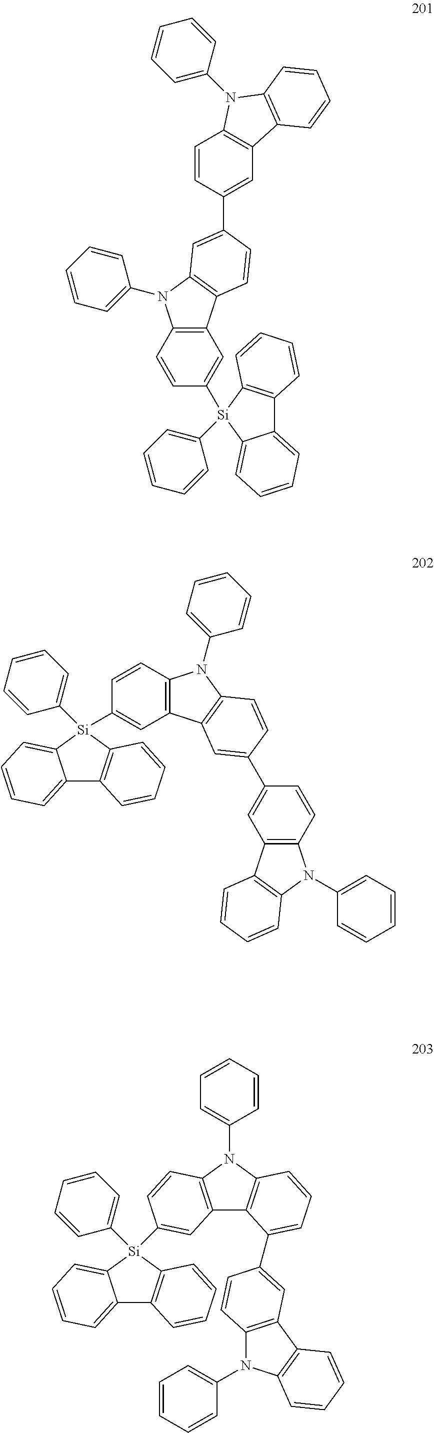 [SMILES: c1ccc(-n2c3ccccc3c3cc(-c4ccc5c6cc([Si]7(c8ccccc8)c8ccccc8-c8ccccc87)ccc6n(-c6ccccc6)c5c4)ccc32)cc1 ; c1ccc(-n2c3ccccc3c3cc(-c4ccc5c(c4)c4cc([Si]6(c7ccccc7)c7ccccc7-c7ccccc76)ccc4n5-c4ccccc4)ccc32)cc1 ; c1ccc(-n2c3ccccc3c3cc(-c4cccc5c4c4cc([Si]6(c7ccccc7)c7ccccc7-c7ccccc76)ccc4n5-c4ccccc4)ccc32)cc1]

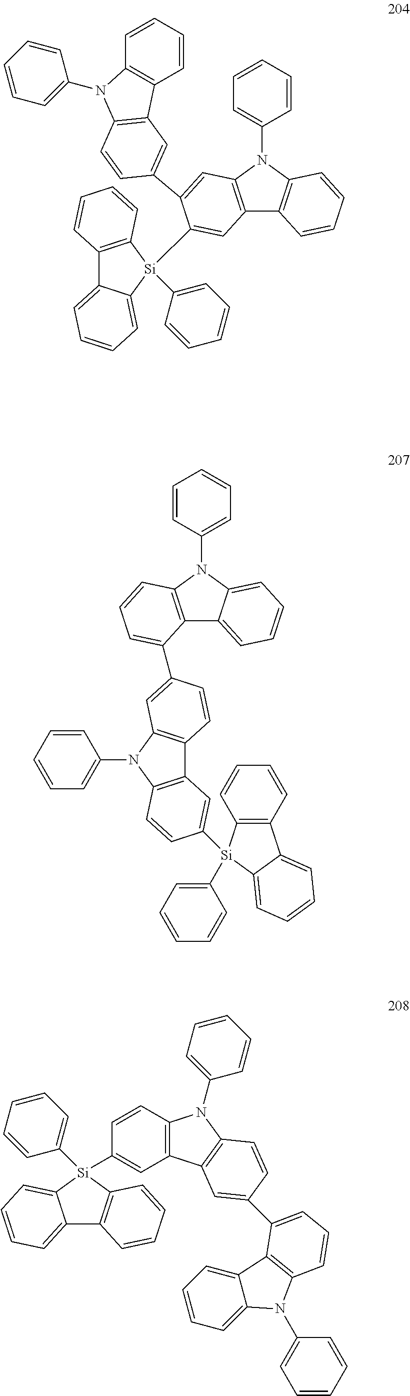 [SMILES: c1ccc(-n2c3ccccc3c3cc(-c4cc5c(cc4[Si]4(c6ccccc6)c6ccccc6-c6ccccc64)c4ccccc4n5-c4ccccc4)ccc32)cc1 ; c1ccc(-n2c3ccc([Si]4(c5ccccc5)c5ccccc5-c5ccccc54)cc3c3ccc(-c4cccc5c4c4ccccc4n5-c4ccccc4)cc32)cc1 ; c1ccc(-n2c3ccc(-c4cccc5c4c4ccccc4n5-c4ccccc4)cc3c3cc([Si]4(c5ccccc5)c5ccccc5-c5ccccc54)ccc32)cc1]

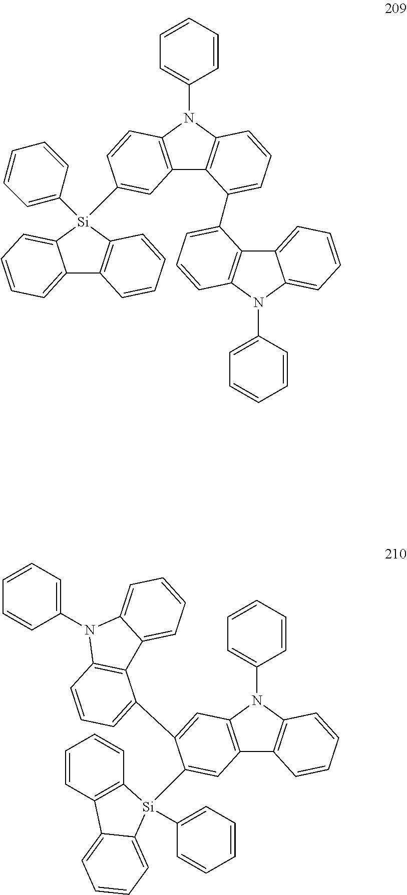 [SMILES: c1ccc(-n2c3ccccc3c3c(-c4cccc5c4c4cc([Si]6(c7ccccc7)c7ccccc7-c7ccccc76)ccc4n5-c4ccccc4)cccc32)cc1 ; c1ccc(-n2c3ccccc3c3cc([Si]4(c5ccccc5)c5ccccc5-c5ccccc54)c(-c4cccc5c4c4ccccc4n5-c4ccccc4)cc32)cc1]

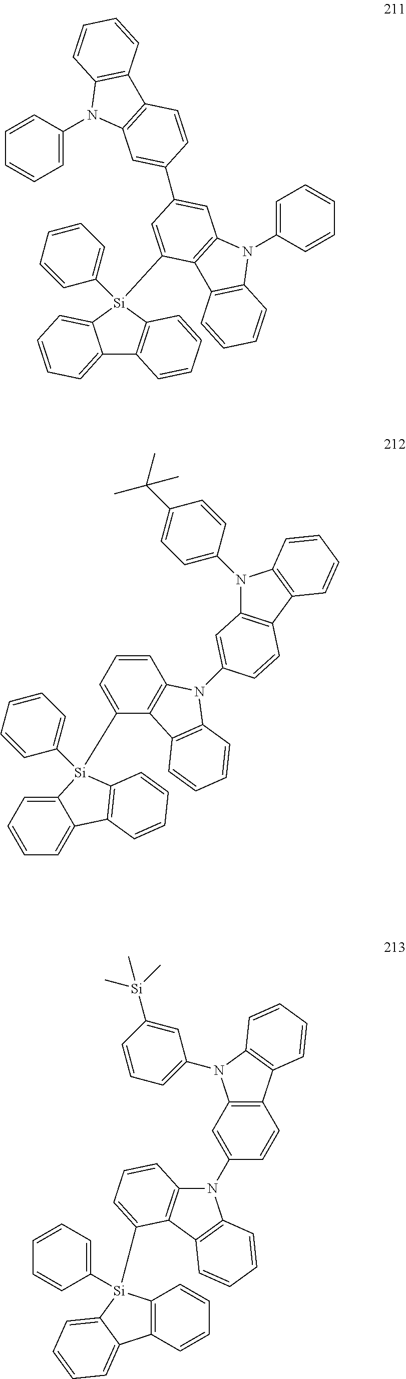 [SMILES: c1ccc(-n2c3ccccc3c3ccc(-c4cc([Si]5(c6ccccc6)c6ccccc6-c6ccccc65)c5c6ccccc6n(-c6ccccc6)c5c4)cc32)cc1 ; CC(C)(C)c1ccc(-n2c3ccccc3c3ccc(-n4c5ccccc5c5c([Si]6(c7ccccc7)c7ccccc7-c7ccccc76)cccc54)cc32)cc1 ; C[Si](C)(C)c1cccc(-n2c3ccccc3c3ccc(-n4c5ccccc5c5c([Si]6(c7ccccc7)c7ccccc7-c7ccccc76)cccc54)cc32)c1]

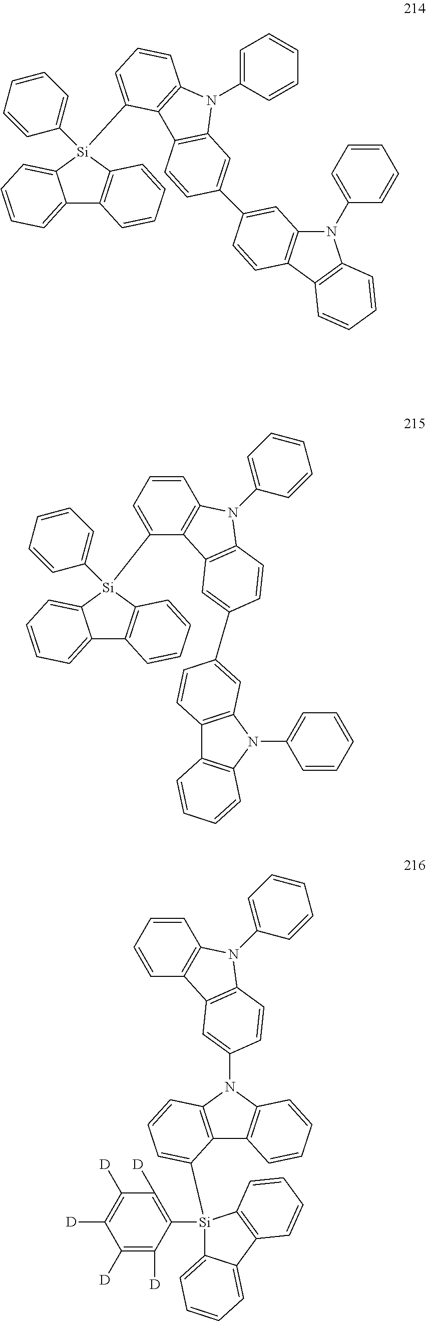 [SMILES: c1ccc(-n2c3ccccc3c3ccc(-c4ccc5c6c([Si]7(c8ccccc8)c8ccccc8-c8ccccc87)cccc6n(-c6ccccc6)c5c4)cc32)cc1 ; c1ccc(-n2c3ccccc3c3ccc(-c4ccc5c(c4)c4c([Si]6(c7ccccc7)c7ccccc7-c7ccccc76)cccc4n5-c4ccccc4)cc32)cc1 ; [2H]c1c([2H])c([2H])c([Si]2(c3cccc4c3c3ccccc3n4-c3ccc4c(c3)c3ccccc3n4-c3ccccc3)c3ccccc3-c3ccccc32)c([2H])c1[2H]]

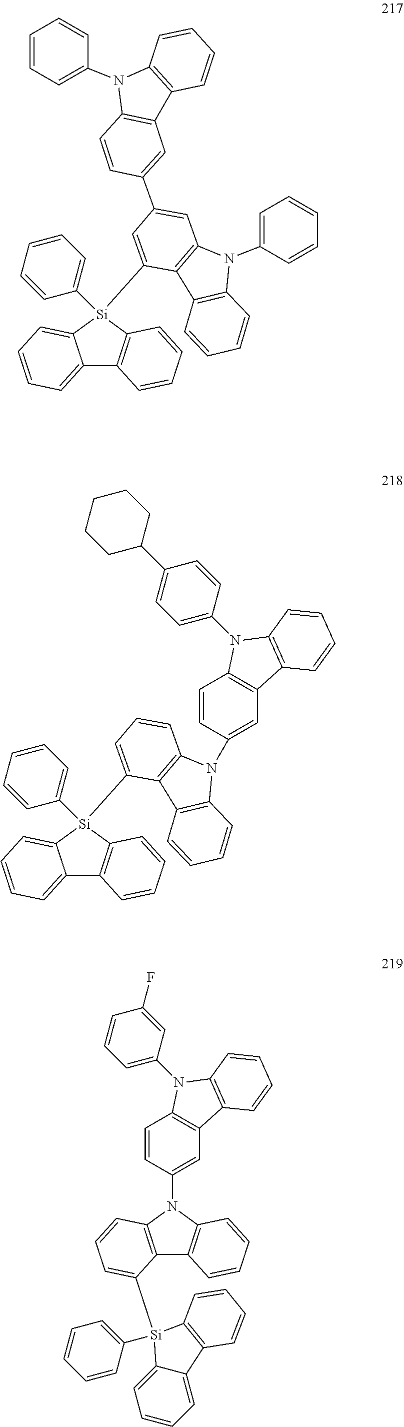 [SMILES: c1ccc(-n2c3ccccc3c3cc(-c4cc([Si]5(c6ccccc6)c6ccccc6-c6ccccc65)c5c6ccccc6n(-c6ccccc6)c5c4)ccc32)cc1 ; c1ccc([Si]2(c3cccc4c3c3ccccc3n4-c3ccc4c(c3)c3ccccc3n4-c3ccc(C4CCCCC4)cc3)c3ccccc3-c3ccccc32)cc1 ; Fc1cccc(-n2c3ccccc3c3cc(-n4c5ccccc5c5c([Si]6(c7ccccc7)c7ccccc7-c7ccccc76)cccc54)ccc32)c1]

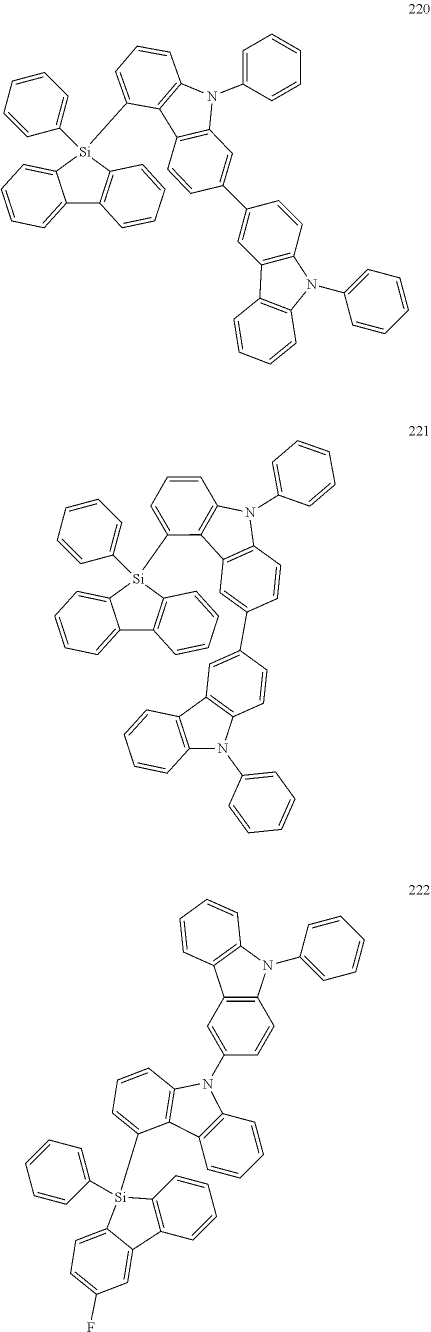 [SMILES: c1ccc(-n2c3ccccc3c3cc(-c4ccc5c6c([Si]7(c8ccccc8)c8ccccc8-c8ccccc87)cccc6n(-c6ccccc6)c5c4)ccc32)cc1 ; c1ccc(-n2c3ccccc3c3cc(-c4ccc5c(c4)c4c([Si]6(c7ccccc7)c7ccccc7-c7ccccc76)cccc4n5-c4ccccc4)ccc32)cc1 ; Fc1ccc2c(c1)-c1ccccc1[Si]2(c1ccccc1)c1cccc2c1c1ccccc1n2-c1ccc2c(c1)c1ccccc1n2-c1ccccc1]

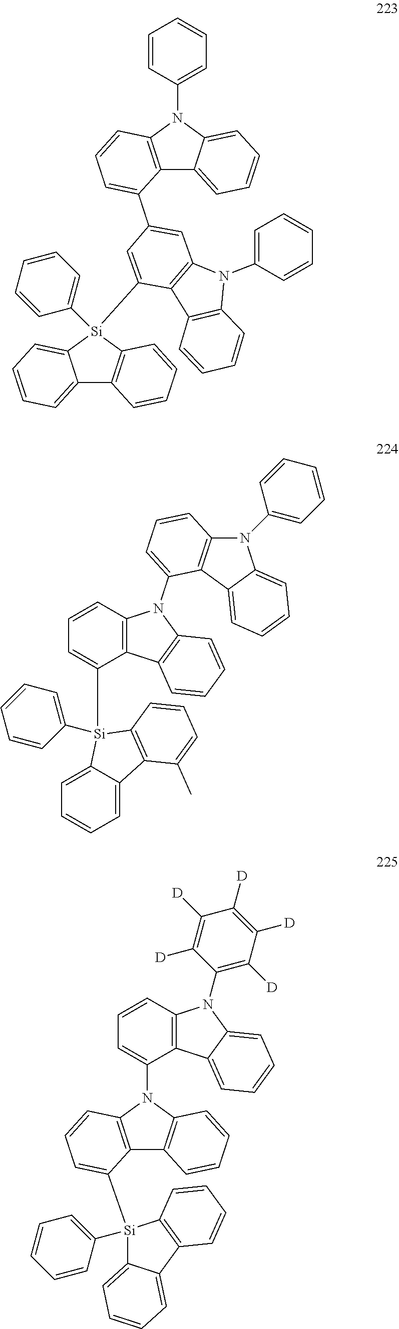 [SMILES: c1ccc(-n2c3ccccc3c3c(-c4cc([Si]5(c6ccccc6)c6ccccc6-c6ccccc65)c5c6ccccc6n(-c6ccccc6)c5c4)cccc32)cc1 ; Cc1cccc2c1-c1ccccc1[Si]2(c1ccccc1)c1cccc2c1c1ccccc1n2-c1cccc2c1c1ccccc1n2-c1ccccc1 ; [2H]c1c([2H])c([2H])c(-n2c3ccccc3c3c(-n4c5ccccc5c5c([Si]6(c7ccccc7)c7ccccc7-c7ccccc76)cccc54)cccc32)c([2H])c1[2H]]

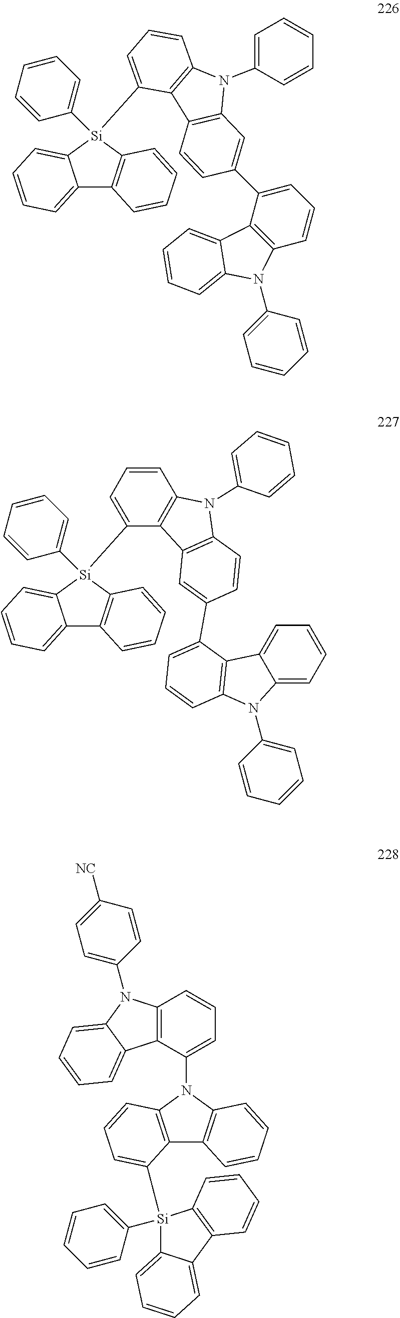 [SMILES: c1ccc(-n2c3ccccc3c3c(-c4ccc5c6c([Si]7(c8ccccc8)c8ccccc8-c8ccccc87)cccc6n(-c6ccccc6)c5c4)cccc32)cc1 ; c1ccc(-n2c3ccccc3c3c(-c4ccc5c(c4)c4c([Si]6(c7ccccc7)c7ccccc7-c7ccccc76)cccc4n5-c4ccccc4)cccc32)cc1 ; N#Cc1ccc(-n2c3ccccc3c3c(-n4c5ccccc5c5c([Si]6(c7ccccc7)c7ccccc7-c7ccccc76)cccc54)cccc32)cc1]

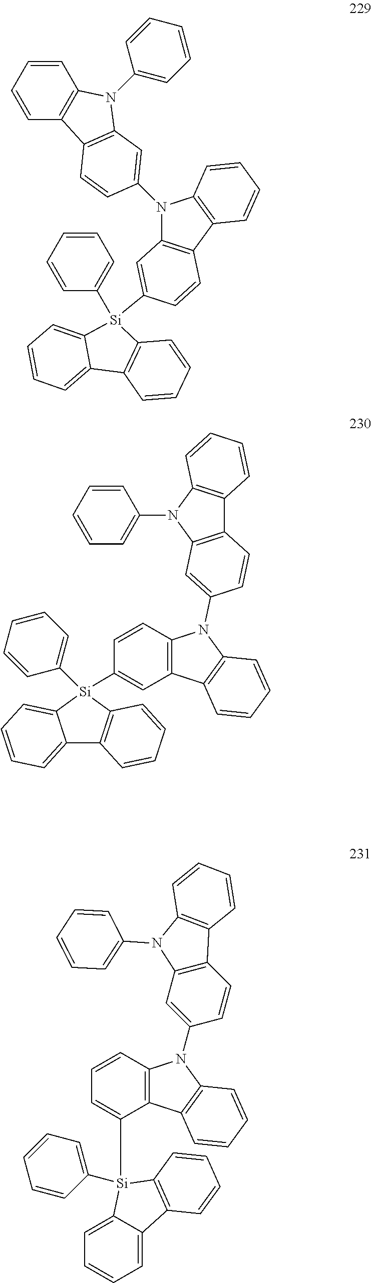 [SMILES: c1ccc(-n2c3ccccc3c3ccc(-n4c5ccccc5c5ccc([Si]6(c7ccccc7)c7ccccc7-c7ccccc76)cc54)cc32)cc1 ; c1ccc(-n2c3ccccc3c3ccc(-n4c5ccccc5c5cc([Si]6(c7ccccc7)c7ccccc7-c7ccccc76)ccc54)cc32)cc1 ; c1ccc(-n2c3ccccc3c3ccc(-n4c5ccccc5c5c([Si]6(c7ccccc7)c7ccccc7-c7ccccc76)cccc54)cc32)cc1]

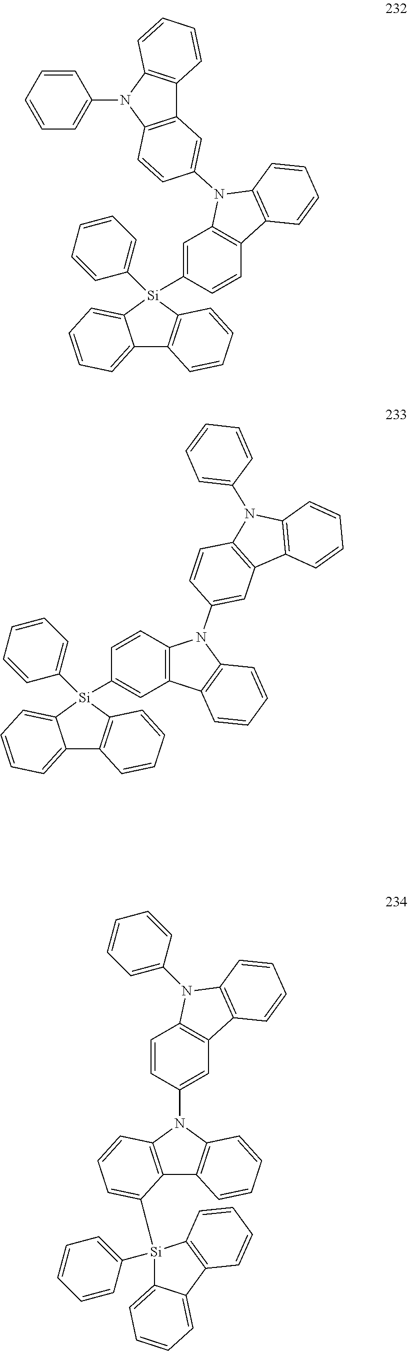 [SMILES: c1ccc(-n2c3ccccc3c3cc(-n4c5ccccc5c5ccc([Si]6(c7ccccc7)c7ccccc7-c7ccccc76)cc54)ccc32)cc1 ; c1ccc(-n2c3ccccc3c3cc(-n4c5ccccc5c5cc([Si]6(c7ccccc7)c7ccccc7-c7ccccc76)ccc54)ccc32)cc1 ; c1ccc(-n2c3ccccc3c3cc(-n4c5ccccc5c5c([Si]6(c7ccccc7)c7ccccc7-c7ccccc76)cccc54)ccc32)cc1]

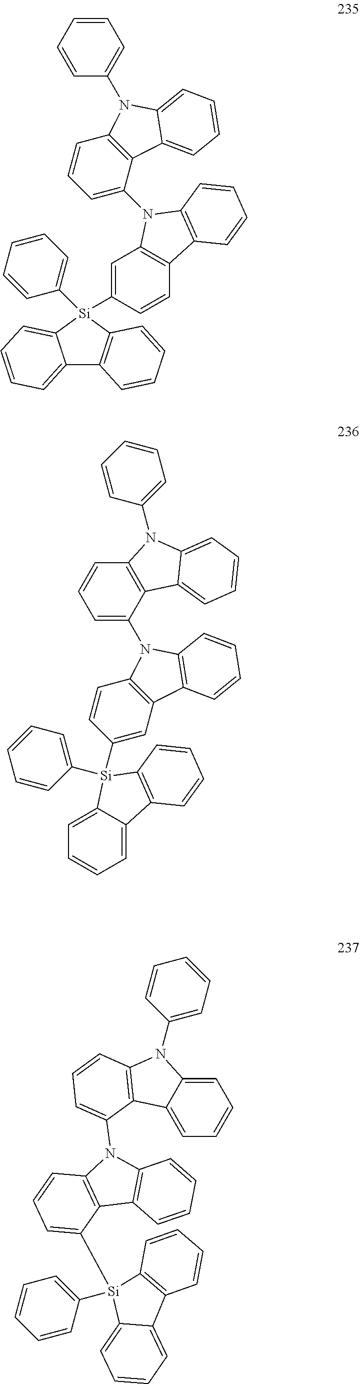 [SMILES: c1ccc(-n2c3ccccc3c3c(-n4c5ccccc5c5ccc([Si]6(c7ccccc7)c7ccccc7-c7ccccc76)cc54)cccc32)cc1 ; c1ccc(-n2c3ccccc3c3c(-n4c5ccccc5c5cc([Si]6(c7ccccc7)c7ccccc7-c7ccccc76)ccc54)cccc32)cc1 ; c1ccc(-n2c3ccccc3c3c(-n4c5ccccc5c5c([Si]6(c7ccccc7)c7ccccc7-c7ccccc76)cccc54)cccc32)cc1]

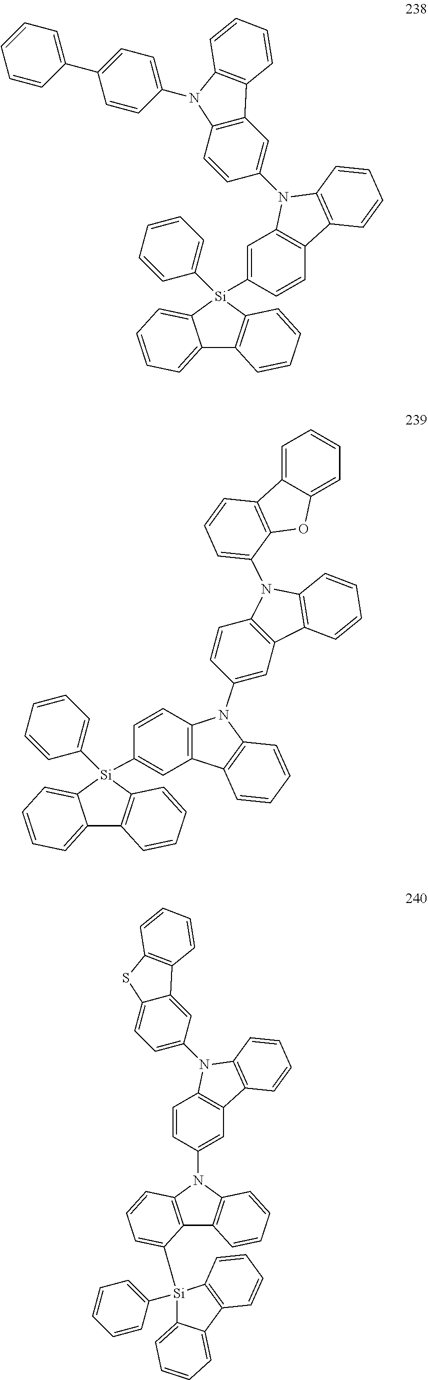 [SMILES: c1ccc(-c2ccc(-n3c4ccccc4c4cc(-n5c6ccccc6c6ccc([Si]7(c8ccccc8)c8ccccc8-c8ccccc87)cc65)ccc43)cc2)cc1 ; c1ccc([Si]2(c3ccc4c(c3)c3ccccc3n4-c3ccc4c(c3)c3ccccc3n4-c3cccc4c3oc3ccccc34)c3ccccc3-c3ccccc32)cc1 ; c1ccc([Si]2(c3cccc4c3c3ccccc3n4-c3ccc4c(c3)c3ccccc3n4-c3ccc4sc5ccccc5c4c3)c3ccccc3-c3ccccc32)cc1]

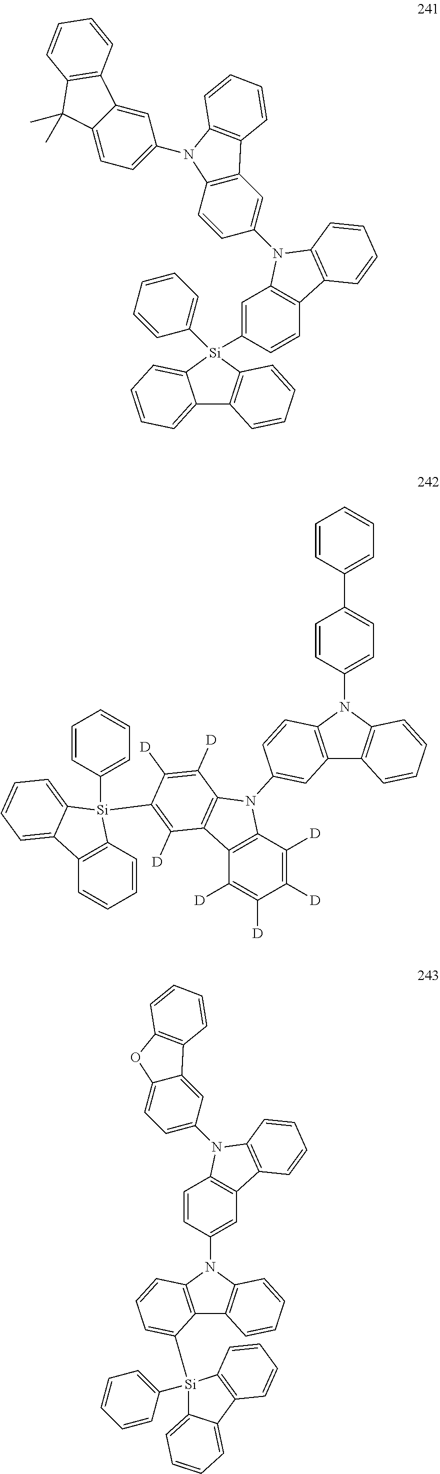 [SMILES: CC1(C)c2ccccc2-c2cc(-n3c4ccccc4c4cc(-n5c6ccccc6c6ccc([Si]7(c8ccccc8)c8ccccc8-c8ccccc87)cc65)ccc43)ccc21 ; [2H]c1c([2H])c([2H])c2c(c1[2H])c1c([2H])c([Si]3(c4ccccc4)c4ccccc4-c4ccccc43)c([2H])c([2H])c1n2-c1ccc2c(c1)c1ccccc1n2-c1ccc(-c2ccccc2)cc1 ; c1ccc([Si]2(c3cccc4c3c3ccccc3n4-c3ccc4c(c3)c3ccccc3n4-c3ccc4oc5ccccc5c4c3)c3ccccc3-c3ccccc32)cc1]

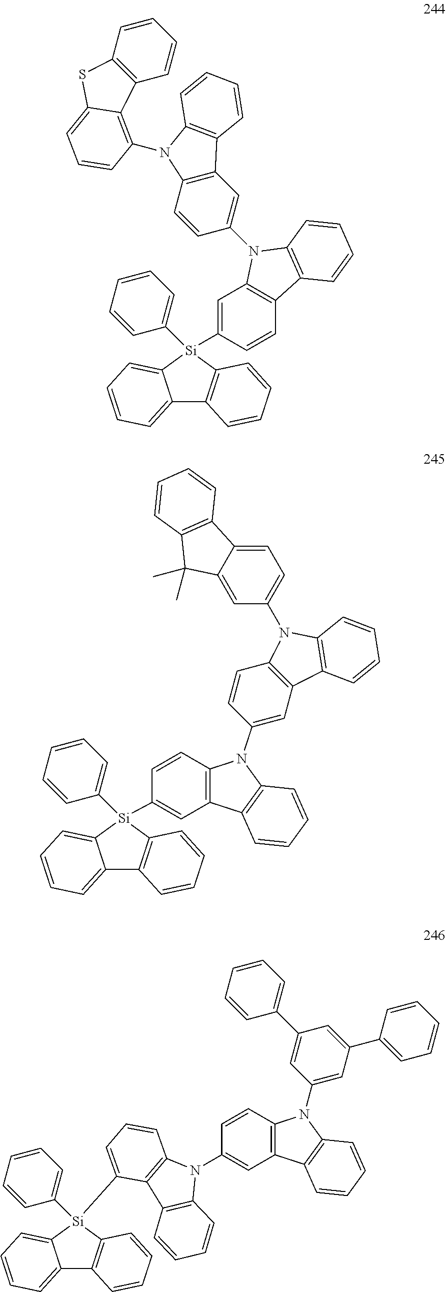 [SMILES: c1ccc([Si]2(c3ccc4c5ccccc5n(-c5ccc6c(c5)c5ccccc5n6-c5cccc6sc7ccccc7c56)c4c3)c3ccccc3-c3ccccc32)cc1 ; CC1(C)c2ccccc2-c2ccc(-n3c4ccccc4c4cc(-n5c6ccccc6c6cc([Si]7(c8ccccc8)c8ccccc8-c8ccccc87)ccc65)ccc43)cc21 ; c1ccc(-c2cc(-c3ccccc3)cc(-n3c4ccccc4c4cc(-n5c6ccccc6c6c([Si]7(c8ccccc8)c8ccccc8-c8ccccc87)cccc65)ccc43)c2)cc1]

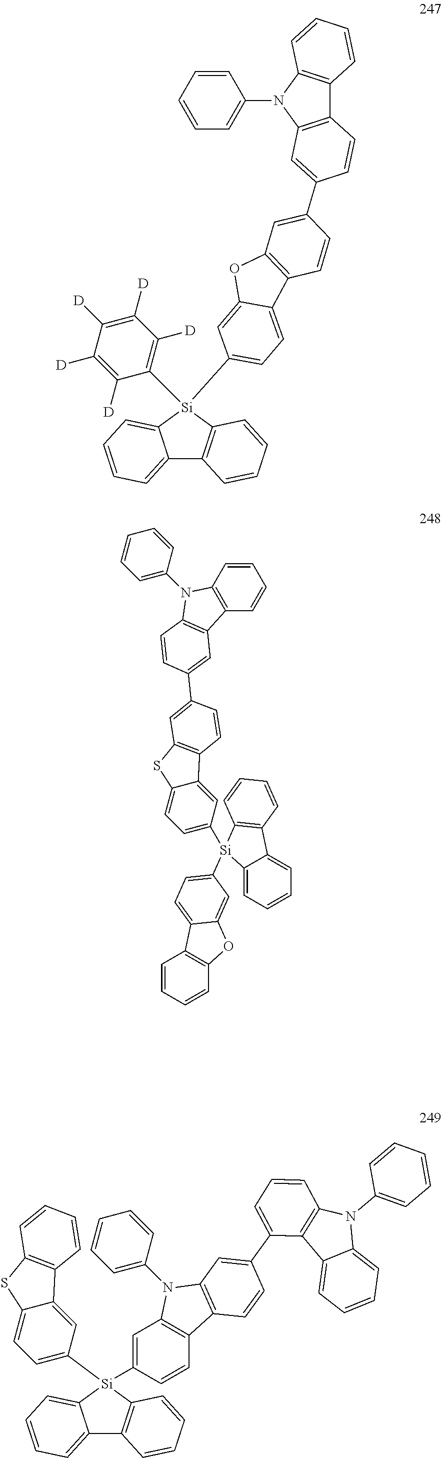 [SMILES: [2H]c1c([2H])c([2H])c([Si]2(c3ccc4c(c3)oc3cc(-c5ccc6c7ccccc7n(-c7ccccc7)c6c5)ccc34)c3ccccc3-c3ccccc32)c([2H])c1[2H] ; c1ccc(-n2c3ccccc3c3cc(-c4ccc5c(c4)sc4ccc([Si]6(c7ccc8c(c7)oc7ccccc78)c7ccccc7-c7ccccc76)cc45)ccc32)cc1 ; c1ccc(-n2c3cc(-c4cccc5c4c4ccccc4n5-c4ccccc4)ccc3c3ccc([Si]4(c5ccc6sc7ccccc7c6c5)c5ccccc5-c5ccccc54)cc32)cc1]

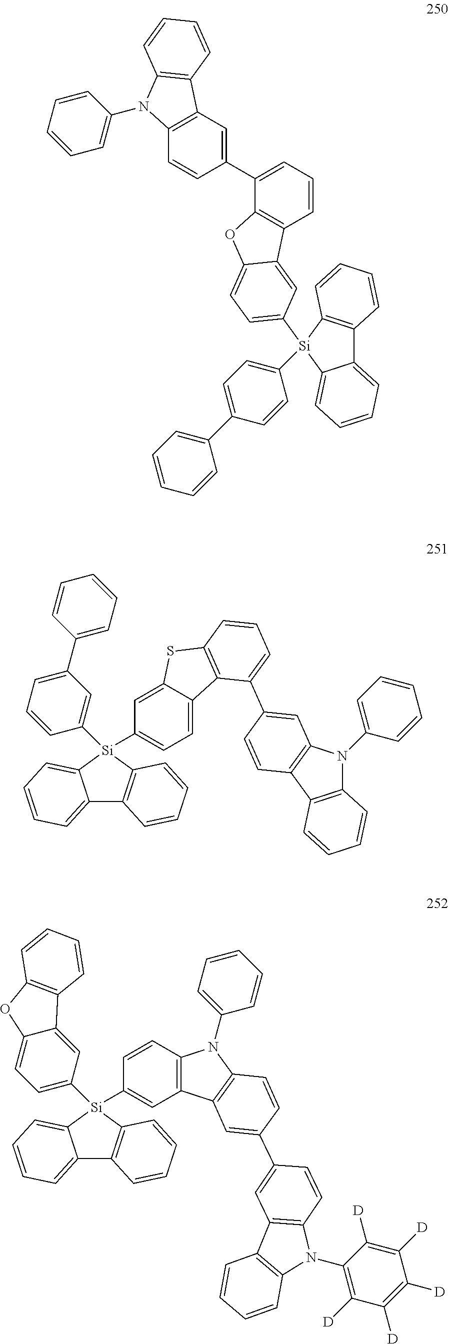 [SMILES: c1ccc(-c2ccc([Si]3(c4ccc5oc6c(-c7ccc8c(c7)c7ccccc7n8-c7ccccc7)cccc6c5c4)c4ccccc4-c4ccccc43)cc2)cc1 ; c1ccc(-c2cccc([Si]3(c4ccc5c(c4)sc4cccc(-c6ccc7c8ccccc8n(-c8ccccc8)c7c6)c45)c4ccccc4-c4ccccc43)c2)cc1 ; [2H]c1c([2H])c([2H])c(-n2c3ccccc3c3cc(-c4ccc5c(c4)c4cc([Si]6(c7ccc8oc9ccccc9c8c7)c7ccccc7-c7ccccc76)ccc4n5-c4ccccc4)ccc32)c([2H])c1[2H]]

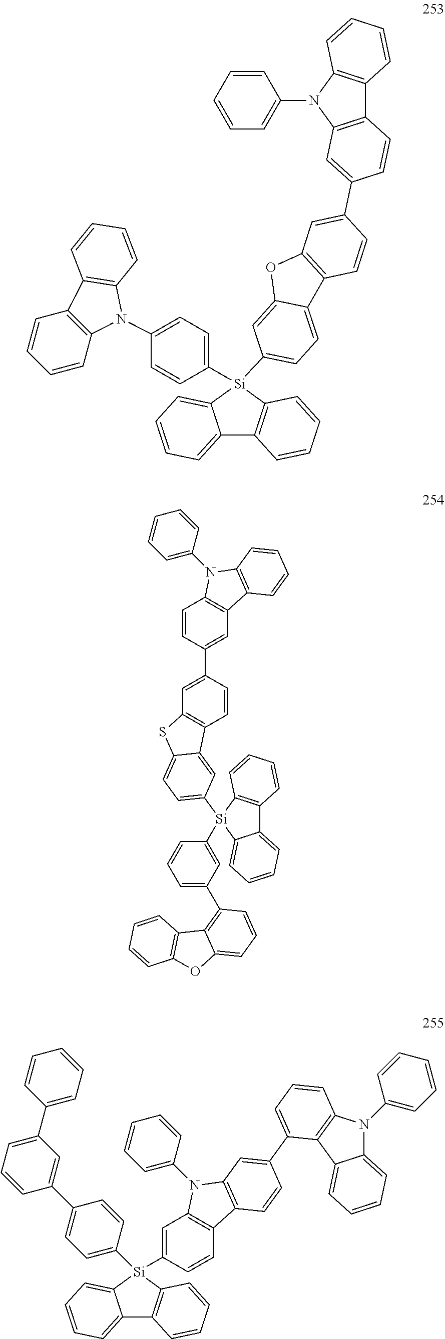 [SMILES: c1ccc(-n2c3ccccc3c3ccc(-c4ccc5c(c4)oc4cc([Si]6(c7ccc(-n8c9ccccc9c9ccccc98)cc7)c7ccccc7-c7ccccc76)ccc45)cc32)cc1 ; c1ccc(-n2c3ccccc3c3cc(-c4ccc5c(c4)sc4ccc([Si]6(c7cccc(-c8cccc9oc%10ccccc%10c89)c7)c7ccccc7-c7ccccc76)cc45)ccc32)cc1 ; c1ccc(-c2cccc(-c3ccc([Si]4(c5ccc6c7ccc(-c8cccc9c8c8ccccc8n9-c8ccccc8)cc7n(-c7ccccc7)c6c5)c5ccccc5-c5ccccc54)cc3)c2)cc1]

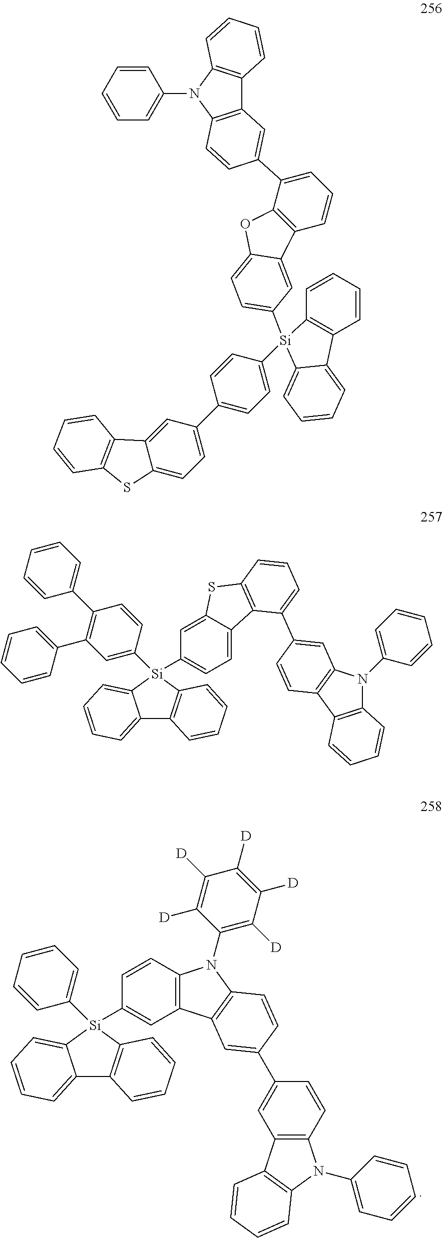 [SMILES: c1ccc(-n2c3ccccc3c3cc(-c4cccc5c4oc4ccc([Si]6(c7ccc(-c8ccc9sc%10ccccc%10c9c8)cc7)c7ccccc7-c7ccccc76)cc45)ccc32)cc1 ; c1ccc(-c2ccc([Si]3(c4ccc5c(c4)sc4cccc(-c6ccc7c8ccccc8n(-c8ccccc8)c7c6)c45)c4ccccc4-c4ccccc43)cc2-c2ccccc2)cc1 ; [2H]c1c([2H])c([2H])c(-n2c3ccc(-c4ccc5c(c4)c4ccccc4n5-c4ccccc4)cc3c3cc([Si]4(c5ccccc5)c5ccccc5-c5ccccc54)ccc32)c([2H])c1[2H]]

In a second aspect, the present disclosure provides an organic electroluminescent device, comprising an anode, a cathode, and a functional layer disposed between the anode and the cathode; wherein the functional layer comprises the organic compound of the first aspect of the present disclosure.

The organic compounds provided in the present disclosure be utilized for the formation of at least one organic film layer within the functional layer, in order to improve the luminous efficiency and the service life, among other characteristics, of organic electroluminescent devices.

Optionally, the functional layer comprises an organic light-emitting layer, which comprises the organic compound. Among them, the organic light-emitting layer can be composed either of the organic compounds provided by the present disclosure or collectively composed of the organic compounds provided by the present disclosure and other materials.

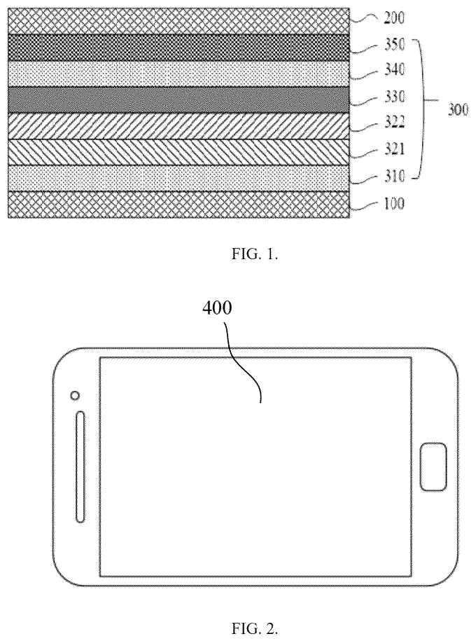

According to one specific embodiment, the organic electroluminescent device is as shown in FIG. 1, and the organic electroluminescent device may comprise an anode 100, a hole injection layer 310, a hole transport layer 321, an electron blocking layer (a hole auxiliary layer) 322, an organic light-emitting layer 330, an electron transport layer 340, an electron injection layer 350, and a cathode 200 that are stacked sequentially.

In the present disclosure, the anode 100 comprises anode materials, which are preferably a high work function material contributing to injection of holes into the functional layer. The specific examples of the anode material include: metals such as nickel, platinum, vanadium, chromium, copper, zinc, and gold, or alloys thereof; metal oxides such as zinc oxide, indium oxide, indium tin oxide (ITO), and indium zinc oxide (IZO); combinations of metals and oxides, such as ZnO:Al or SnO₂:Sb; or conductive polymers such as poly(3-methylthiophene), poly[3,4-(ethylene-1,2-dioxy)thiophene] (PEDT), polypyrrole, and polyaniline, but are not limited thereto. Preferably, a transparent electrode comprising indium tin oxide (ITO) as the anode is included.

In the present disclosure, the hole transport layer may include one or more hole transport material(s). The hole transport materials may be selected from carbazole multimers, carbazole-connected triarylamine based compounds, and other types of compounds. Specifically, the hole transport materials may be selected from the following compounds or any combination thereof:

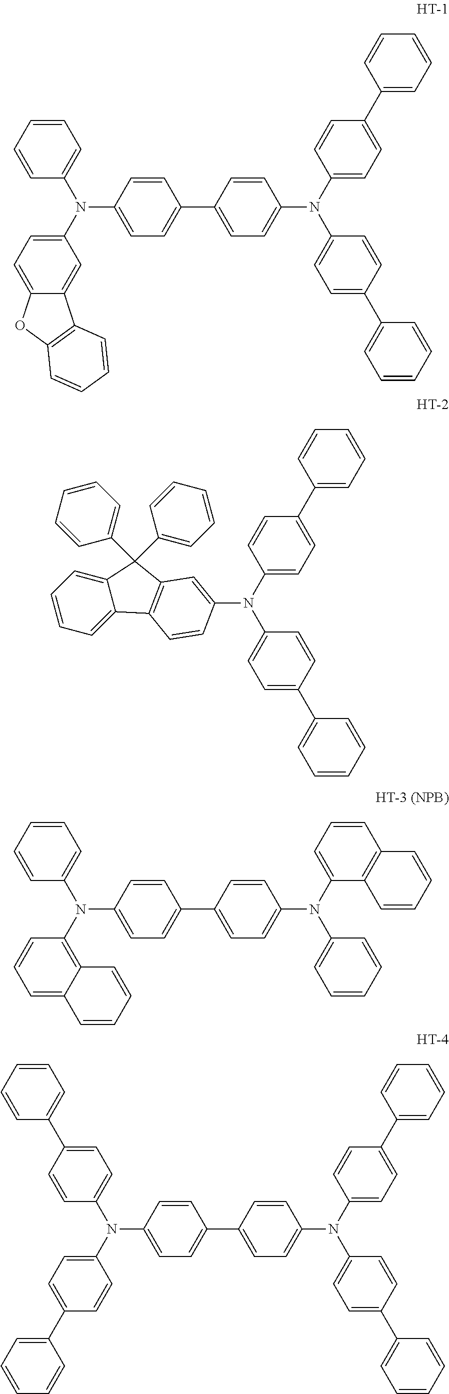 [SMILES: c1ccc(-c2ccc(N(c3ccc(-c4ccccc4)cc3)c3ccc(-c4ccc(N(c5ccccc5)c5ccc6oc7ccccc7c6c5)cc4)cc3)cc2)cc1 ; c1ccc(-c2ccc(N(c3ccc(-c4ccccc4)cc3)c3ccc4c(c3)C(c3ccccc3)(c3ccccc3)c3ccccc3-4)cc2)cc1 ; c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

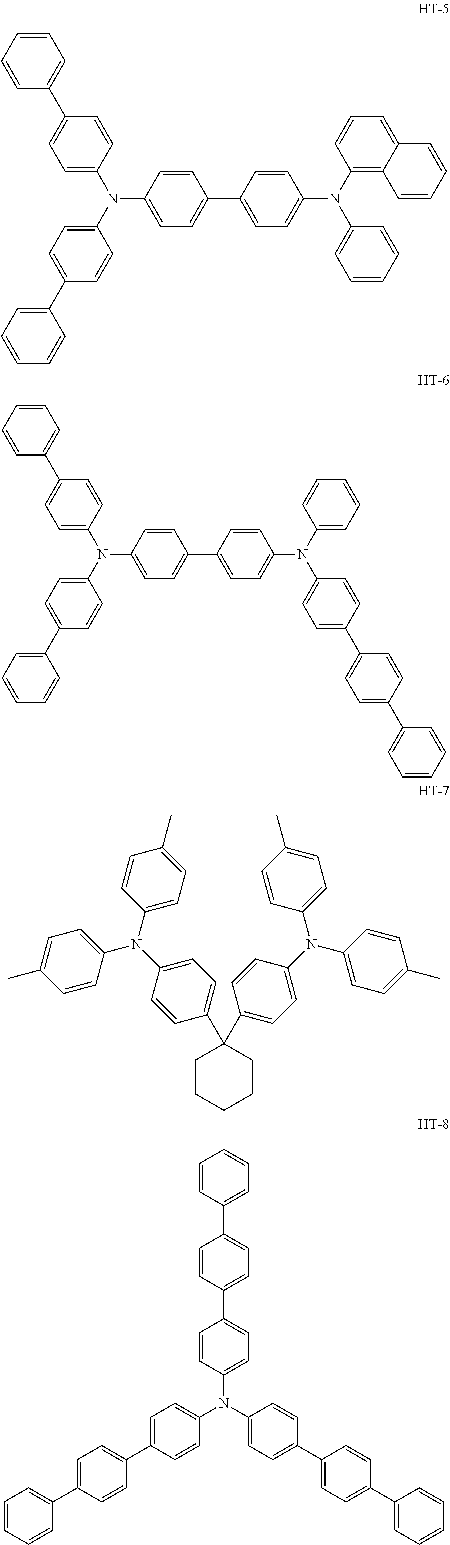

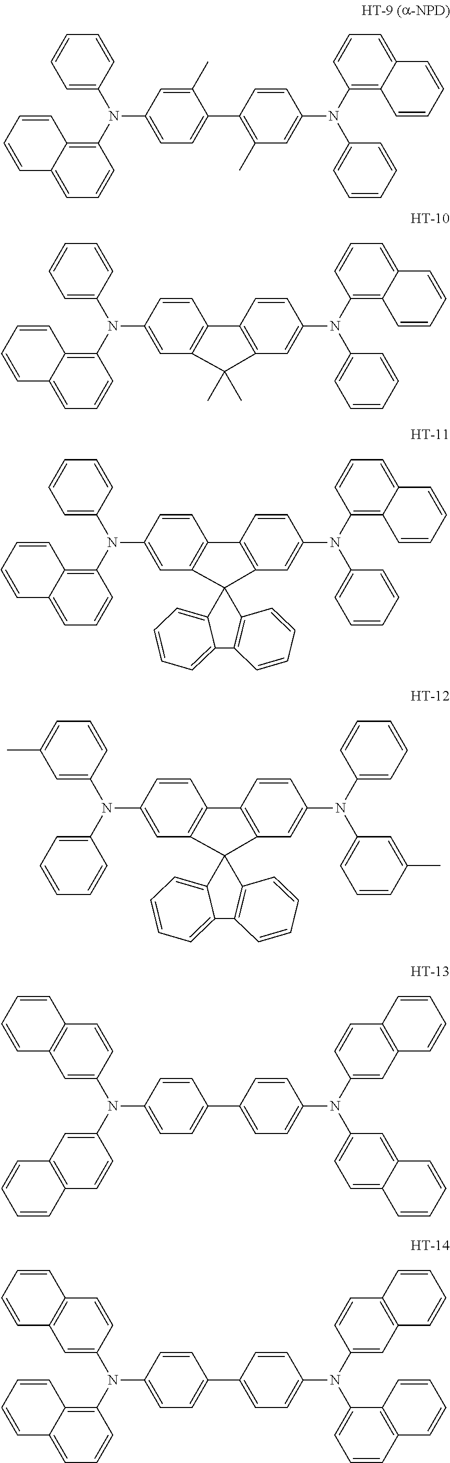

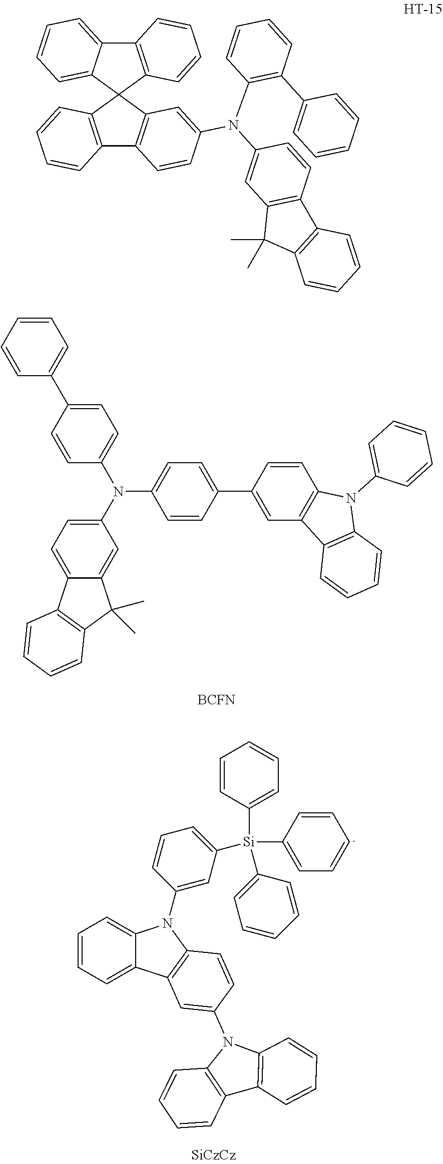 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; "BCFN" ; c1ccc([Si](c2ccccc2)(c2ccccc2)c2cccc(-n3c4ccccc4c4cc(-n5c6ccccc6c6ccccc65)ccc43)c2)cc1]

In one embodiment, the hole transport layer 321 may be composed of BCFN. In one embodiment, the electron blocking layer 322 is composed of SiCzCz.

Optionally, a hole injection layer 310 may be further provided between the anode 100 and the hole transport layer 321 to enhance the ability to inject holes into the hole transport layer 321. The hole injection layer 310 may choose to use a benzidine derivative, a starburst arylamine-based compound, a phthalocyanine derivative or other materials. It is not particularly limited in the present disclosure. The material of the hole injection layer 310 is selected, for example, from the following compounds or any combination thereof:

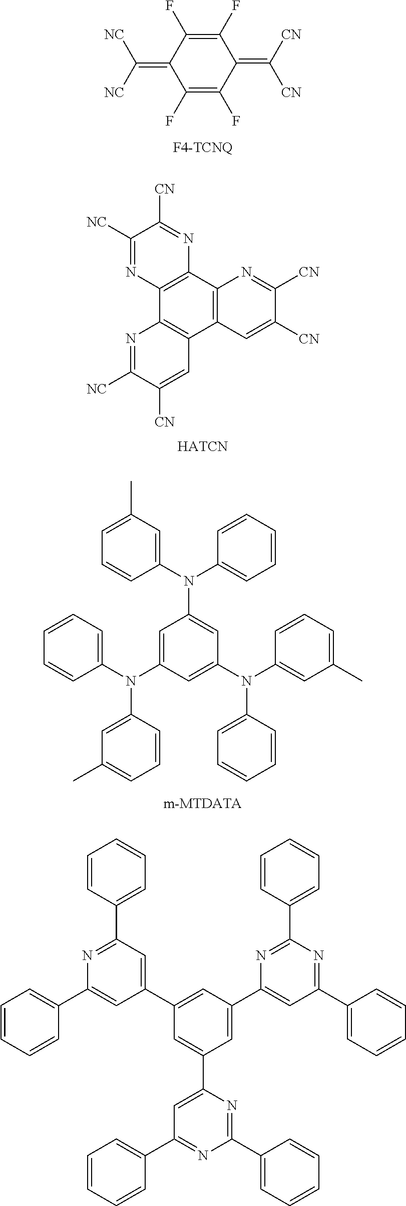

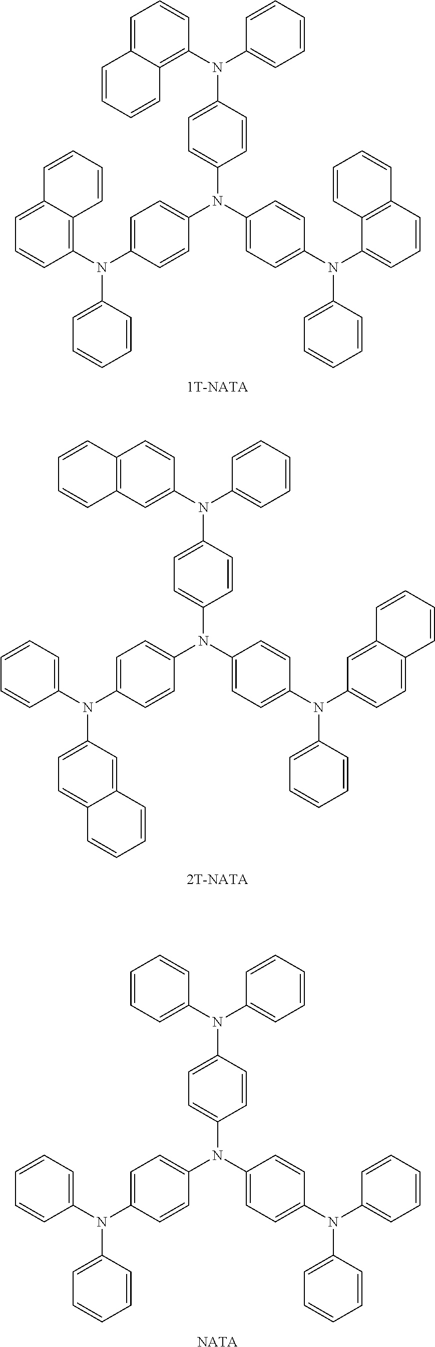

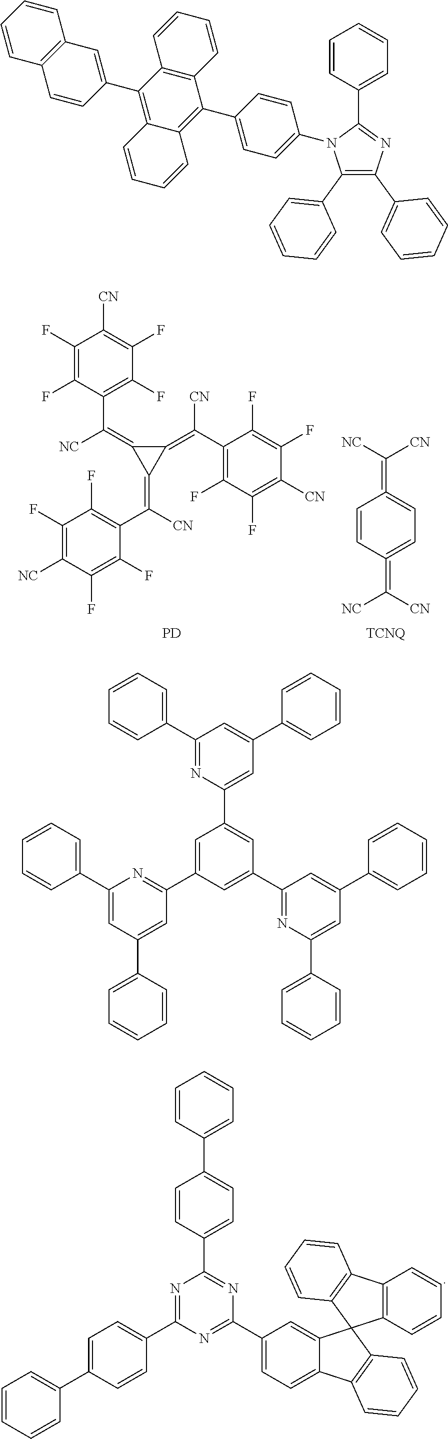

In one embodiment, the hole injection layer 310 is composed of HATCN.

In the present disclosure, the organic light-emitting layer 330 may be composed of a single luminescent material or may comprise a host material and a dopant material. Optionally, the organic light-emitting layer 330 is composed of a host material and a dopant material. The holes injected into the organic light-emitting layer 330 and the electrons injected into the organic light-emitting layer 330 can recombine in the organic light-emitting layer 330 to form excitons. The excitons transmit energy to the host material, and the host material transmits the energy to the dopant material, thereby enabling the dopant material to emit light.

The host material of the organic light-emitting layer 330 may include a metal chelating compound, a stilbene-based derivative, an aromatic amine derivative, a dibenzofuran derivative, or other types of materials. Optionally, the host material includes the organic compounds of the present disclosure. In some examples, the body of the light-emitting layer 330 comprises the organic compound of the present disclosure and BH—N.

The dopant material of the organic light-emitting layer 330 may be a compound having a condensed aryl ring or its derivative, a compound having a heteroaryl ring or its derivative, an aromatic amine derivative, or other materials. It is not particularly limited in the present disclosure. The dopant material is also known as a doping material or a dopant. The dopant can be categorized into fluorescent and phosphorescent dopants on their luminescence mechanisms. The specific examples of the phosphorescent dopant include but are not limited to,

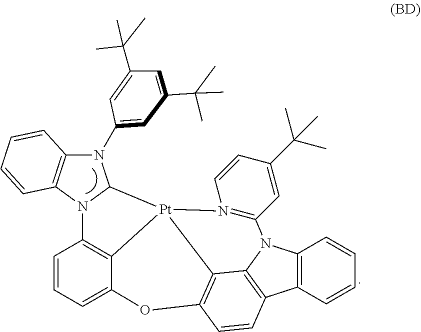

In one embodiment of the present disclosure, the organic electroluminescent device is a blue organic electroluminescent device. In one embodiment, the host material of the organic light-emitting layer 330 comprises the organic compound of the present disclosure. The dopant material is, for example, BD. In another embodiment, the host material of the organic light-emitting layer 330 comprises the organic compound of the present disclosure and BH—N

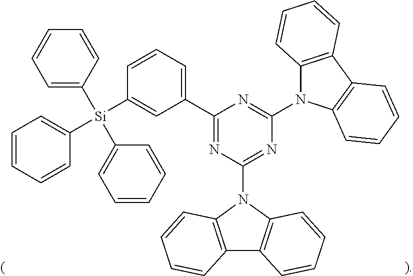 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

The dopant material is, for example, BD.

In one embodiment of the present disclosure, the organic electroluminescent device is a blue organic electroluminescent device. In one more specific embodiment, the host material of the organic light-emitting layer 330 comprises the organic compound of the present disclosure.

The electron transport layer 340 may be a single-layer structure or a multi-layer structure and may comprise one or more electron transport material(s). The electron transport materials may be selected from, but not limited to BTB, LiQ, mSiTrz, benzimidazole derivatives, oxadiazole derivatives, quinoxaline derivatives, and other electron transport materials, and it is not particularly limited in the present disclosure. The material of the electron transport layer 340 includes but is not limited to the following compounds:

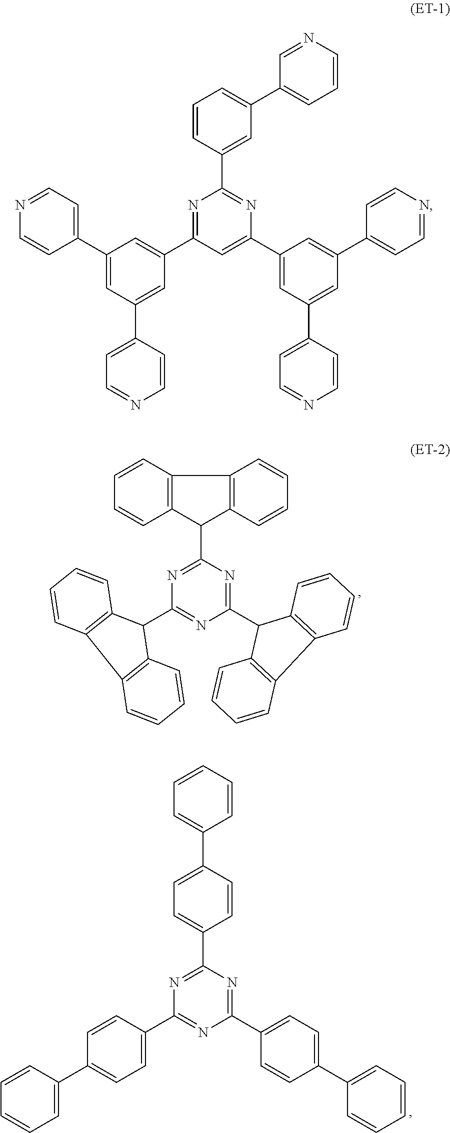 [SMILES: c1cncc(-c2cccc(-c3nc(-c4cc(-c5ccncc5)cc(-c5ccncc5)c4)cc(-c4cc(-c5ccncc5)cc(-c5ccncc5)c4)n3)c2)c1 ; c1ccc2c(c1)-c1ccccc1C2c1nc(C2c3ccccc3-c3ccccc32)nc(C2c3ccccc3-c3ccccc32)n1 ; c1ccc(-c2ccc(-c3nc(-c4ccc(-c5ccccc5)cc4)nc(-c4ccc(-c5ccccc5)cc4)n3)cc2)cc1]

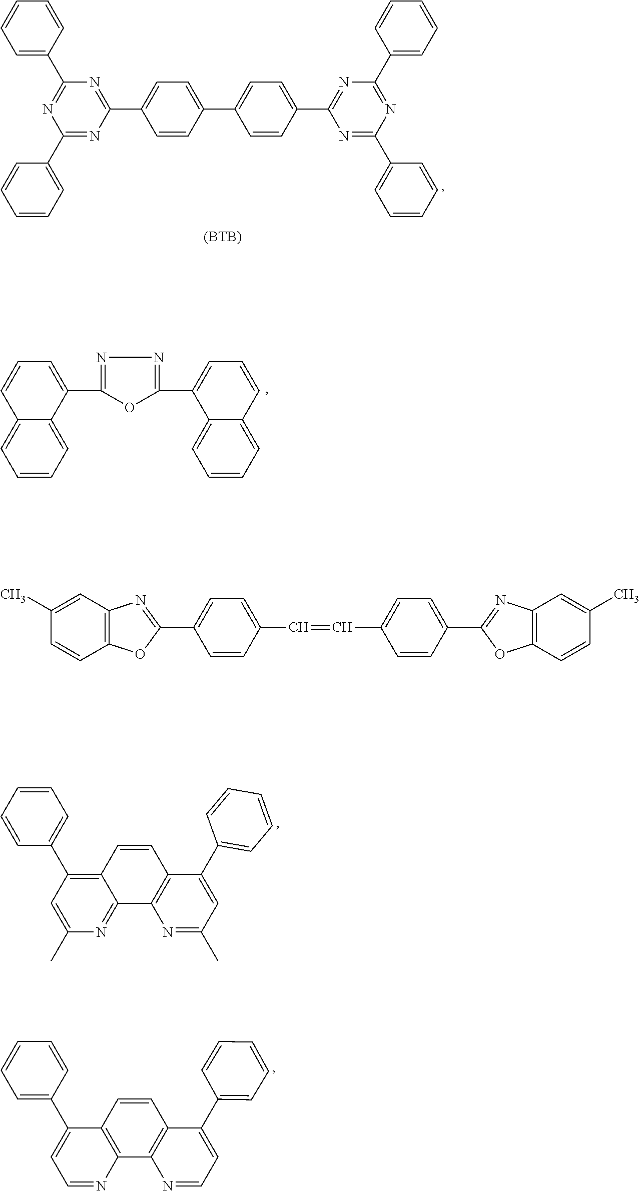

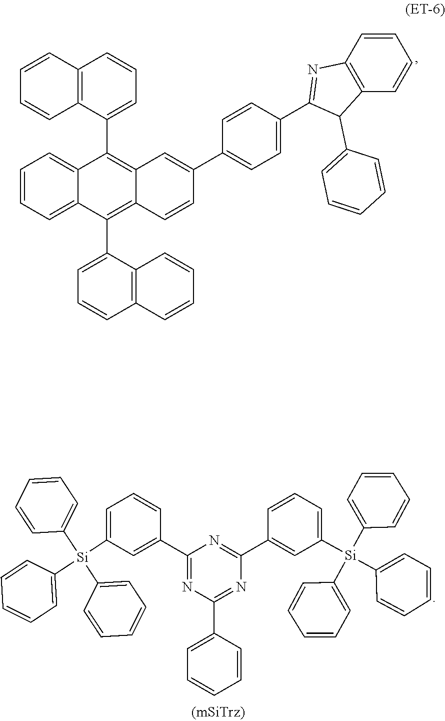 [SMILES: c1ccc(C2C(c3ccc(-c4ccc5c(-c6cccc7ccccc67)c6ccccc6c(-c6cccc7ccccc67)c5c4)cc3)=Nc3ccccc32)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

In one embodiment of the present disclosure, the electron transport layer 340 may be composed of mSiTrz and LiQ.

In the present disclosure, the cathode 200 may comprise a cathode material, which is a low work function material contributing to injection of electrons into the functional layer. Specific examples of the cathode material include, but are not limited to, metals such as magnesium, calcium, sodium, potassium, titanium, indium, yttrium, lithium, gadolinium, aluminum, silver, tin, and lead, or alloys thereof; or multilayer materials such as LiF/Al, Liq/Al, LiO₂/Al, LiF/Ca, LiF/Al, and BaF₂/Ca. Optionally, a metal electrode comprising magnesium and silver as the cathode is included.

Optionally, an electron injection layer 350 may be further provided between the cathode 200 and the electron transport layer 340 to enhance the ability to inject electrons into the electron transport layer 340. The electron injection layer 350 may comprise an inorganic material such as an alkali metal sulfide and an alkali metal halide or may comprise a complex of an alkali metal and an organic compound. In an embodiment of the present disclosure, the electron injection layer 350 may comprise ytterbium (Yb).

In a third aspect, the present disclosure provides an electronic apparatus, comprising the organic electroluminescent device described in the second aspect of the present disclosure.

According to an embodiment, as shown in FIG. 2, the electronic apparatus is an electronic apparatus 400 comprising the above-described organic electroluminescent device. The electronic apparatus 400 may be a display apparatus, a lighting apparatus, an optical communication apparatus, or other type of electronic apparatus, examples of which may include, but are not limited to, computer screens, cell phone screens, televisions, electronic paper, emergency lamps, optical modules, etc.

The synthesis method of the organic compound in the present disclosure will be demonstrated in detail with the following synthesis examples, but the present disclosure is not limited in any way by this.

### Synthetic Example

Professionals in their field should realize that the chemical reactions described in this present disclosure can be used to properly prepare many of the organic compounds in this present disclosure, and other methods used to prepare the compounds in this present disclosure are considered to be within the scope of this present disclosure. For example, according to the present disclosure, the synthesis of those non-exemplified compounds can be successfully completed by the technicians in the field through modification methods, such as appropriate protection of interfering groups, by using other known reagents in addition to the ones described in the present disclosure, or by making some conventional modifications to the reaction conditions. Compounds for which synthesis methods are not mentioned in the present disclosure may be obtained through commercial sources.

### Synthesis of Sub-a1:

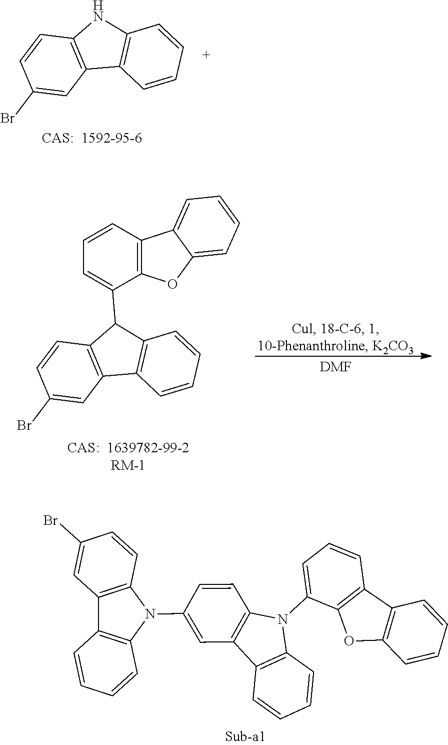

Under a nitrogen atmosphere, 3-bromocarbazole (12.25 g, 50 mmol), RM-1 (27.55 g, 60 mmol), cuprous iodide (1.90 g, 10 mmol), 18-crown-6 (1.32 g, 5 mmol), 1,10-phenanthroline (3.96 g, 20 mmol), potassium carbonate (15.20 g, 110 mmol), and N,N-dimethylformamide (280 mL) were added sequentially to a 500 mL three-necked flask. The mixture was heated to reflux and react overnight with stirring. After the system was cooled to room temperature, the reaction solution was poured into 500 mL of deionized water, filtered under suction, and the filtered solid was collected; the filtered solid was dissolved in dichloromethane and dried over anhydrous sodium sulfate. After filtration, the solvent was removed under reduced pressure to obtain a crude product. The crude product was purified by silica gel chromatography using n-heptane/dichloromethane as the mobile phase, to obtain product Sub-a1 as a white solid (18.70 g; yield 65%).

Sub-a2 was synthesized referring to the synthesis of Sub-a1, except that Reactant A was used instead of 3-bromocarbazole and Reactant B was used instead of RM-1, as indicated in Table 1.

TABLE 1
Synthesis of Sub-a2

| Sub- | | | | |
|---|---|---|---|---|
| ax | | | | Yield |
| No. | Reactant A | Reactant B | Sub-ax structure | (%) |
| Sub- a2 | 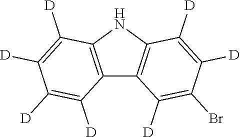 [SMILES: [2H]c1c([2H])c([2H])c2c([nH]c3c([2H])c([2H])c(Br)c([2H])c32)c1[2H]] | 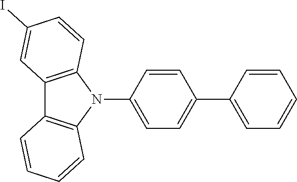 [SMILES: Ic1ccc2c(c1)c1ccccc1n2-c1ccc(-c2ccccc2)cc1] | 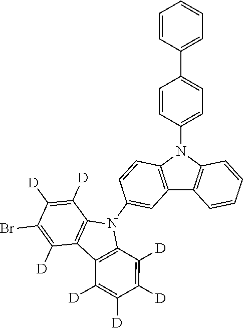 [SMILES: [2H]c1c([2H])c([2H])c2c(c1[2H])c1c([2H])c(Br)c([2H])c([2H])c1n2-c1ccc2c(c1)c1ccccc1n2-c1ccc(-c2ccccc2)cc1] | 64 |
| | CAS: 2764814-81-3 | CAS: 894791-47-0 | | |

### Synthesis of Sub-b1:

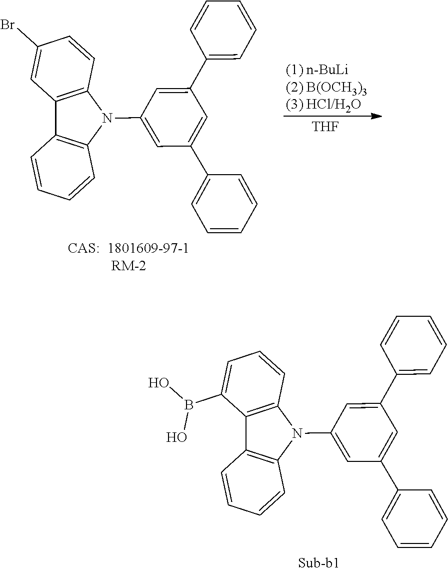 [SMILES: Brc1ccc2c(c1)c1ccccc1n2-c1cc(-c2ccccc2)cc(-c2ccccc2)c1 ; OB(O)c1cccc2c1c1ccccc1n2-c1cc(-c2ccccc2)cc(-c2ccccc2)c1 ; "THF"]

Under a nitrogen atmosphere, RM-2 (33.10 g, 70 mmol) and tetrahydrofuran (after drying, 250 mL) were added sequentially to a 500 mL three-necked flask; the system was cooled to −78° C., and a solution of n-butyllithium (2.0 M, in n-hexane, 38.5 mL, 77 mmol) was added dropwise, and after the addition was complete, the reaction mixture was maintained at −78° C. and stirred for 1 hour; then maintaining at the low temperature of −78° C., trimethylborate (10.91 g, 105 mmol) was added dropwise, and after the addition was complete, the reaction mixture was further maintained at −78° C. for 1 hour before allowing the temperature to naturally rise to room temperature. Dilute hydrochloric acid (2 M, 58 mL) was added dropwise to the reaction solution, followed by stirring for 30 minutes; the solution was extracted with dichloromethane (100 mL×3 times), and the organic phases were combined and dried over anhydrous magnesium sulfate, followed by filtering and removing the solvent under reduced pressure to yield a crude product; the crude product was slurried with n-heptane, to obtain the product Sub-b1 as a white solid by filtering (19.0 g, yield 62%).

Sub-b2 to Sub-b3 were synthesized referring to the synthesis of Sub-b1, except that Reactant C was used instead of RM-2, as indicated in Table 2.

### Table 2: Synthesis of Sub-b2 to Sub-b3

| Sub-bx No. | Reactant C | Sub-bx structure | Yield (%) |
|---|---|---|---|
| Sub-b2 | 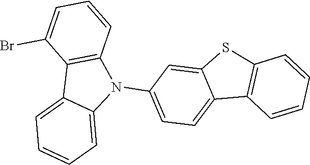 [SMILES: Brc1cccc2c1c1ccccc1n2-c1ccc2c(c1)sc1ccccc12] | 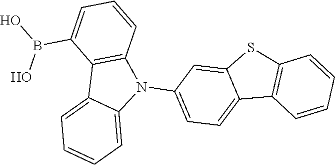 [SMILES: OB(O)c1cccc2c1c1ccccc1n2-c1ccc2c(c1)sc1ccccc12] | 57 |
| | CAS: 1686100-25-3 | | |
| Sub-b3 | 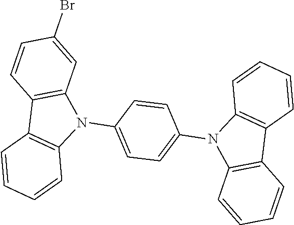 [SMILES: Brc1ccc2c3ccccc3n(-c3ccc(-n4c5ccccc5c5ccccc54)cc3)c2c1] | 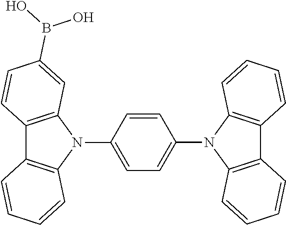 [SMILES: OB(O)c1ccc2c3ccccc3n(-c3ccc(-n4c5ccccc5c5ccccc54)cc3)c2c1] | 66 |
| | CAS: 2653278-64-7 | | |

### Synthesis of Sub-c1:

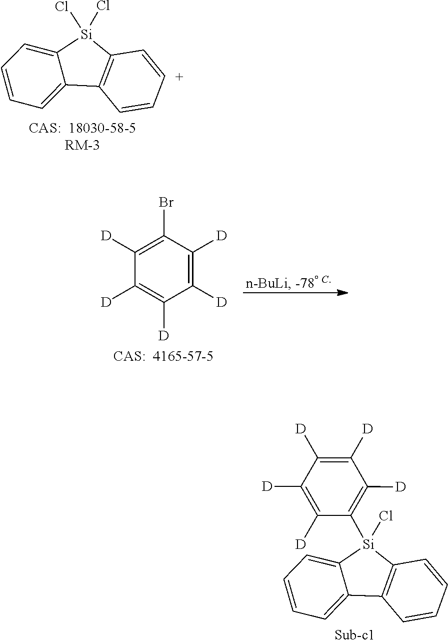 [SMILES: Cl[Si]1(Cl)C2=C(C=C[C+]=C2)c2ccccc21 ; [2H]c1c([2H])c([2H])c(Br)c([2H])c1[2H] ; [2H]c1c([2H])c([2H])c([Si]2(Cl)c3ccccc3-c3ccccc32)c([2H])c1[2H]]

Under a nitrogen atmosphere, deuterated bromobenzene (8.05 g, 50 mmol) and tetrahydrofuran (after drying, 80 mL) were added sequentially to a 500 mL three-necked flask; the system was cooled to −78° C., and a solution of n-butyllithium (2.0 M, in n-hexane, 25 mL, 50 mmol) was added dropwise, after the addition was complete, the reaction mixture was maintained at −78° C. and stirred for 1 hour; a solution of RM-3 (12.5 g, 50 mmol) in tetrahydrofuran (125 mL) was then added dropwise, after the addition was complete, the reaction mixture was maintained at −78° C. for an additional 1 hour, after which the system was allowed to raise naturally to room temperature; after filtration, the solvent was removed by distillation under reduced pressure, to obtain a crude product; the crude product was used directly for the subsequent reaction without purification.

Sub-c2 to Sub-c6 were synthesized following the synthesis of Sub-c1, except that Reactant D was used instead of deuterated bromobenzene, as indicated in Table 3.

### Table 3: Synthesis of Sub-c2 to Sub-c6

| Sub-cx No. | Reactant D | Sub-cx structure |
|---|---|---|
| Sub-c2 | 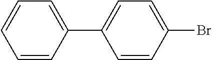 [SMILES: Brc1ccc(-c2ccccc2)cc1] | 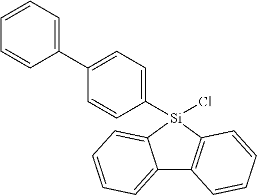 [SMILES: Cl[Si]1(c2ccc(-c3ccccc3)cc2)c2ccccc2-c2ccccc21] |
| | CAS: 92-66-0 | |
| Sub-c3 | 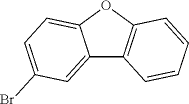 [SMILES: Brc1ccc2oc3ccccc3c2c1] | 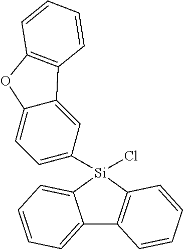 [SMILES: Cl[Si]1(c2ccc3oc4ccccc4c3c2)c2ccccc2-c2ccccc21] |
| | CAS: 86-76-0 | |
| Sub-c4 | 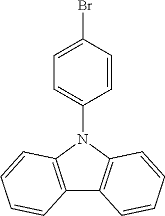 [SMILES: Brc1ccc(-n2c3ccccc3c3ccccc32)cc1] | 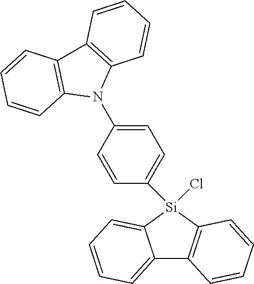 [SMILES: Cl[Si]1(c2ccc(-n3c4ccccc4c4ccccc43)cc2)c2ccccc2-c2ccccc21] |
| | CAS: 57102-42-8 | |
| Sub-c5 | 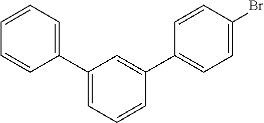 [SMILES: Brc1ccc(-c2cccc(-c3ccccc3)c2)cc1] | 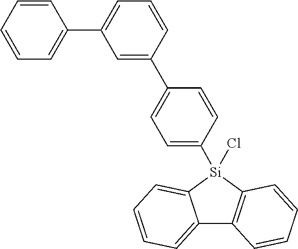 [SMILES: Cl[Si]1(c2ccc(-c3cccc(-c4ccccc4)c3)cc2)c2ccccc2-c2ccccc21] |
| | CAS: 54590-37-3 | |
| Sub-c6 | 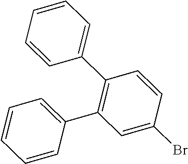 [SMILES: Brc1ccc(-c2ccccc2)c(-c2ccccc2)c1] | 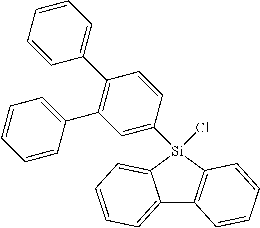 [SMILES: Cl[Si]1(c2ccc(-c3ccccc3)c(-c3ccccc3)c2)c2ccccc2-c2ccccc21] |
| | CAS: 24253-40-5 | |

### Synthesis of Sub-d1

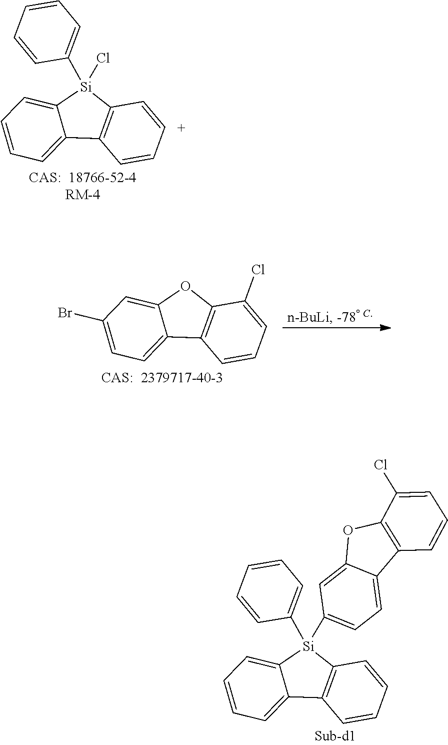 [SMILES: Cl[Si]1(c2ccccc2)c2ccccc2-c2ccccc21 ; Clc1cccc2c1oc1cc(Br)ccc12 ; Clc1cccc2c1oc1cc([Si]3(c4ccccc4)c4ccccc4-c4ccccc43)ccc12]

Under a nitrogen atmosphere, 3-bromo-6-chlorodibenzofuran (14.0 g, 50 mmol) and tetrahydrofuran (after drying, 80 mL) were added sequentially to a 500 mL three-necked flask; the system was cooled to −78° C., and a solution of n-butyllithium (2.0 M in n-hexane, 25 mL, 50 mmol) was added dropwise. After the addition was complete, the reaction mixture was maintained at −78° C. and stirred for 1 hour; a solution of RM-4 (14.6 g, 50 mmol) in tetrahydrofuran (150 mL) was added dropwise, after the addition was complete, the mixture was maintained at −78° C. for additional 1 hour before allowing the system to raise naturally to room temperature; the reaction mixture was extracted with dichloromethane (100 mL×3 times), and the organic phases were combined and dried over anhydrous magnesium sulfate. After filtration, the solvent was removed under reduced pressure to obtain a crude product. The crude product was purified by silica gel column chromatography using dichloromethane/n-heptane as the mobile phase, to obtain compound Sub-d as a white solid (15.35 g, yield 67%).

Sub-d2 to Sub-d22 were synthesized referring to the synthesis of Sub-d1, except that Reactant E was used instead of RM-4 and Reactant F was used instead of 3-bromo-6-chlorodibenzofuran, as indicated in Table 4

TABLE 4
Synthesis of Sub-d2 to Sub-d22

| Sub- | | | | |
|---|---|---|---|---|
| dx | | | | Yield |
| No. | Reactant E | Reactant F | Sub-dx structure | (%) |
| Sub- d2 | 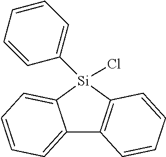 [SMILES: Cl[Si]1(c2ccccc2)c2ccccc2-c2ccccc21] | 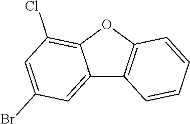 [SMILES: Clc1cc(Br)cc2c1oc1ccccc12] | 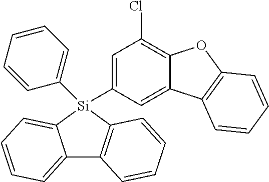 [SMILES: Clc1cc([Si]2(c3ccccc3)c3ccccc3-c3ccccc32)cc2c1oc1ccccc12] | 57 |
| | | CAS: 1960445-63-9 | | |
| Sub- d3 | 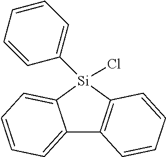 [SMILES: Cl[Si]1(c2ccccc2)c2ccccc2-c2ccccc21] | 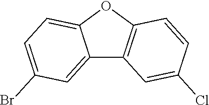 [SMILES: Clc1ccc2oc3ccc(Br)cc3c2c1] | 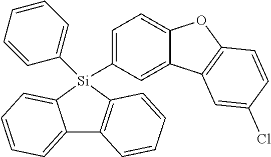 [SMILES: Clc1ccc2oc3ccc([Si]4(c5ccccc5)c5ccccc5-c5ccccc54)cc3c2c1] | 70 |
| | | CAS: 1360145-45-4 | | |
| Sub- d4 | 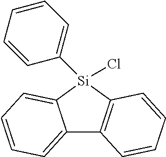 [SMILES: Cl[Si]1(c2ccccc2)c2ccccc2-c2ccccc21] | 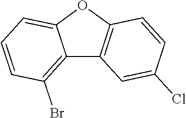 [SMILES: Clc1ccc2oc3cccc(Br)c3c2c1] | 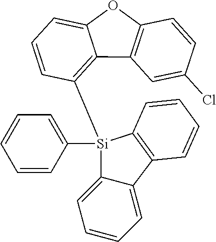 [SMILES: Clc1ccc2oc3cccc([Si]4(c5ccccc5)c5ccccc5-c5ccccc54)c3c2c1] | 47 |
| | | CAS: 2173554-83-9 | | |
| Sub- d5 | 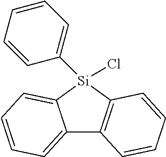 [SMILES: Cl[Si]1(c2ccccc2)c2ccccc2-c2ccccc21] | 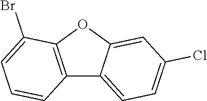 [SMILES: Clc1ccc2c(c1)oc1c(Br)cccc12] | 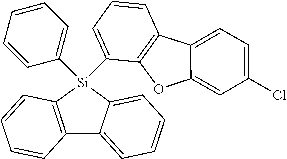 [SMILES: Clc1ccc2c(c1)oc1c([Si]3(c4ccccc4)c4ccccc4-c4ccccc43)cccc12] | 58 |
| | | CAS: 2361279-68-5 | | |
| Sub- d6 | 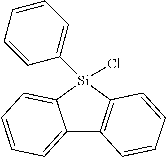 [SMILES: Cl[Si]1(c2ccccc2)c2ccccc2-c2ccccc21] | 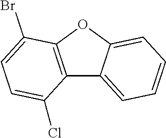 [SMILES: Clc1ccc(Br)c2oc3ccccc3c12] | 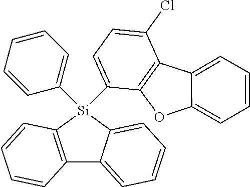 [SMILES: Clc1ccc([Si]2(c3ccccc3)c3ccccc3-c3ccccc32)c2oc3ccccc3c12] | 49 |
| | | CAS: 2183475-72-9 | | |
| Sub- d7 | 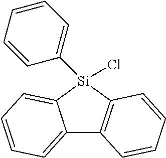 [SMILES: Cl[Si]1(c2ccccc2)c2ccccc2-c2ccccc21] | 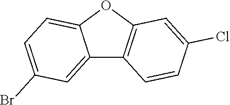 [SMILES: Clc1ccc2c(c1)oc1ccc(Br)cc12] | 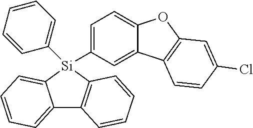 [SMILES: Clc1ccc2c(c1)oc1ccc([Si]3(c4ccccc4)c4ccccc4-c4ccccc43)cc12] | 61 |
| | | CAS: 2355229-03-5 | | |
| Sub- d8 | 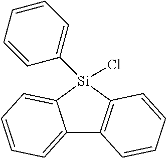 [SMILES: Cl[Si]1(c2ccccc2)c2ccccc2-c2ccccc21] | 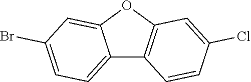 [SMILES: Clc1ccc2c(c1)oc1cc(Br)ccc12] | 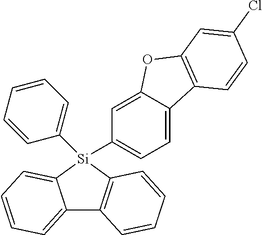 [SMILES: Clc1ccc2c(c1)oc1cc([Si]3(c4ccccc4)c4ccccc4-c4ccccc43)ccc12] | 62 |
| | | CAS: 2244910-28-7 | | |
| Sub- d9 | 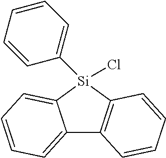 [SMILES: Cl[Si]1(c2ccccc2)c2ccccc2-c2ccccc21] | 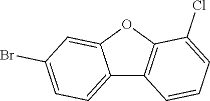 [SMILES: Clc1cccc2c1oc1cc(Br)ccc12] | 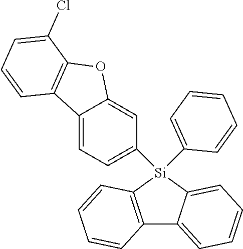 [SMILES: Clc1cccc2c1oc1cc([Si]3(c4ccccc4)c4ccccc4-c4ccccc43)ccc12] | 68 |
| | | CAS: 2379717-40-3 | | |
| Sub- d10 | 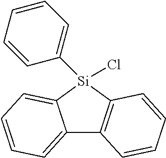 [SMILES: Cl[Si]1(c2ccccc2)c2ccccc2-c2ccccc21] | 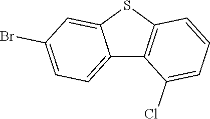 [SMILES: Clc1cccc2sc3cc(Br)ccc3c12] | 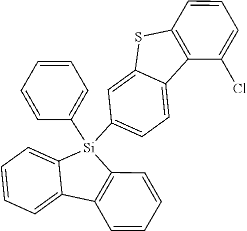 [SMILES: Clc1cccc2sc3cc([Si]4(c5ccccc5)c5ccccc5-c5ccccc54)ccc3c12] | 50 |
| | | CAS: 1622440-56-5 | | |
| Sub- d11 | 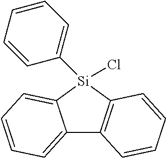 [SMILES: Cl[Si]1(c2ccccc2)c2ccccc2-c2ccccc21] | 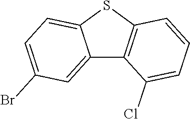 [SMILES: Clc1cccc2sc3ccc(Br)cc3c12] | 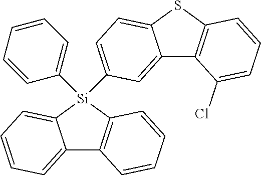 [SMILES: Clc1cccc2sc3ccc([Si]4(c5ccccc5)c5ccccc5-c5ccccc54)cc3c12] | 67 |
| | | CAS: 2055864-36-1 | | |
| Sub- d12 | 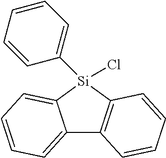 [SMILES: Cl[Si]1(c2ccccc2)c2ccccc2-c2ccccc21] | 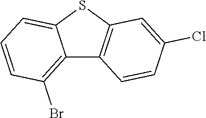 [SMILES: Clc1ccc2c(c1)sc1cccc(Br)c12] | 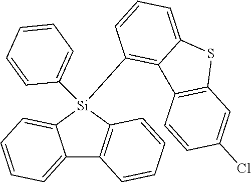 [SMILES: Clc1ccc2c(c1)sc1cccc([Si]3(c4ccccc4)c4ccccc4-c4ccccc43)c12] | 57 |
| | | CAS: 1622440-57-6 | | |
| Sub- d13 | 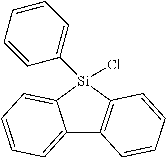 [SMILES: Cl[Si]1(c2ccccc2)c2ccccc2-c2ccccc21] | 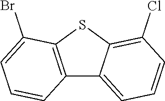 [SMILES: Clc1cccc2c1sc1c(Br)cccc12] | 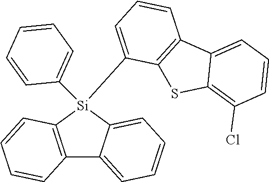 [SMILES: Clc1cccc2c1sc1c([Si]3(c4ccccc4)c4ccccc4-c4ccccc43)cccc12] | 55 |
| | | CAS: 1332939-29-3 | | |
| Sub- d14 | 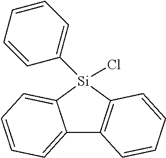 [SMILES: Cl[Si]1(c2ccccc2)c2ccccc2-c2ccccc21] | 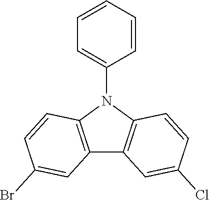 [SMILES: Clc1ccc2c(c1)c1cc(Br)ccc1n2-c1ccccc1] | 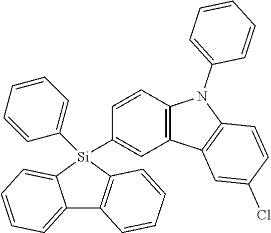 [SMILES: Clc1ccc2c(c1)c1cc([Si]3(c4ccccc4)c4ccccc4-c4ccccc43)ccc1n2-c1ccccc1] | 60 |
| | | CAS: 2055864-37-2 | | |
| Sub- d15 | 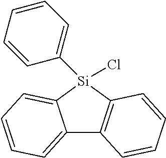 [SMILES: Cl[Si]1(c2ccccc2)c2ccccc2-c2ccccc21] | 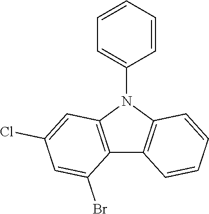 [SMILES: Clc1cc(Br)c2c3ccccc3n(-c3ccccc3)c2c1] | 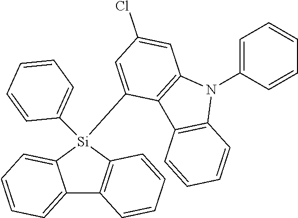 [SMILES: Clc1cc([Si]2(c3ccccc3)c3ccccc3-c3ccccc32)c2c3ccccc3n(-c3ccccc3)c2c1] | 47 |
| | | CAS: 2440193-72-4 | | |
| Sub- d16 | 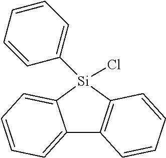 [SMILES: Cl[Si]1(c2ccccc2)c2ccccc2-c2ccccc21] | 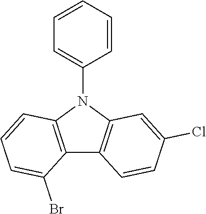 [SMILES: Clc1ccc2c3c(Br)cccc3n(-c3ccccc3)c2c1] | 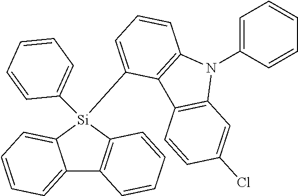 [SMILES: Clc1ccc2c3c([Si]4(c5ccccc5)c5ccccc5-c5ccccc54)cccc3n(-c3ccccc3)c2c1] | 49 |
| | | CAS: 2697709-56-9 | | |
| Sub- d17 | 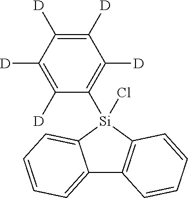 [SMILES: [2H]c1c([2H])c([2H])c([Si]2(Cl)c3ccccc3-c3ccccc32)c([2H])c1[2H]] | 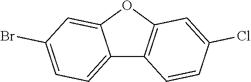 [SMILES: Clc1ccc2c(c1)oc1cc(Br)ccc12] | 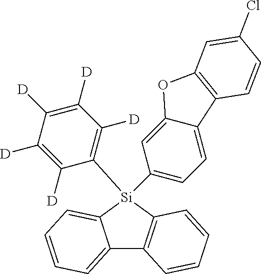 [SMILES: [2H]c1c([2H])c([2H])c([Si]2(c3ccc4c(c3)oc3cc(Cl)ccc34)c3ccccc3-c3ccccc32)c([2H])c1[2H]] | 70 |
| | | CAS: 2244910-28-7 | | |
| Sub- d18 | 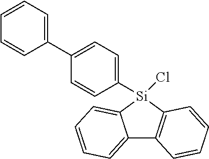 [SMILES: Cl[Si]1(c2ccc(-c3ccccc3)cc2)c2ccccc2-c2ccccc21] | 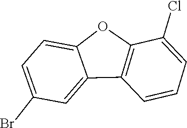 [SMILES: Clc1cccc2c1oc1ccc(Br)cc12] | 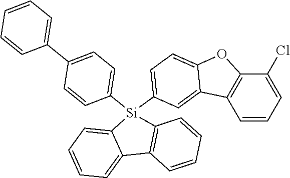 [SMILES: Clc1cccc2c1oc1ccc([Si]3(c4ccc(-c5ccccc5)cc4)c4ccccc4-c4ccccc43)cc12] | 69 |
| | | CAS: 2138490-84-1 | | |
| Sub- d19 | 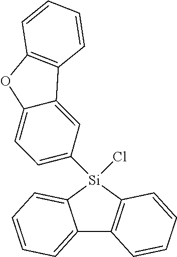 [SMILES: Cl[Si]1(c2ccc3oc4ccccc4c3c2)c2ccccc2-c2ccccc21] | 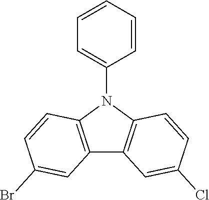 [SMILES: Clc1ccc2c(c1)c1cc(Br)ccc1n2-c1ccccc1] | 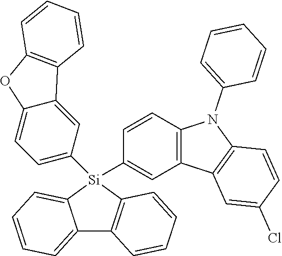 [SMILES: Clc1ccc2c(c1)c1cc([Si]3(c4ccc5oc6ccccc6c5c4)c4ccccc4-c4ccccc43)ccc1n2-c1ccccc1] | 60 |
| | | CAS: 2055864-37-2 | | |
| Sub- d20 | 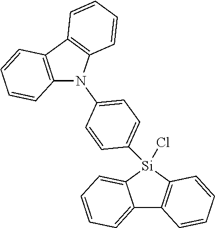 [SMILES: Cl[Si]1(c2ccc(-n3c4ccccc4c4ccccc43)cc2)c2ccccc2-c2ccccc21] | 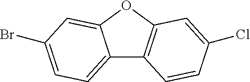 [SMILES: Clc1ccc2c(c1)oc1cc(Br)ccc12] | 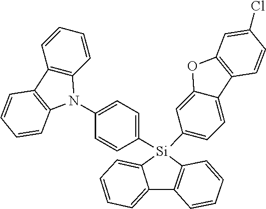 [SMILES: Clc1ccc2c(c1)oc1cc([Si]3(c4ccc(-n5c6ccccc6c6ccccc65)cc4)c4ccccc4-c4ccccc43)ccc12] | 63 |
| | | CAS: 2244910-28-7 | | |
| Sub- d21 | 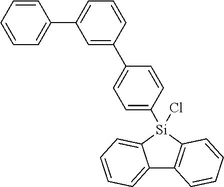 [SMILES: Cl[Si]1(c2ccc(-c3cccc(-c4ccccc4)c3)cc2)c2ccccc2-c2ccccc21] | 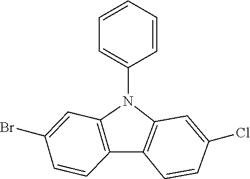 [SMILES: Clc1ccc2c3ccc(Br)cc3n(-c3ccccc3)c2c1] | 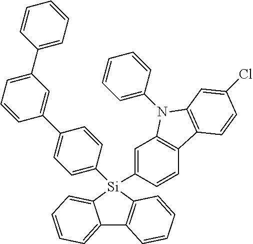 [SMILES: Clc1ccc2c3ccc([Si]4(c5ccc(-c6cccc(-c7ccccc7)c6)cc5)c5ccccc5-c5ccccc54)cc3n(-c3ccccc3)c2c1] | 64 |
| | | CAS: 2595372-49-7 | | |
| Sub- d22 | 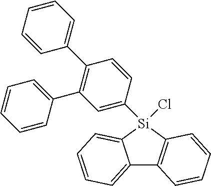 [SMILES: Cl[Si]1(c2ccc(-c3ccccc3)c(-c3ccccc3)c2)c2ccccc2-c2ccccc21] | 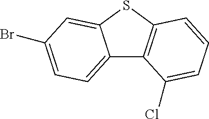 [SMILES: Clc1cccc2sc3cc(Br)ccc3c12] | 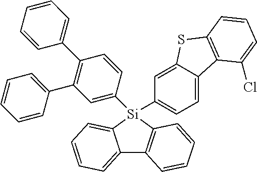 [SMILES: Clc1cccc2sc3cc([Si]4(c5ccc(-c6ccccc6)c(-c6ccccc6)c5)c5ccccc5-c5ccccc54)ccc3c12] | 65 |
| | | CAS: 1622440-56-5 | | |

### Synthesis of Compound 14:

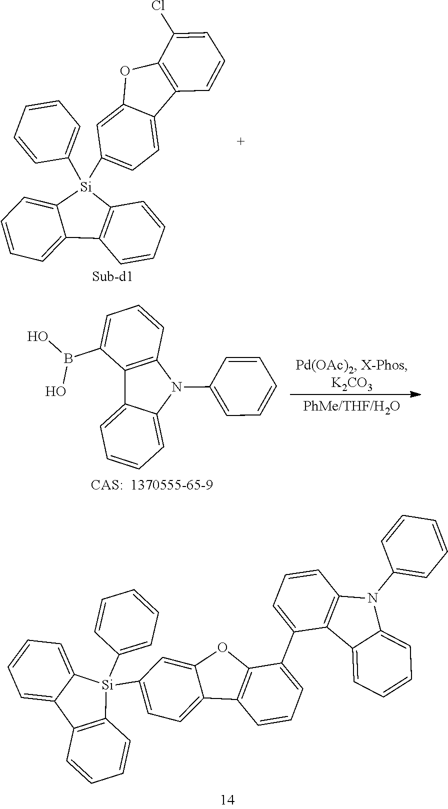

Under a nitrogen atmosphere, Sub-d (9.16 g, 20 mmol), (9-phenyl-9H-carbazole-4-yl) boronic acid (6.32 g, 22 mmol), palladium acetate (Pd(OAc)₂, 0.045 g, 0.2 mmol), (2-dicyclohexylphosphino-2′,4′,6′-triisopropylbiphenyl) (XPhos, 0.19 g, 0.4 mmol), anhydrous potassium carbonate (5.53 g, 40 mmol), toluene (100 mL), tetrahydrofuran (25 mL), and deionized water (25 mL) were added sequentially to a 250 mL three-necked flask. The reaction mixture was stirred and heated to reflux reaction for 16 hours. After the system was cooled to room temperature, the reaction mixture was extracted with dichloromethane (100 mL×3 times). The organic phases were combined and dried over anhydrous magnesium sulfate, followed by filtering, removing the solvent under reduced pressure to obtain a crude product. The crude product was purified by silica gel column chromatography using dichloromethane/n-heptane as the mobile phase, to obtain Compound 14 as a white solid (10.7 g, yield 78%, m/z=666.2 [M+H]⁺.

The compounds of the present disclosure as indicated in Table 5 were synthesized referring to the synthesis of Compound 14, except that Reactant G was used instead of Sub-d1 and Reactant H was used instead of (9-phenyl-9H-carbazole-4-yl) boric acid, as indicated in Table 5.

TABLE 5
Synthesis of the compounds of the present disclosure

| | | Compound structure | m/z | Yield |
|---|---|---|---|---|
| Reactant G | Reactant H | and No. | ([M + H]⁺) | % |
| 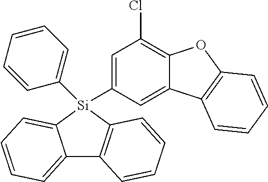 [SMILES: Clc1cc([Si]2(c3ccccc3)c3ccccc3-c3ccccc32)cc2c1oc1ccccc12] | 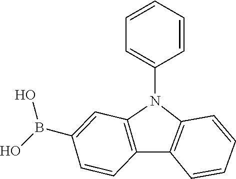 [SMILES: OB(O)c1ccc2c3ccccc3n(-c3ccccc3)c2c1] | 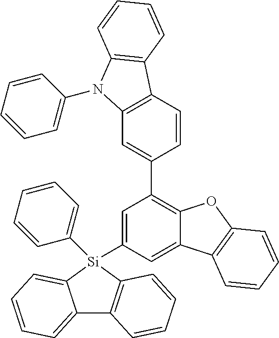 [SMILES: c1ccc(-n2c3ccccc3c3ccc(-c4cc([Si]5(c6ccccc6)c6ccccc6-c6ccccc65)cc5c4oc4ccccc45)cc32)cc1] | 666.2 | 79 |
| Sub-d2 | CAS: 1001911-63-2 | 19 | | |
| 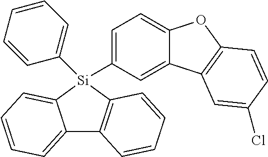 [SMILES: Clc1ccc2oc3ccc([Si]4(c5ccccc5)c5ccccc5-c5ccccc54)cc3c2c1] | 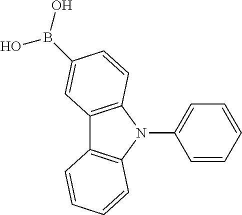 [SMILES: OB(O)c1ccc2c(c1)c1ccccc1n2-c1ccccc1] | 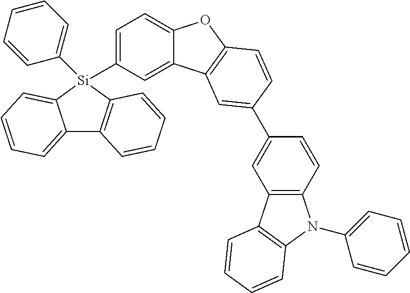 [SMILES: c1ccc(-n2c3ccccc3c3cc(-c4ccc5oc6ccc([Si]7(c8ccccc8)c8ccccc8-c8ccccc87)cc6c5c4)ccc32)cc1] | 666.2 | 75 |
| Sub-d3 | CAS: 854952-58-2 | 20 | | |
| 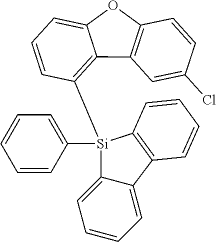 [SMILES: Clc1ccc2oc3cccc([Si]4(c5ccccc5)c5ccccc5-c5ccccc54)c3c2c1] | 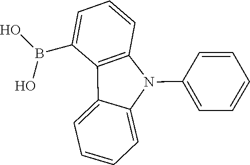 [SMILES: OB(O)c1cccc2c1c1ccccc1n2-c1ccccc1] | 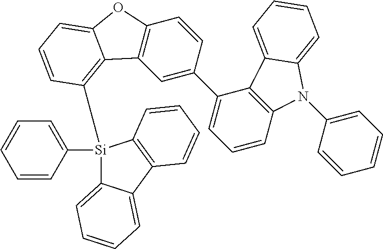 [SMILES: c1ccc(-n2c3ccccc3c3c(-c4ccc5oc6cccc(C[Si]7(c8ccccc8)c8ccccc8-c8ccccc87)c6c5c4)cccc32)cc1] | 666.2 | 75 |
| Sub-d4 | CAS: 1370555-65-9 | 54 | | |
| 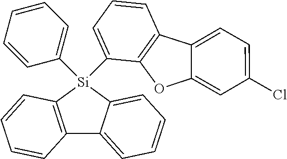 [SMILES: Clc1ccc2c(c1)oc1c([Si]3(c4ccccc4)c4ccccc4-c4ccccc43)cccc12] | 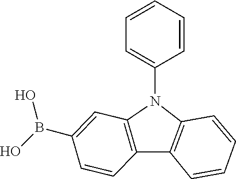 [SMILES: OB(O)c1ccc2c3ccccc3n(-c3ccccc3)c2c1] | 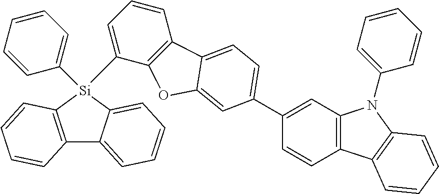 [SMILES: c1ccc(-n2c3ccccc3c3ccc(-c4ccc5c(c4)oc4c([Si]6(c7ccccc7)c7ccccc7-c7ccccc76)cccc45)cc32)cc1] | 666.2 | 66 |
| Sub-d5 | CAS: 1001911-63-2 | 59 | | |
| 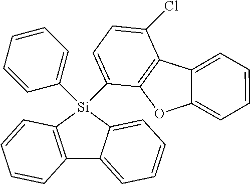 [SMILES: Clc1ccc([Si]2(c3ccccc3)c3ccccc3-c3ccccc32)c2oc3ccccc3c12] | 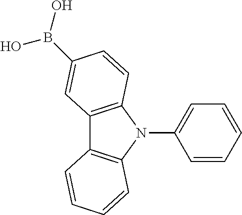 [SMILES: OB(O)c1ccc2c(c1)c1ccccc1n2-c1ccccc1] | 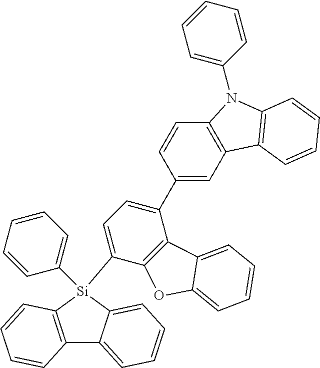 [SMILES: c1ccc(-n2c3ccccc3c3cc(-c4ccc([Si]5(c6ccccc6)c6ccccc6-c6ccccc65)c5oc6ccccc6c45)ccc32)cc1] | 666.2 | 72 |
| Sub-d6 | CAS: 854952-58-2 | 62 | | |
| 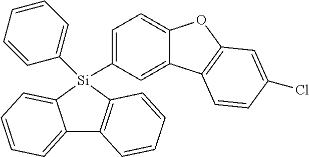 [SMILES: Clc1ccc2c(c1)oc1ccc([Si]3(c4ccccc4)c4ccccc4-c4ccccc43)cc12] | 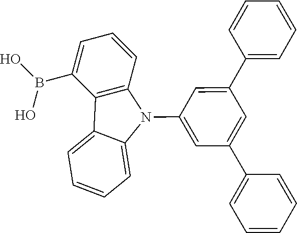 [SMILES: OB(O)c1cccc2c1c1ccccc1n2-c1cc(-c2ccccc2)cc(-c2ccccc2)c1] | 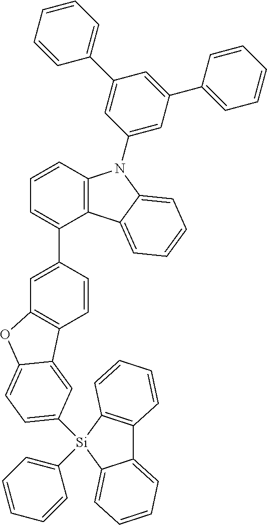 [SMILES: c1ccc(-c2cc(-c3ccccc3)cc(-n3c4ccccc4c4c(-c5ccc6c(c5)oc5ccc([Si]7(c8ccccc8)c8ccccc8-c8ccccc87)cc56)cccc43)c2)cc1] | 818.3 | 64 |
| Sub-d7 | Sub-b1 | 78 | | |
| 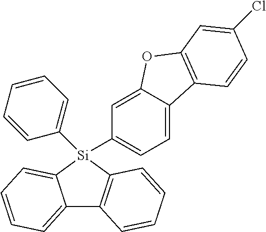 [SMILES: Clc1ccc2c(c1)oc1cc([Si]3(c4ccccc4)c4ccccc4-c4ccccc43)ccc12] | 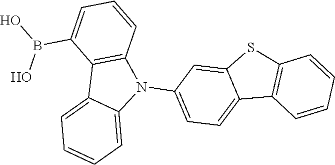 [SMILES: OB(O)c1cccc2c1c1ccccc1n2-c1ccc2c(c1)sc1ccccc12] | 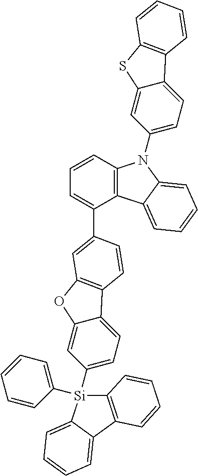 [SMILES: c1ccc([Si]2(c3ccc4c(c3)oc3cc(-c5cccc6c5c5ccccc5n6-c5ccc6c(c5)sc5ccccc56)ccc34)c3ccccc3-c3ccccc32)cc1] | 772.2 | 65 |
| Sub-d8 | Sub-b2 | 81 | | |
| 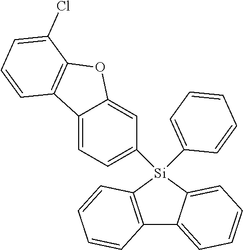 [SMILES: Clc1cccc2c1oc1cc([Si]3(c4ccccc4)c4ccccc4-c4ccccc43)ccc12] | 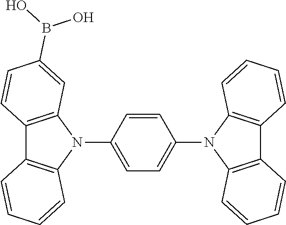 [SMILES: OB(O)c1ccc2c3ccccc3n(-c3ccc(-n4c5ccccc5c5ccccc54)cc3)c2c1] | 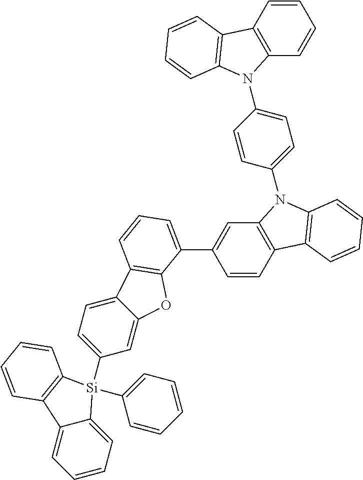 [SMILES: c1ccc([Si]2(c3ccc4c(c3)oc3c(-c5ccc6c7ccccc7n(-c7ccc(-n8c9ccccc9c9ccccc98)cc7)c6c5)cccc34)c3ccccc3-c3ccccc32)cc1] | 831.3 | 73 |
| Sub-d9 | Sub-b3 | 85 | | |
| 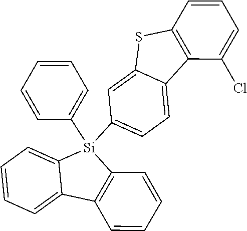 [SMILES: Clc1cccc2sc3cc([Si]4(c5ccccc5)c5ccccc5-c5ccccc54)ccc3c12] | 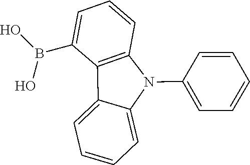 [SMILES: OB(O)c1cccc2c1c1ccccc1n2-c1ccccc1] | 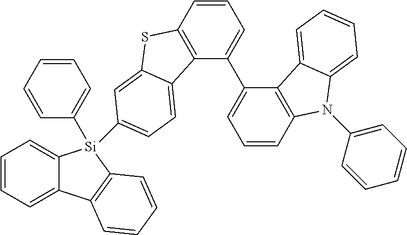 [SMILES: c1ccc(-n2c3ccccc3c3c(-c4cccc5sc6cc([Si]7(c8ccccc8)c8ccccc8-c8ccccc87)ccc6c45)cccc32)cc1] | 682.2 | 63 |
| Sub-d10 | CAS: 1370555-65-9 | 107 | | |
| 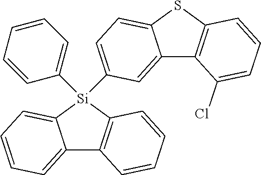 [SMILES: Clc1cccc2sc3ccc([Si]4(c5ccccc5)c5ccccc5-c5ccccc54)cc3c12] | 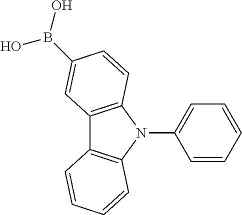 [SMILES: OB(O)c1ccc2c(c1)c1ccccc1n2-c1ccccc1] | 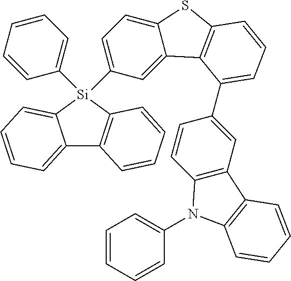 [SMILES: c1ccc(-n2c3ccccc3c3cc(-c4cccc5sc6ccc([Si]7(c8ccccc8)c8ccccc8-c8ccccc87)cc6c45)ccc32)cc1] | 682.2 | 69 |
| Sub-d11 | CAS: 854952-58-2 | 114 | | |
| 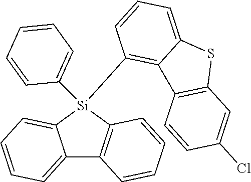 [SMILES: Clc1ccc2c(c1)sc1cccc([Si]3(c4ccccc4)c4ccccc4-c4ccccc43)c12] | 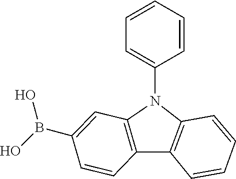 [SMILES: OB(O)c1ccc2c3ccccc3n(-c3ccccc3)c2c1] | 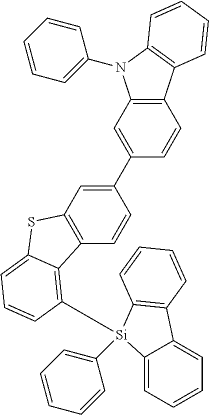 [SMILES: c1ccc(-n2c3ccccc3c3ccc(-c4ccc5c(c4)sc4cccc(C[Si]6(c7ccccc7)c7ccccc7-c7ccccc76)c45)cc32)cc1] | 682.2 | 71 |
| Sub-d12 | CAS: 1001911-63-2 | 131 | | |
| 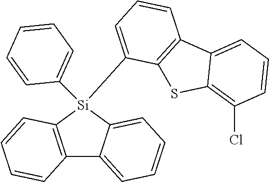 [SMILES: Clc1cccc2c1sc1c([Si]3(c4ccccc4)c4ccccc4-c4ccccc43)cccc12] | 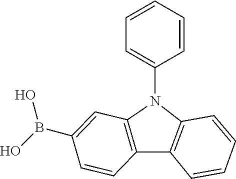 [SMILES: OB(O)c1ccc2c3ccccc3n(-c3ccccc3)c2c1] | 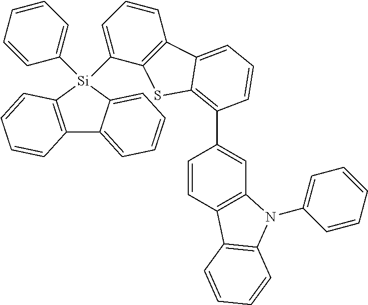 [SMILES: c1ccc(-n2c3ccccc3c3ccc(-c4cccc5c4sc4c([Si]6(c7ccccc7)c7ccccc7-c7ccccc76)cccc45)cc32)cc1] | 682.2 | 63 |
| Sub-d13 | CAS: 1001911-63-2 | 150 | | |
| 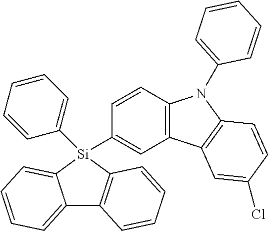 [SMILES: Clc1ccc2c(c1)c1cc([Si]3(c4ccccc4)c4ccccc4-c4ccccc43)ccc1n2-c1ccccc1] | 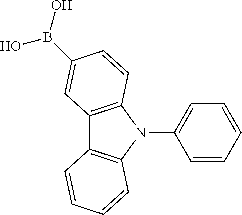 [SMILES: OB(O)c1ccc2c(c1)c1ccccc1n2-c1ccccc1] | 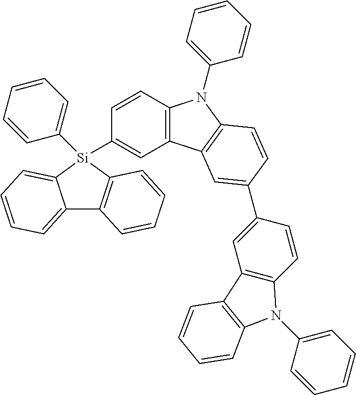 [SMILES: c1ccc(-n2c3ccccc3c3cc(-c4ccc5c(c4)c4cc([Si]6(c7ccccc7)c7ccccc7-c7ccccc76)ccc4n5-c4ccccc4)ccc32)cc1] | 741.3 | 73 |
| Sub-d14 | CAS: 854952-58-2 | 202 | | |
| 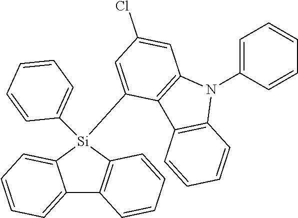 [SMILES: Clc1cc([Si]2(c3ccccc3)c3ccccc3-c3ccccc32)c2c3ccccc3n(-c3ccccc3)c2c1] | 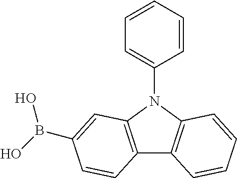 [SMILES: OB(O)c1ccc2c3ccccc3n(-c3ccccc3)c2c1] | 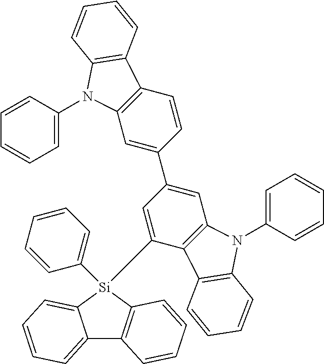 [SMILES: c1ccc(-n2c3ccccc3c3ccc(-c4cc(C[Si]5(c6ccccc6)c6ccccc6-c6ccccc65)c5c6ccccc6n(-c6ccccc6)c5c4)cc32)cc1] | 741.3 | 61 |
| | CAS: 1001911-63-2 | 211 | | |
| 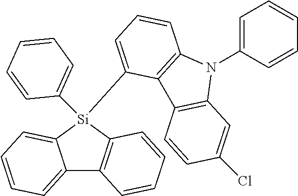 [SMILES: Clc1ccc2c3c([Si]4(c5ccccc5)c5ccccc5-c5ccccc54)cccc3n(-c3ccccc3)c2c1] | 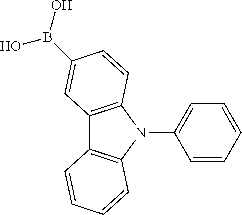 [SMILES: OB(O)c1ccc2c(c1)c1ccccc1n2-c1ccccc1] | 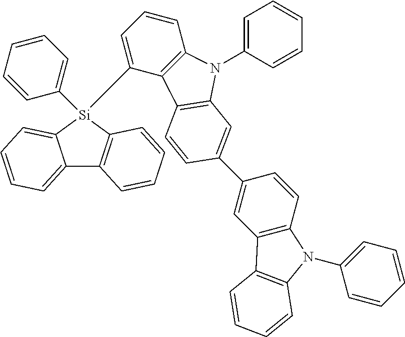 [SMILES: c1ccc(-n2c3ccccc3c3cc(-c4ccc5c6c(C[Si]7(c8ccccc8)c8ccccc8-c8ccccc87)cccc6n(-c6ccccc6)c5c4)ccc32)cc1] | 741.2 | 73 |
| | CAS: 854952-58-2 | 220 | | |
| 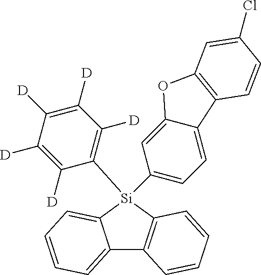 [SMILES: [2H]c1c([2H])c([2H])c([Si]2(c3ccc4c(c3)oc3cc(Cl)ccc34)c3ccccc3-c3ccccc32)c([2H])c1[2H]] | 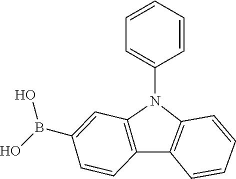 [SMILES: OB(O)c1ccc2c3ccccc3n(-c3ccccc3)c2c1] | 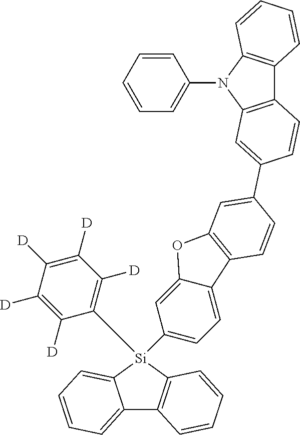 [SMILES: [2H]c1c([2H])c([2H])c(C[Si]2(c3ccc4c(c3)oc3cc(-c5ccc6c7ccccc7n(-c7ccccc7)c6c5)ccc34)c3ccccc3-c3ccccc32)c([2H])c1[2H]] | 671.2 | 70 |
| | CAS: 1001911-63-2 | 247 | | |
| 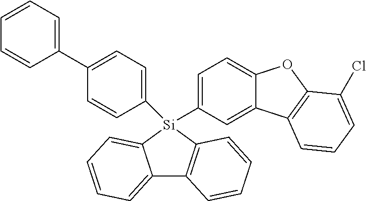 [SMILES: Clc1cccc2c1oc1ccc([Si]3(c4ccc(-c5ccccc5)cc4)c4ccccc4-c4ccccc43)cc12] | 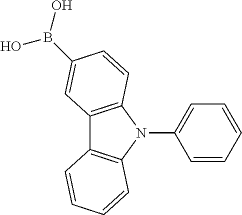 [SMILES: OB(O)c1ccc2c(c1)c1ccccc1n2-c1ccccc1] | 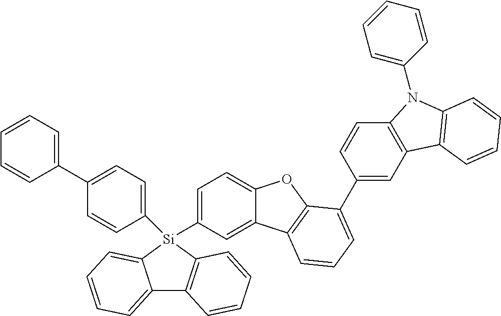 [SMILES: c1ccc(-c2ccc([Si]3(c4ccc5oc6c(-c7ccc8c(c7)c7ccccc7n8-c7ccccc7)cccc6c5c4)c4ccccc4-c4ccccc43)cc2)cc1] | 742.2 | 72 |
| | CAS: 854952-58-2 | 250 | | |
| 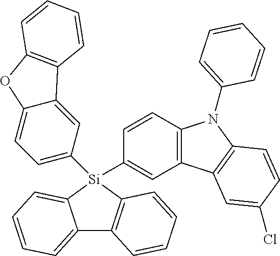 [SMILES: Clc1ccc2c(c1)c1cc([Si]3(c4ccc5oc6ccccc6c5c4)c4ccccc4-c4ccccc43)ccc1n2-c1ccccc1] | 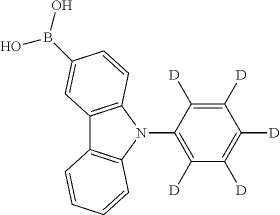 [SMILES: [2H]c1c([2H])c([2H])c(-n2c3ccccc3c3cc(B(O)O)ccc32)c([2H])c1[2H]] | 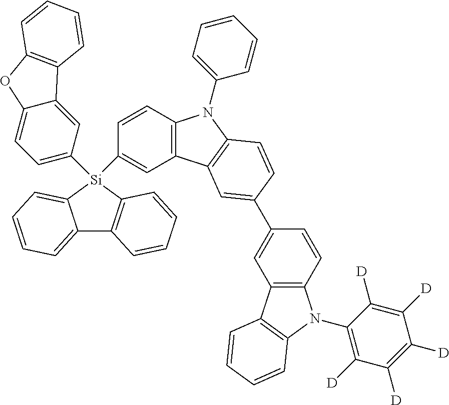 [SMILES: [2H]c1c([2H])c([2H])c(-n2c3ccccc3c3cc(-c4ccc5c(c4)c4cc([Si]6(c7ccc8oc9ccccc9c8c7)c7ccccc7-c7ccccc76)ccc4n5-c4ccccc4)ccc32)c([2H])c1[2H]] | 836.3 | 66 |
| | CAS: 1927886-82-5 | 252 | | |
| 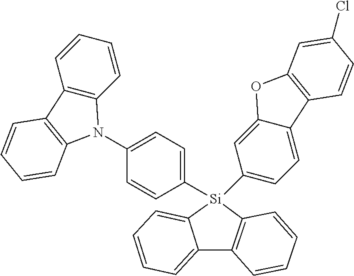 [SMILES: Clc1ccc2c(c1)oc1cc([Si]3(c4ccc(-n5c6ccccc6c6ccccc65)cc4)c4ccccc4-c4ccccc43)ccc12] | 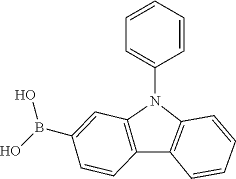 [SMILES: OB(O)c1ccc2c3ccccc3n(-c3ccccc3)c2c1] | 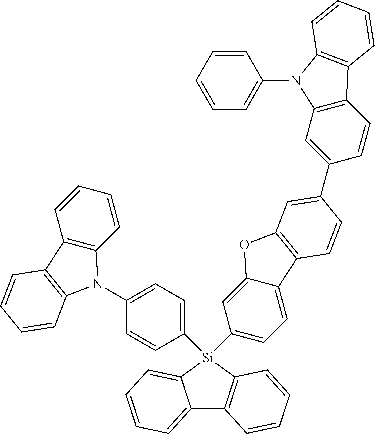 [SMILES: c1ccc(-n2c3ccccc3c3ccc(-c4ccc5c(c4)oc4cc([Si]6(c7ccc(-n8c9ccccc9c9ccccc98)cc7)c7ccccc7-c7ccccc76)ccc45)cc32)cc1] | 831.3 | 67 |
| | CAS: 1001911-63-2 | 253 | | |
| 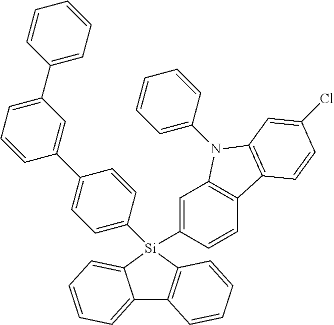 [SMILES: Clc1ccc2c3ccc([Si]4(c5ccc(-c6cccc(-c7ccccc7)c6)cc5)c5ccccc5-c5ccccc54)cc3n(-c3ccccc3)c2c1] | 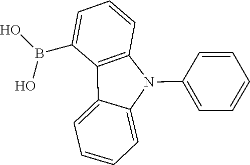 [SMILES: OB(O)c1cccc2c1c1ccccc1n2-c1ccccc1] | 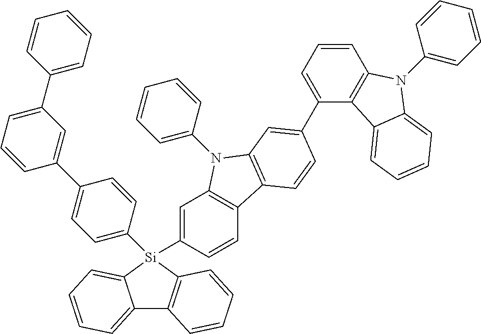 [SMILES: c1ccc(-c2cccc(-c3ccc([Si]4(c5ccc6c7ccc(-c8cccc9c8c8ccccc8n9-c8ccccc8)cc7n(-c7ccccc7)c6c5)c5ccccc5-c5ccccc54)cc3)c2)cc1] | 893.3 | 75 |
| | CAS: 1370555-65-9 | 255 | | |
| 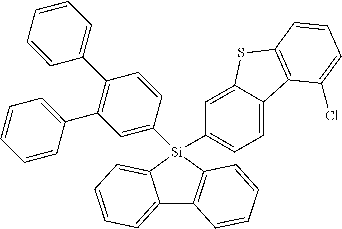 [SMILES: Clc1cccc2sc3cc([Si]4(c5ccc(-c6ccccc6)c(-c6ccccc6)c5)c5ccccc5-c5ccccc54)ccc3c12] | 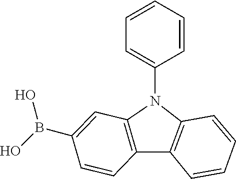 [SMILES: OB(O)c1ccc2c3ccccc3n(-c3ccccc3)c2c1] | 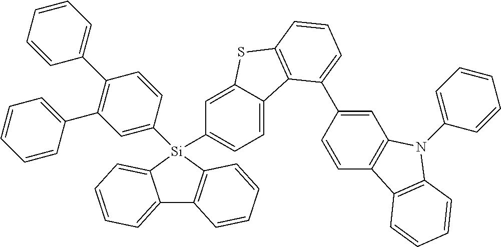 [SMILES: c1ccc(-c2ccc([Si]3(c4ccc5c(c4)sc4cccc(-c6ccc7c8ccccc8n(-c8ccccc8)c7c6)c45)c4ccccc4-c4ccccc43)cc2-c2ccccc2)cc1] | 834.2 | 70 |
| | CAS: 1001911-63-2 | 257 | | |

### Synthesis of Compound 229:

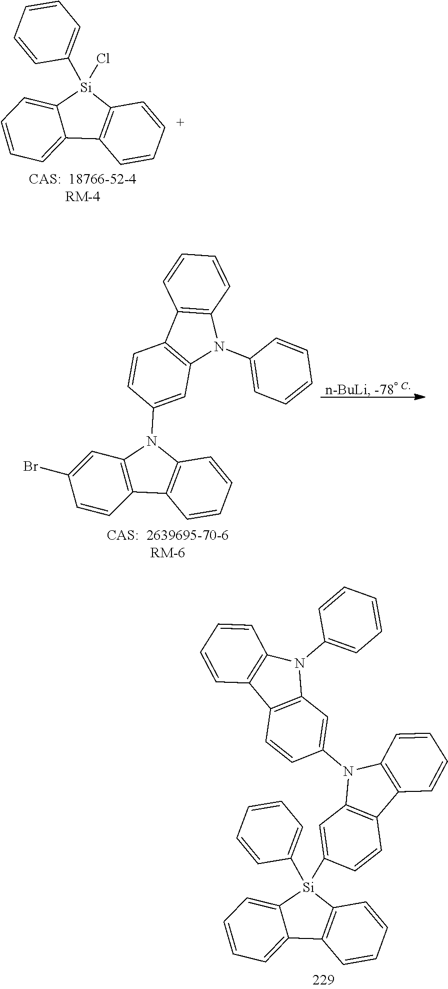 [SMILES: Cl[Si]1(c2ccccc2)C2=C(C=C[C+]=C2)c2ccccc21 ; Brc1ccc2c3ccccc3n(-c3ccc4c5ccccc5n(-c5ccccc5)c4c3)c2c1 ; c1ccc(-n2c3ccccc3c3ccc(-n4c5ccccc5c5ccc([Si]6(c7ccccc7)c7ccccc7-c7ccccc76)cc54)cc32)cc1]

Under a nitrogen atmosphere, RM-5 (14.0 g, 25 mmol) and tetrahydrofuran (dried, 80 mL) were added sequentially to a 250 mL three-necked flask; the system was cooled to −78° C., and a solution of n-butyllithium (2.0 M in n-hexane, 12.5 mL, 25 mmol) was added dropwise, and after the addition was complete, the reaction mixture was maintained at −78° C. and stirred for 1 hour; a solution of RM-4 (7.3 g, 25 mmol) in tetrahydrofuran (75 mL) was added dropwise, and after the addition was complete, the system was maintained at −78° C. for an additional 1 hour, then allowed to raise naturally to room temperature; the reaction mixture was extracted with dichloromethane (100 mL×3 times), and the organic phases were combined and dried over anhydrous magnesium sulfate, followed by filtering, and removing the solvent under reduced pressure to obtain a crude product. The crude product was purified by silica gel chromatography using dichloromethane/n-heptane as the mobile phase, to obtain Compound 229 as a white solid (8.80 g, yield 53%, m/z=665.2 [M+H]⁺).

The compounds of the present disclosure as indicated in Table 6 were synthesized referring to the synthesis of Compound 229, except that Reactant J was used instead of RM-5, as indicated in Table 6.

TABLE 6
The synthesis of compounds 239 and 242 in the present disclosure

| | | m/z | |
|---|---|---|---|
| | Compound structure | ([M + | Yield |
| Reactant J | and No. | H]⁺) | % |
| 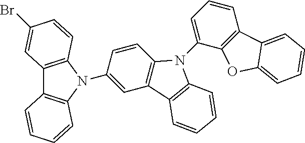 [SMILES: Brc1ccc2c(c1)c1ccccc1n2-c1ccc2c(c1)c1ccccc1n2-c1cccc2c1oc1ccccc12] | 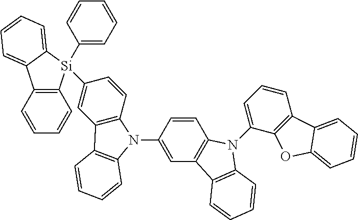 [SMILES: c1ccc([Si]2(c3ccc4c(c3)c3ccccc3n4-c3ccc4c(c3)c3ccccc3n4-c3cccc4c3oc3ccccc34)c3ccccc3-c3ccccc32)cc1] | 755.3 | 60 |
| Sub-a1 | 239 | | |
| 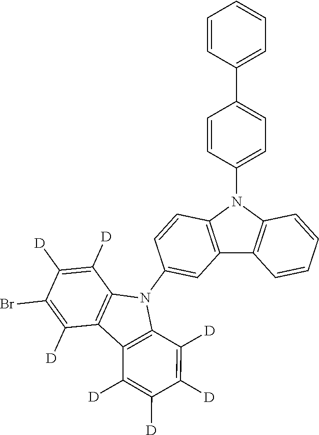 [SMILES: [2H]c1c([2H])c([2H])c2c(c1[2H])c1c([2H])c(Br)c([2H])c([2H])c1n2-c1ccc2c(c1)c1ccccc1n2-c1ccc(-c2ccccc2)cc1] | 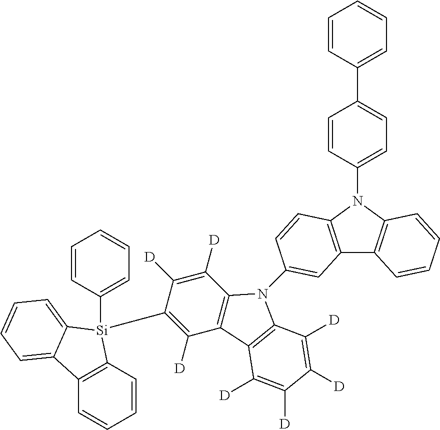 [SMILES: [2H]c1c([2H])c([2H])c2c(c1[2H])c1c([2H])c(C[Si]3(c4ccccc4)c4ccccc4-c4ccccc43)c([2H])c([2H])c1n2-c1ccc2c(c1)c1ccccc1n2-c1ccc(-c2ccccc2)cc1] | 748.3 | 59 |
| Sub-a2 | 242 | | |

Compound 19: ¹H-NMR (400 MHz, Methylene-Chloride-D₂) δ ppm 8.03 (d, 2H), 7.95 (d, 1H), 7.91-7.87 (m, 2H), 7.79-7.71 (m, 5H), 7.60-7.46 (m, 11H), 7.43-7.25 (m, 10H).

### Fabrication and Evaluation of Organic Electroluminescent Device:

### Example 1: Blue Organic Electroluminescent Device

First, an anode pretreatment was performed by the following processes: the surface of ITO/Ag/ITO substrate with a thickness of 100 Å, 1000 Å, and 100 Å in sequence was performed using ultraviolet ozone and O₂:N₂ plasma to increase the work function of the anode. The surface of the ITO substrate can also be cleaned with an organic solvent to remove impurities and oil stains.

On the test substrate (anode), HATCN was vacuum vapor deposited to form a hole injection layer (HIL) with a thickness of 100 Å, and then on the hole injection layer, BCFN was vacuum vapor deposited to form a hole transport layer with a thickness of 560 Å.

Then, on the hole transport layer, SiCzCz was vacuum vapor deposited to form an electron blocking layer (EBL) with a thickness of 50 Å. Then, Compound 14:BH—N:BD were collectively vapor deposited at a rate of 60%:27%:13% to form a blue light-emitting layer (EML) with a thickness of 350 Å.

On the light-emitting layer, the Compound mSiTrz and LiQ were mixed in a weight ratio of 1:1 and vapor deposited to form an electron transport layer (ETL) with a thickness of 350 Å. Yb was vapor deposited on the electron transport layer to form an electron injection layer (EIL) with a thickness of 10 Å, followed by the vacuum vapor deposition of aluminum (Al) on the electron injection layer to form a cathode with a thickness of 800 Å. Thereby, a blue organic electroluminescent device was fabricated.

Among them, the structures of the compounds utilized in the preparation of various examples and comparative examples are as follows:

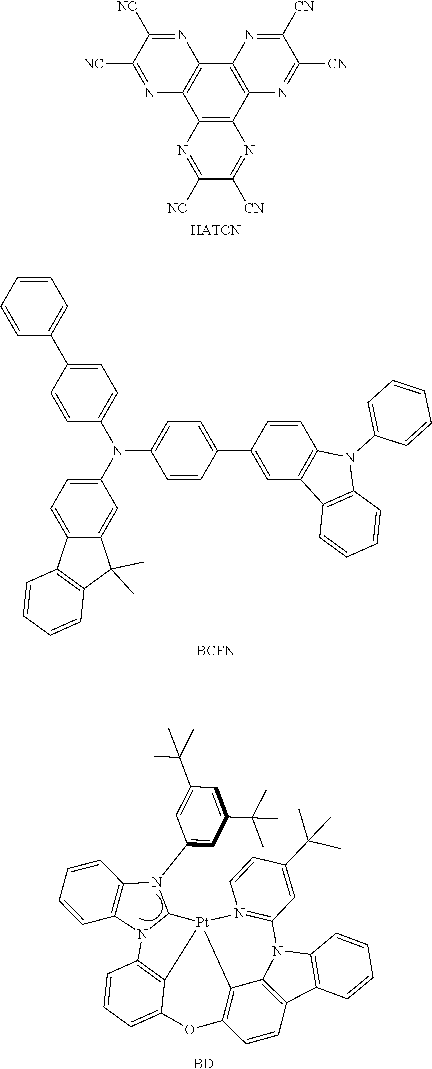

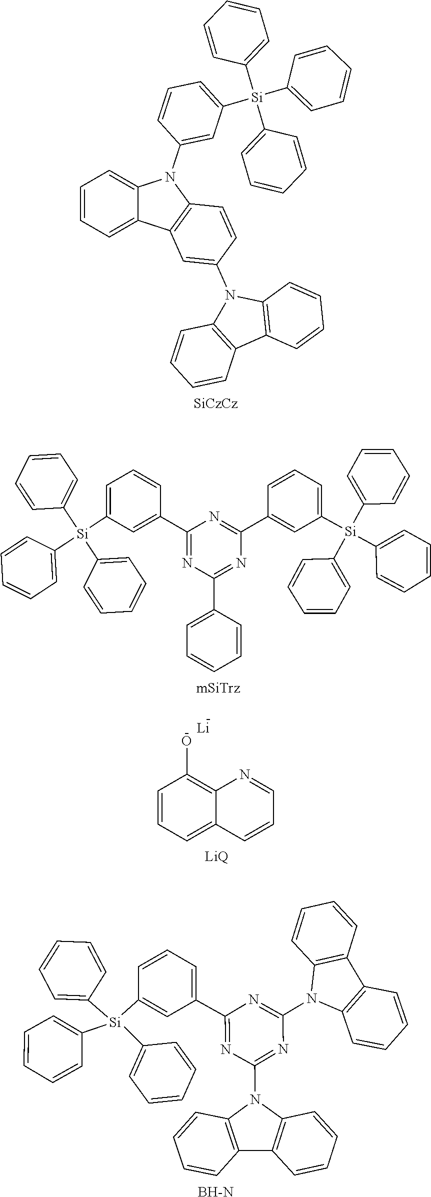

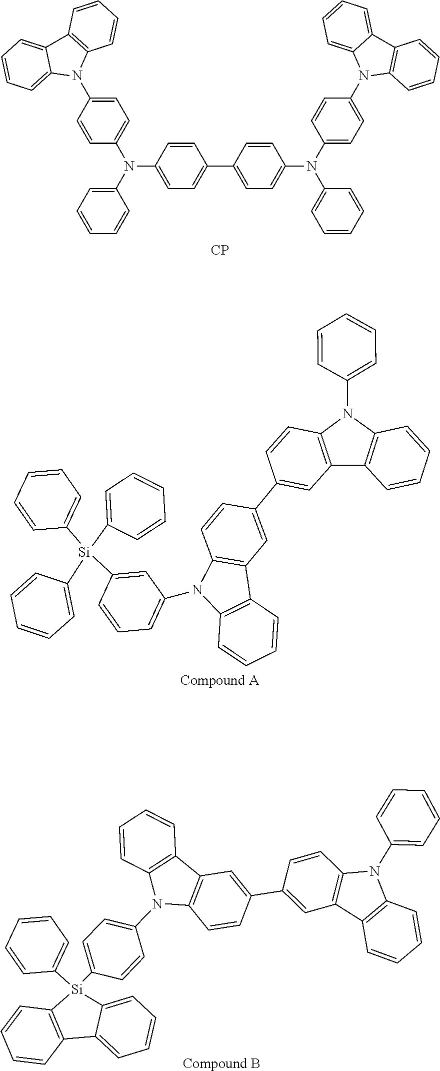

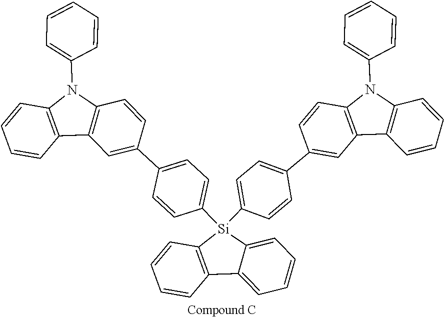 [SMILES: c1ccc(-n2c3ccccc3c3cc(-c4ccc([Si]5(c6ccc(-c7ccc8c(c7)c7ccccc7n8-c7ccccc7)cc6)c6ccccc6-c6ccccc65)cc4)ccc32)cc1]

### Examples 2 to 25

Organic electroluminescent devices were fabricated by the same method as used in Example 1, except that Compound X listed in Table 7 below was used instead of the Compound 14 in Example 1 when forming the light-emitting layer.

### Comparative Examples 1 to 3

Organic electroluminescent devices were fabricated by the same method as used in Example 1, except that Compound A, Compound B, and Compound C were used respectively instead of the Compound 14 in Example 1 when forming the light-emitting layer.

The performances of the blue organic electroluminescent devices prepared in Examples 1 to 25 and Comparative Examples 1 to 3 were tested, specifically, the voltage, efficiency, and service life characteristics of the devices were tested under a luminance of 1000 nit. The test results are presented in Table 7.

TABLE 7

| | Light-emitting | | | | | |
|---|---|---|---|---|---|---|
| | layer | Operating | | | | |
| | Compound X: | voltage | | | | T95 |
| Example No. | BH-N: BD | Volt (V) | Cd/A | CIEx | CIEy | (hrs) |
| Example 1 | Compound 14 | 6.17 | 29.66 | 0.140 | 0.140 | 213 |
| Example 2 | Compound 19 | 6.11 | 29.63 | 0.140 | 0.140 | 214 |
| Example 3 | Compound 28 | 6.11 | 29.09 | 0.140 | 0.140 | 225 |
| Example 4 | Compound 54 | 6.18 | 29.65 | 0.140 | 0.140 | 204 |
| Example 5 | Compound 59 | 6.16 | 28.98 | 0.140 | 0.140 | 213 |
| Example 6 | Compound 62 | 6.11 | 29.30 | 0.140 | 0.140 | 225 |
| Example 7 | Compound 78 | 6.11 | 29.12 | 0.140 | 0.140 | 223 |
| Example 8 | Compound 81 | 6.18 | 29.31 | 0.140 | 0.140 | 226 |
| Example 9 | Compound 85 | 6.10 | 29.61 | 0.140 | 0.140 | 208 |
| Example 10 | Compound 107 | 6.14 | 29.02 | 0.140 | 0.140 | 220 |
| Example 11 | Compound 114 | 6.10 | 29.88 | 0.140 | 0.140 | 212 |
| Example 12 | Compound 131 | 6.12 | 29.15 | 0.140 | 0.140 | 210 |
| Example 13 | Compound 150 | 6.13 | 29.02 | 0.140 | 0.140 | 221 |
| Example 14 | Compound 202 | 6.11 | 29.64 | 0.140 | 0.140 | 215 |
| Example 15 | Compound 211 | 6.11 | 29.38 | 0.140 | 0.140 | 206 |
| Example 16 | Compound 220 | 6.17 | 29.30 | 0.140 | 0.140 | 204 |
| Example 17 | Compound 229 | 6.17 | 28.90 | 0.140 | 0.140 | 226 |
| Example 18 | Compound 239 | 6.17 | 29.70 | 0.140 | 0.140 | 210 |
| Example 19 | Compound 242 | 6.17 | 29.33 | 0.140 | 0.140 | 247 |
| Example 20 | Compound 247 | 6.11 | 29.48 | 0.140 | 0.140 | 250 |
| Example 21 | Compound 250 | 6.11 | 29.21 | 0.140 | 0.140 | 222 |
| Example 22 | Compound 252 | 6.10 | 29.27 | 0.140 | 0.140 | 253 |
| Example 23 | Compound 253 | 6.18 | 29.89 | 0.140 | 0.140 | 212 |
| Example 24 | Compound 255 | 6.18 | 29.61 | 0.140 | 0.140 | 217 |
| Example 25 | Compound 257 | 6.11 | 29.84 | 0.140 | 0.140 | 209 |
| Comparative | Compound A | 6.22 | 24.22 | 0.140 | 0.140 | 152 |
| Example 1 | | | | | | |
| Comparative | Compound B | 6.27 | 25.21 | 0.140 | 0.140 | 165 |
| Example 2 | | | | | | |
| Comparative | Compound C | 6.19 | 20.15 | 0.140 | 0.140 | 177 |
| Example 3 | | | | | | |

As can be seen from Table 7, when the compounds of the present disclosure were used as the host material for blue organic electroluminescent devices, the efficiency was increased by at least 14.6% and the service life was prolonged by at least 15.2%.

The underlying reason is that, in the structure of the compound of the present disclosure, the parent nucleus containing a silafluorenyl is connected to carbazole via a heteroarylene, wherein the parent nucleus of the silafluorenyl and the two substituents at the position 9 are situated on three distinct planes, resulting in a significant molecular distortion, which endows the compound with a higher glass transition temperature, and enabling the formation of a superior amorphous thin film; in addition, silafluorenyl and carbazole are connected by a dibenzo-penta-membered heterocyclic ring, such that the entire molecule is endowed with a higher first excited triplet energy level. When the compound of the present disclosure is used as a hole-transporting type material in a hybrid blue light host material. On one hand, the compound is of higher first excited triplet energy level such that the efficiency of energy transfer from the host material to the blue light doping material can be improved, thereby enhancing the luminous efficiency of the device. On the other hand, the compound's high glass transition temperature can ensure that the light-emitting layer forms a good amorphous thin film, thus prolonging the service life of the devices.

The preferred embodiments of the present invention are described in detail above in conjunction with the accompanying drawings. However, the present invention is not limited to the specific details of the above embodiments. Within the scope of the technical concept of the present invention, various simple modifications can be made to the technical solutions of the present invention, and these simple modifications all fall within the scope of protection of the present invention.

1. An organic compound, having the structure represented by Formula 1 as follows: 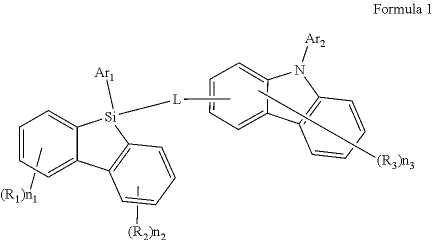
wherein, Ar₁ and Ar₂ are the same or different, and are each independently selected from a substituted or unsubstituted aryl having 6 to 40 carbon atoms, and a substituted or unsubstituted heteroaryl having 3 to 40 carbon atoms;
L is selected from a substituted or unsubstituted heteroarylene having 3 to 30 carbon atoms;
each R₁, R₂, and R₃ are the same or different, and are each independently selected from a deuterium, a cyano, a halogen group, an alkyl having 1 to 10 carbon atoms, a haloalkyl having 1 to 10 carbon atoms, a deuterated alkyl having 1 to 10 carbon atoms, a trialkylsilyl having 3 to 12 carbon atoms, a triphenylsilyl, an aryl having 6 to 20 carbon atoms, a deuterated aryl having 6 to 20 carbon atoms, a haloaryl having 6 to 20 carbon atoms, a heteroaryl having 3 to 20 carbon atoms, and a cycloalkyl having 3 to 10 carbon atoms;
n₁ is selected from 0, 1, 2, 3, and 4;
n₂ is selected from 0, 1, 2, 3, and 4;
n₃ is selected from 0, 1, 2, 3, 4, 5, 6, and 7;
substituent(s) in L, Ar₁, and Ar₂ are the same or different, and are each independently selected from a deuterium, a cyano, a halogen group, an alkyl having 1 to 10 carbon atoms, a haloalkyl having 1 to 10 carbon atoms, a deuterated alkyl having 1 to 10 carbon atoms, a trialkylsilyl having 3 to 12 carbon atoms, a triphenylsilyl, an aryl having 6 to 20 carbon atoms, a deuterated aryl having 6 to 20 carbon atoms, a haloaryl having 6 to 20 carbon atoms, a heteroaryl having 3 to 20 carbon atoms, and a cycloalkyl having 3 to 10 carbon atoms; optionally, any two adjacent substituents in Ar₂ form a ring.

2. The organic compound according to claim 1, wherein Ar₁ is selected from a substituted or unsubstituted aryl having 6 to 25 carbon atoms, and a substituted or unsubstituted heteroaryl having 5 to 18 carbon atoms;
optionally, substituent(s) in Ar₂ are each independently selected from a deuterium, a halogen group, a cyano, a haloalkyl having 1 to 4 carbon atoms, a deuterated alkyl having 1 to 4 carbon atoms, an alkyl having 1 to 4 carbon atoms, a cycloalkyl having 5 to 10 carbon atoms, an aryl having 6 to 15 carbon atoms, a deuterated aryl having 6 to 12 carbon atoms, a heteroaryl having 5 to 12 carbon atoms, and a trialkylsilyl having 3 to 8 carbon atoms; optionally, any two adjacent substituents in Ar₂ form a 5 to 13 membered ring.

3. The organic compound according to claim 1, wherein Ar₂ is selected from a substituted or unsubstituted V, wherein the unsubstituted group V is selected from the following groups: 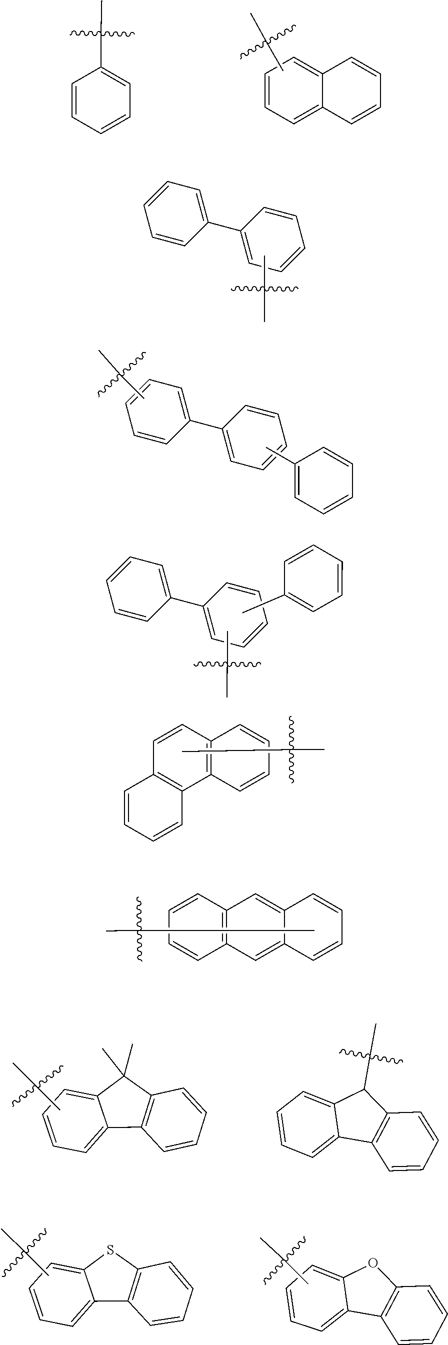 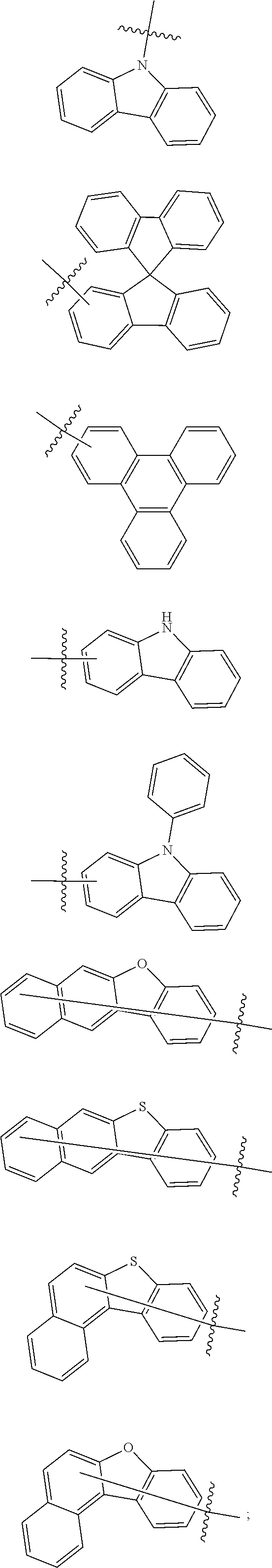
substituted group V has one or more substituent(s), and are each independently selected from a deuterium, a fluorine, a cyano, a trimethylsilyl, a trideuterated methyl, a trifluoromethyl, a cyclopentyl, a cyclohexyl, a methyl, an ethyl, an isopropyl, a tert-butyl, a phenyl, a naphthyl, a biphenyl, a fluorenyl, a 9,9-dimethylfluorenyl, a phenanthryl, a dibenzofuranyl, a dibenzothienyl, and a carbazolyl, and when the number of substituents on the group V is greater than 1, the substituents are the same or different.

4. The organic compound according to claim 1, wherein Ar₂ is selected from the group consisting of the following groups:

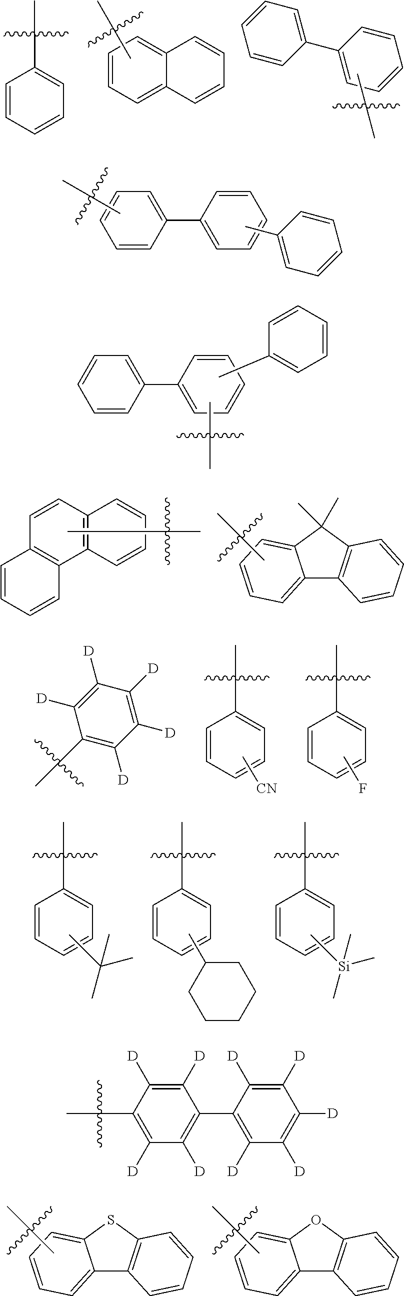

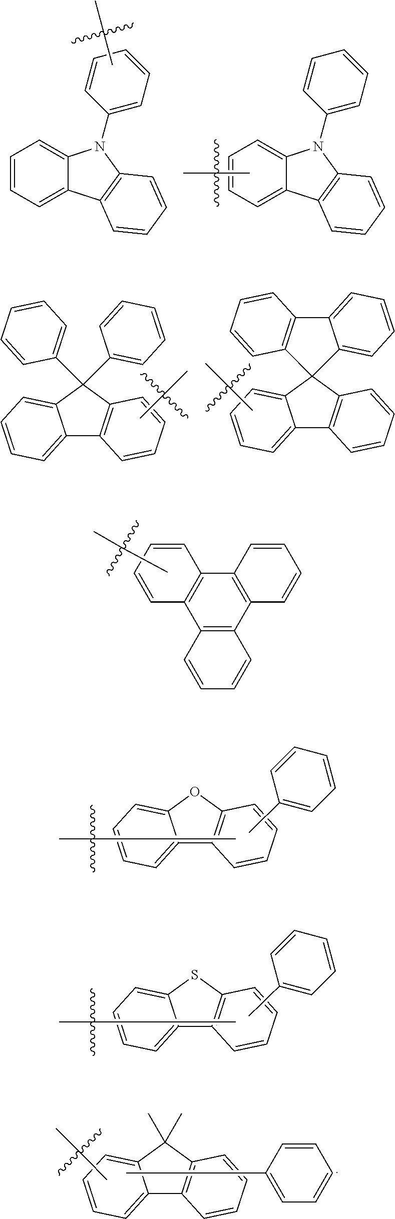

5. The organic compound according to claim 1, wherein Ar₁ is selected from a substituted or unsubstituted aryl having 6 to 21 carbon atoms, and a substituted or unsubstituted heteroaryl having 12 to 18 carbon atoms;
optionally, substituent(s) in Ar₁ are each independently selected from a deuterium, a halogen group, a cyano, a haloalkyl having 1 to 4 carbon atoms, a deuterated alkyl having 1 to 4 carbon atoms, an alkyl having 1 to 4 carbon atoms, a cycloalkyl having 5 to 10 carbon atoms, an aryl having 6 to 12 carbon atoms, a deuterated aryl having 6 to 12 carbon atoms, a heteroaryl having 5 to 12 carbon atoms, and a trialkylsilyl having 3 to 8 carbon atoms.

6. The organic compound according to claim 1, wherein Ar₁ is selected from a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted phenanthryl, a substituted or unsubstituted anthryl, a substituted or unsubstituted pyrenyl, a substituted or unsubstituted triphenylene, a substituted or unsubstituted dibenzofuranyl, a substituted or unsubstituted dibenzothienyl, and a substituted or unsubstituted carbazolyl;
optionally, substituent(s) in Ar₁ are each independently selected from a deuterium, a fluorine, a cyano, a trimethylsilyl, a trideuterated methyl, a trifluoromethyl, a cyclopentyl, a cyclohexyl, a methyl, an ethyl, an isopropyl, a tert-butyl, a carbazolyl, a dibenzothienyl, a dibenzofuranyl, a phenyl, a pentadeuterated phenyl, and a naphthyl.

7. The organic compound according to claim 1, wherein Ar₁ is selected from the group consisting of the following groups:

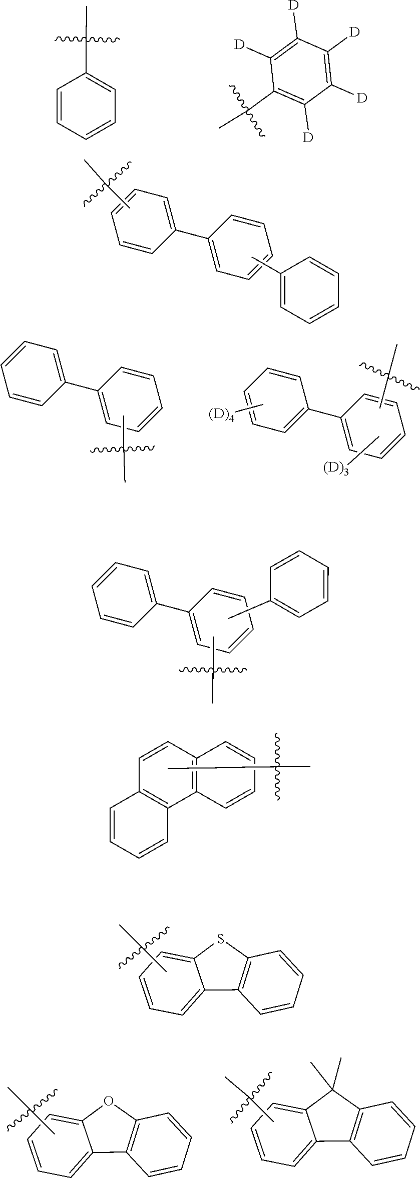

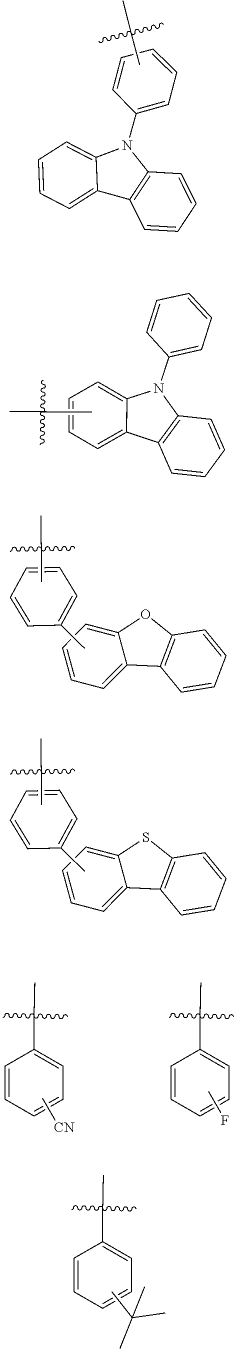

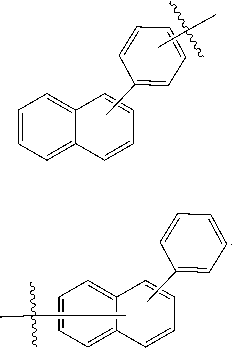

8. The organic compound according to claim 1, wherein L is selected from a substituted or unsubstituted dibenzothienylene, a substituted or unsubstituted dibenzofuranylene, and a substituted or unsubstituted carbazolylene;
optionally, substituent(s) in L are the same or different, and are each independently selected from a deuterium, a fluorine, a cyano, a methyl, an ethyl, an isopropyl, a tert-butyl, a trifluoromethyl, a trideuterated methyl, a trimethylsilyl, a phenyl, a pentadeuterated phenyl, a biphenyl, and a naphthyl.

9. The organic compound according to claim 1, wherein L is selected from the group consisting of the following groups:

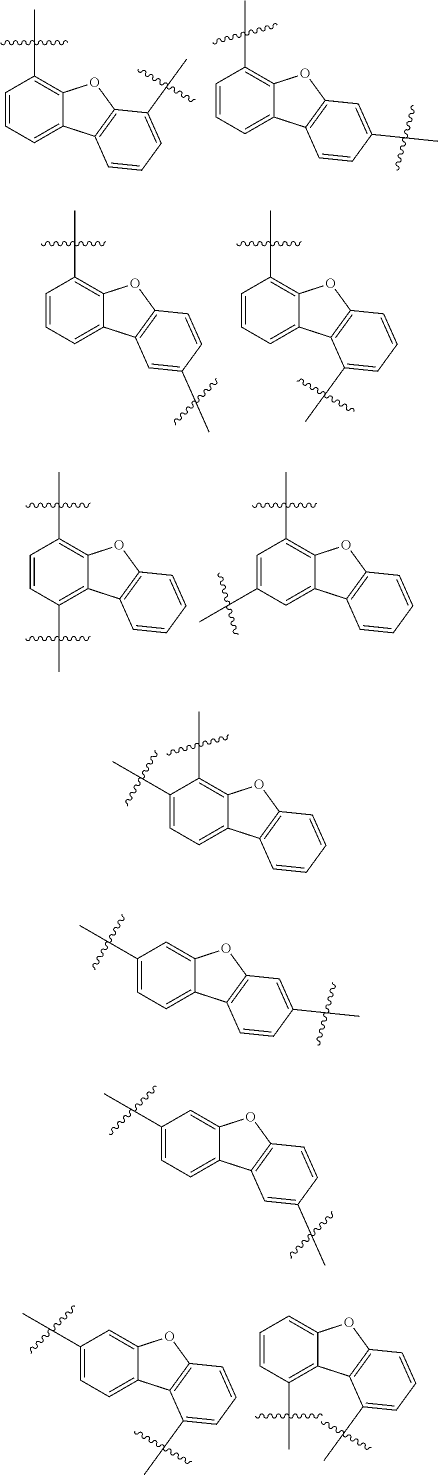

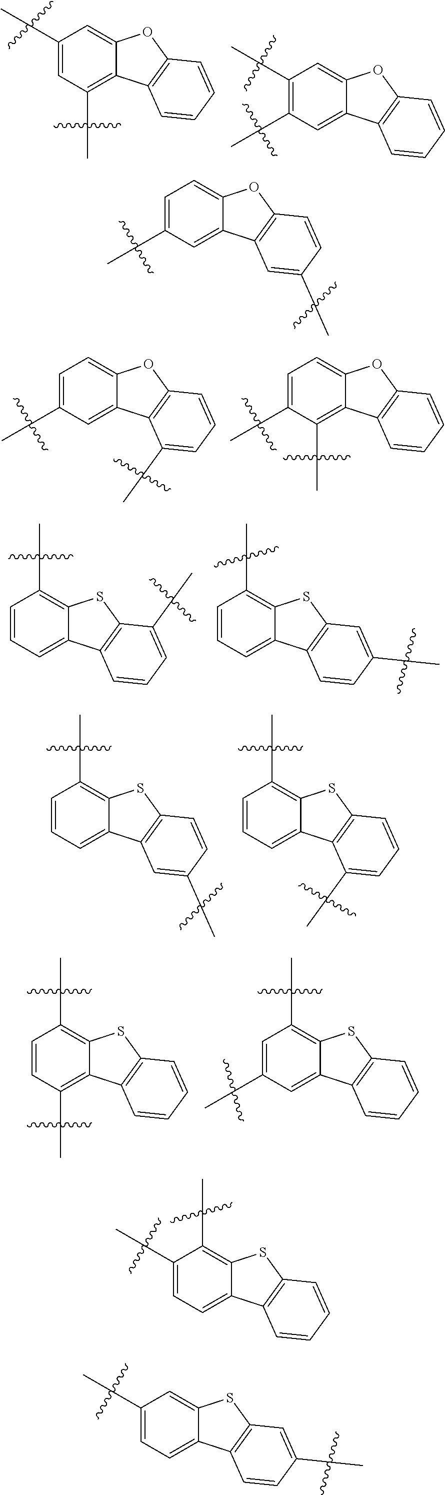

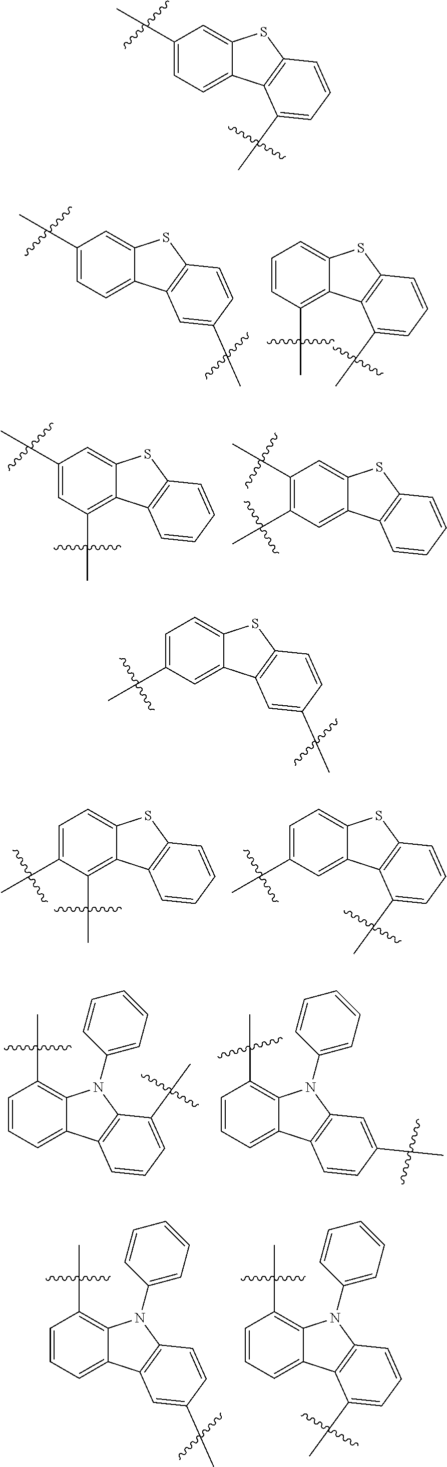

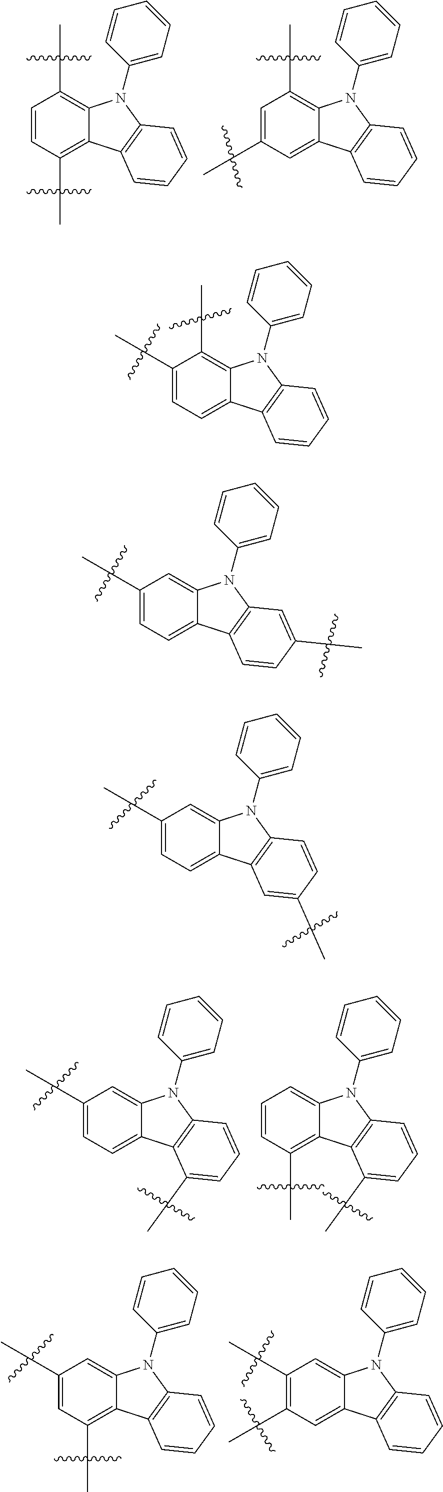

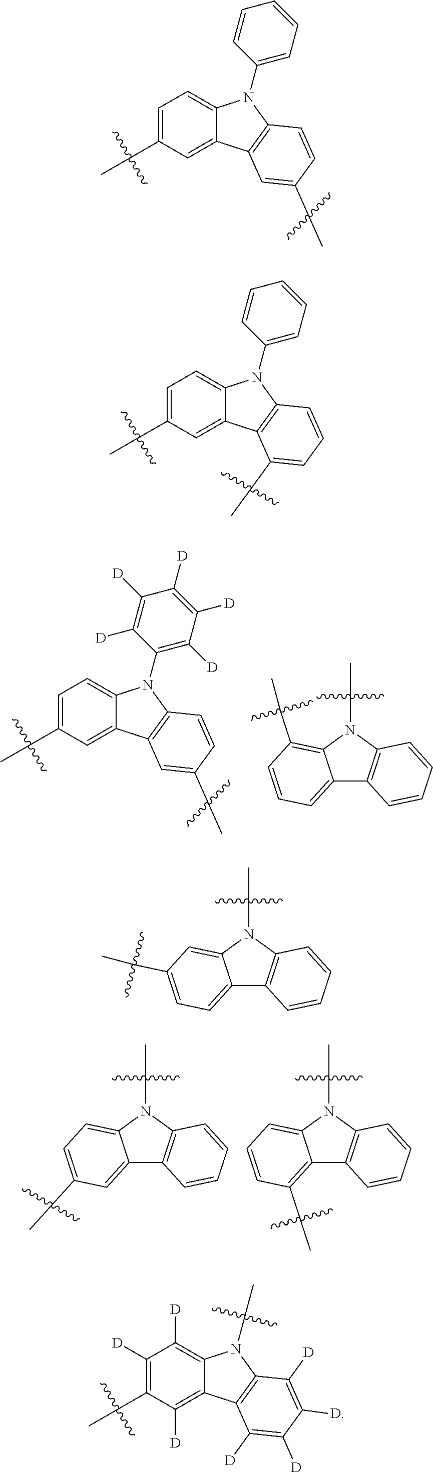

10. The organic compound according to claim 1, wherein each R₁, R₂, and R₃ are the same or different, and are each independently selected from a deuterium, a cyano, a fluorine, a methyl, an ethyl, an isopropyl, a tert-butyl, a trifluoromethyl, a trideuterated methyl, a trimethylsilyl, a phenyl, a pentadeuterated phenyl, a biphenyl, and a naphthyl.

11. The organic compound according to claim 1, wherein the organic compound is selected from the group consisting of the following compounds:

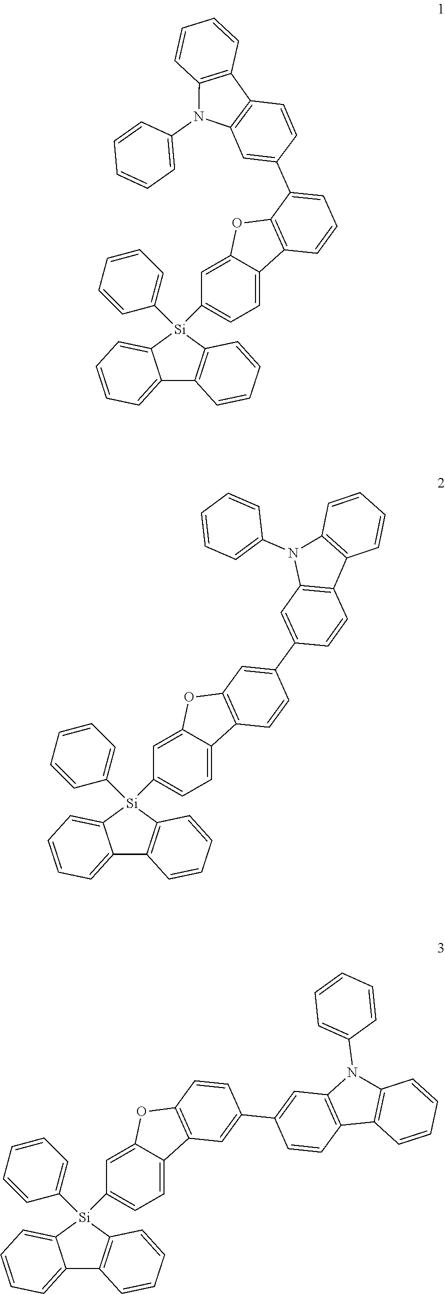 [SMILES: c1ccc(-n2c3ccccc3c3ccc(-c4cccc5c4oc4cc([Si]6(c7ccccc7)c7ccccc7-c7ccccc76)ccc45)cc32)cc1 ; c1ccc(-n2c3ccccc3c3ccc(-c4ccc5c(c4)oc4cc([Si]6(c7ccccc7)c7ccccc7-c7ccccc76)ccc45)cc32)cc1 ; c1ccc(-n2c3ccccc3c3ccc(-c4ccc5oc6cc([Si]7(c8ccccc8)c8ccccc8-c8ccccc87)ccc6c5c4)cc32)cc1]

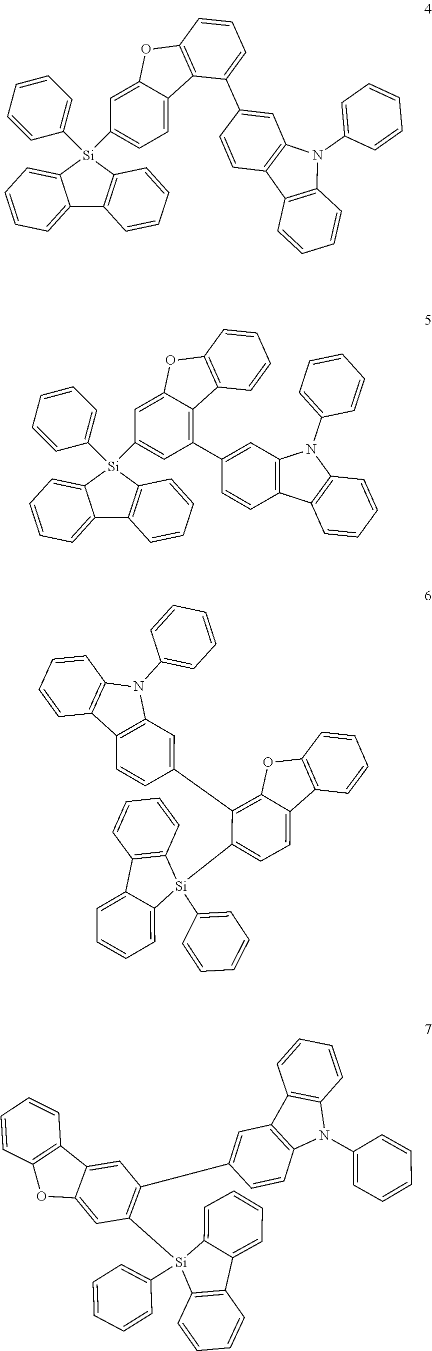 [SMILES: c1ccc(-n2c3ccccc3c3ccc(-c4cccc5oc6cc([Si]7(c8ccccc8)c8ccccc8-c8ccccc87)ccc6c45)cc32)cc1 ; c1ccc(-n2c3ccccc3c3ccc(-c4cc([Si]5(c6ccccc6)c6ccccc6-c6ccccc65)cc5oc6ccccc6c45)cc32)cc1 ; c1ccc(-n2c3ccccc3c3ccc(-c4c([Si]5(c6ccccc6)c6ccccc6-c6ccccc65)ccc5c4oc4ccccc45)cc32)cc1 ; c1ccc(-n2c3ccccc3c3cc(-c4cc5c(cc4[Si]4(c6ccccc6)c6ccccc6-c6ccccc64)oc4ccccc45)ccc32)cc1]

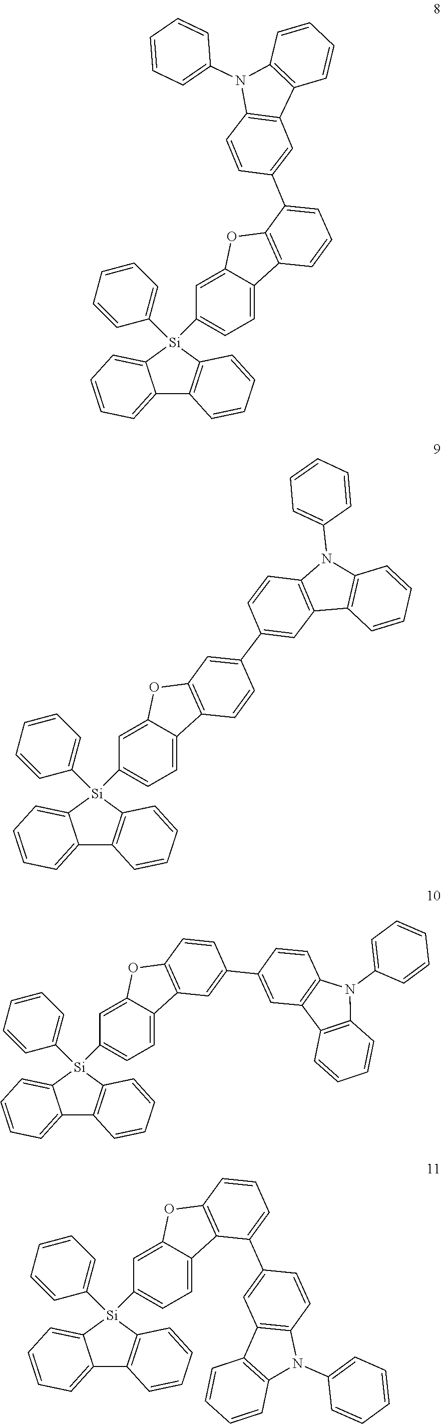 [SMILES: c1ccc(-n2c3ccccc3c3cc(-c4cccc5c4oc4cc([Si]6(c7ccccc7)c7ccccc7-c7ccccc76)ccc45)ccc32)cc1 ; c1ccc(-n2c3ccccc3c3cc(-c4ccc5c(c4)oc4cc([Si]6(c7ccccc7)c7ccccc7-c7ccccc76)ccc45)ccc32)cc1 ; c1ccc(-n2c3ccccc3c3cc(-c4ccc5oc6cc([Si]7(c8ccccc8)c8ccccc8-c8ccccc87)ccc6c5c4)ccc32)cc1 ; c1ccc(-n2c3ccccc3c3cc(-c4cccc5oc6cc([Si]7(c8ccccc8)c8ccccc8-c8ccccc87)ccc6c45)ccc32)cc1]

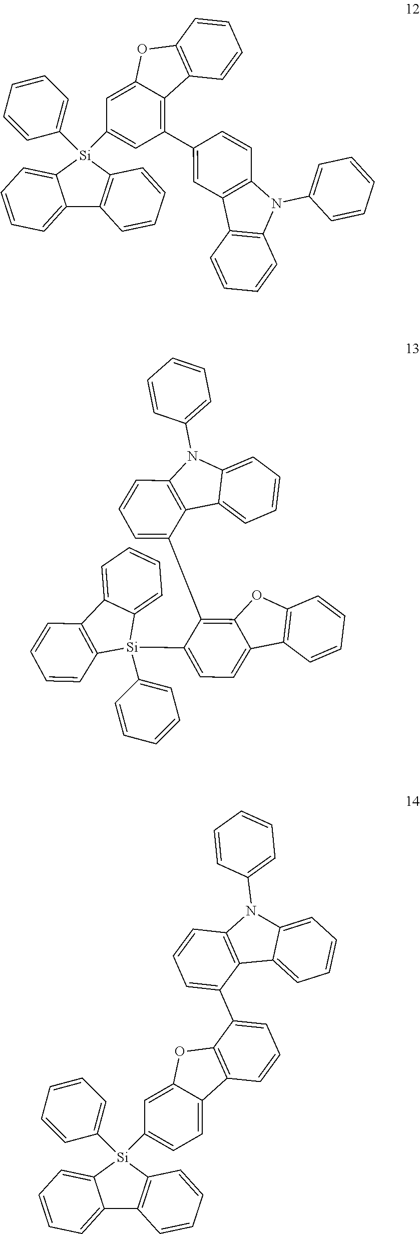 [SMILES: c1ccc(-n2c3ccccc3c3cc(-c4cc([Si]5(c6ccccc6)c6ccccc6-c6ccccc65)cc5oc6ccccc6c45)ccc32)cc1 ; c1ccc(-n2c3ccccc3c3c(-c4c([Si]5(c6ccccc6)c6ccccc6-c6ccccc65)ccc5c4oc4ccccc45)cccc32)cc1 ; c1ccc(-n2c3ccccc3c3c(-c4cccc5c4oc4cc([Si]6(c7ccccc7)c7ccccc7-c7ccccc76)ccc45)cccc32)cc1]

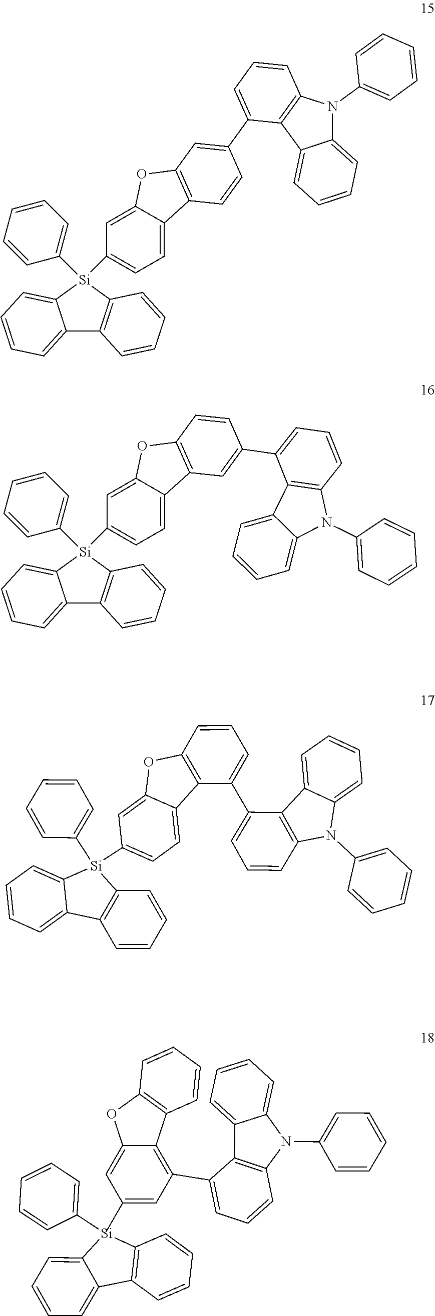

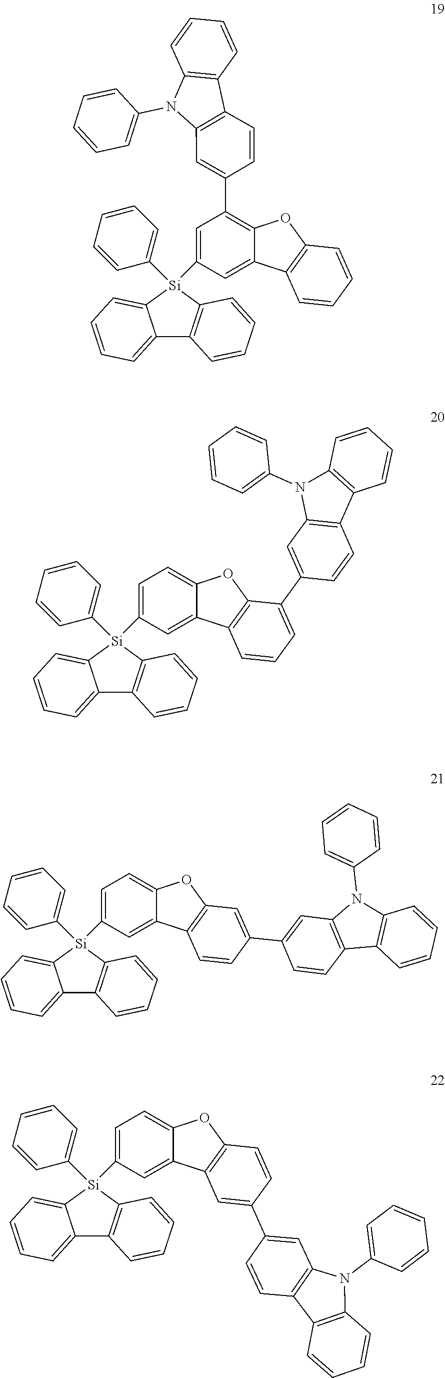 [SMILES: c1ccc(-n2c3ccccc3c3ccc(-c4cc([Si]5(c6ccccc6)c6ccccc6-c6ccccc65)cc5c4oc4ccccc45)cc32)cc1 ; c1ccc(-n2c3ccccc3c3ccc(-c4cccc5c4oc4ccc([Si]6(c7ccccc7)c7ccccc7-c7ccccc76)cc45)cc32)cc1 ; c1ccc(-n2c3ccccc3c3ccc(-c4ccc5c(c4)oc4ccc([Si]6(c7ccccc7)c7ccccc7-c7ccccc76)cc45)cc32)cc1 ; c1ccc(-n2c3ccccc3c3ccc(-c4ccc5oc6ccc([Si]7(c8ccccc8)c8ccccc8-c8ccccc87)cc6c5c4)cc32)cc1]

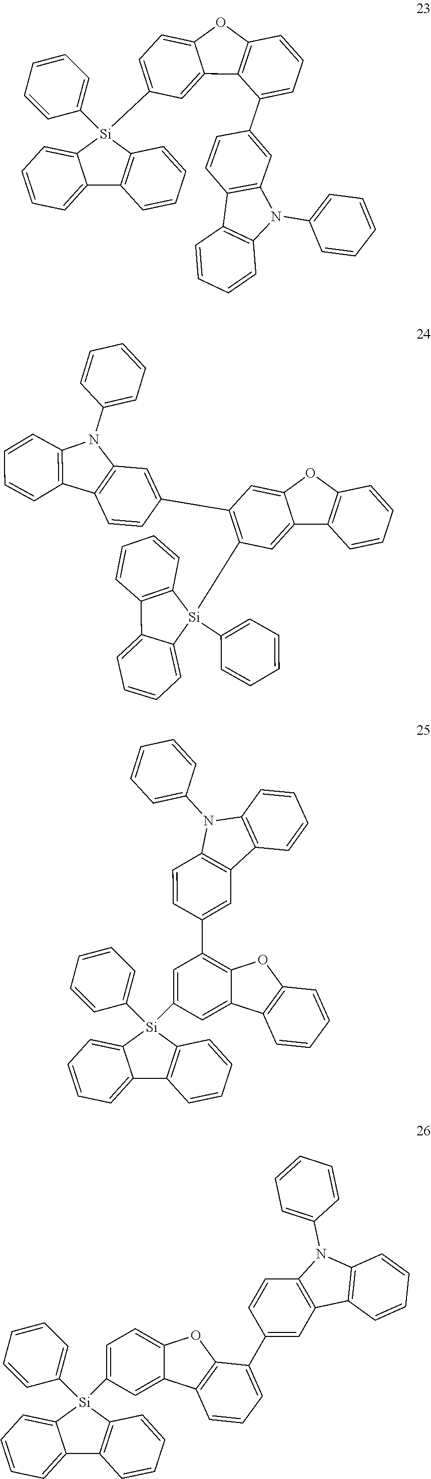

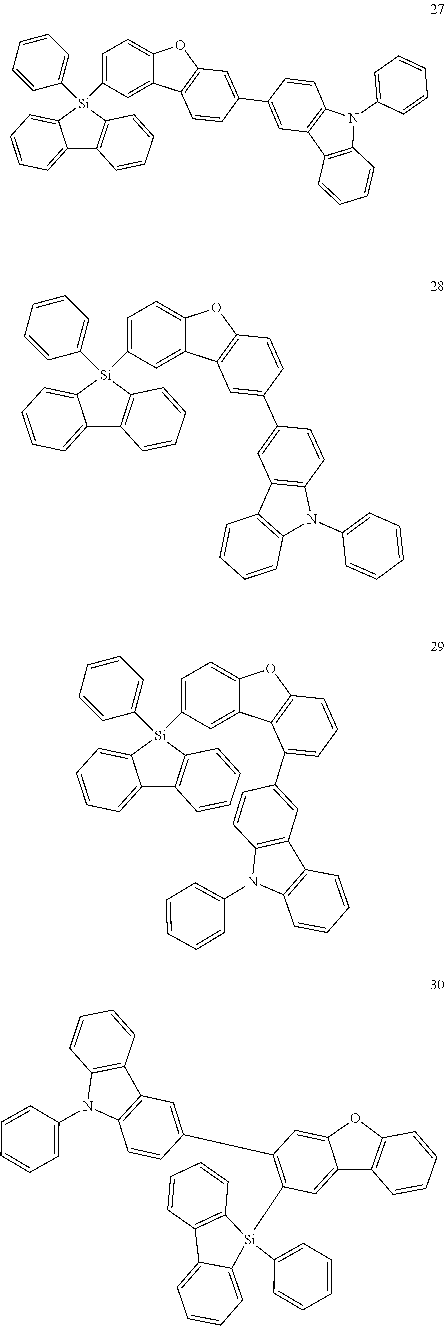 [SMILES: c1ccc(-n2c3ccccc3c3cc(-c4ccc5c(c4)oc4ccc([Si]6(c7ccccc7)c7ccccc7-c7ccccc76)cc45)ccc32)cc1 ; c1ccc(-n2c3ccccc3c3cc(-c4ccc5oc6ccc([Si]7(c8ccccc8)c8ccccc8-c8ccccc87)cc6c5c4)ccc32)cc1 ; c1ccc(-n2c3ccccc3c3cc(-c4cccc5oc6ccc([Si]7(c8ccccc8)c8ccccc8-c8ccccc87)cc6c45)ccc32)cc1 ; c1ccc(-n2c3ccccc3c3cc(-c4cc5oc6ccccc6c5cc4[Si]4(c5ccccc5)c5ccccc5-c5ccccc54)ccc32)cc1]

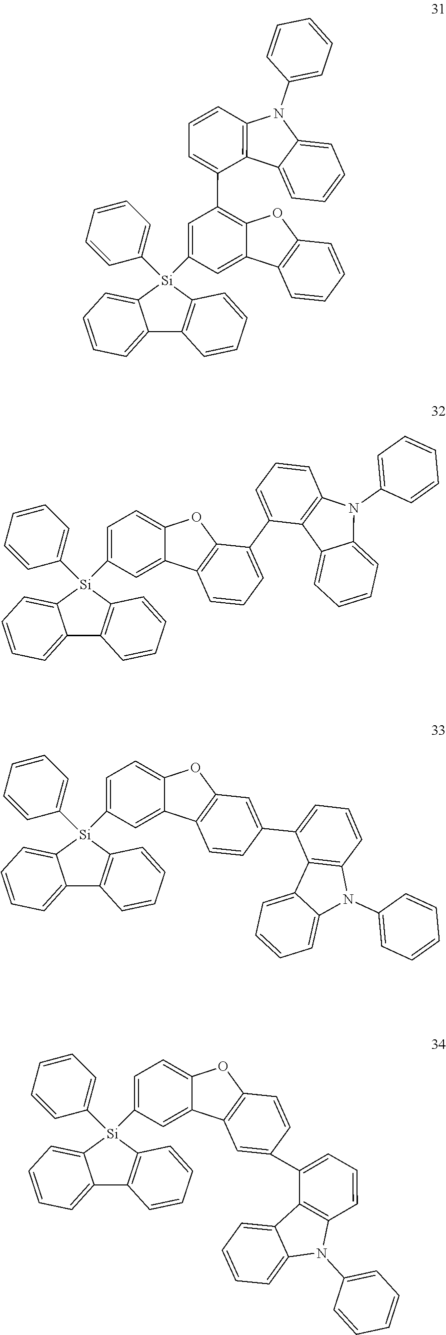 [SMILES: c1ccc(-n2c3ccccc3c3c(-c4cc([Si]5(c6ccccc6)c6ccccc6-c6ccccc65)cc5c4oc4ccccc45)cccc32)cc1 ; c1ccc(-n2c3ccccc3c3c(-c4cccc5c4oc4ccc([Si]6(c7ccccc7)c7ccccc7-c7ccccc76)cc45)cccc32)cc1 ; c1ccc(-n2c3ccccc3c3c(-c4ccc5c(c4)oc4ccc([Si]6(c7ccccc7)c7ccccc7-c7ccccc76)cc45)cccc32)cc1 ; c1ccc(-n2c3ccccc3c3c(-c4ccc5oc6ccc([Si]7(c8ccccc8)c8ccccc8-c8ccccc87)cc6c5c4)cccc32)cc1]

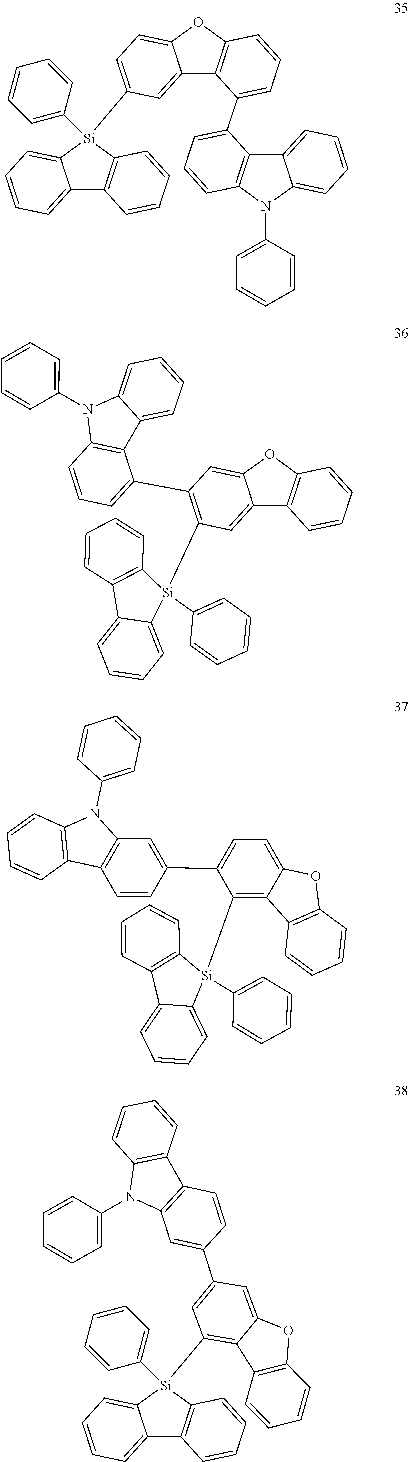

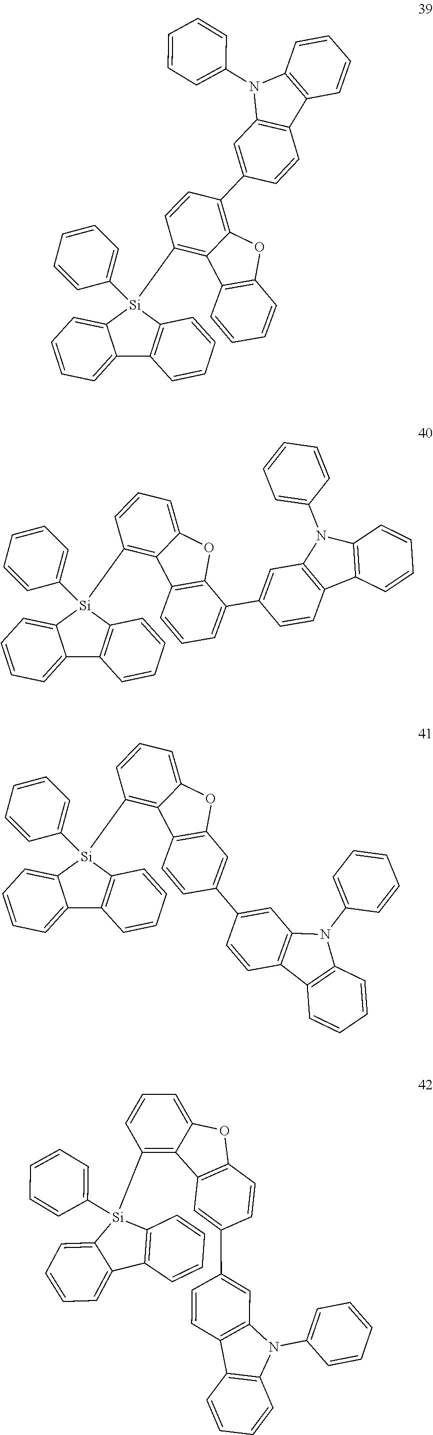 [SMILES: c1ccc(-n2c3ccccc3c3ccc(-c4ccc([Si]5(c6ccccc6)c6ccccc6-c6ccccc65)c5c4oc4ccccc45)cc32)cc1 ; c1ccc(-n2c3ccccc3c3ccc(-c4cccc5c4oc4cccc([Si]6(c7ccccc7)c7ccccc7-c7ccccc76)c45)cc32)cc1 ; c1ccc(-n2c3ccccc3c3ccc(-c4ccc5c(c4)oc4cccc([Si]6(c7ccccc7)c7ccccc7-c7ccccc76)c45)cc32)cc1 ; c1ccc(-n2c3ccccc3c3ccc(-c4ccc5oc6cccc([Si]7(c8ccccc8)c8ccccc8-c8ccccc87)c6c5c4)cc32)cc1]

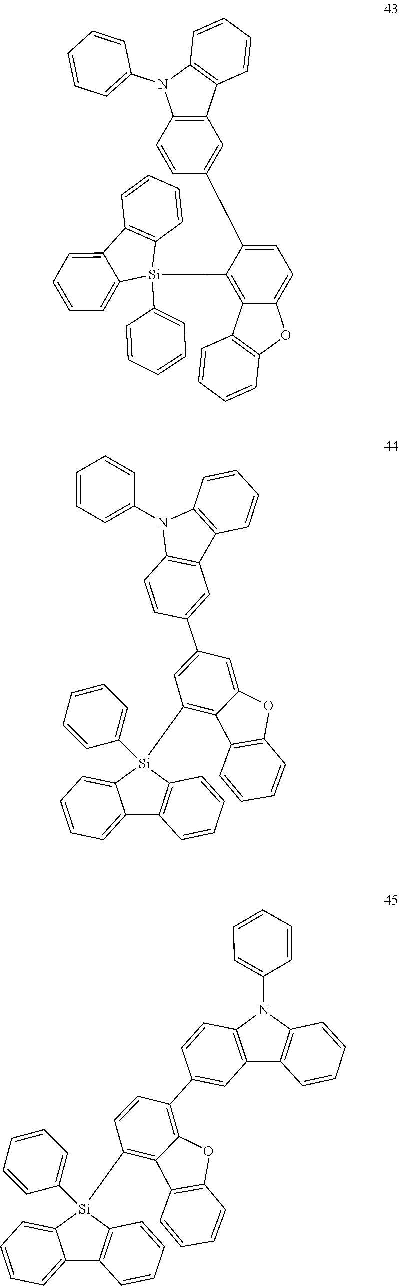 [SMILES: c1ccc(-n2c3ccccc3c3cc(-c4ccc5oc6ccccc6c5c4[Si]4(c5ccccc5)c5ccccc5-c5ccccc54)ccc32)cc1 ; c1ccc(-n2c3ccccc3c3cc(-c4cc([Si]5(c6ccccc6)c6ccccc6-c6ccccc65)c5c(c4)oc4ccccc45)ccc32)cc1 ; c1ccc(-n2c3ccccc3c3cc(-c4ccc([Si]5(c6ccccc6)c6ccccc6-c6ccccc65)c5c4oc4ccccc45)ccc32)cc1]

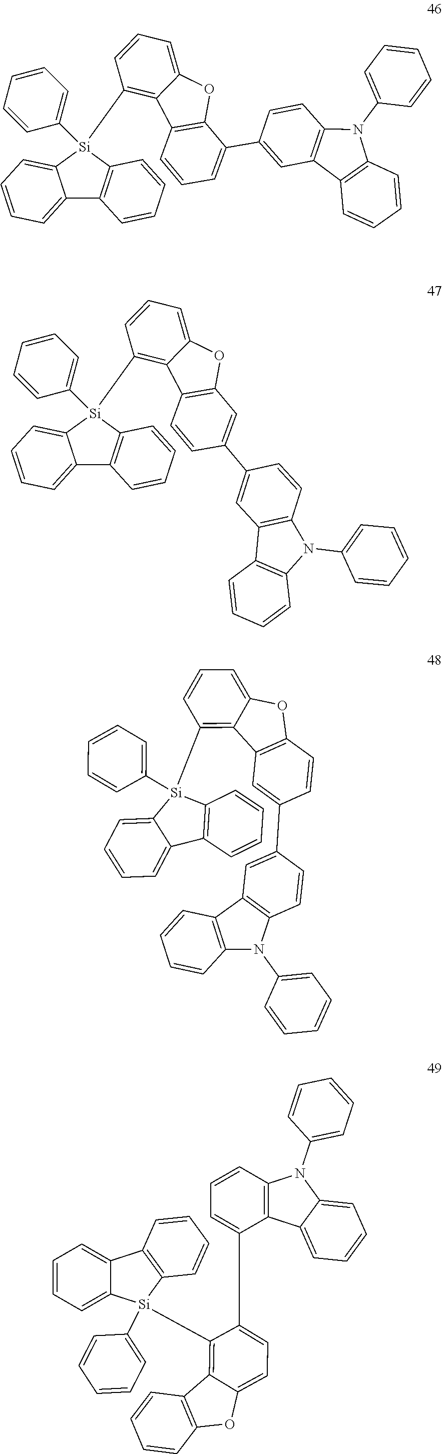 [SMILES: c1ccc(-n2c3ccccc3c3cc(-c4cccc5c4oc4cccc([Si]6(c7ccccc7)c7ccccc7-c7ccccc76)c45)ccc32)cc1 ; c1ccc(-n2c3ccccc3c3cc(-c4ccc5c(c4)oc4cccc([Si]6(c7ccccc7)c7ccccc7-c7ccccc76)c45)ccc32)cc1 ; c1ccc(-n2c3ccccc3c3cc(-c4ccc5oc6cccc([Si]7(c8ccccc8)c8ccccc8-c8ccccc87)c6c5c4)ccc32)cc1 ; c1ccc(-n2c3ccccc3c3c(-c4ccc5oc6ccccc6c5c4[Si]4(c5ccccc5)c5ccccc5-c5ccccc54)cccc32)cc1]

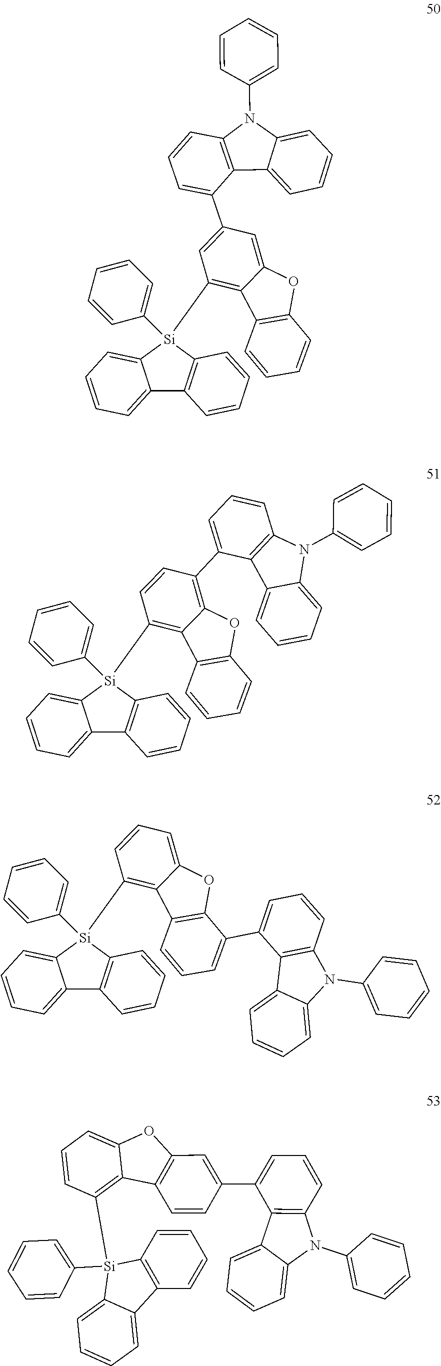 [SMILES: c1ccc(-n2c3ccccc3c3c(-c4cc([Si]5(c6ccccc6)c6ccccc6-c6ccccc65)c5c(c4)oc4ccccc45)cccc32)cc1 ; c1ccc(-n2c3ccccc3c3c(-c4ccc([Si]5(c6ccccc6)c6ccccc6-c6ccccc65)c5c4oc4ccccc45)cccc32)cc1 ; c1ccc(-n2c3ccccc3c3c(-c4cccc5c4oc4cccc([Si]6(c7ccccc7)c7ccccc7-c7ccccc76)c45)cccc32)cc1 ; c1ccc(-n2c3ccccc3c3c(-c4ccc5c(c4)oc4cccc([Si]6(c7ccccc7)c7ccccc7-c7ccccc76)c45)cccc32)cc1]

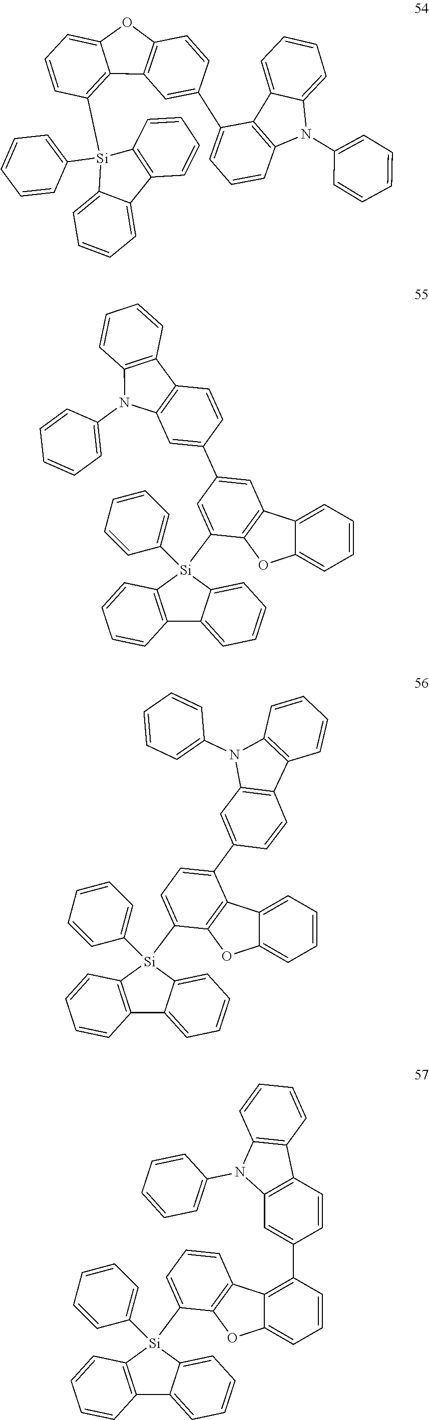 [SMILES: c1ccc(-n2c3ccccc3c3c(-c4ccc5oc6cccc([Si]7(c8ccccc8)c8ccccc8-c8ccccc87)c6c5c4)cccc32)cc1 ; c1ccc(-n2c3ccccc3c3ccc(-c4cc([Si]5(c6ccccc6)c6ccccc6-c6ccccc65)c5oc6ccccc6c5c4)cc32)cc1 ; c1ccc(-n2c3ccccc3c3ccc(-c4ccc([Si]5(c6ccccc6)c6ccccc6-c6ccccc65)c5oc6ccccc6c45)cc32)cc1 ; c1ccc(-n2c3ccccc3c3ccc(-c4cccc5oc6c([Si]7(c8ccccc8)c8ccccc8-c8ccccc87)cccc6c45)cc32)cc1]

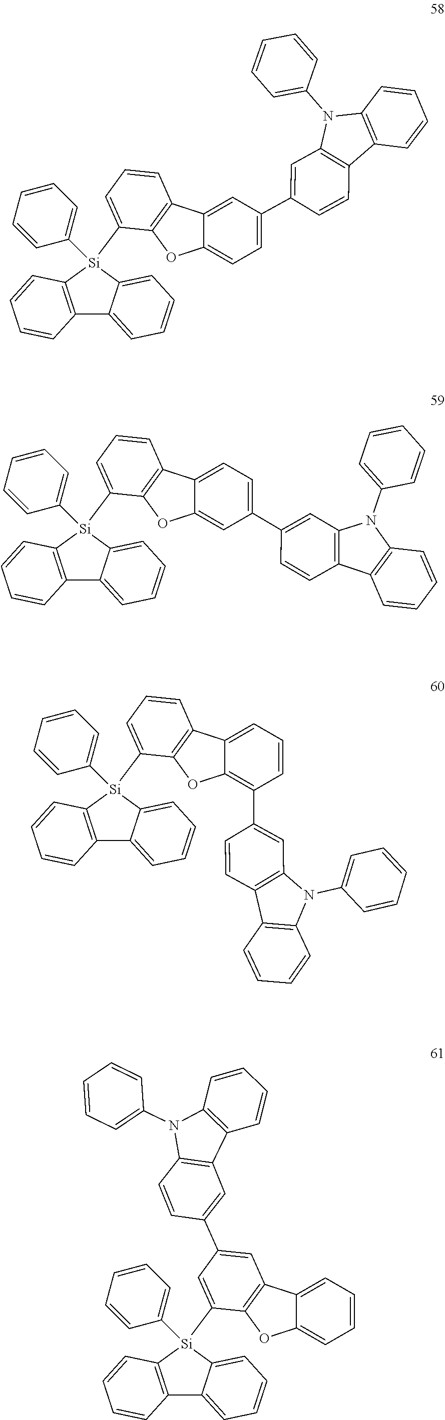 [SMILES: c1ccc(-n2c3ccccc3c3ccc(-c4ccc5oc6c([Si]7(c8ccccc8)c8ccccc8-c8ccccc87)cccc6c5c4)cc32)cc1 ; c1ccc(-n2c3ccccc3c3ccc(-c4ccc5c(c4)oc4c([Si]6(c7ccccc7)c7ccccc7-c7ccccc76)cccc45)cc32)cc1 ; c1ccc(-n2c3ccccc3c3ccc(-c4cccc5c4oc4c([Si]6(c7ccccc7)c7ccccc7-c7ccccc76)cccc45)cc32)cc1 ; c1ccc(-n2c3ccccc3c3cc(-c4cc([Si]5(c6ccccc6)c6ccccc6-c6ccccc65)c5oc6ccccc6c5c4)ccc32)cc1]

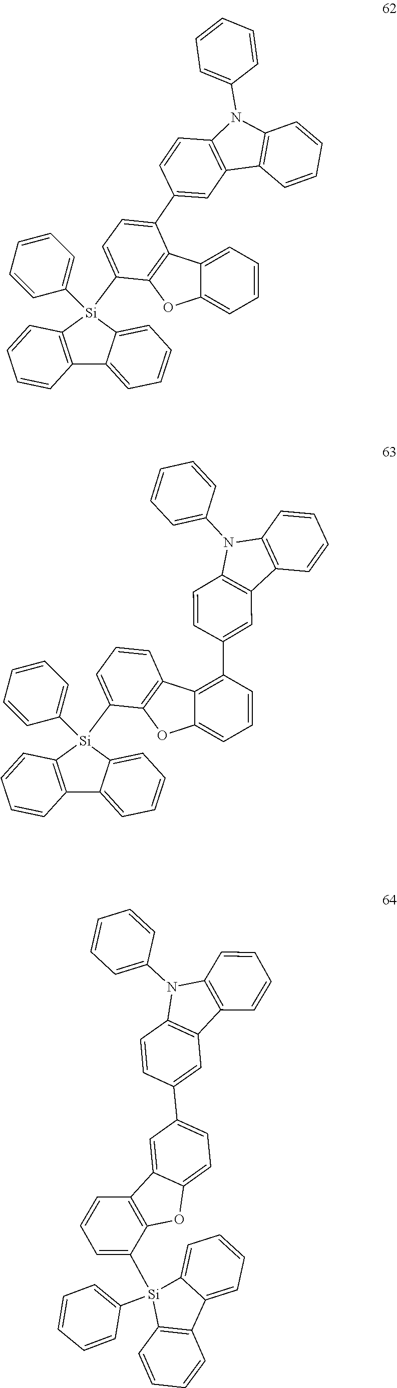 [SMILES: c1ccc(-n2c3ccccc3c3cc(-c4ccc([Si]5(c6ccccc6)c6ccccc6-c6ccccc65)c5oc6ccccc6c45)ccc32)cc1 ; c1ccc(-n2c3ccccc3c3cc(-c4cccc5oc6c([Si]7(c8ccccc8)c8ccccc8-c8ccccc87)cccc6c45)ccc32)cc1 ; c1ccc(-n2c3ccccc3c3cc(-c4ccc5oc6c([Si]7(c8ccccc8)c8ccccc8-c8ccccc87)cccc6c5c4)ccc32)cc1]

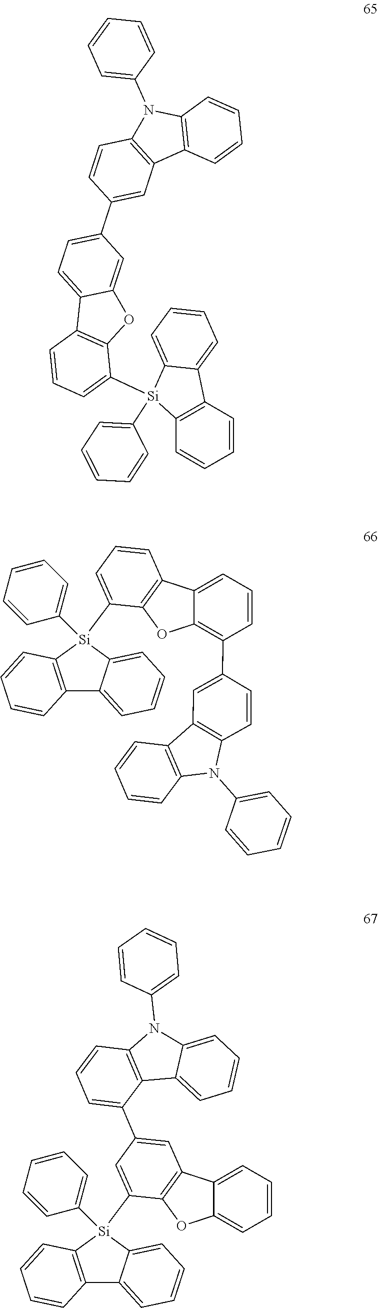 [SMILES: c1ccc(-n2c3ccccc3c3cc(-c4ccc5c(c4)oc4c([Si]6(c7ccccc7)c7ccccc7-c7ccccc76)cccc45)ccc32)cc1 ; c1ccc(-n2c3ccccc3c3cc(-c4cccc5c4oc4c([Si]6(c7ccccc7)c7ccccc7-c7ccccc76)cccc45)ccc32)cc1 ; c1ccc(-n2c3ccccc3c3c(-c4cc([Si]5(c6ccccc6)c6ccccc6-c6ccccc65)c5oc6ccccc6c5c4)cccc32)cc1]

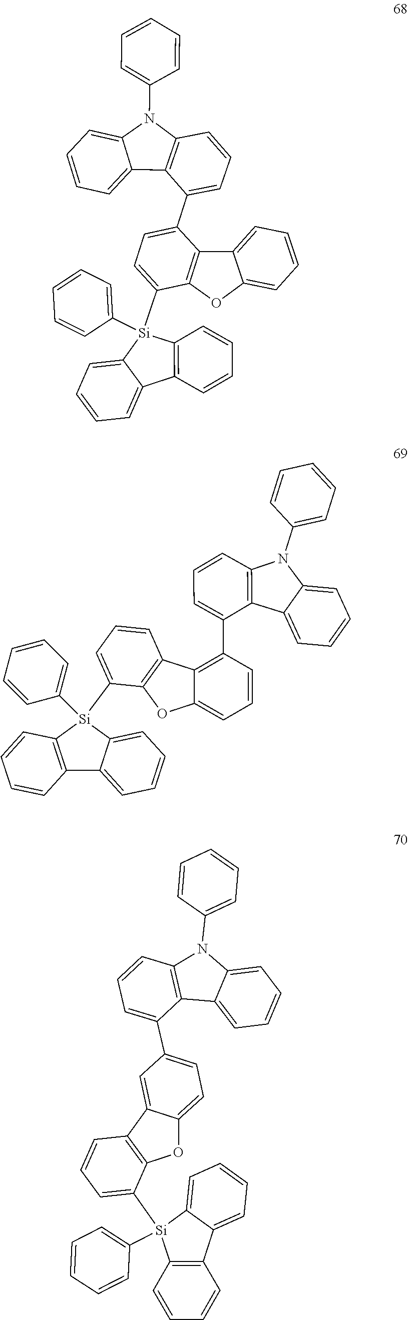 [SMILES: c1ccc(-n2c3ccccc3c3c(-c4ccc([Si]5(c6ccccc6)c6ccccc6-c6ccccc65)c5oc6ccccc6c45)cccc32)cc1 ; c1ccc(-n2c3ccccc3c3c(-c4cccc5oc6c([Si]7(c8ccccc8)c8ccccc8-c8ccccc87)cccc6c45)cccc32)cc1 ; c1ccc(-n2c3ccccc3c3c(-c4ccc5oc6c([Si]7(c8ccccc8)c8ccccc8-c8ccccc87)cccc6c5c4)cccc32)cc1]

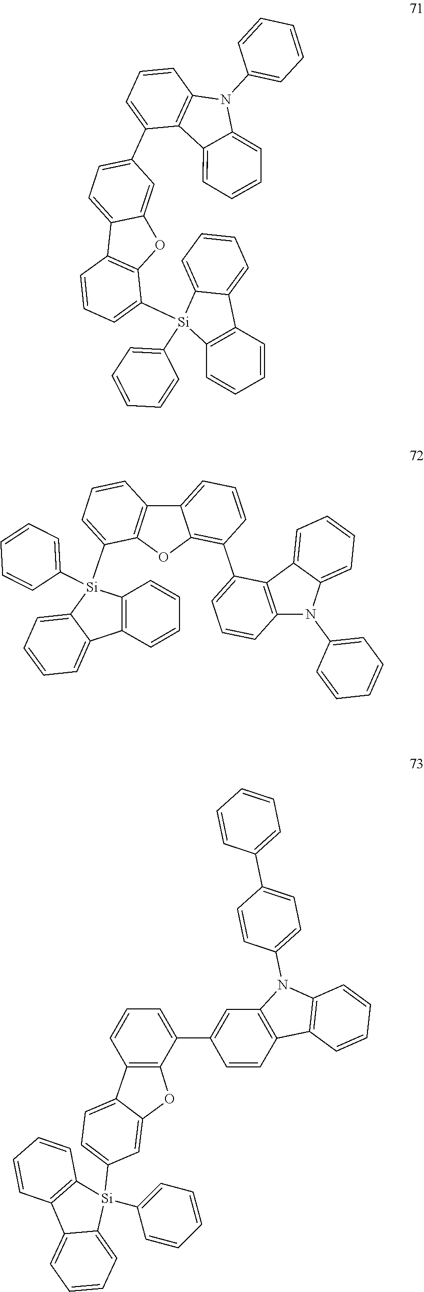 [SMILES: c1ccc(-n2c3ccccc3c3c(-c4ccc5c(c4)oc4c([Si]6(c7ccccc7)c7ccccc7-c7ccccc76)cccc45)cccc32)cc1 ; c1ccc(-n2c3ccccc3c3c(-c4cccc5c4oc4c([Si]6(c7ccccc7)c7ccccc7-c7ccccc76)cccc45)cccc32)cc1 ; c1ccc(-c2ccc(-n3c4ccccc4c4ccc(-c5cccc6c5oc5cc([Si]7(c8ccccc8)c8ccccc8-c8ccccc87)ccc56)cc43)cc2)cc1]

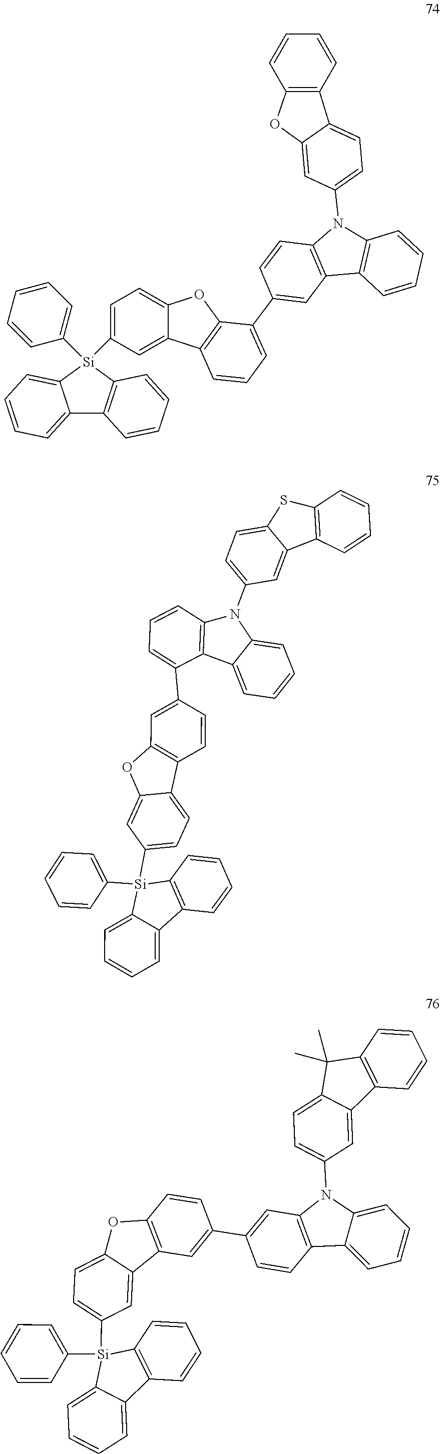 [SMILES: c1ccc([Si]2(c3ccc4oc5c(-c6ccc7c(c6)c6ccccc6n7-c6ccc7c(c6)oc6ccccc67)cccc5c4c3)c3ccccc3-c3ccccc32)cc1 ; c1ccc([Si]2(c3ccc4c(c3)oc3cc(-c5cccc6c5c5ccccc5n6-c5ccc6sc7ccccc7c6c5)ccc34)c3ccccc3-c3ccccc32)cc1 ; CC1(C)c2ccccc2-c2cc(-n3c4ccccc4c4ccc(-c5ccc6oc7ccc([Si]8(c9ccccc9)c9ccccc9-c9ccccc98)cc7c6c5)cc43)ccc21]

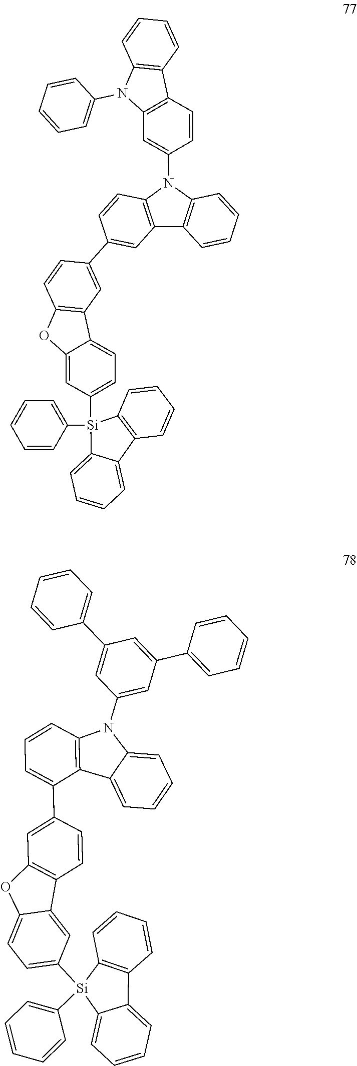

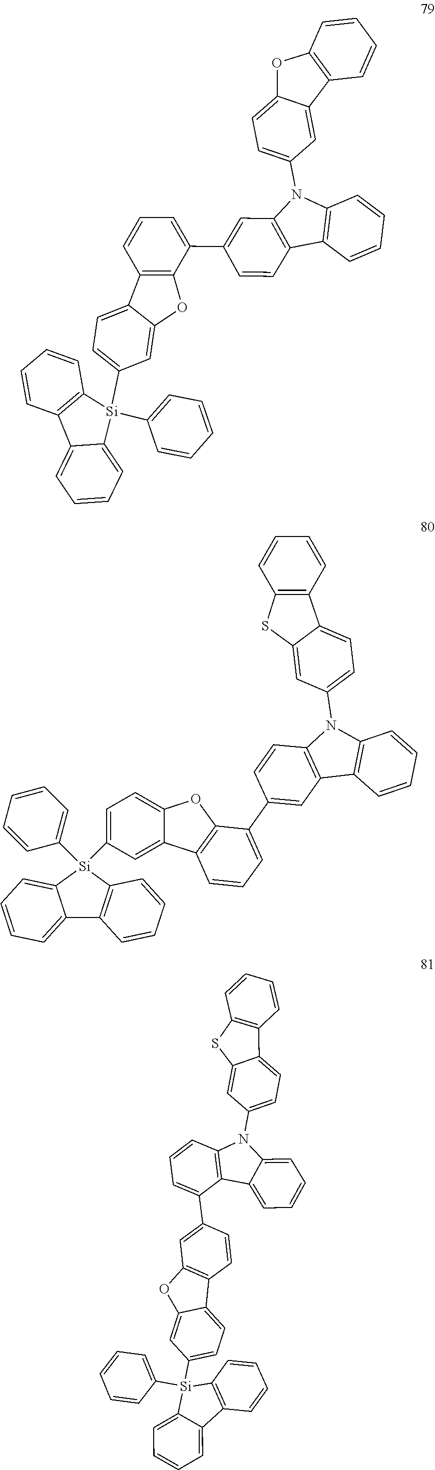 [SMILES: c1ccc([Si]2(c3ccc4c(c3)oc3c(-c5ccc6c7ccccc7n(-c7ccc8oc9ccccc9c8c7)c6c5)cccc34)c3ccccc3-c3ccccc32)cc1 ; c1ccc([Si]2(c3ccc4oc5c(-c6ccc7c(c6)c6ccccc6n7-c6ccc7c(c6)sc6ccccc67)cccc5c4c3)c3ccccc3-c3ccccc32)cc1 ; c1ccc([Si]2(c3ccc4c(c3)oc3cc(-c5cccc6c5c5ccccc5n6-c5ccc6c(c5)sc5ccccc56)ccc34)c3ccccc3-c3ccccc32)cc1]

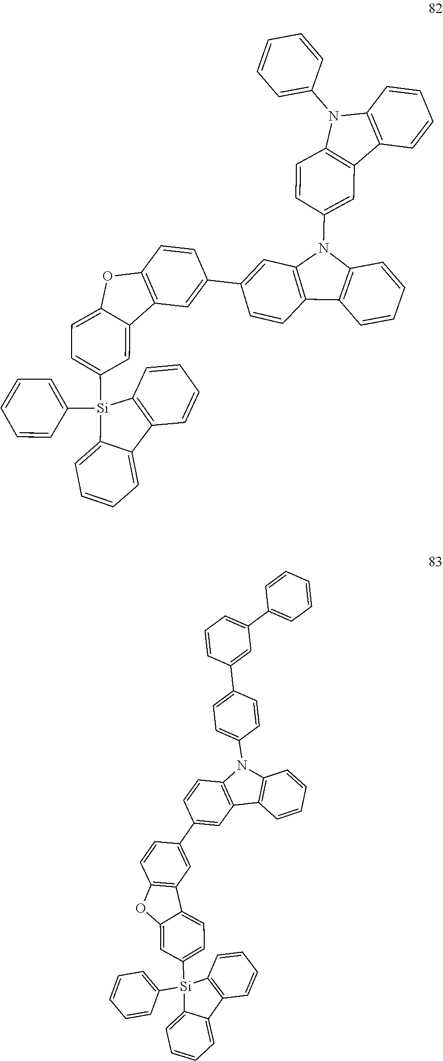 [SMILES: c1ccc(-n2c3ccccc3c3cc(-n4c5ccccc5c5ccc(-c6ccc7oc8ccc([Si]9(c%10ccccc%10)c%10ccccc%10-c%10ccccc%109)cc8c7c6)cc54)ccc32)cc1 ; c1ccc(-c2cccc(-c3ccc(-n4c5ccccc5c5cc(-c6ccc7oc8cc([Si]9(c%10ccccc%10)c%10ccccc%10-c%10ccccc%109)ccc8c7c6)ccc54)cc3)c2)cc1]

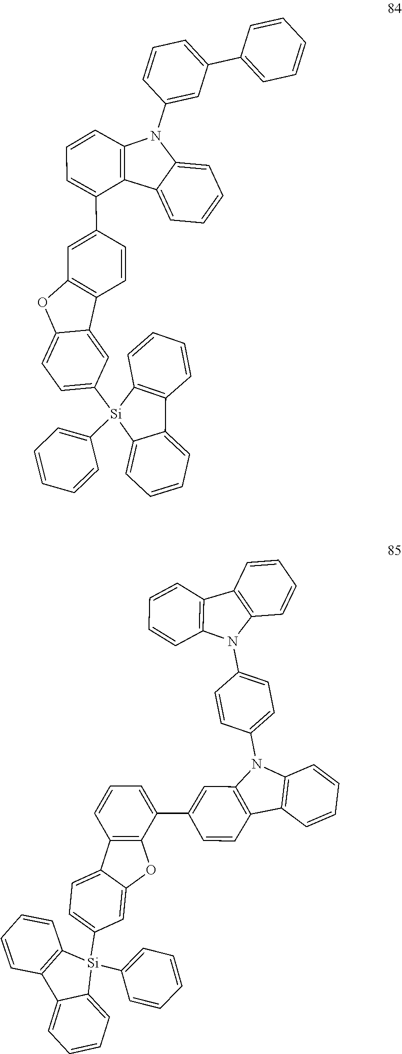 [SMILES: c1ccc(-c2cccc(-n3c4ccccc4c4c(-c5ccc6c(c5)oc5ccc([Si]7(c8ccccc8)c8ccccc8-c8ccccc87)cc56)cccc43)c2)cc1 ; c1ccc([Si]2(c3ccc4c(c3)oc3c(-c5ccc6c7ccccc7n(-c7ccc(-n8c9ccccc9c9ccccc98)cc7)c6c5)cccc34)c3ccccc3-c3ccccc32)cc1]

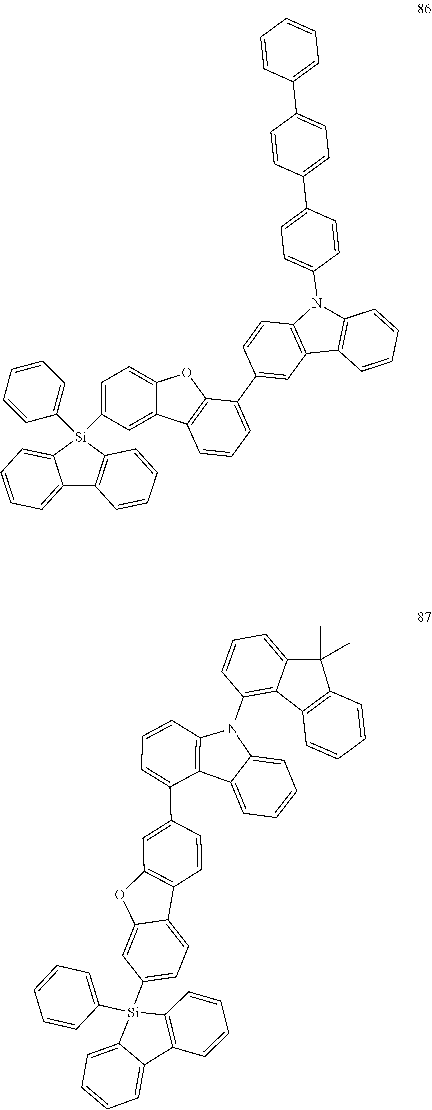 [SMILES: c1ccc(-c2ccc(-c3ccc(-n4c5ccccc5c5cc(-c6cccc7c6oc6ccc([Si]8(c9ccccc9)c9ccccc9-c9ccccc98)cc67)ccc54)cc3)cc2)cc1 ; CC1(C)c2ccccc2-c2c(-n3c4ccccc4c4c(-c5ccc6c(c5)oc5cc([Si]7(c8ccccc8)c8ccccc8-c8ccccc87)ccc56)cccc43)cccc21]

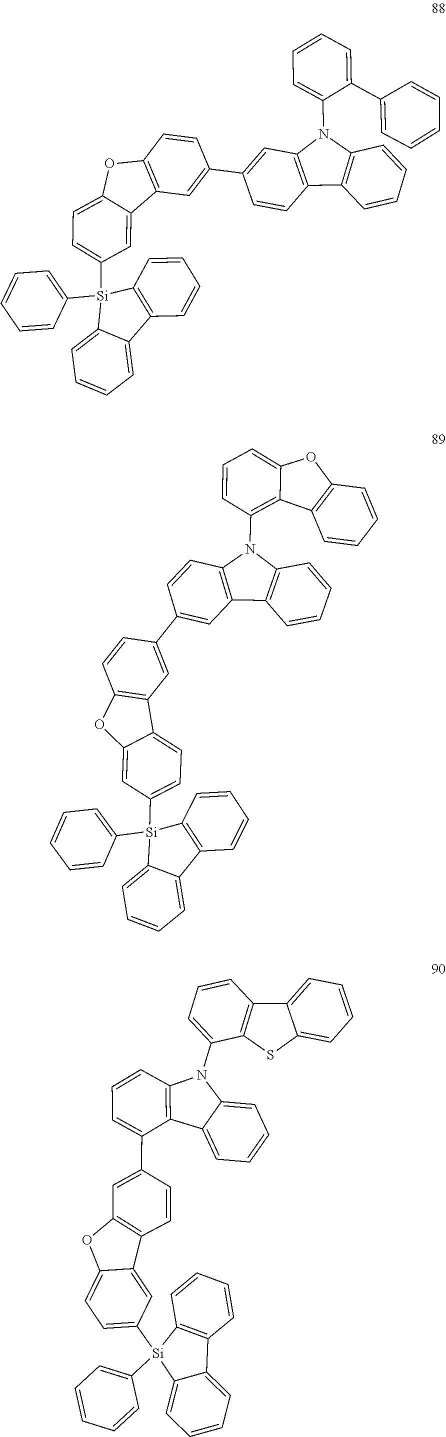 [SMILES: c1ccc(-c2ccccc2-n2c3ccccc3c3ccc(-c4ccc5oc6ccc([Si]7(c8ccccc8)c8ccccc8-c8ccccc87)cc6c5c4)cc32)cc1 ; c1ccc([Si]2(c3ccc4c(c3)oc3ccc(-c5ccc6c(c5)c5ccccc5n6-c5cccc6oc7ccccc7c56)cc34)c3ccccc3-c3ccccc32)cc1 ; c1ccc([Si]2(c3ccc4oc5cc(-c6cccc7c6c6ccccc6n7-c6cccc7c6sc6ccccc67)ccc5c4c3)c3ccccc3-c3ccccc32)cc1]

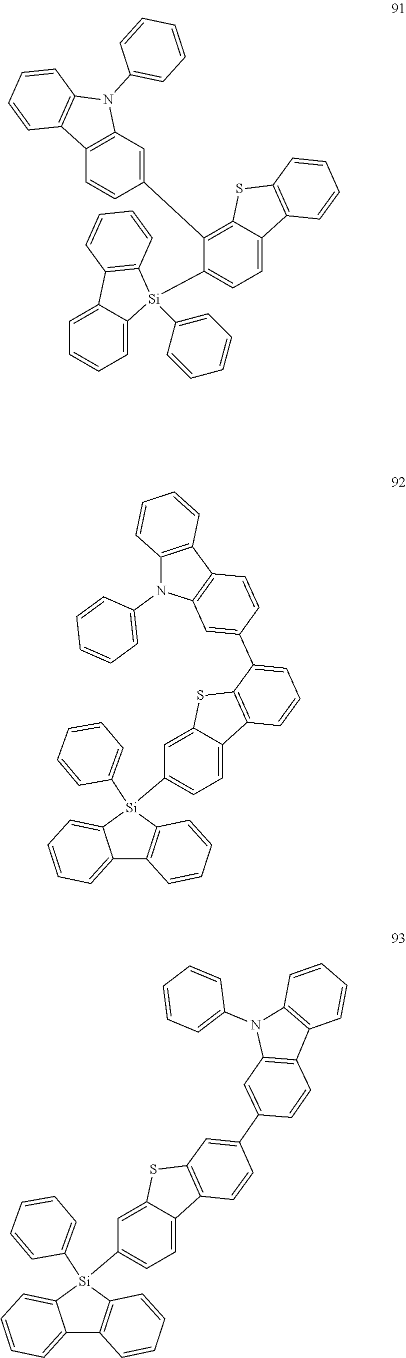 [SMILES: c1ccc(-n2c3ccccc3c3ccc(-c4c([Si]5(c6ccccc6)c6ccccc6-c6ccccc65)ccc5c4sc4ccccc45)cc32)cc1 ; c1ccc(-n2c3ccccc3c3ccc(-c4cccc5c4sc4cc([Si]6(c7ccccc7)c7ccccc7-c7ccccc76)ccc45)cc32)cc1 ; c1ccc(-n2c3ccccc3c3ccc(-c4ccc5c(c4)sc4cc([Si]6(c7ccccc7)c7ccccc7-c7ccccc76)ccc45)cc32)cc1]

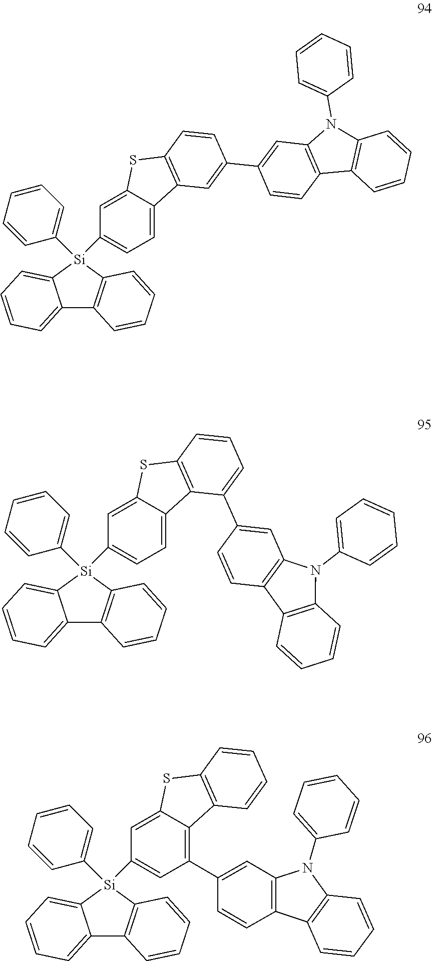 [SMILES: c1ccc(-n2c3ccccc3c3ccc(-c4ccc5sc6cc([Si]7(c8ccccc8)c8ccccc8-c8ccccc87)ccc6c5c4)cc32)cc1 ; c1ccc(-n2c3ccccc3c3ccc(-c4cccc5sc6cc([Si]7(c8ccccc8)c8ccccc8-c8ccccc87)ccc6c45)cc32)cc1 ; c1ccc(-n2c3ccccc3c3ccc(-c4cc([Si]5(c6ccccc6)c6ccccc6-c6ccccc65)cc5sc6ccccc6c45)cc32)cc1]

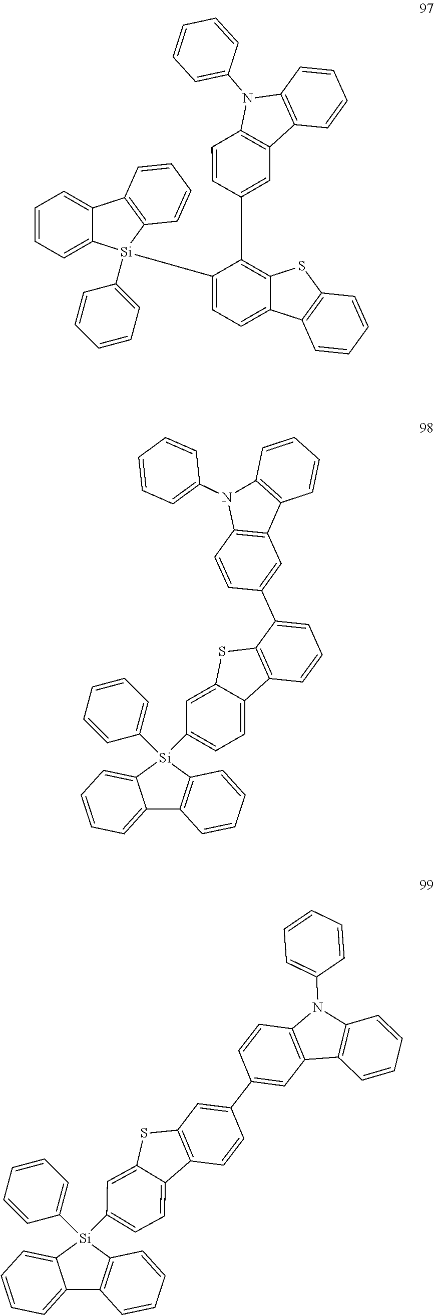 [SMILES: c1ccc(-n2c3ccccc3c3cc(-c4c([Si]5(c6ccccc6)c6ccccc6-c6ccccc65)ccc5c4sc4ccccc45)ccc32)cc1 ; c1ccc(-n2c3ccccc3c3cc(-c4cccc5c4sc4cc([Si]6(c7ccccc7)c7ccccc7-c7ccccc76)ccc45)ccc32)cc1 ; c1ccc(-n2c3ccccc3c3cc(-c4ccc5c(c4)sc4cc([Si]6(c7ccccc7)c7ccccc7-c7ccccc76)ccc45)ccc32)cc1]

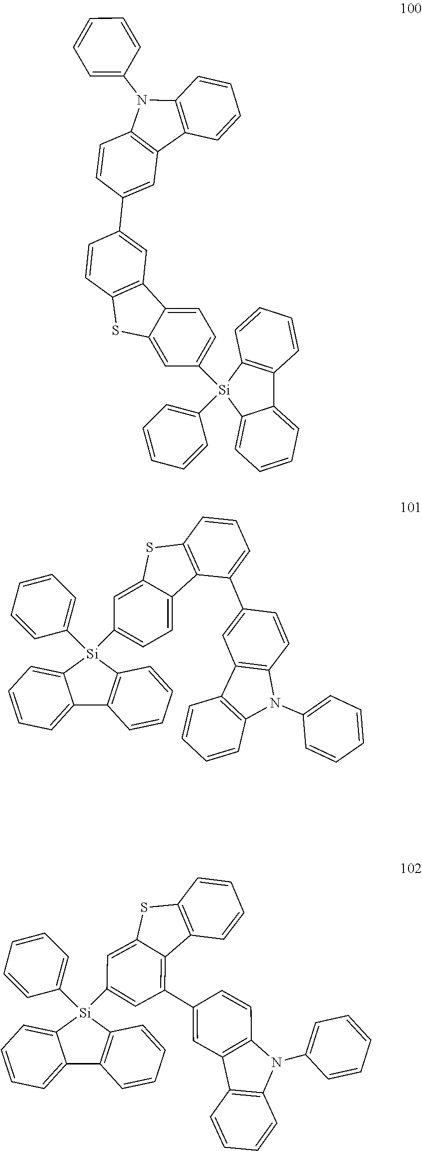 [SMILES: c1ccc(-n2c3ccccc3c3cc(-c4ccc5sc6cc([Si]7(c8ccccc8)c8ccccc8-c8ccccc87)ccc6c5c4)ccc32)cc1 ; c1ccc(-n2c3ccccc3c3cc(-c4cccc5sc6cc([Si]7(c8ccccc8)c8ccccc8-c8ccccc87)ccc6c45)ccc32)cc1 ; c1ccc(-n2c3ccccc3c3cc(-c4cc([Si]5(c6ccccc6)c6ccccc6-c6ccccc65)cc5sc6ccccc6c45)ccc32)cc1]

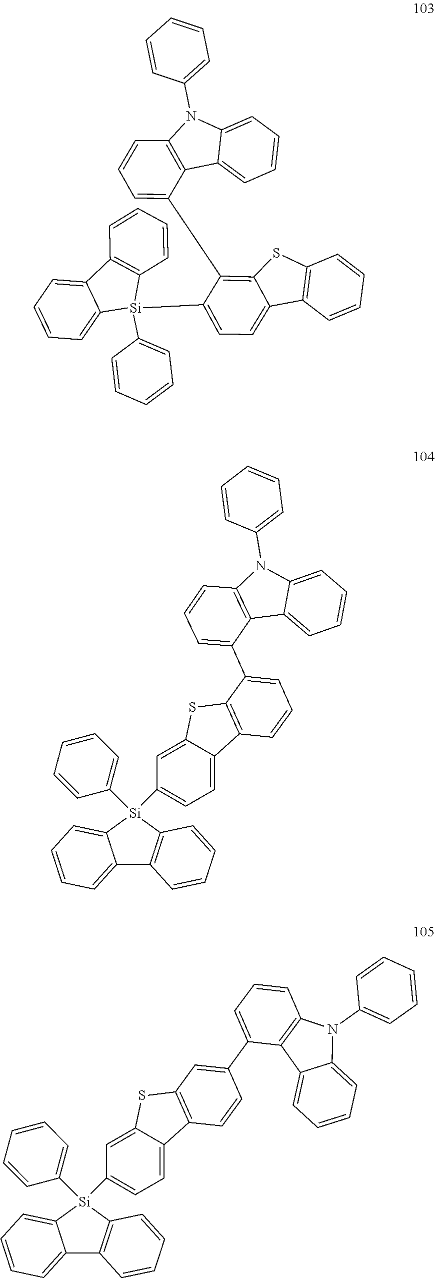 [SMILES: c1ccc(-n2c3ccccc3c3c(-c4c([Si]5(c6ccccc6)c6ccccc6-c6ccccc65)ccc5c4sc4ccccc45)cccc32)cc1 ; c1ccc(-n2c3ccccc3c3c(-c4cccc5c4sc4cc([Si]6(c7ccccc7)c7ccccc7-c7ccccc76)ccc45)cccc32)cc1 ; c1ccc(-n2c3ccccc3c3c(-c4ccc5c(c4)sc4cc([Si]6(c7ccccc7)c7ccccc7-c7ccccc76)ccc45)cccc32)cc1]

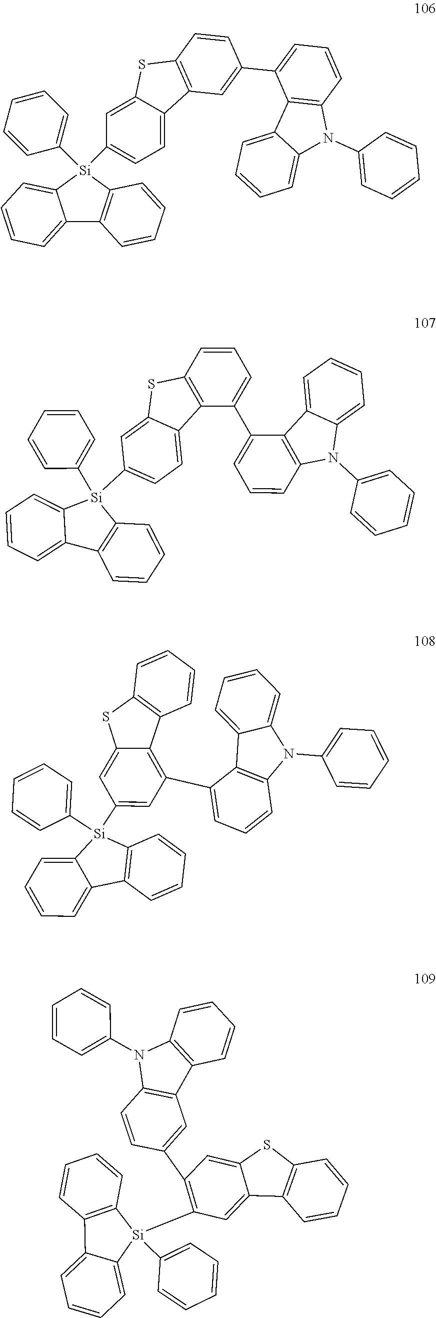 [SMILES: c1ccc(-n2c3ccccc3c3c(-c4ccc5sc6cc([Si]7(c8ccccc8)c8ccccc8-c8ccccc87)ccc6c5c4)cccc32)cc1 ; c1ccc(-n2c3ccccc3c3c(-c4cccc5sc6cc([Si]7(c8ccccc8)c8ccccc8-c8ccccc87)ccc6c45)cccc32)cc1 ; c1ccc(-n2c3ccccc3c3c(-c4cc([Si]5(c6ccccc6)c6ccccc6-c6ccccc65)cc5sc6ccccc6c45)cccc32)cc1 ; c1ccc(-n2c3ccccc3c3cc(-c4cc5sc6ccccc6c5cc4[Si]4(c5ccccc5)c5ccccc5-c5ccccc54)ccc32)cc1]

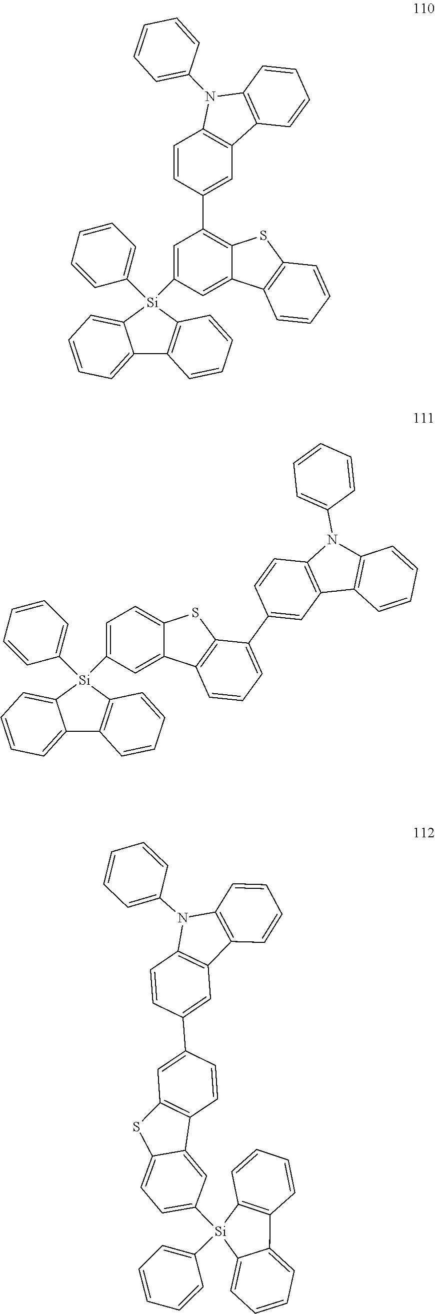 [SMILES: c1ccc(-n2c3ccccc3c3cc(-c4cc([Si]5(c6ccccc6)c6ccccc6-c6ccccc65)cc5c4sc4ccccc45)ccc32)cc1 ; c1ccc(-n2c3ccccc3c3cc(-c4cccc5c4sc4ccc([Si]6(c7ccccc7)c7ccccc7-c7ccccc76)cc45)ccc32)cc1 ; c1ccc(-n2c3ccccc3c3cc(-c4ccc5c(c4)sc4ccc([Si]6(c7ccccc7)c7ccccc7-c7ccccc76)cc45)ccc32)cc1]

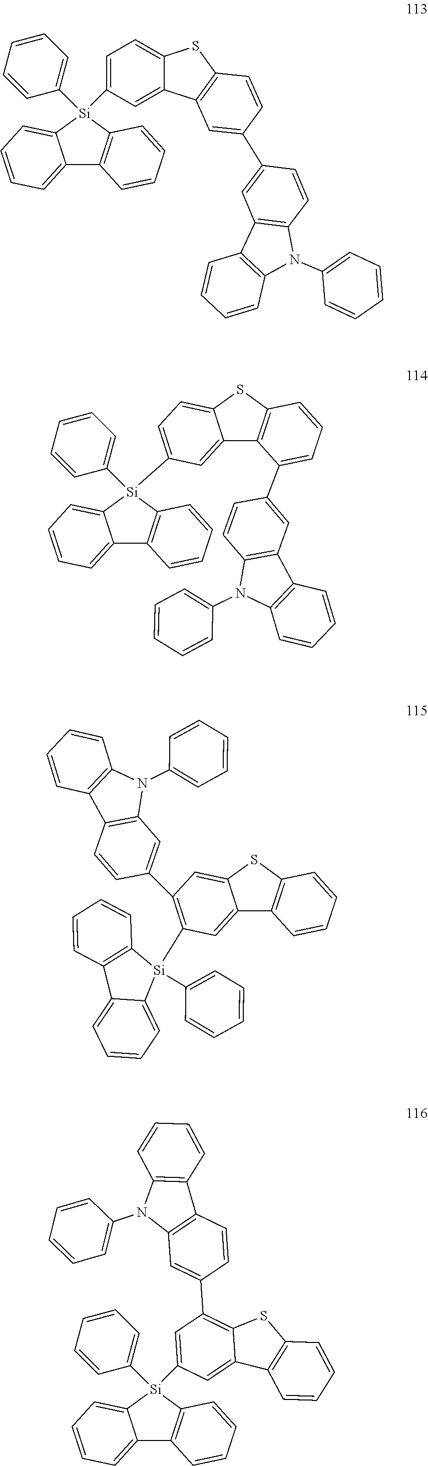 [SMILES: c1ccc(-n2c3ccccc3c3cc(-c4ccc5sc6ccc([Si]7(c8ccccc8)c8ccccc8-c8ccccc87)cc6c5c4)ccc32)cc1 ; c1ccc(-n2c3ccccc3c3cc(-c4cccc5sc6ccc([Si]7(c8ccccc8)c8ccccc8-c8ccccc87)cc6c45)ccc32)cc1 ; c1ccc(-n2c3ccccc3c3ccc(-c4cc5sc6ccccc6c5cc4[Si]4(c5ccccc5)c5ccccc5-c5ccccc54)cc32)cc1 ; c1ccc(-n2c3ccccc3c3ccc(-c4cc([Si]5(c6ccccc6)c6ccccc6-c6ccccc65)cc5c4sc4ccccc45)cc32)cc1]

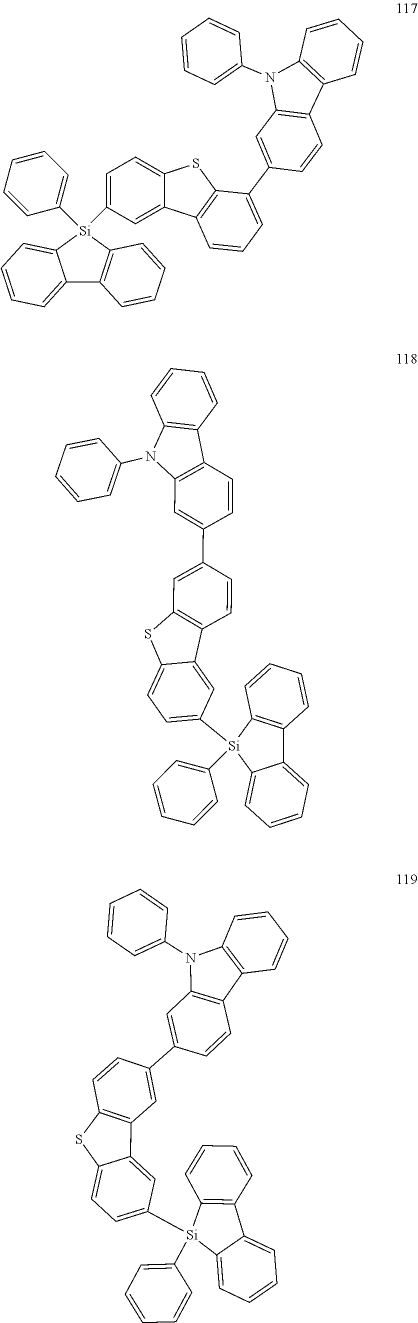 [SMILES: c1ccc(-n2c3ccccc3c3ccc(-c4cccc5c4sc4ccc([Si]6(c7ccccc7)c7ccccc7-c7ccccc76)cc45)cc32)cc1 ; c1ccc(-n2c3ccccc3c3ccc(-c4ccc5c(c4)sc4ccc([Si]6(c7ccccc7)c7ccccc7-c7ccccc76)cc45)cc32)cc1 ; c1ccc(-n2c3ccccc3c3ccc(-c4ccc5sc6ccc([Si]7(c8ccccc8)c8ccccc8-c8ccccc87)cc6c5c4)cc32)cc1]

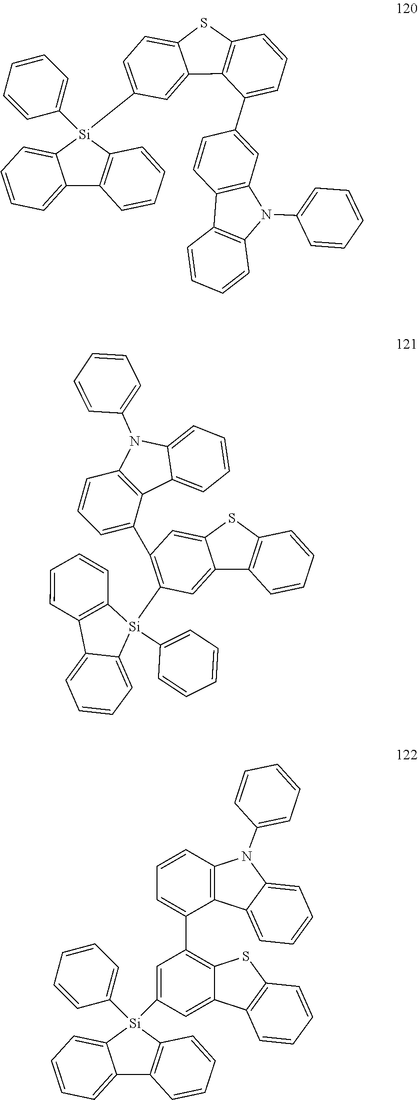 [SMILES: c1ccc(-n2c3ccccc3c3ccc(-c4cccc5sc6ccc([Si]7(c8ccccc8)c8ccccc8-c8ccccc87)cc6c45)cc32)cc1 ; c1ccc(-n2c3ccccc3c3c(-c4cc5sc6ccccc6c5cc4[Si]4(c5ccccc5)c5ccccc5-c5ccccc54)cccc32)cc1 ; c1ccc(-n2c3ccccc3c3c(-c4cc([Si]5(c6ccccc6)c6ccccc6-c6ccccc65)cc5c4sc4ccccc45)cccc32)cc1]

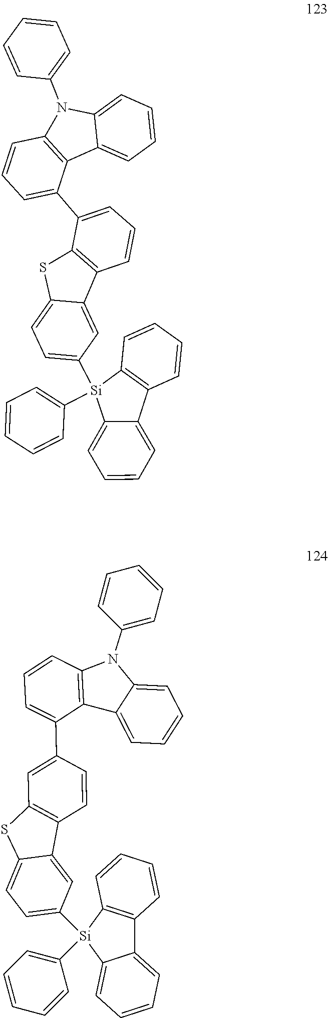 [SMILES: c1ccc(-n2c3ccccc3c3c(-c4cccc5c4sc4ccc([Si]6(c7ccccc7)c7ccccc7-c7ccccc76)cc45)cccc32)cc1 ; c1ccc(-n2c3ccccc3c3c(-c4ccc5c(c4)sc4ccc([Si]6(c7ccccc7)c7ccccc7-c7ccccc76)cc45)cccc32)cc1]

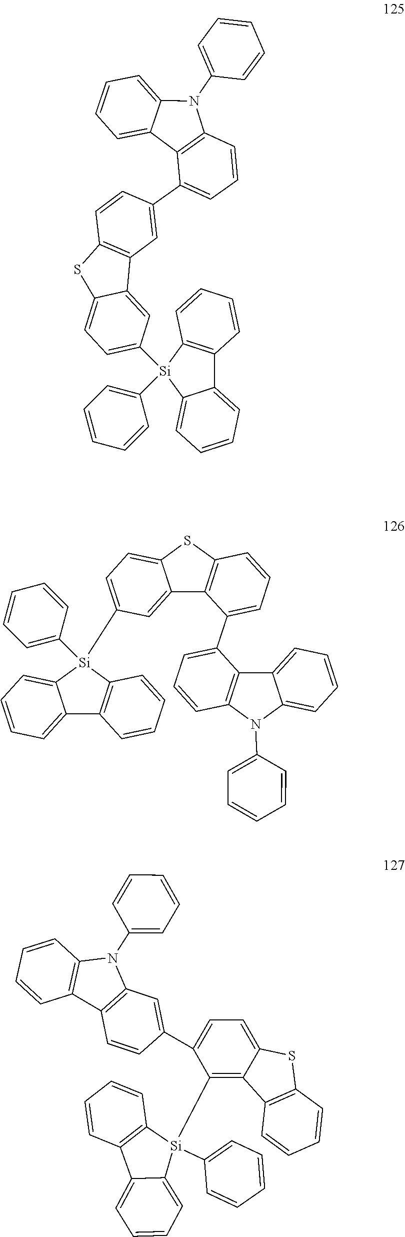 [SMILES: c1ccc(-n2c3ccccc3c3c(-c4ccc5sc6ccc([Si]7(c8ccccc8)c8ccccc8-c8ccccc87)cc6c5c4)cccc32)cc1 ; c1ccc(-n2c3ccccc3c3c(-c4cccc5sc6ccc([Si]7(c8ccccc8)c8ccccc8-c8ccccc87)cc6c45)cccc32)cc1 ; c1ccc(-n2c3ccccc3c3ccc(-c4ccc5sc6ccccc6c5c4[Si]4(c5ccccc5)c5ccccc5-c5ccccc54)cc32)cc1]

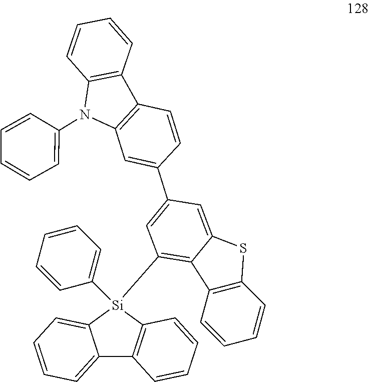 [SMILES: c1ccc(-n2c3ccccc3c3ccc(-c4cc([Si]5(c6ccccc6)c6ccccc6-c6ccccc65)c5c(c4)sc4ccccc45)cc32)cc1]

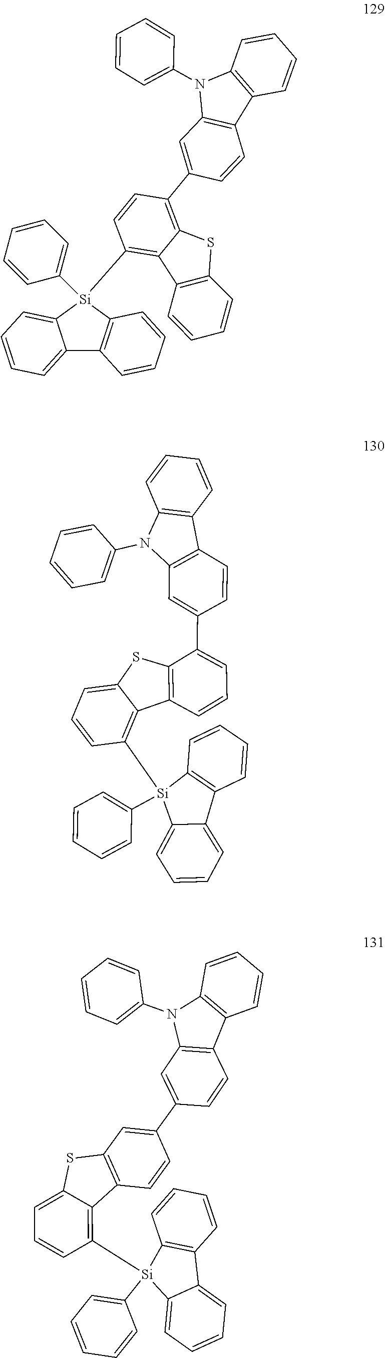 [SMILES: c1ccc(-n2c3ccccc3c3ccc(-c4ccc([Si]5(c6ccccc6)c6ccccc6-c6ccccc65)c5c4sc4ccccc45)cc32)cc1 ; c1ccc(-n2c3ccccc3c3ccc(-c4cccc5c4sc4cccc([Si]6(c7ccccc7)c7ccccc7-c7ccccc76)c45)cc32)cc1 ; c1ccc(-n2c3ccccc3c3ccc(-c4ccc5c(c4)sc4cccc([Si]6(c7ccccc7)c7ccccc7-c7ccccc76)c45)cc32)cc1]

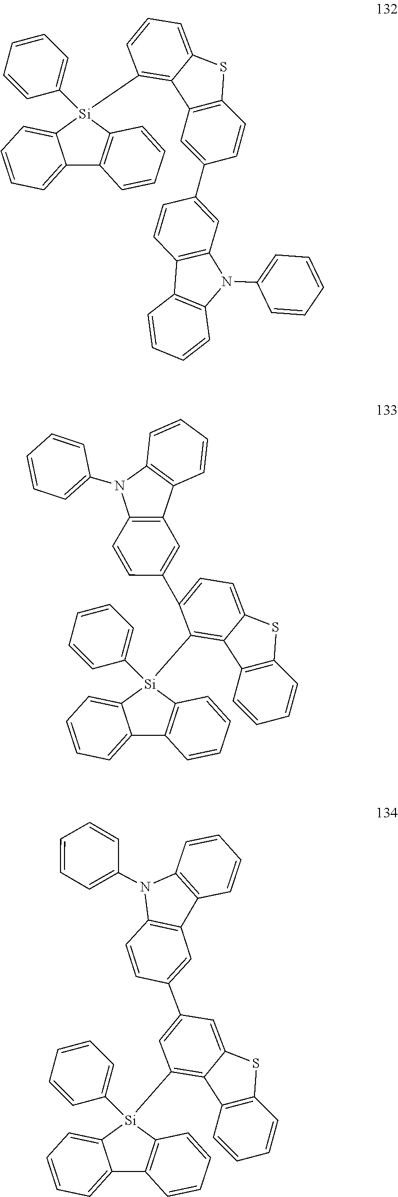 [SMILES: c1ccc(-n2c3ccccc3c3ccc(-c4ccc5sc6cccc([Si]7(c8ccccc8)c8ccccc8-c8ccccc87)c6c5c4)cc32)cc1 ; c1ccc(-n2c3ccccc3c3cc(-c4ccc5sc6ccccc6c5c4[Si]4(c5ccccc5)c5ccccc5-c5ccccc54)ccc32)cc1 ; c1ccc(-n2c3ccccc3c3cc(-c4cc([Si]5(c6ccccc6)c6ccccc6-c6ccccc65)c5c(c4)sc4ccccc45)ccc32)cc1]

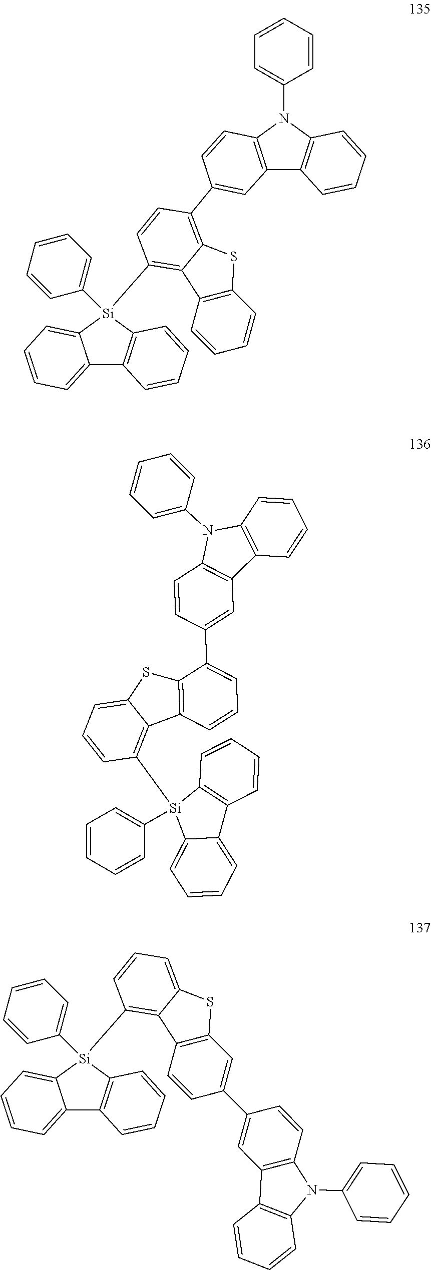 [SMILES: c1ccc(-n2c3ccccc3c3cc(-c4ccc([Si]5(c6ccccc6)c6ccccc6-c6ccccc65)c5c4sc4ccccc45)ccc32)cc1 ; c1ccc(-n2c3ccccc3c3cc(-c4cccc5c4sc4cccc([Si]6(c7ccccc7)c7ccccc7-c7ccccc76)c45)ccc32)cc1 ; c1ccc(-n2c3ccccc3c3cc(-c4ccc5c(c4)sc4cccc([Si]6(c7ccccc7)c7ccccc7-c7ccccc76)c45)ccc32)cc1]

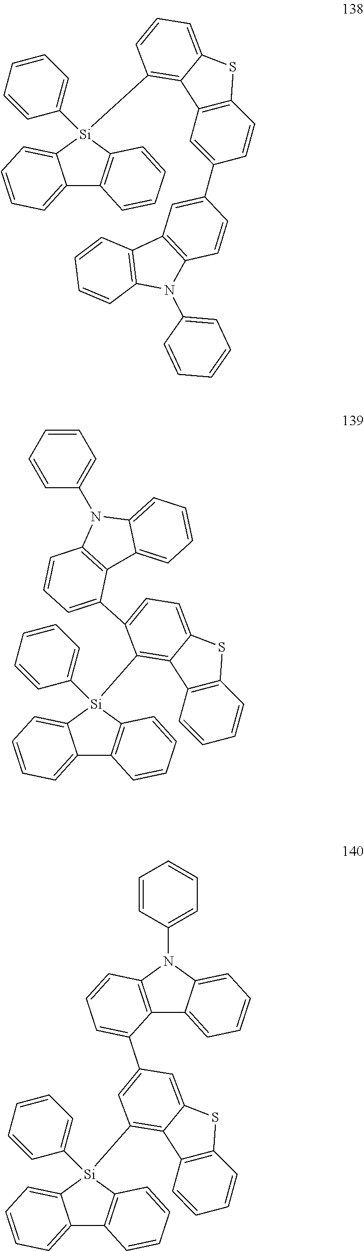 [SMILES: c1ccc(-n2c3ccccc3c3cc(-c4ccc5sc6cccc([Si]7(c8ccccc8)c8ccccc8-c8ccccc87)c6c5c4)ccc32)cc1 ; c1ccc(-n2c3ccccc3c3c(-c4ccc5sc6ccccc6c5c4[Si]4(c5ccccc5)c5ccccc5-c5ccccc54)cccc32)cc1 ; c1ccc(-n2c3ccccc3c3c(-c4cc([Si]5(c6ccccc6)c6ccccc6-c6ccccc65)c5c(c4)sc4ccccc45)cccc32)cc1]

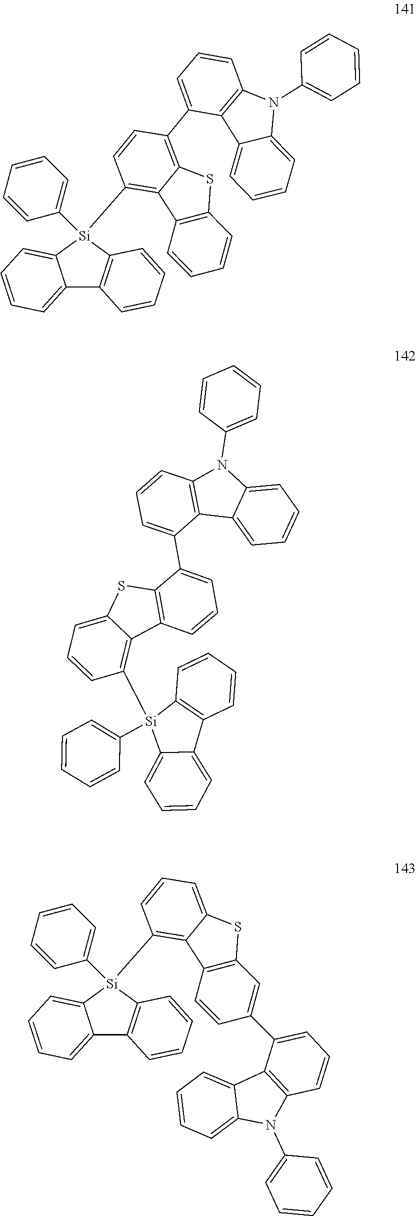 [SMILES: c1ccc(-n2c3ccccc3c3c(-c4ccc([Si]5(c6ccccc6)c6ccccc6-c6ccccc65)c5c4sc4ccccc45)cccc32)cc1 ; c1ccc(-n2c3ccccc3c3c(-c4cccc5c4sc4cccc([Si]6(c7ccccc7)c7ccccc7-c7ccccc76)c45)cccc32)cc1 ; c1ccc(-n2c3ccccc3c3c(-c4ccc5c(c4)sc4cccc([Si]6(c7ccccc7)c7ccccc7-c7ccccc76)c45)cccc32)cc1]

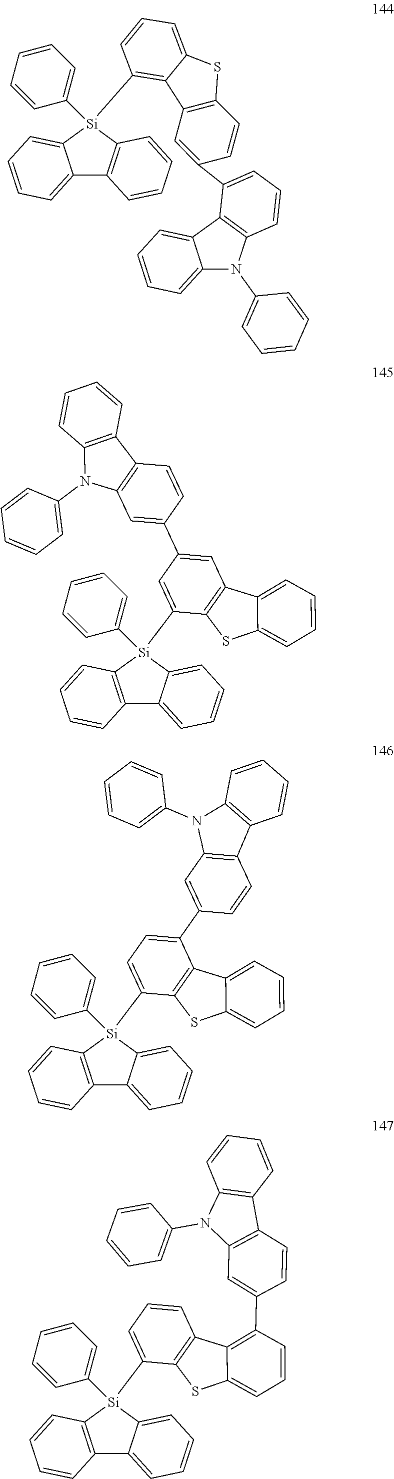

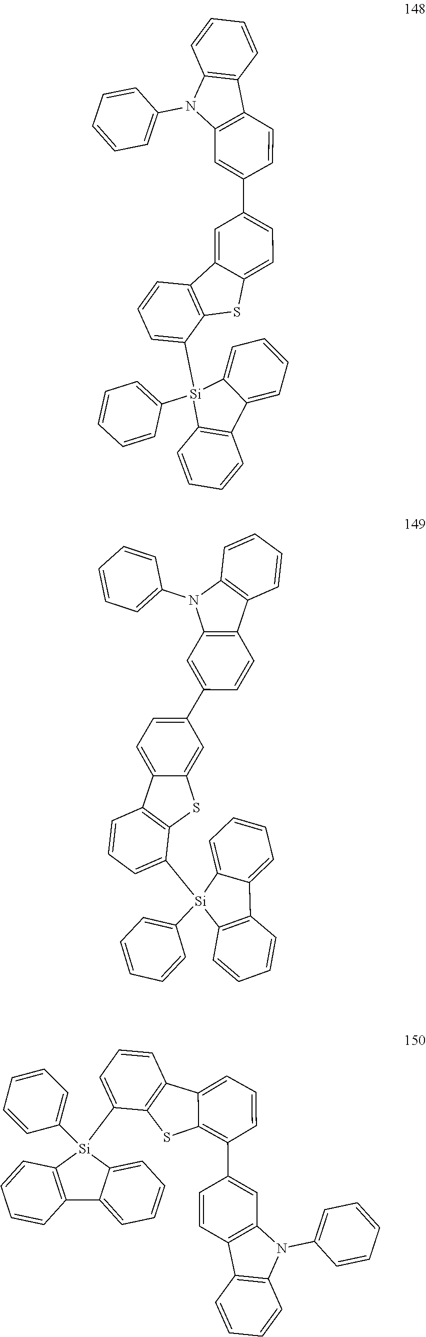 [SMILES: c1ccc(-n2c3ccccc3c3ccc(-c4ccc5sc6c([Si]7(c8ccccc8)c8ccccc8-c8ccccc87)cccc6c5c4)cc32)cc1 ; c1ccc(-n2c3ccccc3c3ccc(-c4ccc5c(c4)sc4c([Si]6(c7ccccc7)c7ccccc7-c7ccccc76)cccc45)cc32)cc1 ; c1ccc(-n2c3ccccc3c3ccc(-c4cccc5c4sc4c([Si]6(c7ccccc7)c7ccccc7-c7ccccc76)cccc45)cc32)cc1]

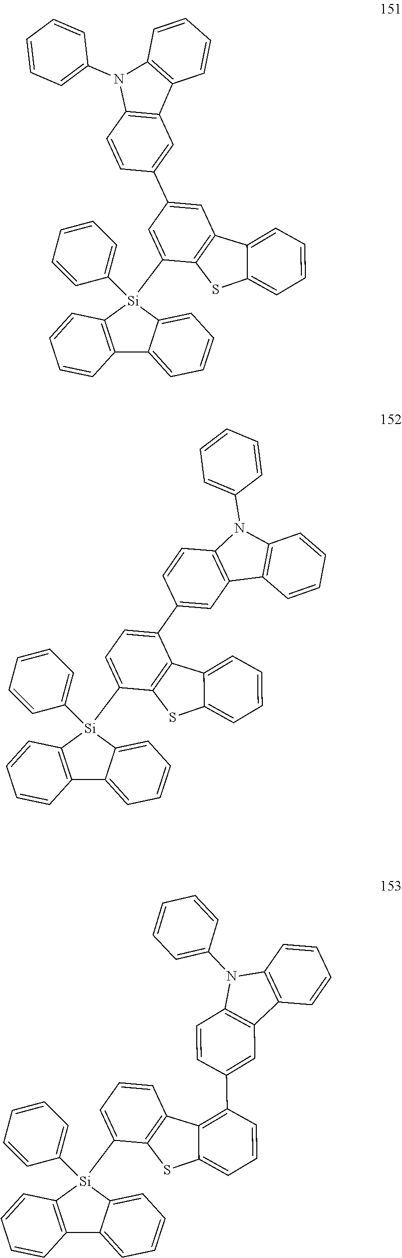 [SMILES: c1ccc(-n2c3ccccc3c3cc(-c4cc([Si]5(c6ccccc6)c6ccccc6-c6ccccc65)c5sc6ccccc6c5c4)ccc32)cc1 ; c1ccc(-n2c3ccccc3c3cc(-c4ccc([Si]5(c6ccccc6)c6ccccc6-c6ccccc65)c5sc6ccccc6c45)ccc32)cc1 ; c1ccc(-n2c3ccccc3c3cc(-c4cccc5sc6c([Si]7(c8ccccc8)c8ccccc8-c8ccccc87)cccc6c45)ccc32)cc1]

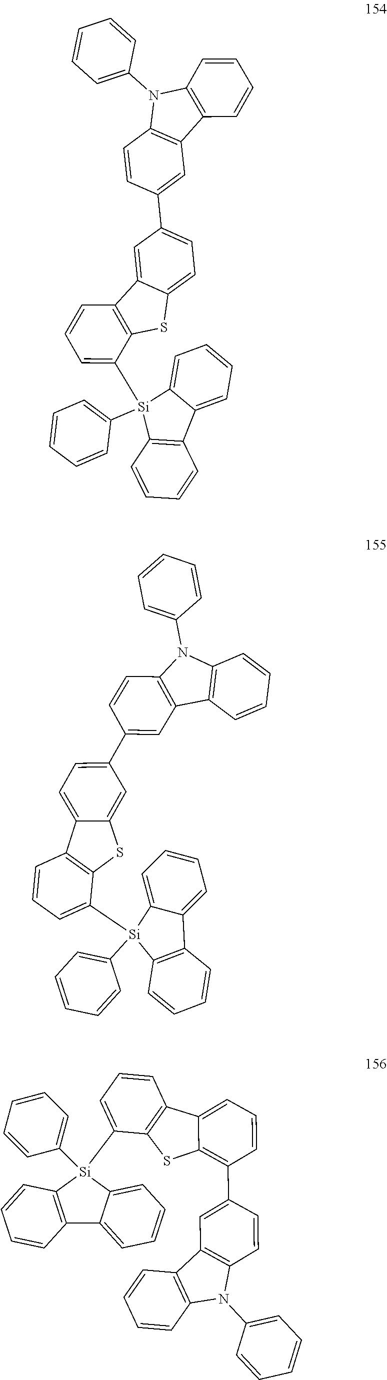 [SMILES: c1ccc(-n2c3ccccc3c3cc(-c4ccc5sc6c([Si]7(c8ccccc8)c8ccccc8-c8ccccc87)cccc6c5c4)ccc32)cc1 ; c1ccc(-n2c3ccccc3c3cc(-c4ccc5c(c4)sc4c([Si]6(c7ccccc7)c7ccccc7-c7ccccc76)cccc45)ccc32)cc1 ; c1ccc(-n2c3ccccc3c3cc(-c4cccc5c4sc4c([Si]6(c7ccccc7)c7ccccc7-c7ccccc76)cccc45)ccc32)cc1]

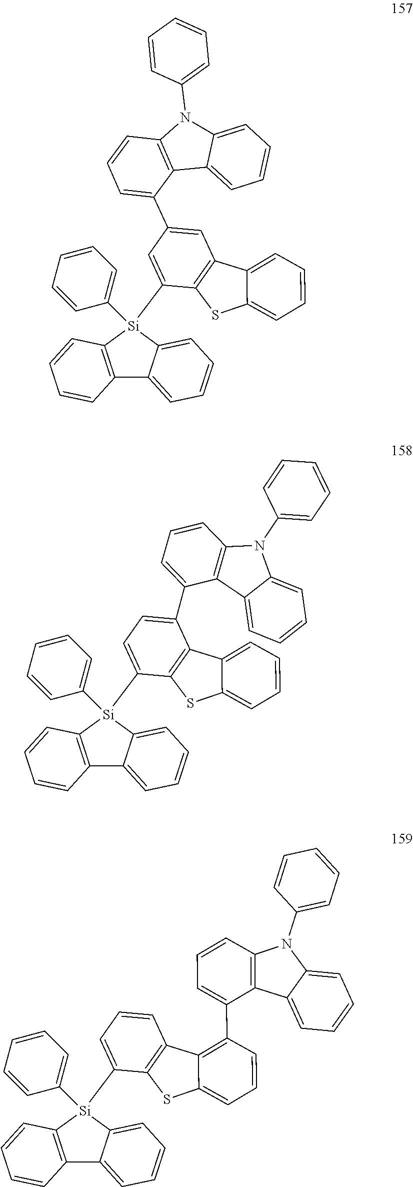 [SMILES: c1ccc(-n2c3ccccc3c3c(-c4cc([Si]5(c6ccccc6)c6ccccc6-c6ccccc65)c5sc6ccccc6c5c4)cccc32)cc1 ; c1ccc(-n2c3ccccc3c3c(-c4ccc([Si]5(c6ccccc6)c6ccccc6-c6ccccc65)c5sc6ccccc6c45)cccc32)cc1 ; c1ccc(-n2c3ccccc3c3c(-c4cccc5sc6c([Si]7(c8ccccc8)c8ccccc8-c8ccccc87)cccc6c45)cccc32)cc1]

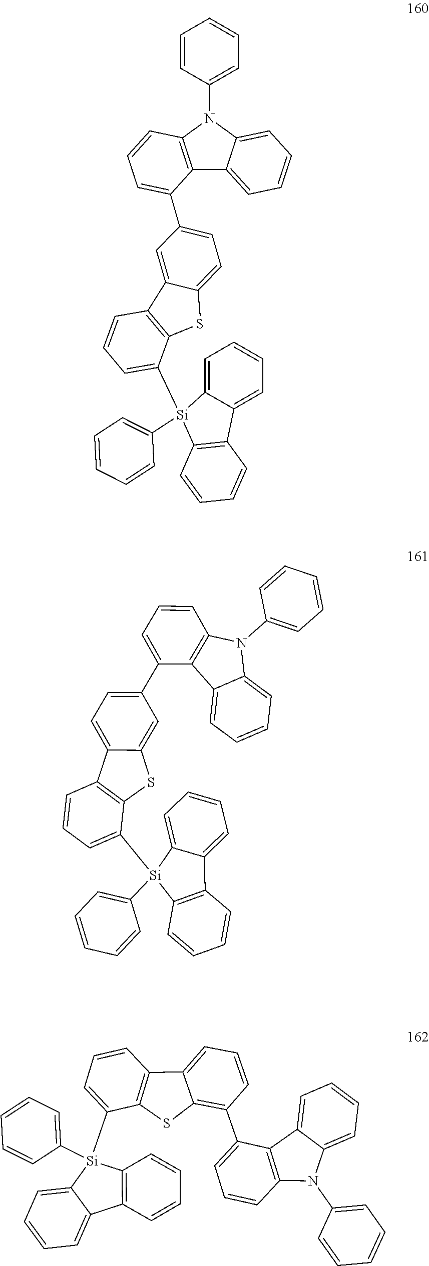 [SMILES: c1ccc(-n2c3ccccc3c3c(-c4ccc5sc6c([Si]7(c8ccccc8)c8ccccc8-c8ccccc87)cccc6c5c4)cccc32)cc1 ; c1ccc(-n2c3ccccc3c3c(-c4ccc5c(c4)sc4c([Si]6(c7ccccc7)c7ccccc7-c7ccccc76)cccc45)cccc32)cc1 ; c1ccc(-n2c3ccccc3c3c(-c4cccc5c4sc4c([Si]6(c7ccccc7)c7ccccc7-c7ccccc76)cccc45)cccc32)cc1]

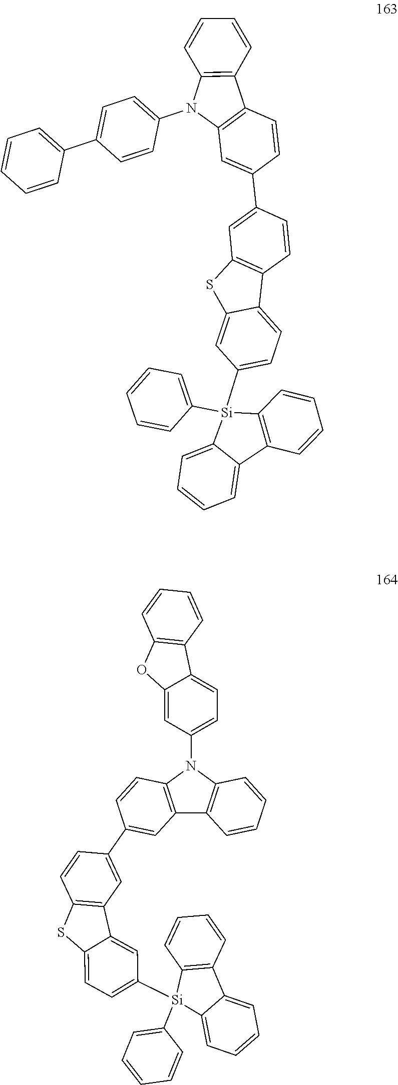 [SMILES: c1ccc(-c2ccc(-n3c4ccccc4c4ccc(-c5ccc6c(c5)sc5cc([Si]7(c8ccccc8)c8ccccc8-c8ccccc87)ccc56)cc43)cc2)cc1 ; c1ccc([Si]2(c3ccc4sc5ccc(-c6ccc7c(c6)c6ccccc6n7-c6ccc7c(c6)oc6ccccc67)cc5c4c3)c3ccccc3-c3ccccc32)cc1]

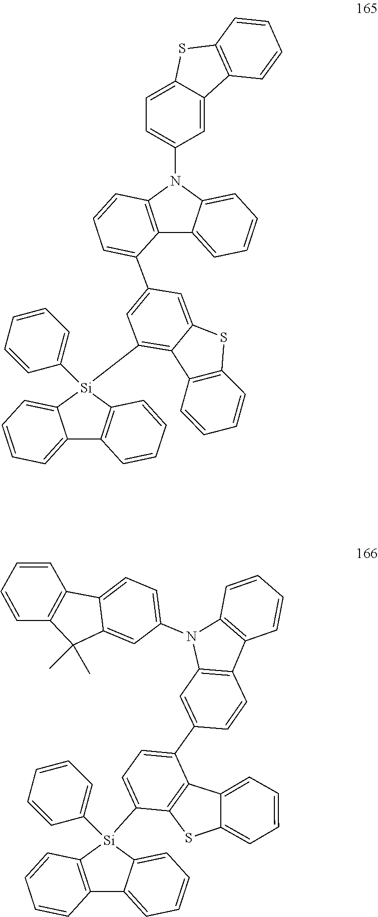 [SMILES: c1ccc([Si]2(c3cc(-c4cccc5c4c4ccccc4n5-c4ccc5sc6ccccc6c5c4)cc4sc5ccccc5c34)c3ccccc3-c3ccccc32)cc1 ; CC1(C)c2ccccc2-c2ccc(-n3c4ccccc4c4ccc(-c5ccc([Si]6(c7ccccc7)c7ccccc7-c7ccccc76)c6sc7ccccc7c56)cc43)cc21]

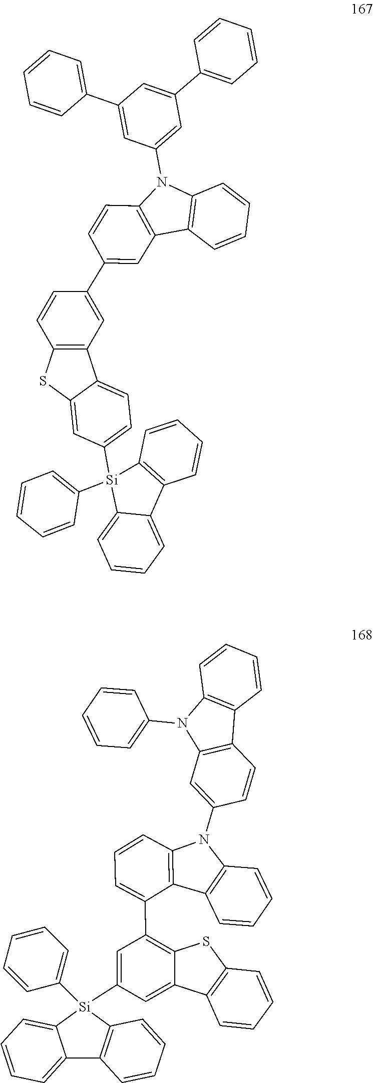 [SMILES: c1ccc(-c2cc(-c3ccccc3)cc(-n3c4ccccc4c4cc(-c5ccc6sc7cc([Si]8(c9ccccc9)c9ccccc9-c9ccccc98)ccc7c6c5)ccc43)c2)cc1 ; c1ccc(-n2c3ccccc3c3ccc(-n4c5ccccc5c5c(-c6cc([Si]7(c8ccccc8)c8ccccc8-c8ccccc87)cc7c6sc6ccccc67)cccc54)cc32)cc1]

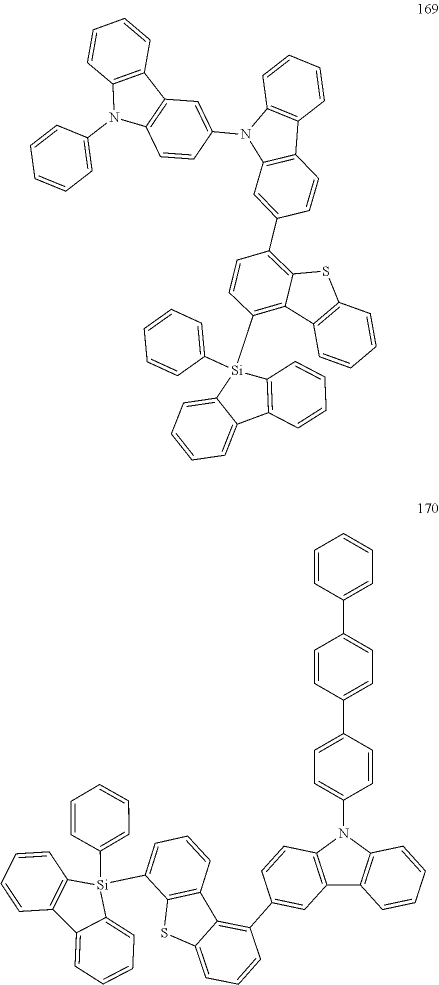 [SMILES: c1ccc(-n2c3ccccc3c3cc(-n4c5ccccc5c5ccc(-c6ccc([Si]7(c8ccccc8)c8ccccc8-c8ccccc87)c7c6sc6ccccc67)cc54)ccc32)cc1 ; c1ccc(-c2ccc(-c3ccc(-n4c5ccccc5c5cc(-c6cccc7sc8c([Si]9(c%10ccccc%10)c%10ccccc%10-c%10ccccc%109)cccc8c67)ccc54)cc3)cc2)cc1]

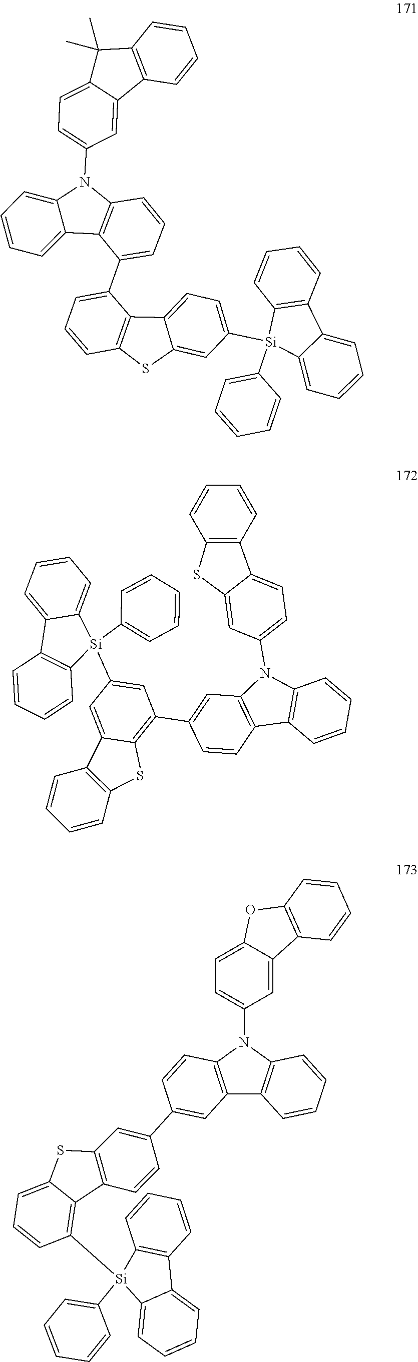 [SMILES: CC1(C)c2ccccc2-c2cc(-n3c4ccccc4c4c(-c5cccc6sc7cc([Si]8(c9ccccc9)c9ccccc9-c9ccccc98)ccc7c56)cccc43)ccc21 ; c1ccc([Si]2(c3cc(-c4ccc5c6ccccc6n(-c6ccc7c(c6)sc6ccccc67)c5c4)c4sc5ccccc5c4c3)c3ccccc3-c3ccccc32)cc1 ; c1ccc([Si]2(c3cccc4sc5cc(-c6ccc7c(c6)c6ccccc6n7-c6ccc7oc8ccccc8c7c6)ccc5c34)c3ccccc3-c3ccccc32)cc1]

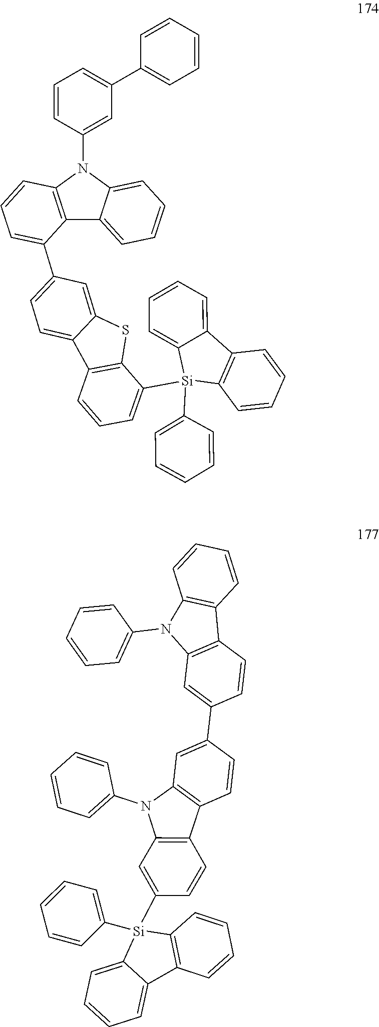 [SMILES: c1ccc(-c2cccc(-n3c4ccccc4c4c(-c5ccc6c(c5)sc5c([Si]7(c8ccccc8)c8ccccc8-c8ccccc87)cccc56)cccc43)c2)cc1 ; c1ccc(-n2c3ccccc3c3ccc(-c4ccc5c6ccc([Si]7(c8ccccc8)c8ccccc8-c8ccccc87)cc6n(-c6ccccc6)c5c4)cc32)cc1]

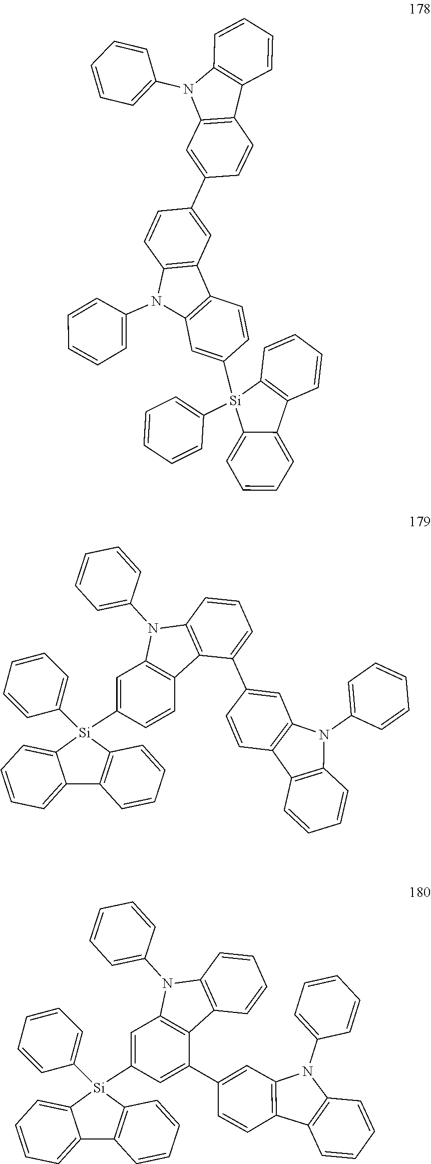 [SMILES: c1ccc(-n2c3ccccc3c3ccc(-c4ccc5c(c4)c4ccc([Si]6(c7ccccc7)c7ccccc7-c7ccccc76)cc4n5-c4ccccc4)cc32)cc1 ; c1ccc(-n2c3ccccc3c3ccc(-c4cccc5c4c4ccc([Si]6(c7ccccc7)c7ccccc7-c7ccccc76)cc4n5-c4ccccc4)cc32)cc1 ; c1ccc(-n2c3ccccc3c3ccc(-c4cc([Si]5(c6ccccc6)c6ccccc6-c6ccccc65)cc5c4c4ccccc4n5-c4ccccc4)cc32)cc1]

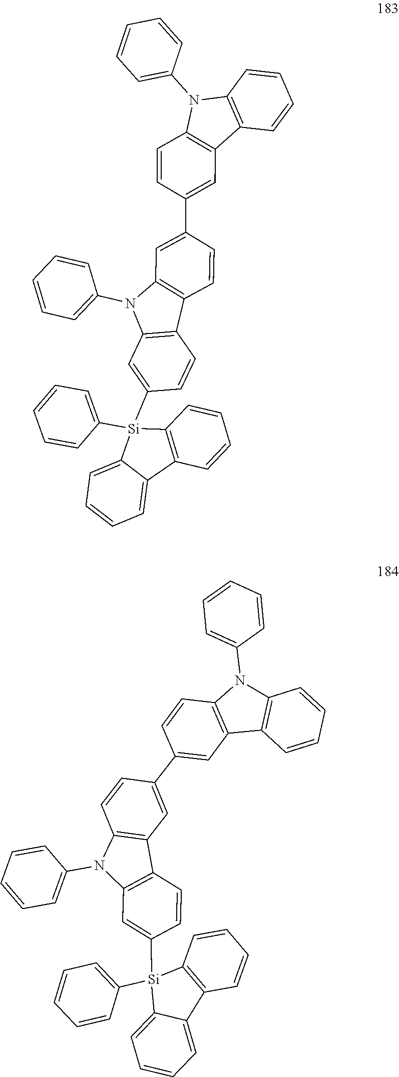 [SMILES: c1ccc(-n2c3ccccc3c3cc(-c4ccc5c6ccc([Si]7(c8ccccc8)c8ccccc8-c8ccccc87)cc6n(-c6ccccc6)c5c4)ccc32)cc1 ; c1ccc(-n2c3ccccc3c3cc(-c4ccc5c(c4)c4ccc([Si]6(c7ccccc7)c7ccccc7-c7ccccc76)cc4n5-c4ccccc4)ccc32)cc1]

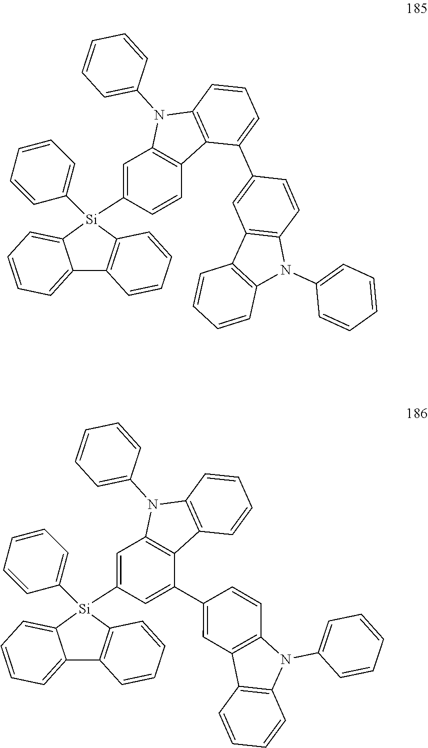 [SMILES: c1ccc(-n2c3ccccc3c3cc(-c4cccc5c4c4ccc([Si]6(c7ccccc7)c7ccccc7-c7ccccc76)cc4n5-c4ccccc4)ccc32)cc1 ; c1ccc(-n2c3ccccc3c3cc(-c4cc([Si]5(c6ccccc6)c6ccccc6-c6ccccc65)cc5c4c4ccccc4n5-c4ccccc4)ccc32)cc1]

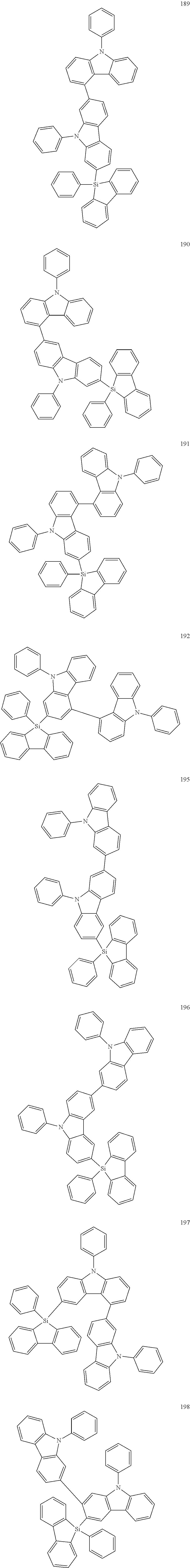

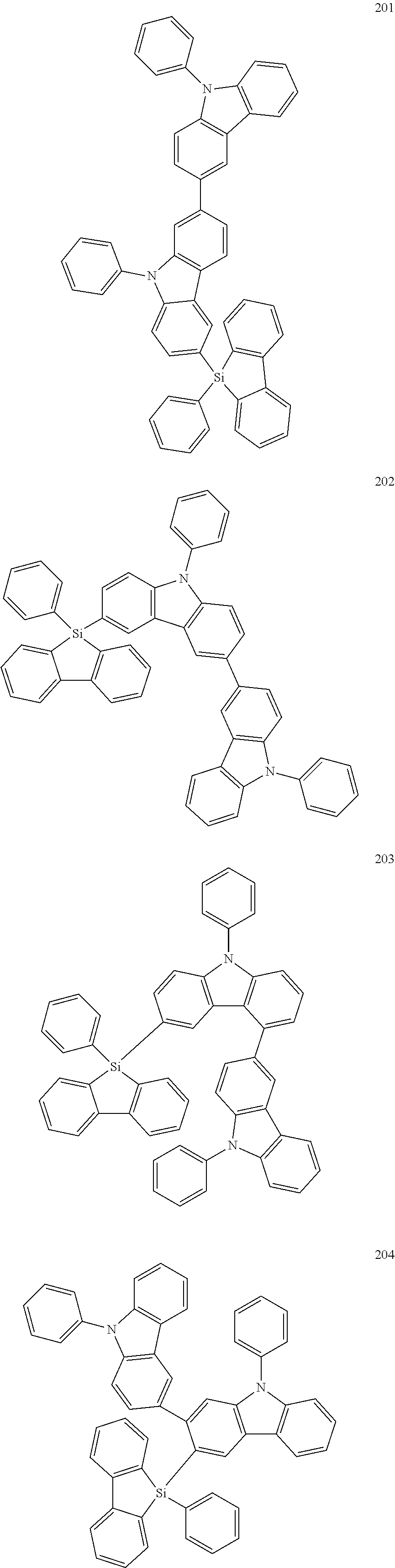

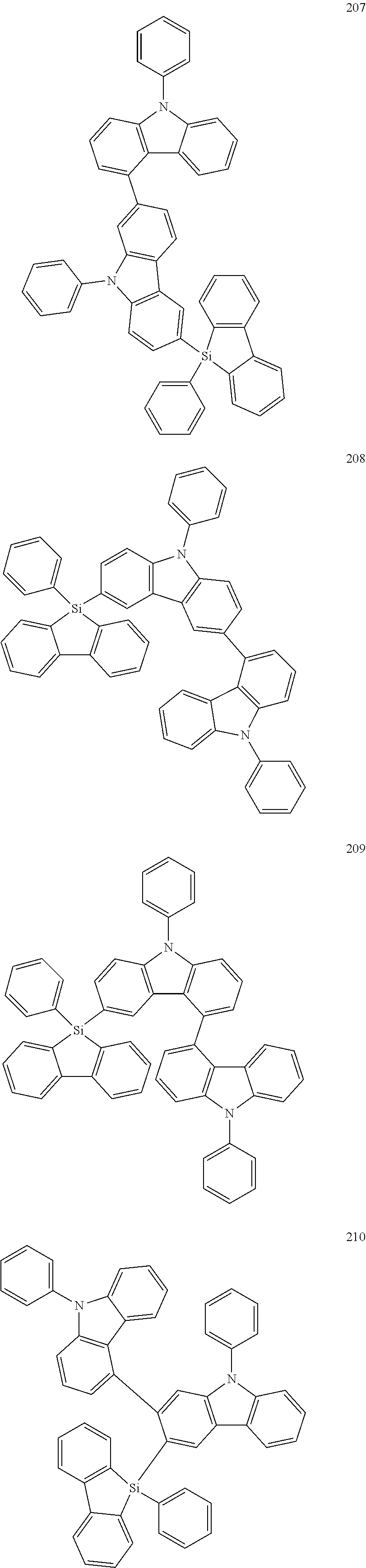

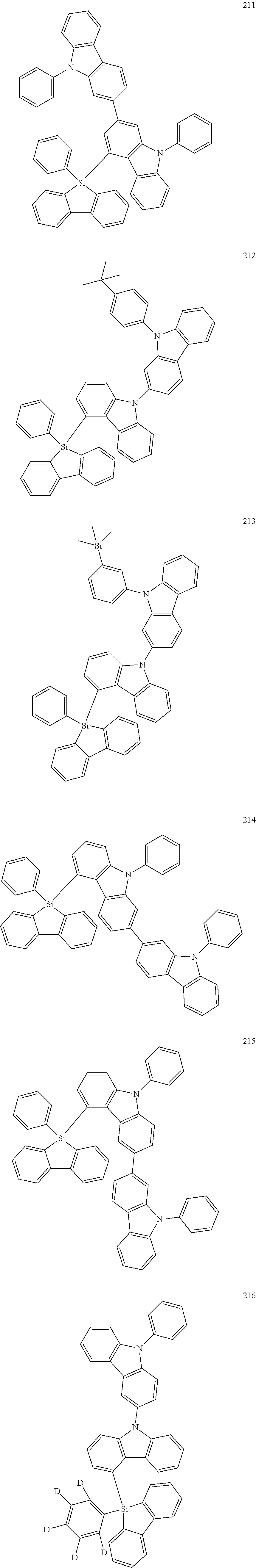

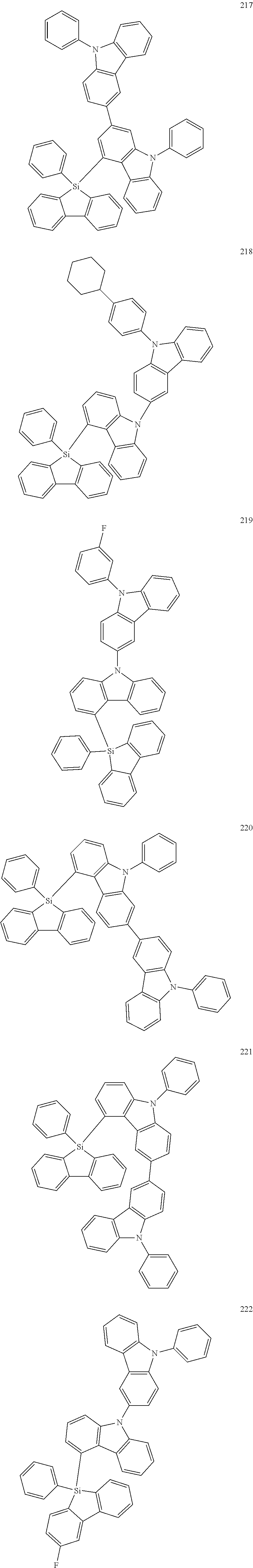

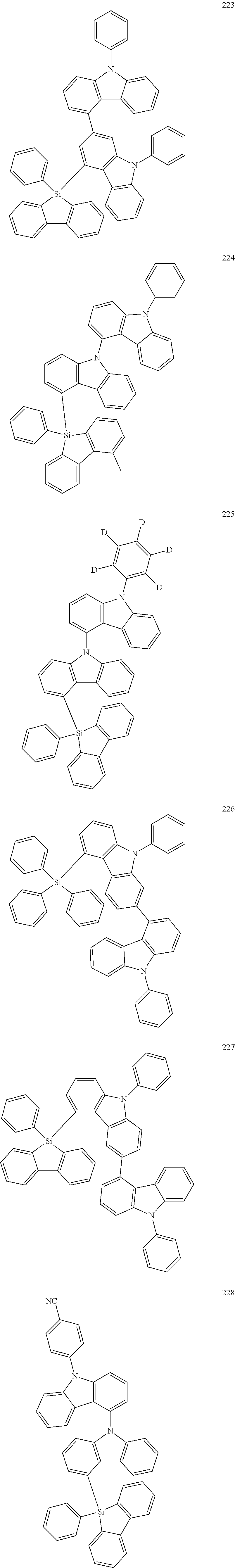

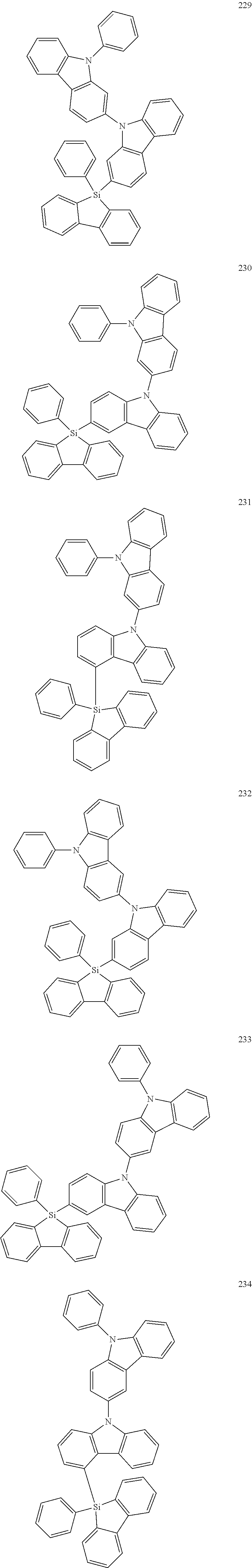

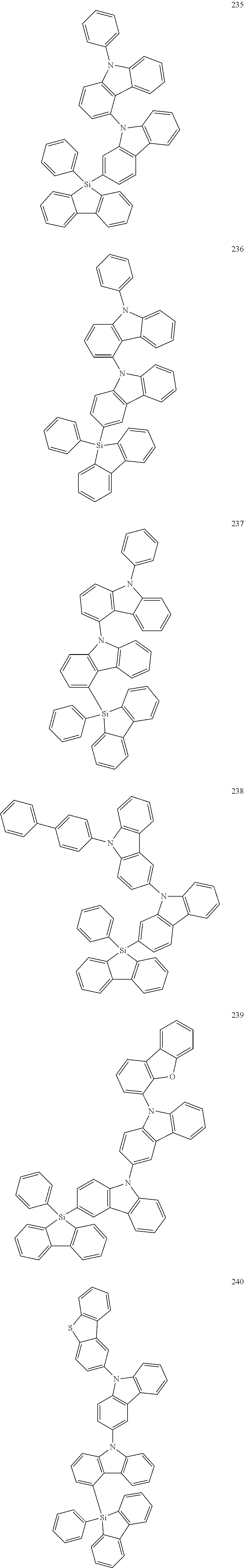

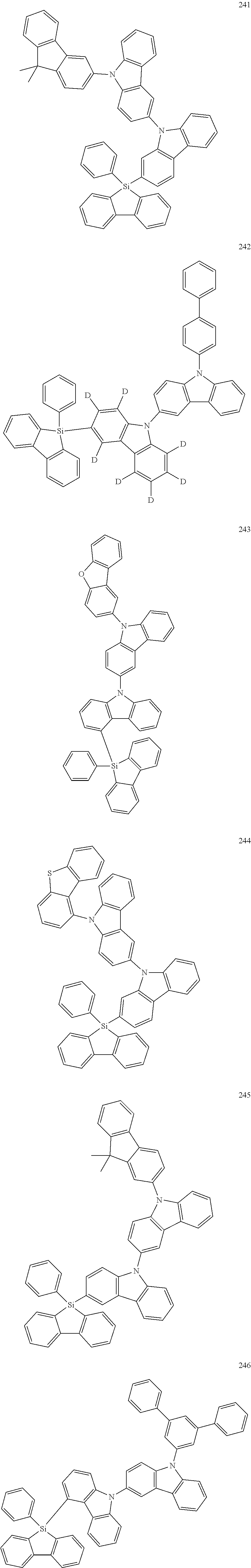

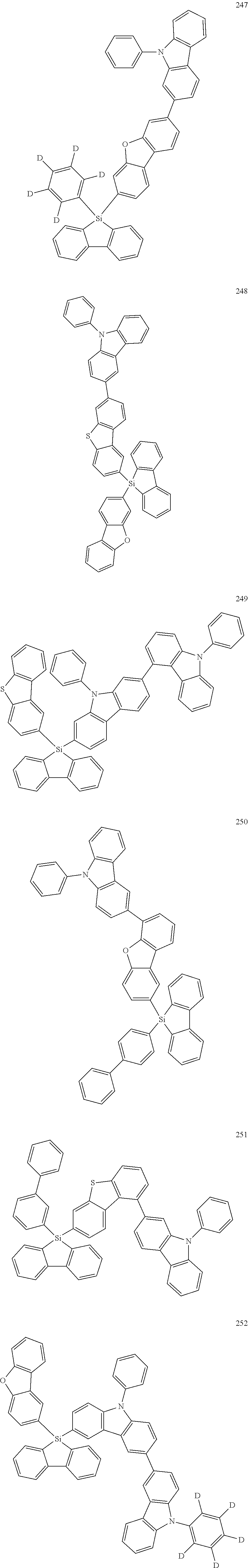

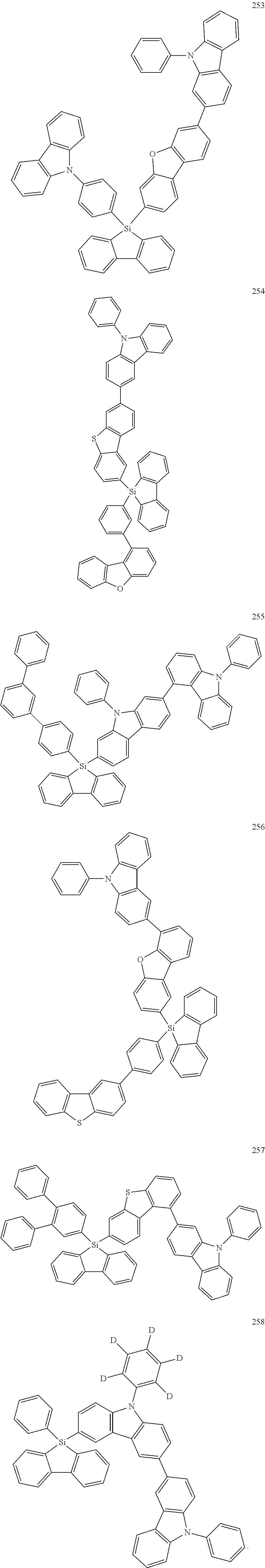

12. An organic electroluminescent device, comprising an anode and a cathode disposed opposite to each other, and a functional layer disposed between the anode and the cathode; wherein the functional layer comprises the organic compound according to claim 1.

13. The organic electroluminescent device according to claim 12, wherein the functional layer comprises an organic light-emitting layer, and the organic light-emitting layer comprises the organic compound.

14. An electronic apparatus, comprising the organic electroluminescent device according to claim 12.
